(19) United States
(12) Patent Application Publication
(10) Pub. No.: US 2026/0114123 A1
(43) Pub. Date: Apr. 23, 2026

(54) LIGHT-EMITTING DIODE, ELECTRONIC DEVICE INCLUDING THE SAME AND COMPOUNDS FOR LIGHT-EMITTING DIODE

(71) Applicant: Samsung Display Co., Ltd., Yongin-si (KR)

(72) Inventors: HAYOUNG YU, Yongin-si (KR); GYEONGHEON KIM, Yongin-si (KR); HOI-LIM KIM, Yongin-si (KR); JUNYOUNG LEE, Yongin-si (KR)

(21) Appl. No.: 19/231,727

(22) Filed: Jun. 9, 2025

(30) Foreign Application Priority Data
Oct. 23, 2024 (KR) 10-2024-0145811

(51) Int. Cl. H10K 50/17; H10K 50/155; H10K 85/60; H10K 101/30; H10K 102/00

(52) U.S. Cl. CPC H10K 50/17; H10K 50/155; H10K 85/626; H10K 85/633; H10K 85/636; H10K 85/6572; H10K 85/6574; H10K 85/6576; H10K 2101/30; H10K 2102/351

(57) ABSTRACT

The present disclosure provides a light-emitting diode including: a first electrode; a second electrode opposite to on the first electrode; and at least one functional layer between the first electrode and the second electrode and including a compound represented by Formula 1. In addition, an electronic device including the light-emitting diode, and a compound for the light-emitting diode are also provided.

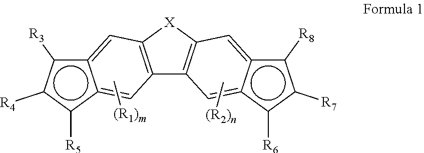

### CROSS-REFERENCE TO RELATED APPLICATION

The present application claims priority to and the benefit of Korean Patent Application No. 10-2024-0145811, filed on Oct. 23, 2024, in the Korean Intellectual Property Office, the entire content of which is incorporated herein by reference.

### BACKGROUND

### 1. Field

One or more embodiments of the present disclosure relate to a light-emitting diode, an electronic device including the light-emitting diode and a compound for the light-emitting diode.

### 2. Description of the Related Art

For example, an organic light-emitting diode may have a structure in which a first electrode is arranged on a substrate, followed sequentially by a hole function layer, a light-emitting layer, an electron function layer, and a second electrode.

Holes injected from the first electrode may be transported to the light-emitting layer through the hole transport layer, while electrons injected from the second electrode may be transported to the light-emitting layer through the electron transport layer. Carriers, such as the holes and the electrons, may be recombined in the light-emitting layer to produce excitons in an excited state. The excitons may decay from the excited state to a ground state to emit light.

Currently, there are continuous demands for improving light-emitting properties such as improved efficiency, operation, and/or lifespan of the light-emitting diode. To fulfill these demands, significant efforts have been focused on hole injection layer materials used in a hole transport region (e.g., in a hole transport layer).

### SUMMARY

One or more aspects of embodiments of the present disclosure are directed toward a light-emitting diode, an electronic device including the light-emitting diode and a compound for the light-emitting diode. Additional aspects will be set forth in part in the description which follows and, in part, will be apparent from the description, or may be learned by practice of the presented embodiments of the disclosure.

It shall be clearly construed by those of ordinary skill in the art to which the present disclosure pertains that aspects of the present disclosure are not limited to the description, and other undescribed technical objects may be clearly understood from the description and appreciated by those of ordinary skill in the art to which the present disclosure pertains.

According to one or more embodiments of the present disclosure, a light-emitting diode may include: a first electrode; a second electrode opposite to (e.g., facing) the first electrode; and at least one functional layer between (e.g., interposed between) the first electrode and the second electrode, wherein the at least one functional layer includes a compound represented by Formula 1:

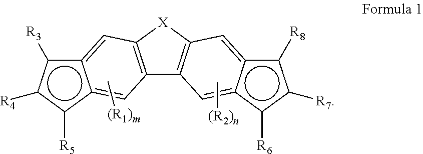

According to one or more embodiments, in Formula 1, X may be O, S, Ga, In, Ge, Sn, Pb, Sb, Bi, Se, or Te, R₁ to R₈ may each independently be selected from among: hydrogen, deuterium, halogens, a haloalkyl group, a hydroxyl group, a cyano group, a nitro group, a trifluoromethyl group, an amine group, an amidino group, a hydrazino group, a hydrazono group, and an alkoxy group; or be a phenyl group, an alkyl group having 1 to 10 carbons, an alkenyl group having 2 to 10 carbons, an alkynyl group having 2 to 10 carbons, an aryl group having 6 to 30 ring-forming carbons, a heteroaryl group having 2 to 30 ring-forming carbons, or any combination thereof, each substituted or unsubstituted with deuterium, a halogen, a hydroxyl group, a cyano group, a nitro group, a trifluoromethyl group, an amidino group, a hydrazino group, a hydrazono group, an alkoxy group, or any combination thereof, and m and n may each independently be an integer between 0 and 2, inclusive.

According to one or more embodiments, the compound represented by Formula 1 may be represented by Formula 1-1 or Formula 1-2:

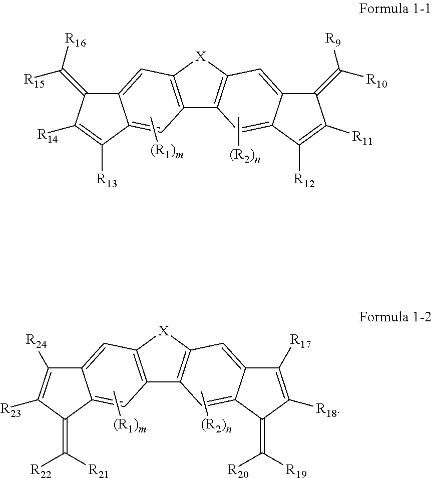

According to one or more embodiments, in Formulae 1-1 and 1-2, X may be selected from among O, S, Ga, In, Ge, Sn, Pb, Sb, Bi, Se, and Te,

R₁, R₂, and R₉ to R₂₄ may each independently be: hydrogen; deuterium; a halogen; a haloalkyl group; a hydroxyl group; a cyano group; a nitro group; a trifluoromethyl group; an amine group; an amidino group; a hydrazino group; a hydrazono group; an alkoxy group; or a phenyl group, an alkyl group having 1 to 10 carbons, an alkenyl group having 2 to 10 carbons, an alkynyl group having 2 to 10 carbons, an aryl group having 6 to 30 ring-forming carbons, a heteroaryl group having 2 to 30 ring-forming carbons, or any combination thereof, each substituted or unsubstituted with deuterium, a halogen, a haloalkyl group, a hydroxyl group, a cyano group, a nitro group, a trifluoromethyl group, an amine group, an amidino group, a hydrazino group, a hydrazono group, an alkoxy group, or any combination thereof (e.g., R₁, R₂, and R₉ to R₂₄ may each independently be selected from: the group consisting of hydrogen, deuterium, halogens, a haloalkyl group, a hydroxyl group, a cyano group, a nitro group, a trifluoromethyl group, an amine group, an amidino group, a hydrazino group, a hydrazono group, and an alkoxy group; or be a phenyl group, an alkyl group having 1 to 10 carbons, an alkenyl group having 2 to 10 carbons, an alkynyl group having 2 to 10 carbons, an aryl group having 6 to 30 ring-forming carbons, a heteroaryl group having 2 to 30 ring-forming carbons, or any combination thereof, each substituted or unsubstituted with hydrogen, deuterium, halogens, a haloalkyl group, a hydroxyl group, a cyano group, a nitro group, a trifluoromethyl group, an amine group, an amidino group, a hydrazino group, a hydrazono group, an alkoxy group, or any combination thereof), and

m and n may each independently be an integer between 0 and 2, inclusive.

According to one or more embodiments, the R₁, R₂, R₁₉, R₂₀, R₂₁, and R₂₂ may each independently be: a haloalkyl group, a hydroxyl group, a cyano group, a nitro group, a trifluoromethyl group, an amine group, or an alkoxy group; or be an alkenyl group having 2 to 10 carbons substituted or unsubstituted with a haloalkyl group, a hydroxyl group, a cyano group, a nitro group, a trifluoromethyl group, an amine group, an alkoxy group, or any combination thereof (e.g., R₁, R₂, R₁₉, R₂₀, R₂₁, and R₂₂ may each independently be: a haloalkyl group, a hydroxyl group, a cyano group, a nitro group, a trifluoromethyl group, an amine group, or an alkoxy group; or an alkenyl group having 2 to 10 carbons, substituted or unsubstituted with a haloalkyl group, a hydroxyl group, a cyano group, a nitro group, a trifluoromethyl group, an amine group, an alkoxy group, or any combination thereof).

According to one or more embodiments, the X may be O or S.

According to one or more embodiments, the compound represented by the Formula 1 may include at least one selected from among compounds of Compound Group 1 and/or at least one selected from among compounds of Compound Group 2:

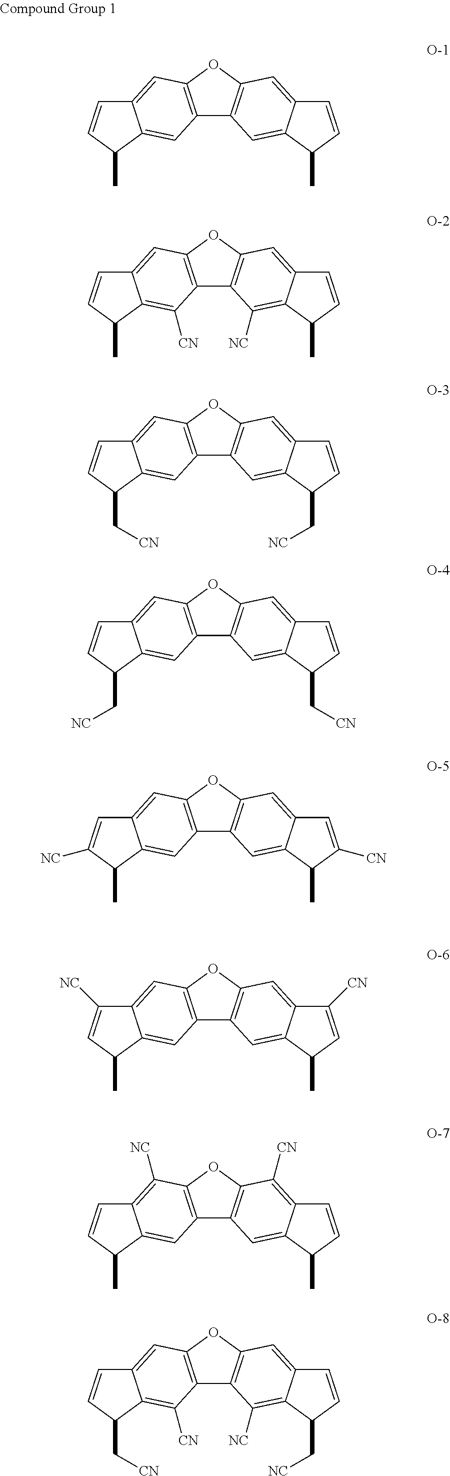

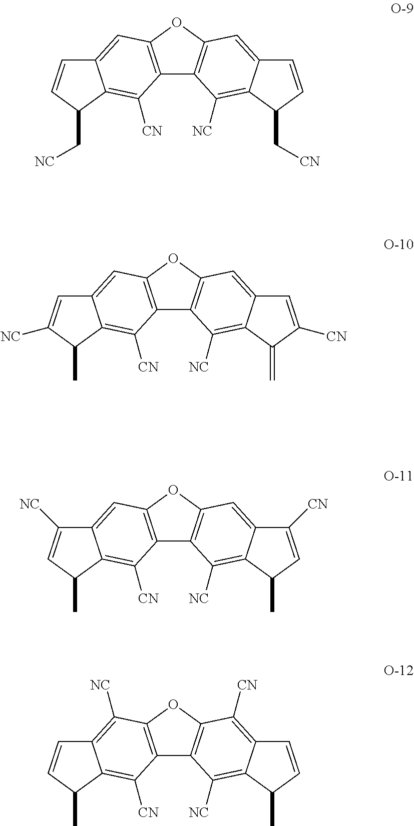 [SMILES: N#CC[C@H]1C=Cc2cc3oc4cc5c(c(C#N)c4c3c(C#N)c21)[C@H](CC#N)C=C5 ; C=C1C(C#N)=Cc2cc3oc4cc5c(c(C#N)c4c3c(C#N)c21)[C@@H](C)C(C#N)=C5 ; C[C@@H]1C=C(C#N)c2cc3oc4cc5c(c(C#N)c4c3c(C#N)c21)[C@@H](C)C=C5C#N ; C[C@@H]1C=Cc2c1c(C#N)c1c(oc3c(C#N)c4c(c(C#N)c31)[C@@H](C)C=C4)c2C#N]

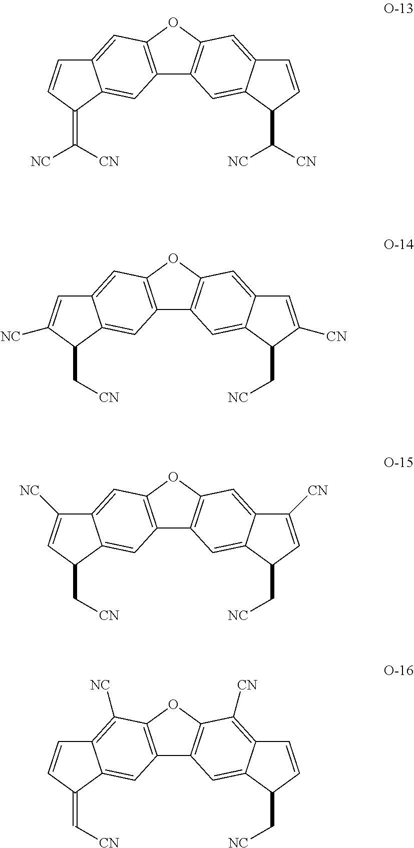 [SMILES: N#CC(C#N)=C1C=Cc2cc3oc4cc5c(cc4c3cc21)[C@H](C(C#N)C#N)C=C5 ; N#CC[C@@H]1C(C#N)=Cc2cc3oc4cc5c(cc4c3cc21)[C@@H](CC#N)C(C#N)=C5 ; N#CC[C@H]1C=C(C#N)c2cc3oc4cc5c(cc4c3cc21)[C@H](CC#N)C=C5C#N ; N#C/C=C1/C=Cc2c1cc1c(oc3c(C#N)c4c(cc31)[C@H](CC#N)C=C4)c2C#N]

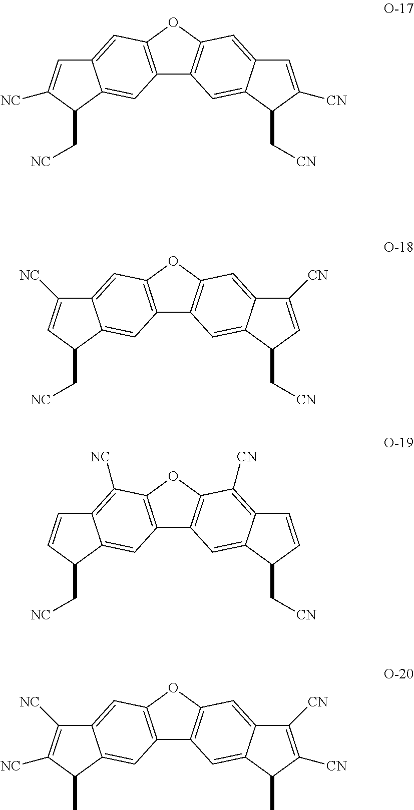 [SMILES: N#CC[C@@H]1C(C#N)=Cc2cc3oc4cc5c(cc4c3cc21)[C@@H](CC#N)C(C#N)=C5 ; N#CC[C@H]1C=C(C#N)c2cc3oc4cc5c(cc4c3cc21)[C@H](CC#N)C=C5C#N ; N#CC[C@H]1C=Cc2c1cc1c(oc3c(C#N)c4c(cc31)[C@H](CC#N)C=C4)c2C#N ; C[C@@H]1C(C#N)=C(C#N)c2cc3oc4cc5c(cc4c3cc21)[C@@H](C)C(C#N)=C5C#N]

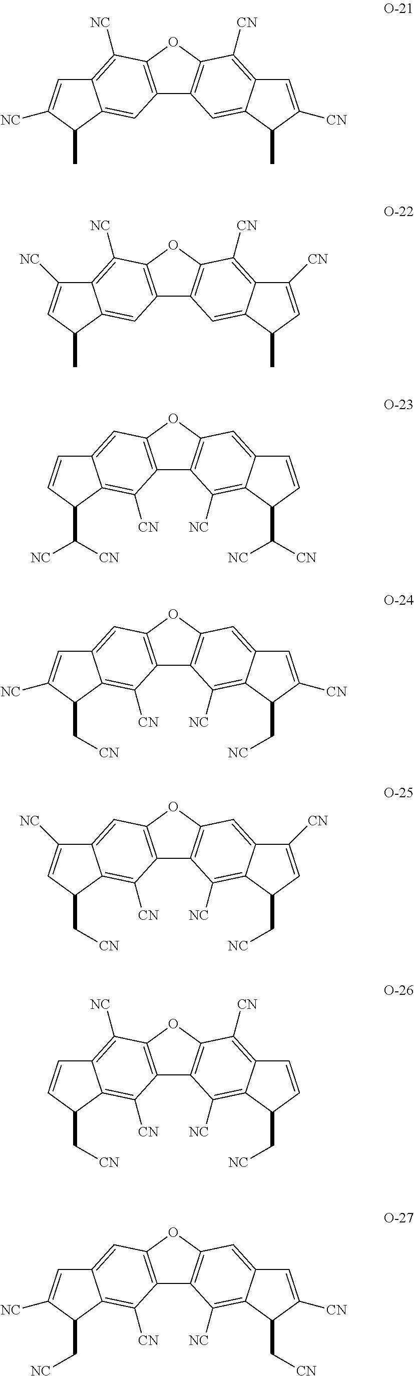

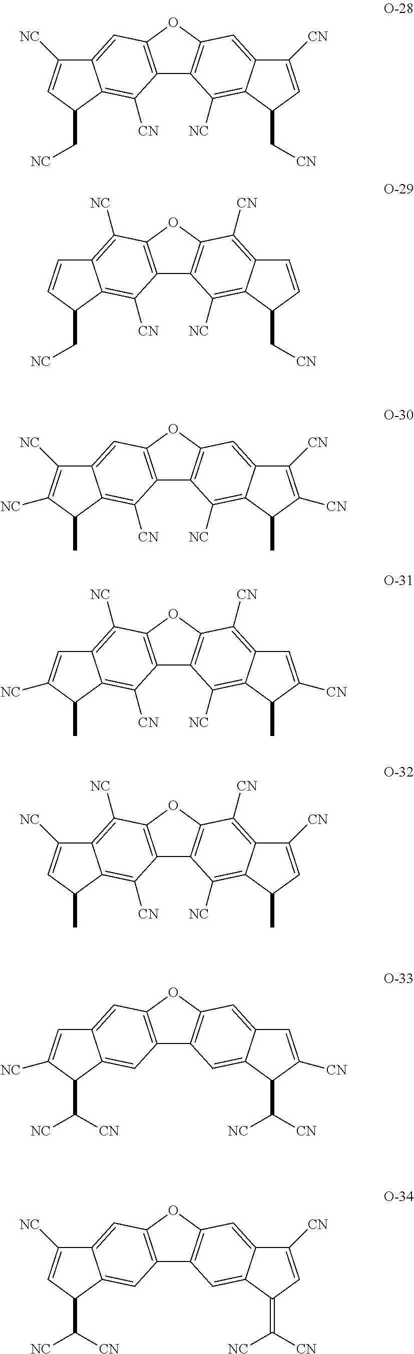

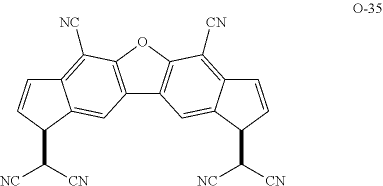 [SMILES: N#Cc1c2c(cc3c1oc1c(C#N)c4c(cc13)[C@@H](C(C#N)C#N)C=C4)[C@H](C(C#N)C#N)C=C2]

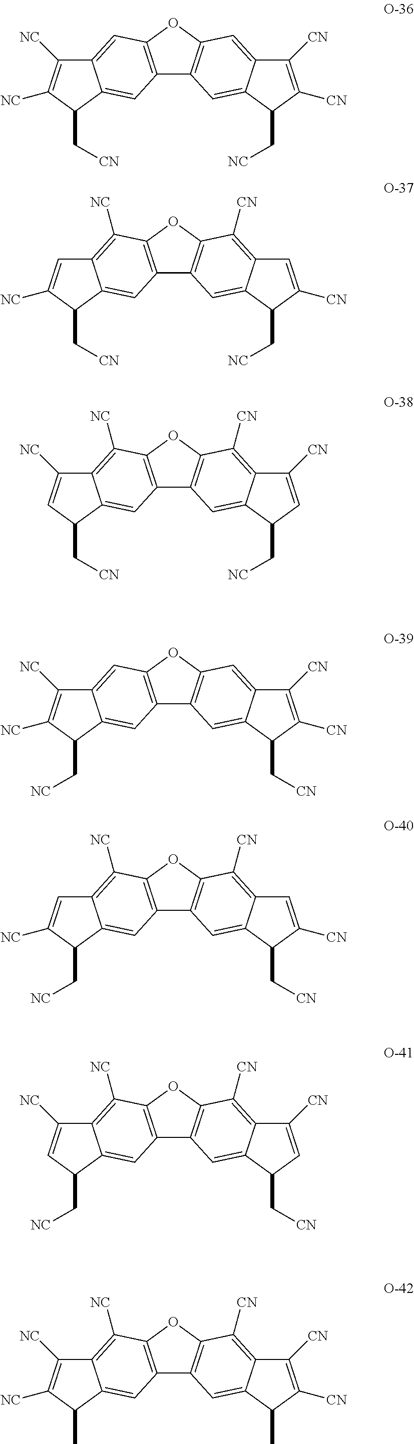

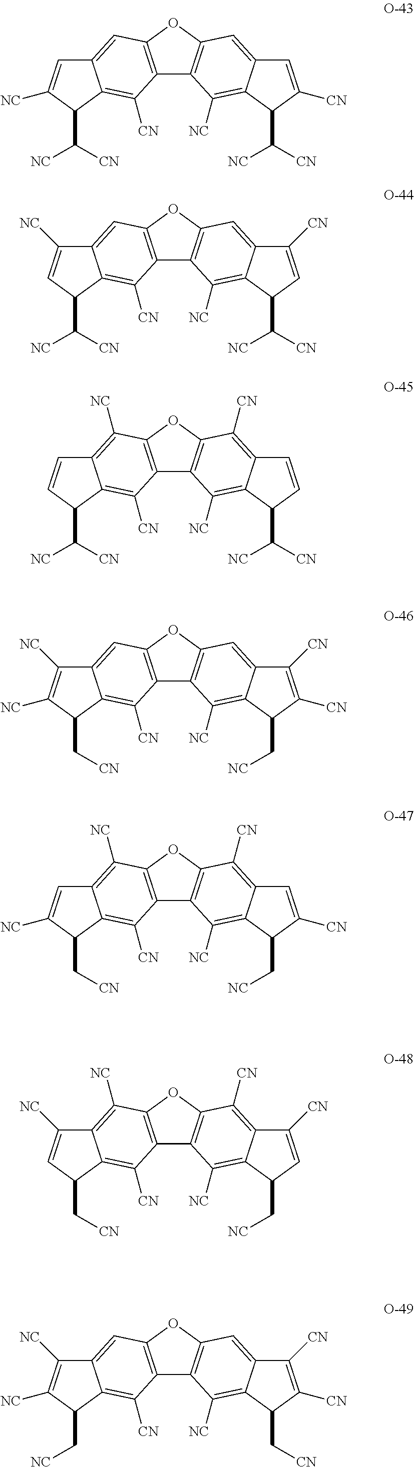

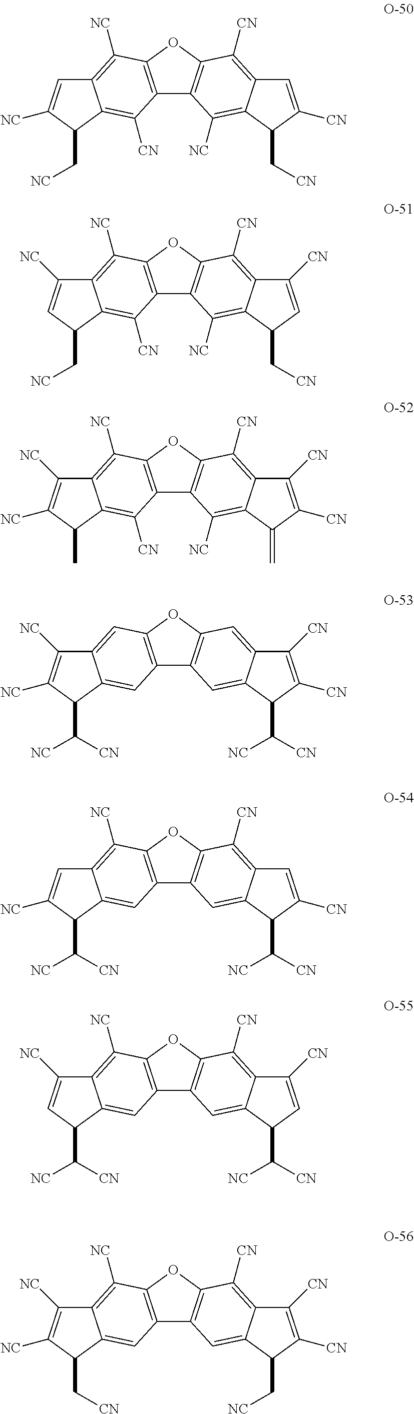

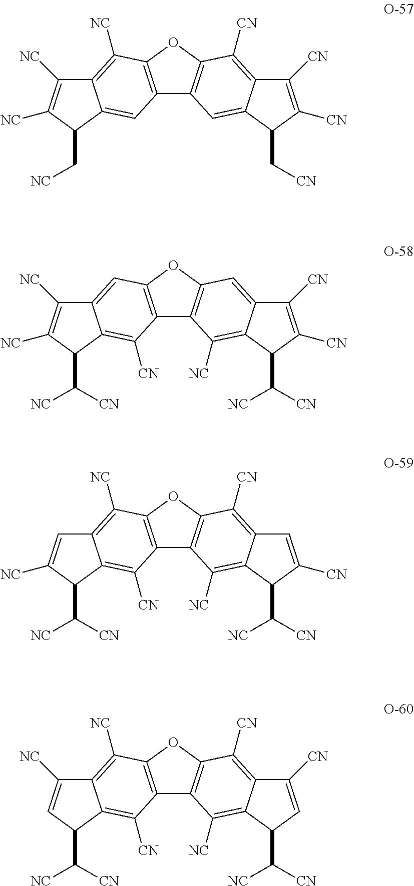 [SMILES: N#CC[C@@H]1C(C#N)=C(C#N)c2c1cc1c(oc3c(C#N)c4c(cc31)[C@@H](CC#N)C(C#N)=C4C#N)c2C#N ; N#CC1=C(C#N)[C@@H](C(C#N)C#N)c2c1cc1oc3cc4c(c(C#N)c3c1c2C#N)[C@@H](C(C#N)C#N)C(C#N)=C4C#N ; N#CC1=Cc2c(c(C#N)c3c(oc4c(C#N)c5c(c(C#N)c43)[C@@H](C(C#N)C#N)C(C#N)=C5)c2C#N)[C@@H]1C(C#N)C#N ; N#CC1=C[C@@H](C(C#N)C#N)c2c1c(C#N)c1oc3c(C#N)c4c(c(C#N)c3c1c2C#N)[C@@H](C(C#N)C#N)C=C4C#N]

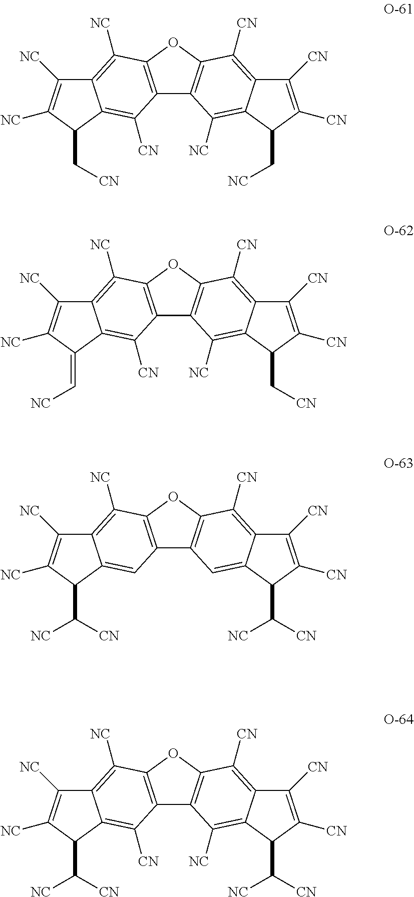 [SMILES: N#CC[C@@H]1C(C#N)=C(C#N)c2c1c(C#N)c1c(oc3c(C#N)c4c(c(C#N)c31)[C@@H](CC#N)C(C#N)=C4C#N)c2C#N ; N#C/C=C1\C(C#N)=C(C#N)c2c1c(C#N)c1c(oc3c(C#N)c4c(c(C#N)c31)[C@H](CC#N)C(C#N)=C4C#N)c2C#N ; N#CC1=C(C#N)[C@@H](C(C#N)C#N)c2cc3c(oc4c(C#N)c5c(cc43)[C@@H](C(C#N)C#N)C(C#N)=C5C#N)c(C#N)c21 ; N#CC1=C(C#N)[C@@H](C(C#N)C#N)c2c1c(C#N)c1oc3c(C#N)c4c(c(C#N)c3c1c2C#N)[C@@H](C(C#N)C#N)C(C#N)=C4C#N]

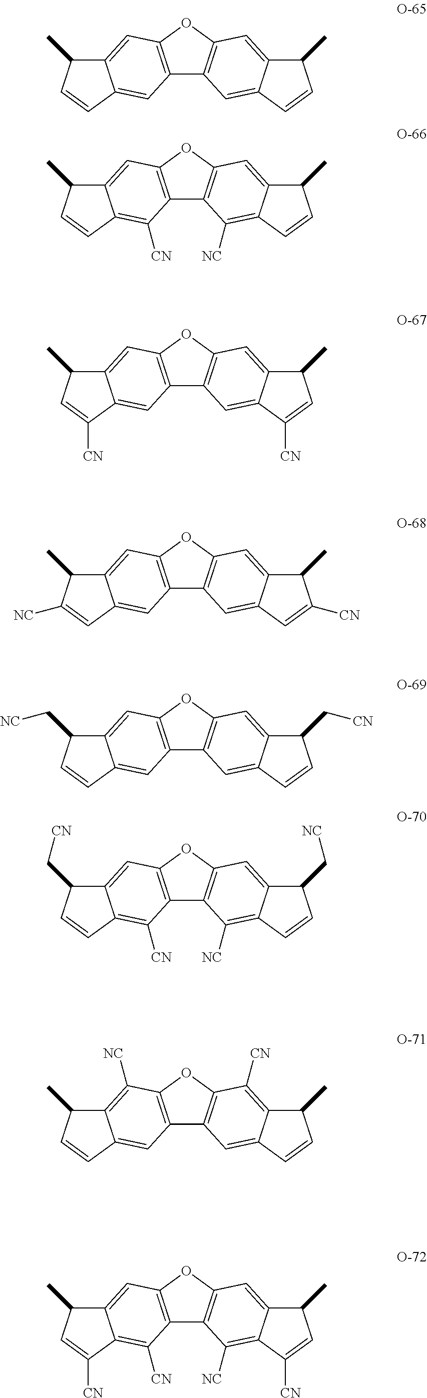

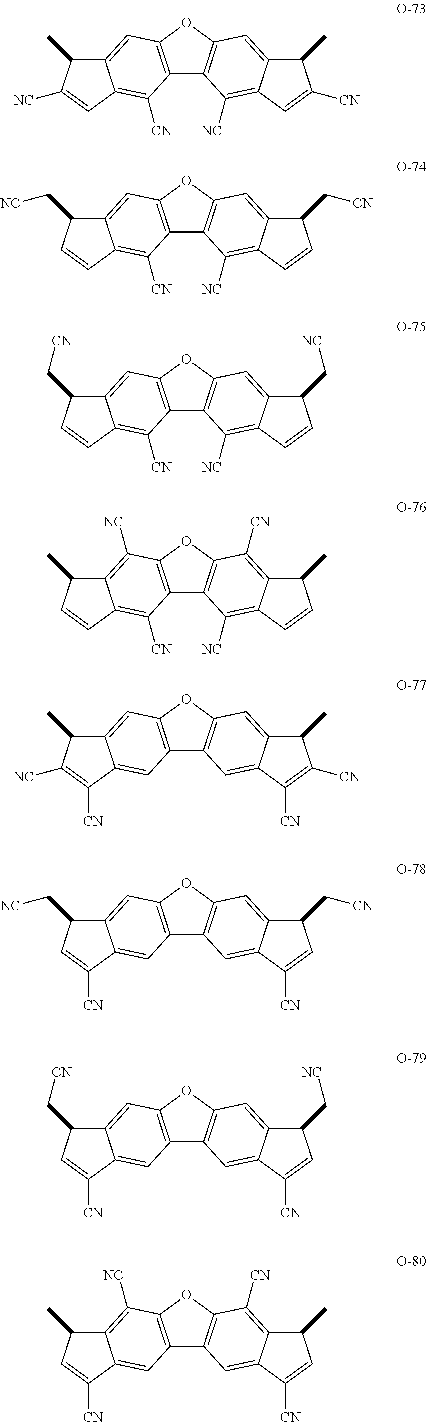

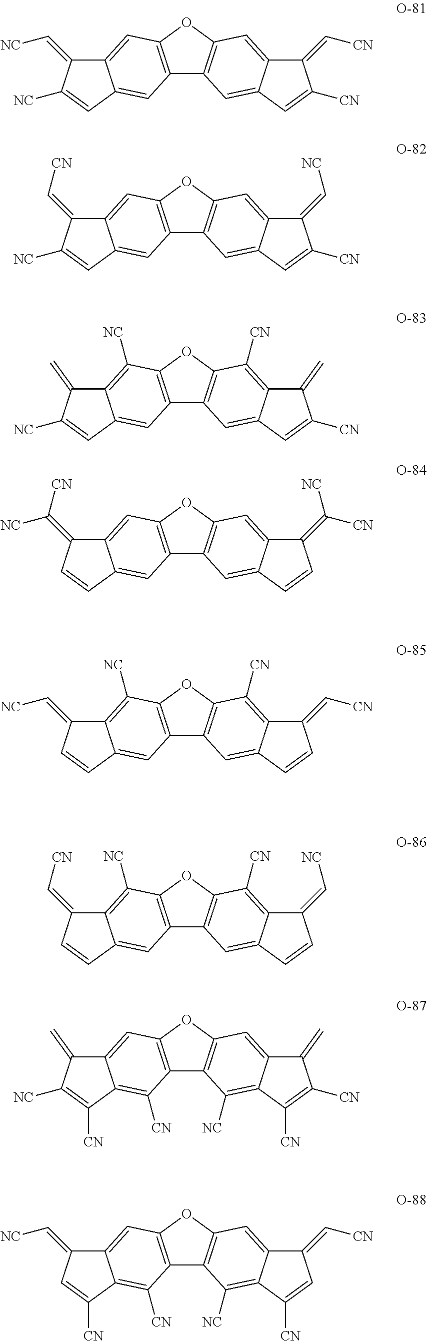

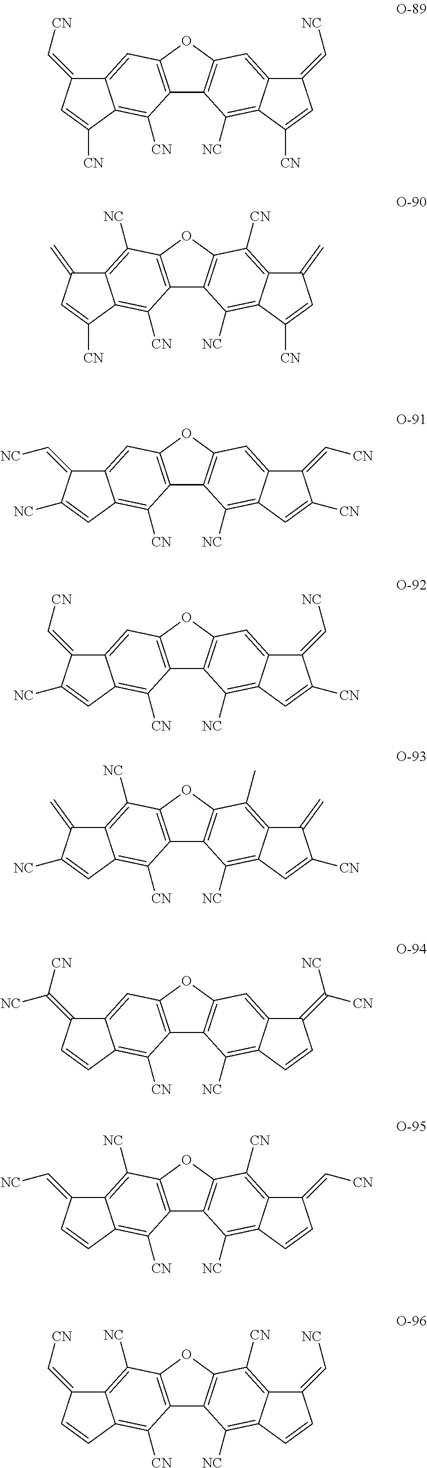

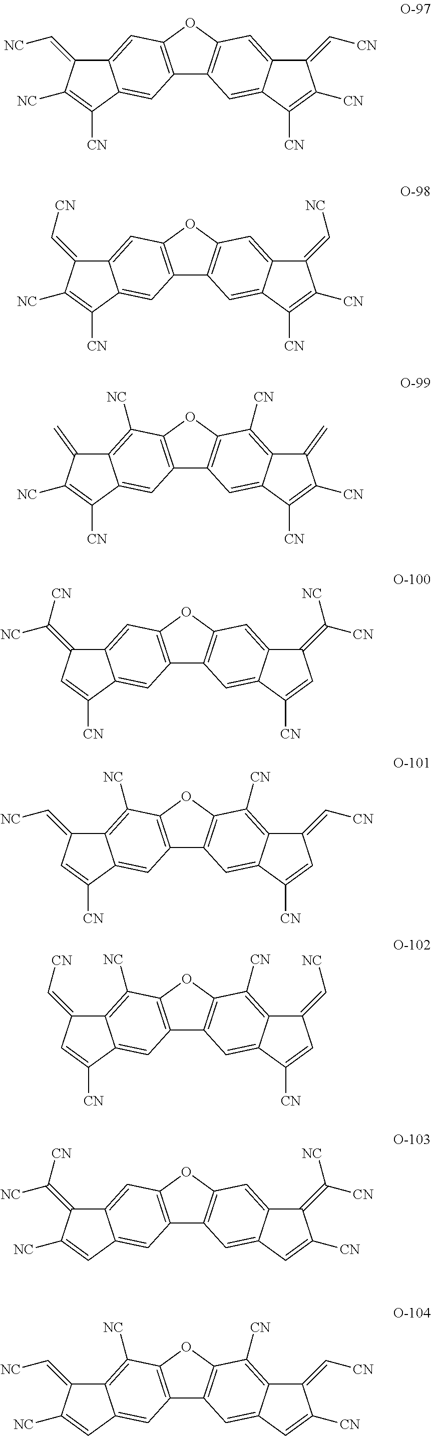

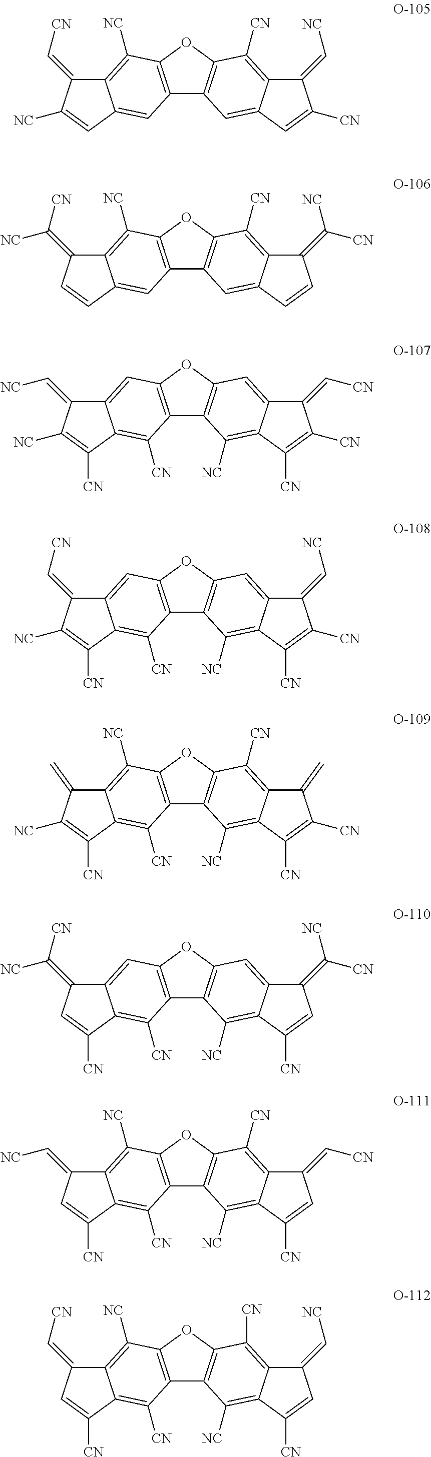

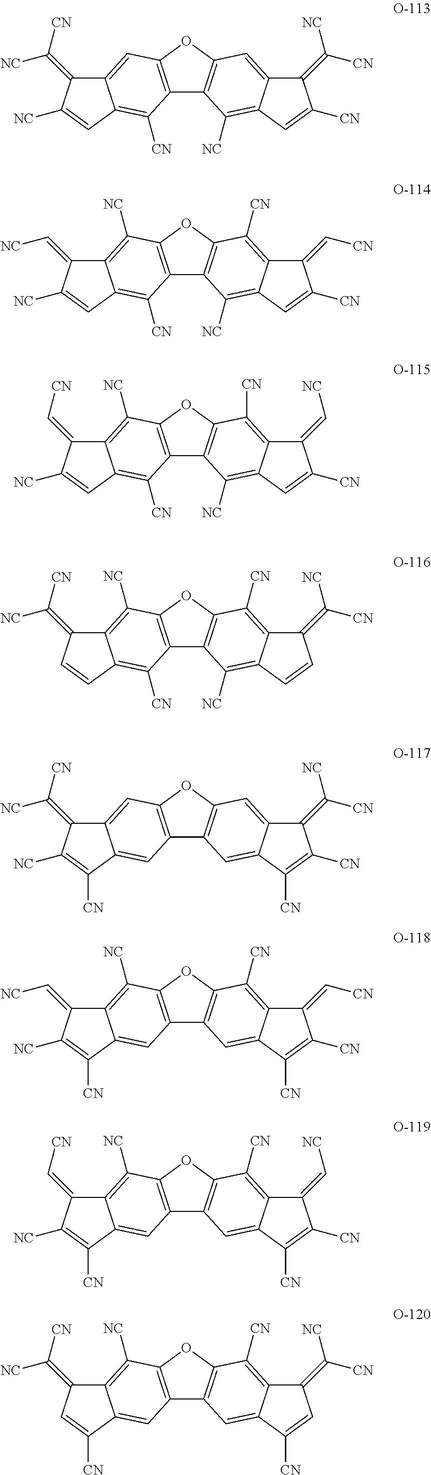

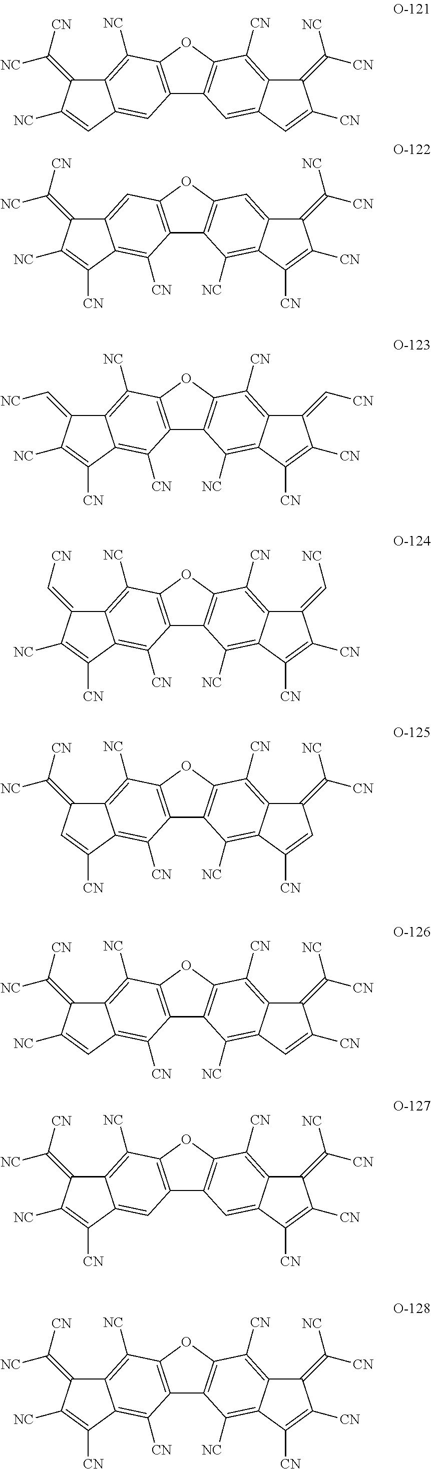

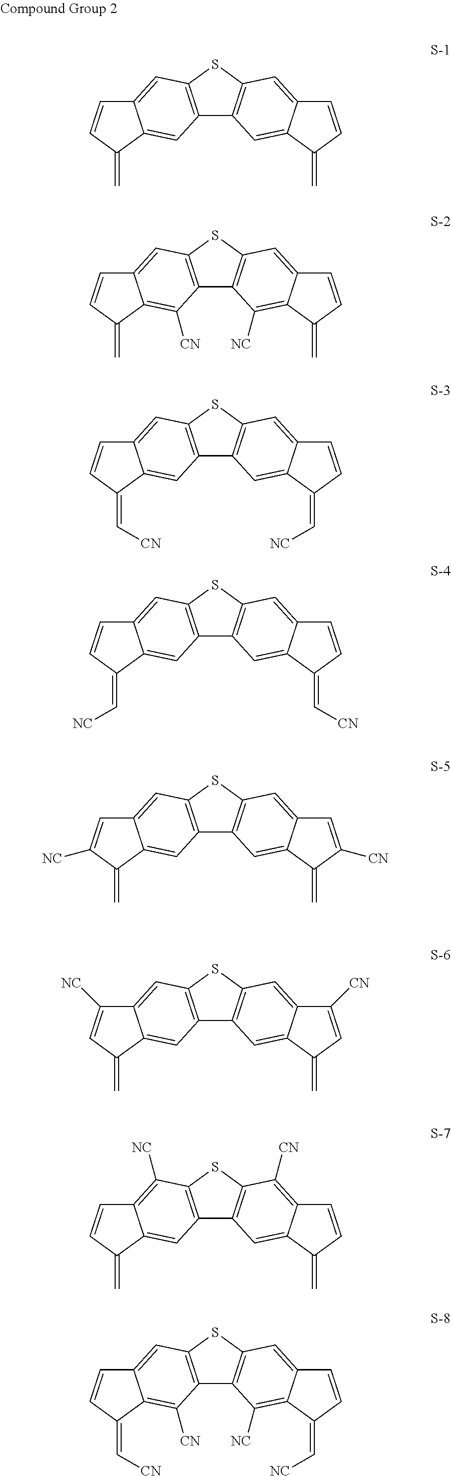

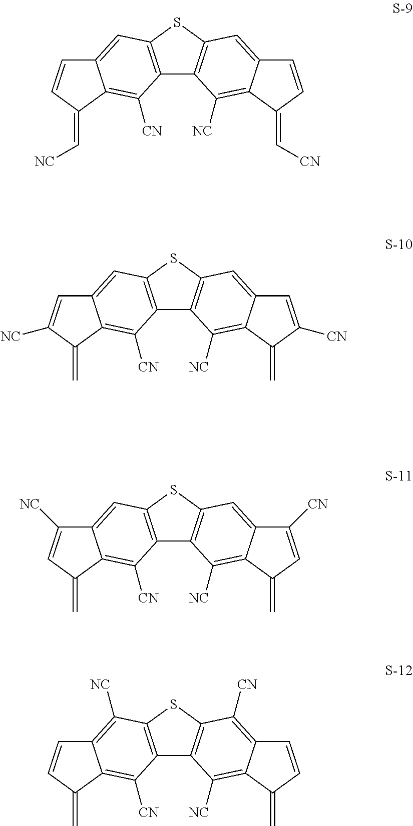 [SMILES: N#C/C=C1\C=Cc2cc3sc4cc5c(c(C#N)c4c3c(C#N)c21)/C(=C/C#N)C=C5 ; C=C1C(C#N)=Cc2cc3sc4cc5c(c(C#N)c4c3c(C#N)c21)C(=C)C(C#N)=C5 ; C=C1C=C(C#N)c2cc3sc4cc5c(c(C#N)c4c3c(C#N)c21)C(=C)C=C5C#N ; C=C1C=Cc2c1c(C#N)c1c(sc3c(C#N)c4c(c(C#N)c31)C(=C)C=C4)c2C#N]

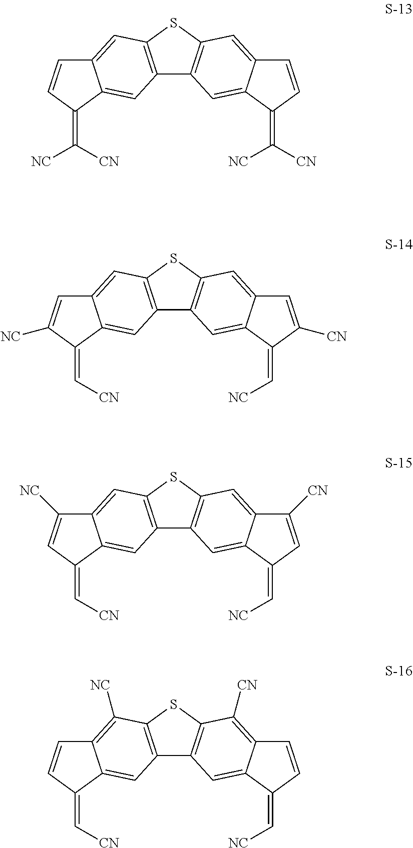 [SMILES: N#CC(C#N)=C1C=Cc2cc3sc4cc5c(cc4c3cc21)C(=C(C#N)C#N)C=C5 ; N#C/C=C1/C(C#N)=Cc2cc3sc4cc5c(cc4c3cc21)/C(=C\C#N)C(C#N)=C5 ; N#C/C=C1/C=C(C#N)c2cc3sc4cc5c(cc4c3cc21)/C(=C\C#N)C=C5C#N ; N#C/C=C1/C=Cc2c1cc1c(sc3c(C#N)c4c(cc31)/C(=C\C#N)C=C4)c2C#N]

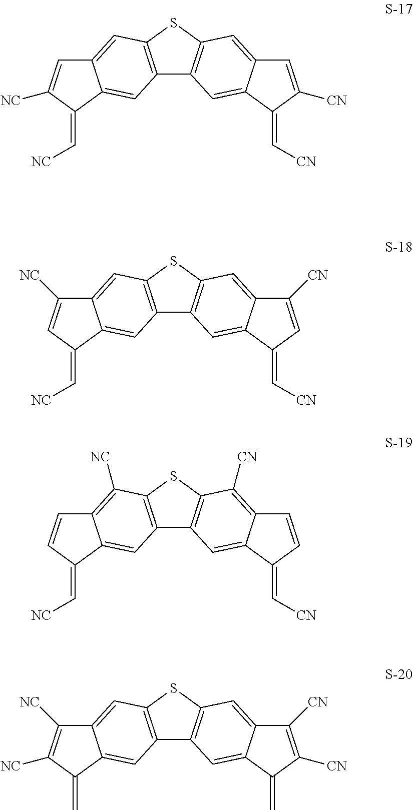 [SMILES: N#C/C=C1\C(C#N)=Cc2cc3sc4cc5c(cc4c3cc21)/C(=C/C#N)C(C#N)=C5 ; N#C/C=C1\C=C(C#N)c2cc3sc4cc5c(cc4c3cc21)/C(=C/C#N)C=C5C#N ; N#C/C=C1\C=Cc2c1cc1c(sc3c(C#N)c4c(cc31)/C(=C/C#N)C=C4)c2C#N ; C=C1C(C#N)=C(C#N)c2cc3sc4cc5c(cc4c3cc21)C(=C)C(C#N)=C5C#N]

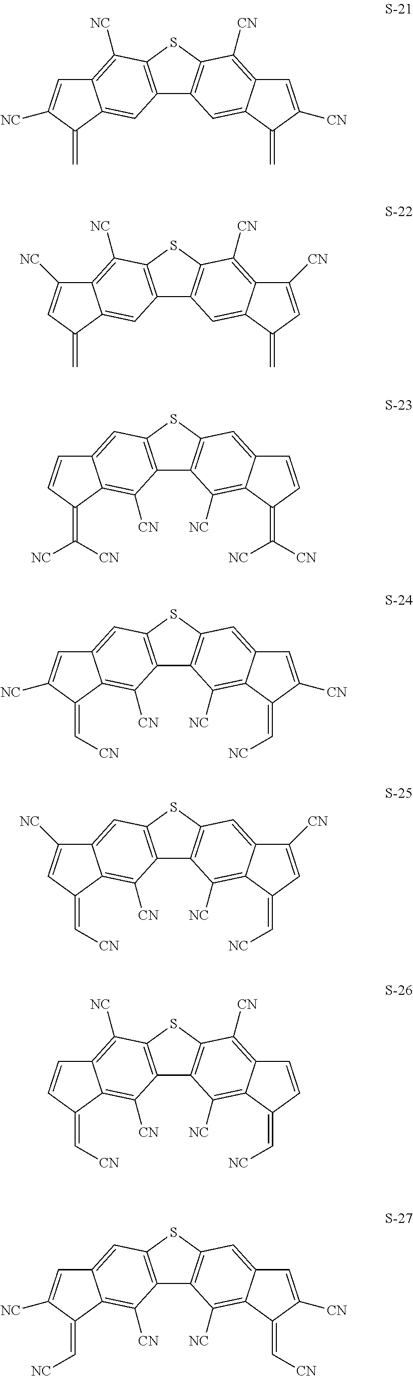

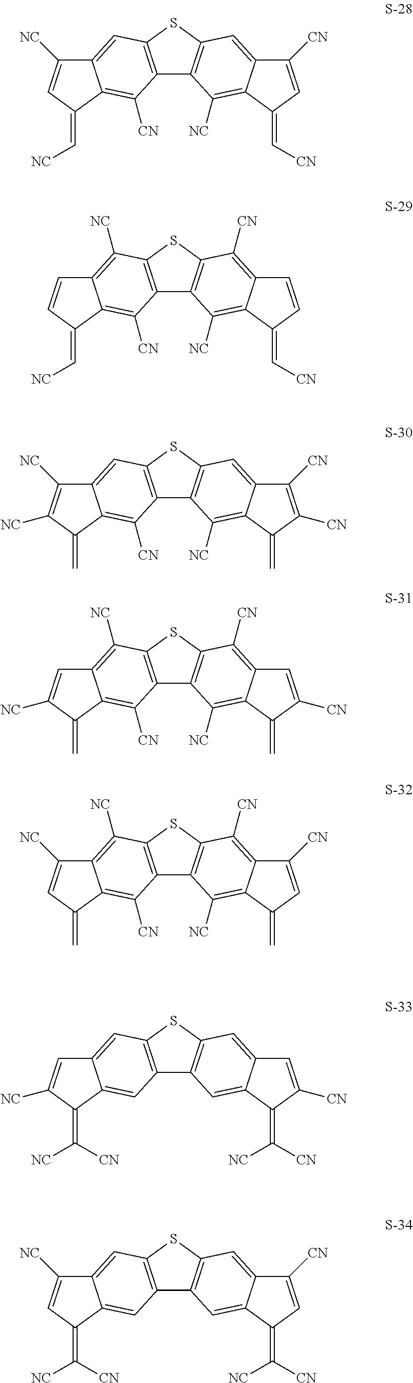

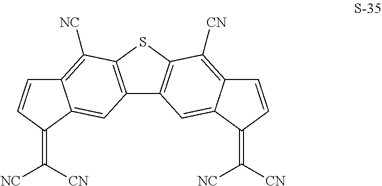 [SMILES: N#CC(C#N)=C1C=Cc2c1cc1c(sc3c(C#N)c4c(cc31)C(=C(C#N)C#N)C=C4)c2C#N]

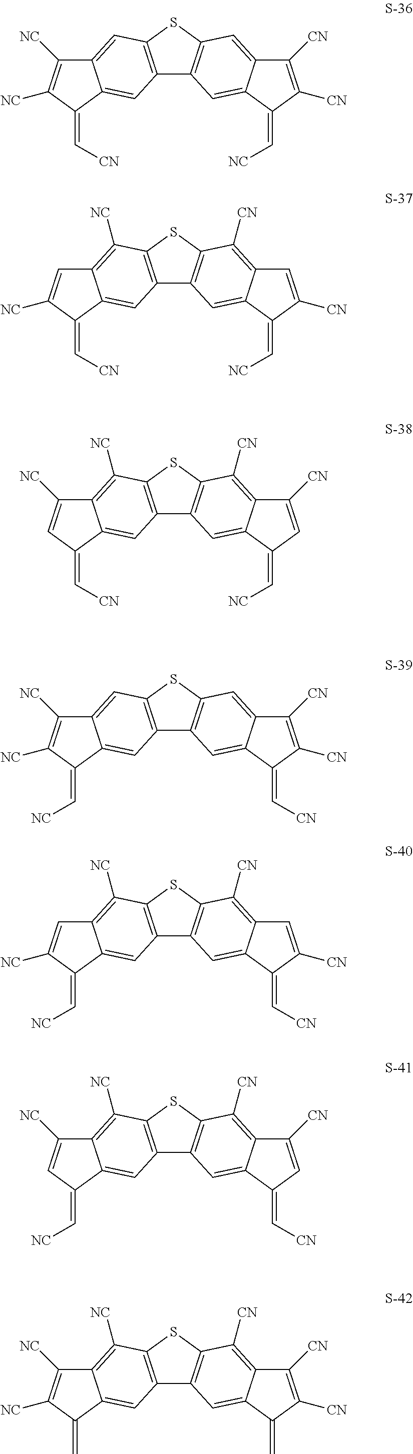

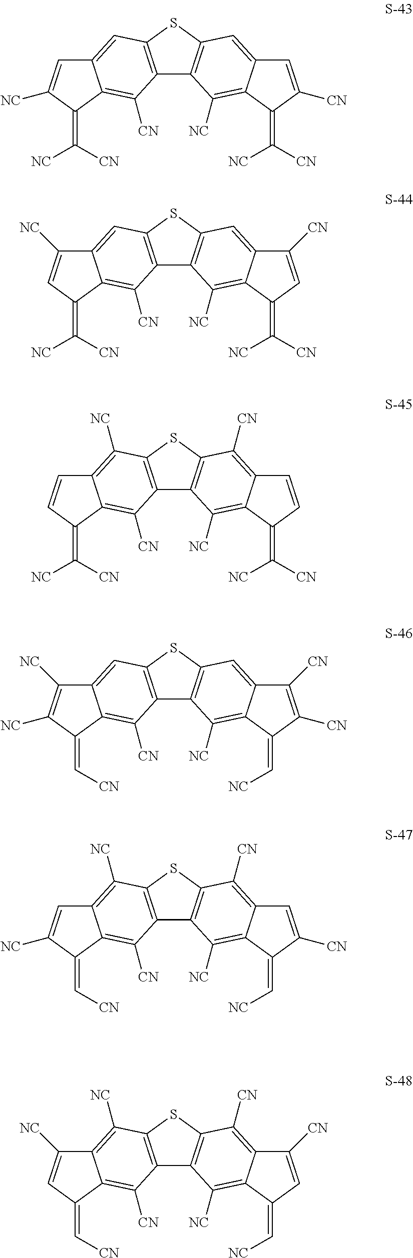 [SMILES: N#CC1=Cc2cc3sc4cc5c(c(C#N)c4c3c(C#N)c2C1=C(C#N)C#N)C(=C(C#N)C#N)C(C#N)=C5 ; N#CC1=CC(=C(C#N)C#N)c2c1cc1sc3cc4c(c(C#N)c3c1c2C#N)C(=C(C#N)C#N)C=C4C#N ; N#CC(C#N)=C1C=Cc2c1c(C#N)c1c(sc3c(C#N)c4c(c(C#N)c31)C(=C(C#N)C#N)C=C4)c2C#N ; N#C/C=C1/C(C#N)=C(C#N)c2cc3sc4cc5c(c(C#N)c4c3c(C#N)c21)/C(=C\C#N)C(C#N)=C5C#N ; N#C/C=C1/C(C#N)=Cc2c1c(C#N)c1c(sc3c(C#N)c4c(c(C#N)c31)/C(=C\C#N)C(C#N)=C4)c2C#N ; N#C/C=C1/C=C(C#N)c2c1c(C#N)c1c(sc3c(C#N)c4c(c(C#N)c31)/C(=C\C#N)C=C4C#N)c2C#N]

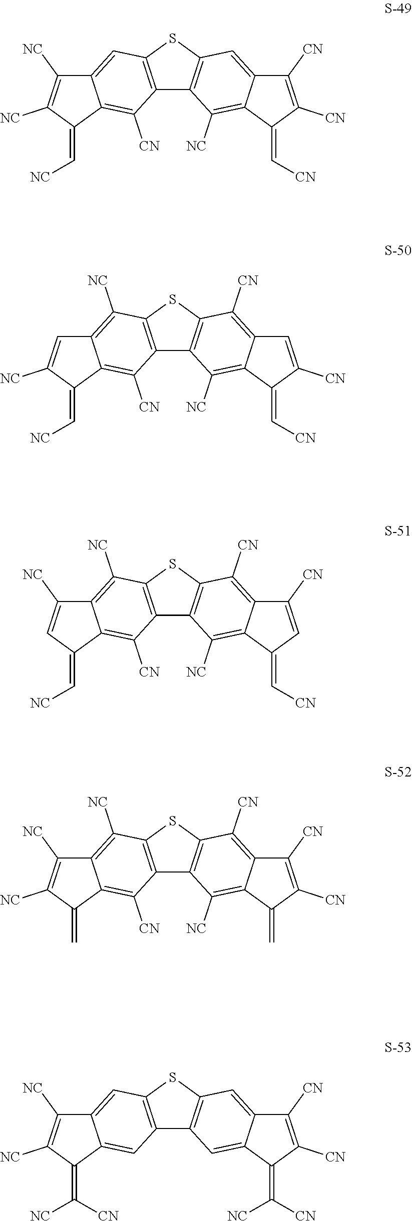 [SMILES: N#C/C=C1\C(C#N)=C(C#N)c2cc3sc4cc5c(c(C#N)c4c3c(C#N)c21)/C(=C/C#N)C(C#N)=C5C#N ; N#C/C=C1\C(C#N)=Cc2c1c(C#N)c1c(sc3c(C#N)c4c(c(C#N)c31)/C(=C/C#N)C(C#N)=C4)c2C#N ; N#C/C=C1\C=C(C#N)c2c1c(C#N)c1c(sc3c(C#N)c4c(c(C#N)c31)/C(=C/C#N)C=C4C#N)c2C#N ; C=C1C(C#N)=C(C#N)c2c1c(C#N)c1c(sc3c(C#N)c4c(c(C#N)c31)C(=C)C(C#N)=C4C#N)c2C#N ; N#CC(C#N)=C1C(C#N)=C(C#N)c2cc3sc4cc5c(cc4c3cc21)C(=C(C#N)C#N)C(C#N)=C5C#N]

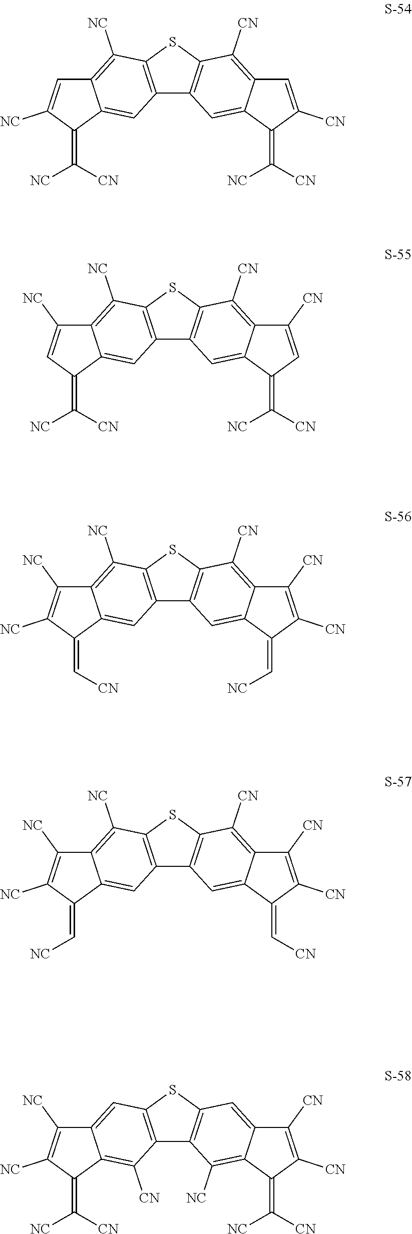 [SMILES: N#CC1=Cc2c(cc3c(sc4c(C#N)c5c(cc43)C(=C(C#N)C#N)C(C#N)=C5)c2C#N)C1=C(C#N)C#N ; N#CC1=CC(=C(C#N)C#N)c2cc3c(sc4c(C#N)c5c(cc43)C(=C(C#N)C#N)C=C5C#N)c(C#N)c21 ; N#C/C=C1/C(C#N)=C(C#N)c2c1cc1c(sc3c(C#N)c4c(cc31)/C(=C\C#N)C(C#N)=C4C#N)c2C#N ; N#C/C=C1\C(C#N)=C(C#N)c2c1cc1c(sc3c(C#N)c4c(cc31)/C(=C/C#N)C(C#N)=C4C#N)c2C#N ; N#CC(C#N)=C1C(C#N)=C(C#N)c2cc3sc4cc5c(c(C#N)c4c3c(C#N)c21)C(=C(C#N)C#N)C(C#N)=C5C#N]

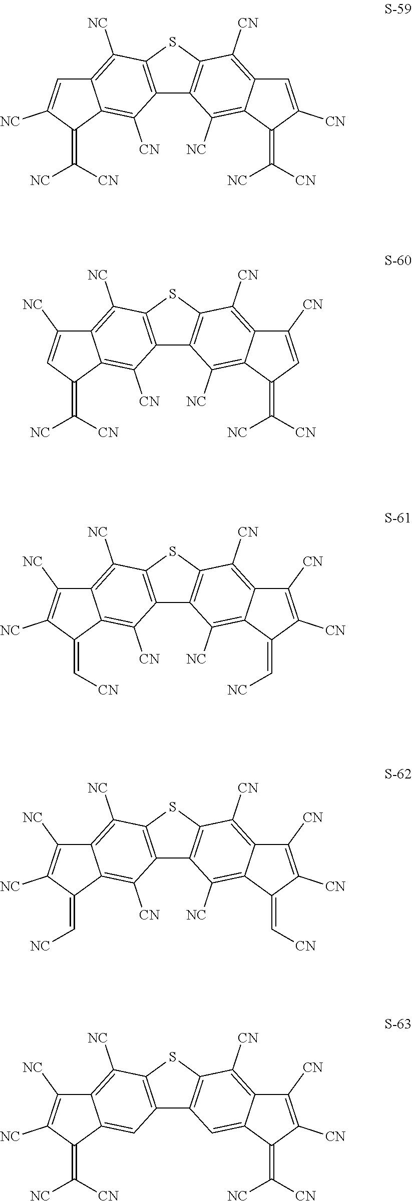 [SMILES: N#CC1=Cc2c(c(C#N)c3c(sc4c(C#N)c5c(c(C#N)c43)C(=C(C#N)C#N)C(C#N)=C5)c2C#N)C1=C(C#N)C#N ; N#CC1=CC(=C(C#N)C#N)c2c1c(C#N)c1sc3c(C#N)c4c(c(C#N)c3c1c2C#N)C(=C(C#N)C#N)C=C4C#N ; N#C/C=C1/C(C#N)=C(C#N)c2c1c(C#N)c1c(sc3c(C#N)c4c(c(C#N)c31)/C(=C\C#N)C(C#N)=C4C#N)c2C#N ; N#C/C=C1\C(C#N)=C(C#N)c2c1c(C#N)c1c(sc3c(C#N)c4c(c(C#N)c31)/C(=C/C#N)C(C#N)=C4C#N)c2C#N ; N#CC(C#N)=C1C(C#N)=C(C#N)c2c1cc1c(sc3c(C#N)c4c(cc31)C(=C(C#N)C#N)C(C#N)=C4C#N)c2C#N]

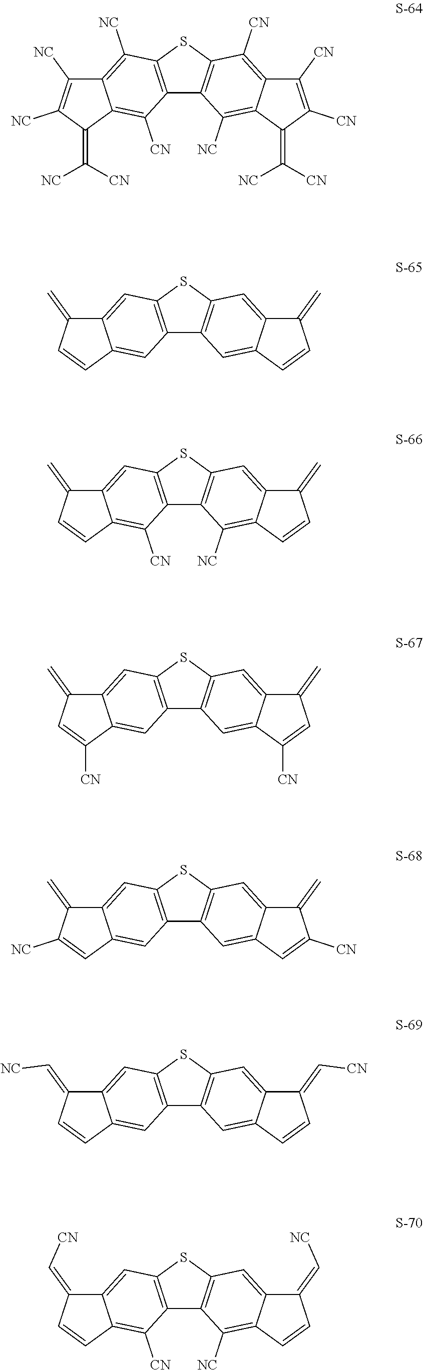

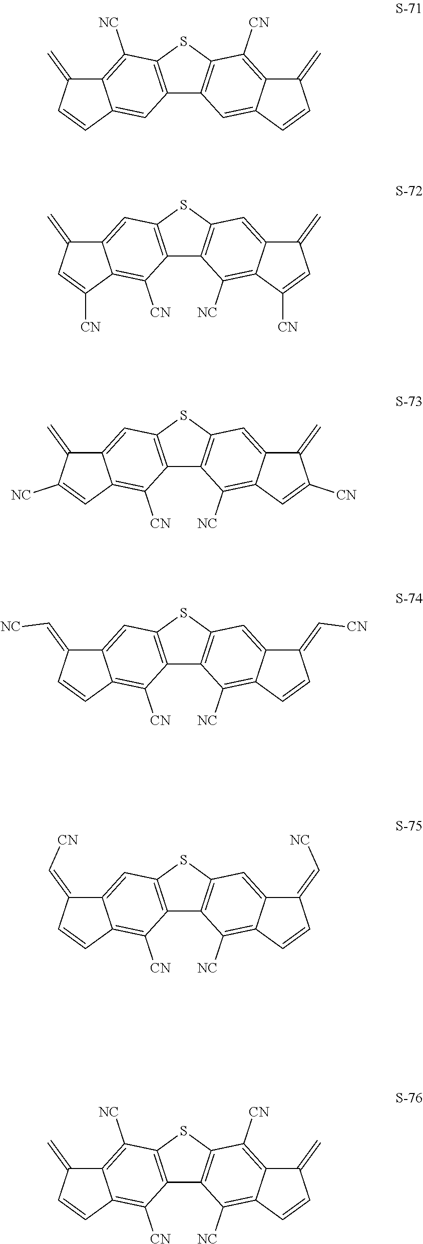

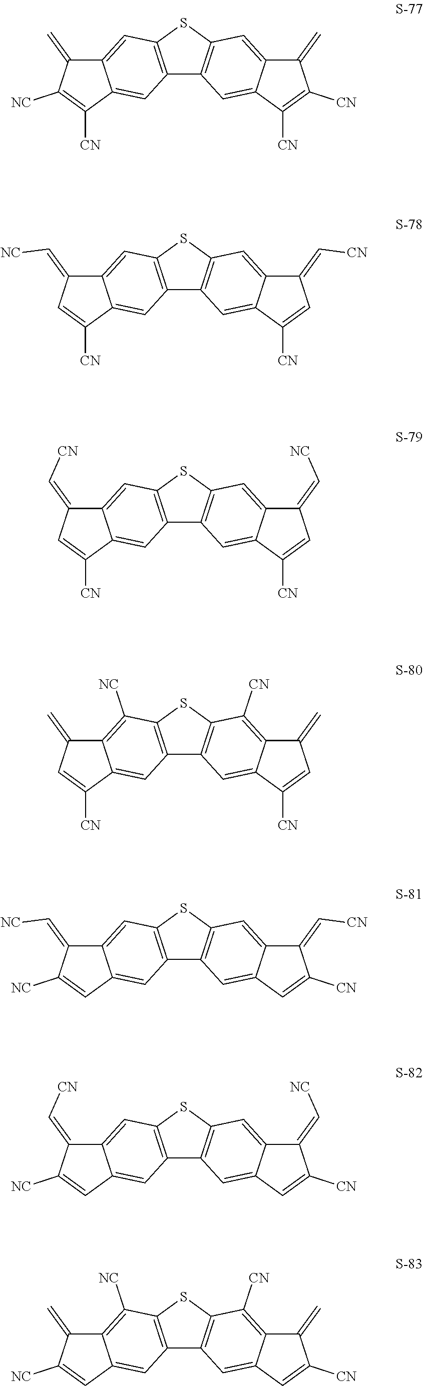

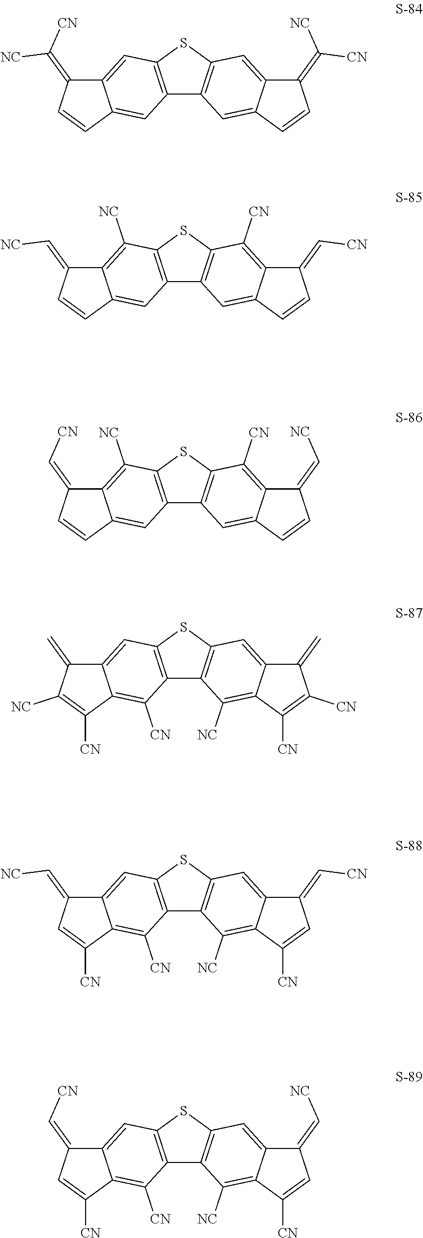 [SMILES: N#CC(C#N)=C1C=Cc2cc3c(cc21)sc1cc2c(cc13)C=CC2=C(C#N)C#N ; N#C/C=C1\C=Cc2cc3c(sc4c(C#N)c5c(cc43)C=C/C5=C\C#N)c(C#N)c21 ; N#C/C=C1/C=Cc2cc3c(sc4c(C#N)c5c(cc43)C=C/C5=C/C#N)c(C#N)c21 ; C=C1C(C#N)=C(C#N)c2c1cc1sc3cc4c(c(C#N)c3c1c2C#N)C(C#N)=C(C#N)C4=C ; N#C/C=C1\C=C(C#N)c2c1cc1sc3cc4c(c(C#N)c3c1c2C#N)C(C#N)=C/C4=C\C#N ; N#C/C=C1/C=C(C#N)c2c1cc1sc3cc4c(c(C#N)c3c1c2C#N)C(C#N)=C/C4=C/C#N]

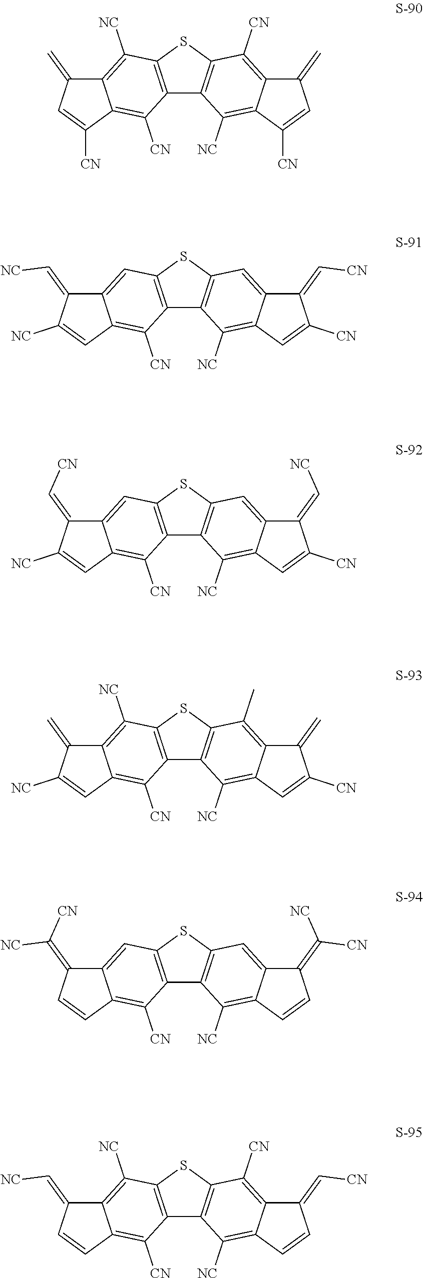

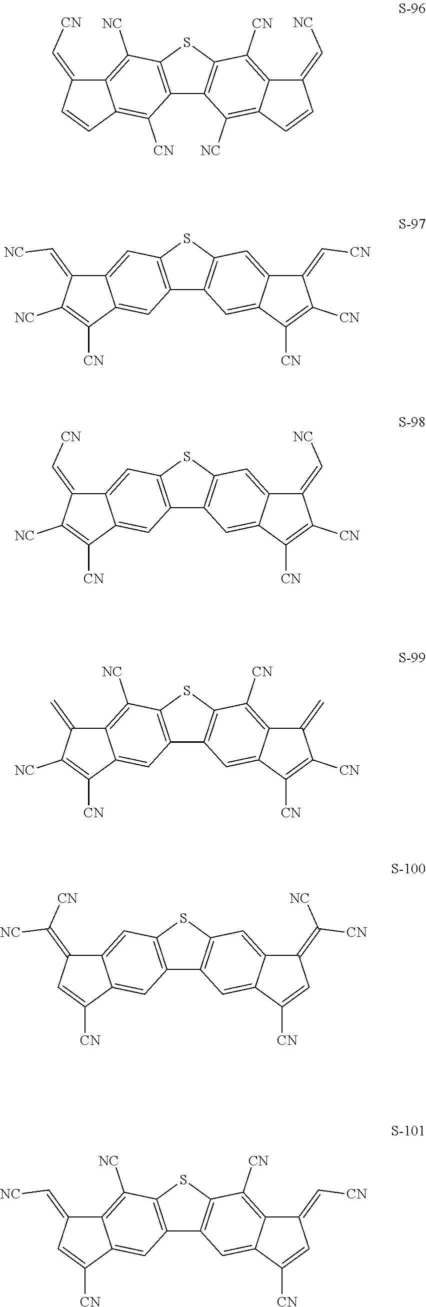 [SMILES: N#C/C=C1/C=Cc2c1c(C#N)c1sc3c(C#N)c4c(c(C#N)c3c1c2C#N)C=C/C4=C/C#N ; N#C/C=C1\C(C#N)=C(C#N)c2cc3c(cc21)sc1cc2c(cc13)C(C#N)=C(C#N)/C2=C\C#N ; N#C/C=C1/C(C#N)=C(C#N)c2cc3c(cc21)sc1cc2c(cc13)C(C#N)=C(C#N)/C2=C/C#N ; C=C1C(C#N)=C(C#N)c2cc3c(sc4c(C#N)c5c(cc43)C(C#N)=C(C#N)C5=C)c(C#N)c21 ; N#CC1=CC(=C(C#N)C#N)c2cc3sc4cc5c(cc4c3cc21)C(C#N)=CC5=C(C#N)C#N ; N#C/C=C1\C=C(C#N)c2cc3c(sc4c(C#N)c5c(cc43)C(C#N)=C/C5=C\C#N)c(C#N)c21]

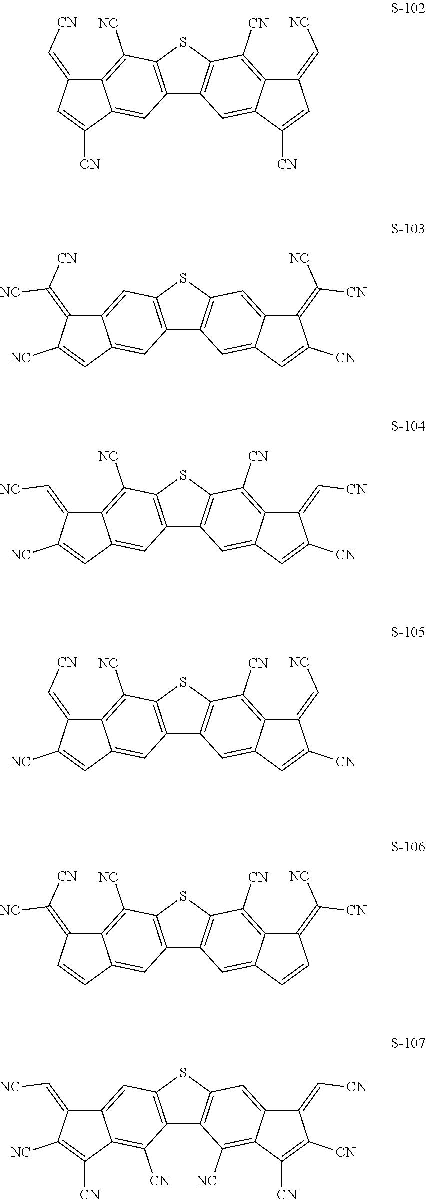 [SMILES: N#C/C=C1/C=C(C#N)c2cc3c(sc4c(C#N)c5c(cc43)C(C#N)=C/C5=C/C#N)c(C#N)c21 ; N#CC1=Cc2cc3c(cc2C1=C(C#N)C#N)sc1cc2c(cc13)C=C(C#N)C2=C(C#N)C#N ; N#C/C=C1\C(C#N)=Cc2cc3c(sc4c(C#N)c5c(cc43)C=C(C#N)/C5=C\C#N)c(C#N)c21 ; N#C/C=C1/C(C#N)=Cc2cc3c(sc4c(C#N)c5c(cc43)C=C(C#N)/C5=C/C#N)c(C#N)c21 ; N#CC(C#N)=C1C=Cc2cc3c(sc4c(C#N)c5c(cc43)C=CC5=C(C#N)C#N)c(C#N)c21 ; N#C/C=C1\C(C#N)=C(C#N)c2c1cc1sc3cc4c(c(C#N)c3c1c2C#N)C(C#N)=C(C#N)/C4=C\C#N]

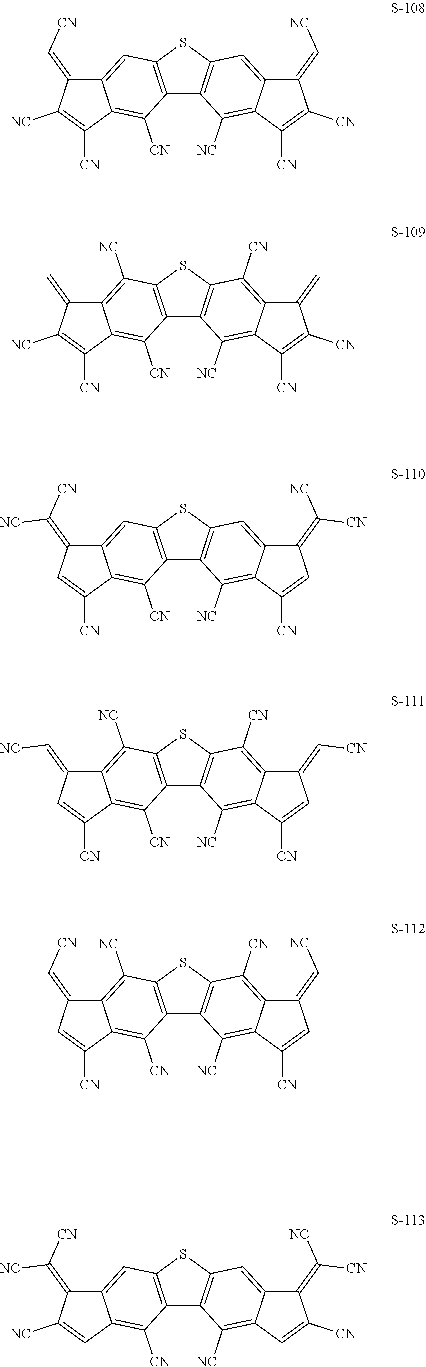 [SMILES: N#C/C=C1/C(C#N)=C(C#N)c2c1cc1sc3cc4c(c(C#N)c3c1c2C#N)C(C#N)=C(C#N)/C4=C/C#N ; C=C1C(C#N)=C(C#N)c2c1c(C#N)c1sc3c(C#N)c4c(c(C#N)c3c1c2C#N)C(C#N)=C(C#N)C4=C ; N#CC1=CC(=C(C#N)C#N)c2cc3sc4cc5c(c(C#N)c4c3c(C#N)c21)C(C#N)=CC5=C(C#N)C#N ; N#C/C=C1\C=C(C#N)c2c1c(C#N)c1sc3c(C#N)c4c(c(C#N)c3c1c2C#N)C(C#N)=C/C4=C\C#N ; N#C/C=C1/C=C(C#N)c2c1c(C#N)c1sc3c(C#N)c4c(c(C#N)c3c1c2C#N)C(C#N)=C/C4=C/C#N ; N#CC1=Cc2c(cc3sc4cc5c(c(C#N)c4c3c2C#N)C=C(C#N)C5=C(C#N)C#N)C1=C(C#N)C#N]

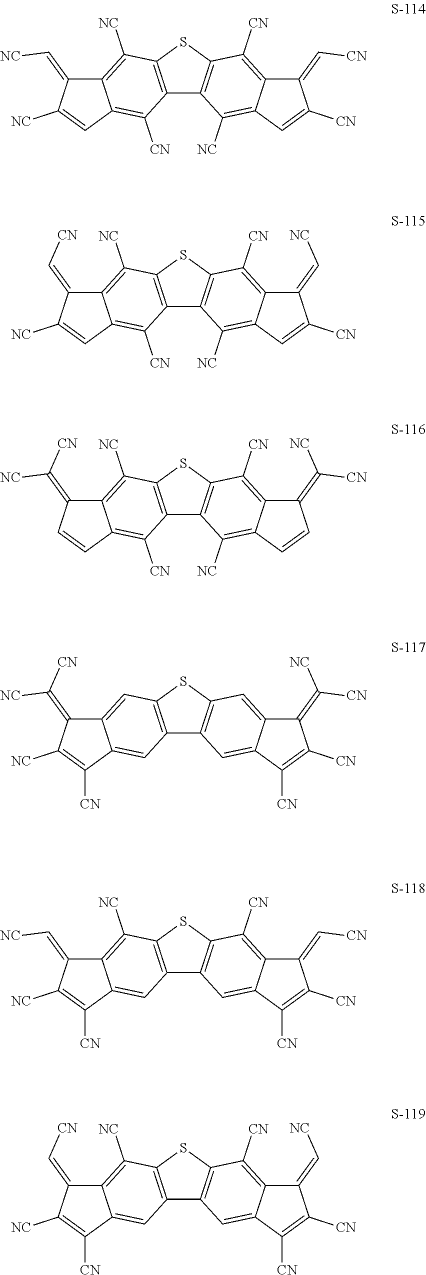 [SMILES: N#C/C=C1\C(C#N)=Cc2c1c(C#N)c1sc3c(C#N)c4c(c(C#N)c3c1c2C#N)C=C(C#N)/C4=C\C#N ; N#C/C=C1/C(C#N)=Cc2c1c(C#N)c1sc3c(C#N)c4c(c(C#N)c3c1c2C#N)C=C(C#N)/C4=C/C#N ; N#CC(C#N)=C1C=Cc2c1c(C#N)c1sc3c(C#N)c4c(c(C#N)c3c1c2C#N)C=CC4=C(C#N)C#N ; N#CC(C#N)=C1C(C#N)=C(C#N)c2cc3c(cc21)sc1cc2c(cc13)C(C#N)=C(C#N)C2=C(C#N)C#N ; N#C/C=C1\C(C#N)=C(C#N)c2cc3c(sc4c(C#N)c5c(cc43)C(C#N)=C(C#N)/C5=C\C#N)c(C#N)c21 ; N#C/C=C1/C(C#N)=C(C#N)c2cc3c(sc4c(C#N)c5c(cc43)C(C#N)=C(C#N)/C5=C/C#N)c(C#N)c21]

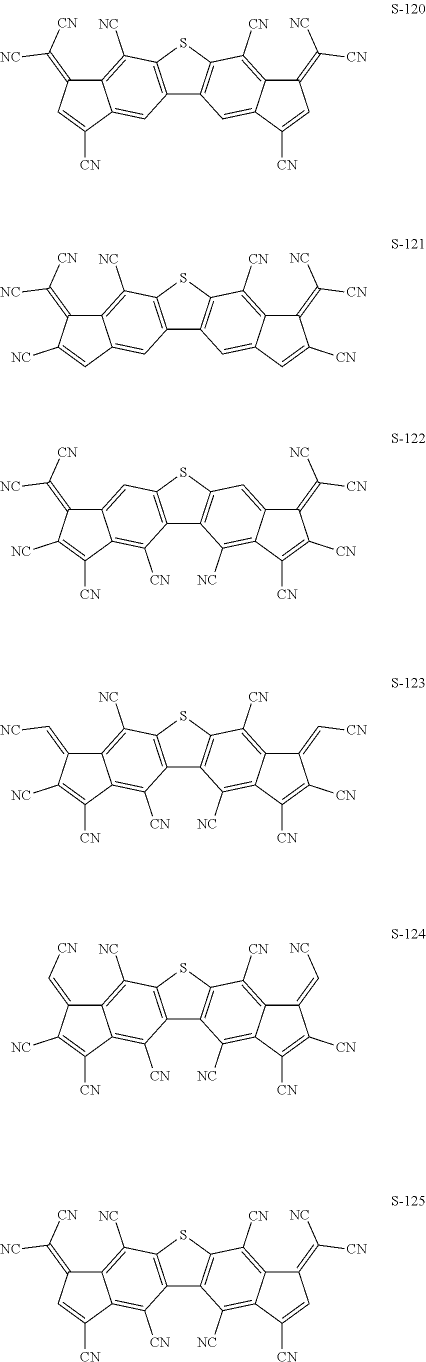 [SMILES: N#CC1=CC(=C(C#N)C#N)c2c1cc1c(sc3c(C#N)c4c(cc31)C(C#N)=CC4=C(C#N)C#N)c2C#N ; N#CC1=Cc2cc3c(sc4c(C#N)c5c(cc43)C=C(C#N)C5=C(C#N)C#N)c(C#N)c2C1=C(C#N)C#N ; N#CC(C#N)=C1C(C#N)=C(C#N)c2c1cc1sc3cc4c(c(C#N)c3c1c2C#N)C(C#N)=C(C#N)C4=C(C#N)C#N ; N#C/C=C1\C(C#N)=C(C#N)c2c1c(C#N)c1sc3c(C#N)c4c(c(C#N)c3c1c2C#N)C(C#N)=C(C#N)/C4=C\C#N ; N#C/C=C1/C(C#N)=C(C#N)c2c1c(C#N)c1sc3c(C#N)c4c(c(C#N)c3c1c2C#N)C(C#N)=C(C#N)/C4=C/C#N ; N#CC1=CC(=C(C#N)C#N)c2c1c(C#N)c1c(sc3c(C#N)c4c(c(C#N)c31)C(C#N)=CC4=C(C#N)C#N)c2C#N]

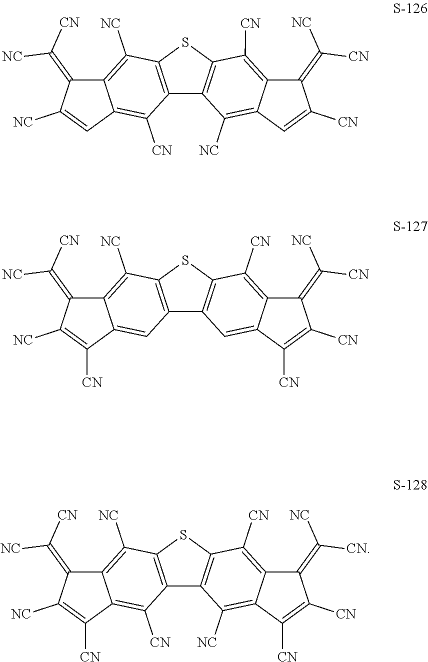 [SMILES: N#CC1=Cc2c(c(C#N)c3sc4c(C#N)c5c(c(C#N)c4c3c2C#N)C=C(C#N)C5=C(C#N)C#N)C1=C(C#N)C#N ; N#CC(C#N)=C1C(C#N)=C(C#N)c2cc3c(sc4c(C#N)c5c(cc43)C(C#N)=C(C#N)C5=C(C#N)C#N)c(C#N)c21 ; N#CC(C#N)=C1C(C#N)=C(C#N)c2c1c(C#N)c1sc3c(C#N)c4c(c(C#N)c3c1c2C#N)C(C#N)=C(C#N)C4=C(C#N)C#N]

According to one or more embodiments, the light-emitting diode may include the at least one of functional layer and a charge generation layer. The at least one functional layer may include: a hole functional layer on (e.g., arranged on) the first electrode; and a light-emitting layer on (e.g., arranged on) the hole functional layer, and at least one of the hole functional layer the light-emitting layer, or the charge generation layer may include the compound represented by the Formula 1.

According to one or more embodiments, the hole functional layer may include a hole injection layer and a hole transport layer, and at least one of the hole injection layer or the hole transport layer may include the compound represented by the Formula 1.

According to one or more embodiments, a thickness of the hole injection layer may be about 10 angstroms (Å) to about 500 Å.

According to one or more embodiments, the compound represented by the Formula 1 may be a p-type (kind) dopant.

According to one or more embodiments, the p-type (kind) dopant may be in an amount of about 0.5 parts to about 15 parts by weight based on 100 parts by an entire weight of compounds composing the hole functional layer or the charge generation layer. For example, the p-type (kind) dopant may be in an amount of about 0.5 parts to about 15 parts by weight based on 100 parts by an entire weight of compounds composing the hole functional layer. For example, the p-type (kind) dopant may be in an amount of about 0.5 parts to about 15 parts by weight based on 100 parts by an entire weight of compounds composing the charge generation layer.

According to one or more embodiments, a lowest unoccupied molecular orbital (LUMO) energy level of the p-type (kind) dopant may be −4.8 eV or less.

According to one or more embodiments, an electron mobility of the p-type (kind) dopant may be about 1.0×10⁻⁵ cm²/(Vs) to about 1.0×10⁻² cm²/(Vs).

According to one or more embodiments, a hole mobility of the p-type (kind) dopant may be 1.0×10⁻⁶ cm²/(Vs) to about 1.0×10⁻¹ cm²/(Vs).

According one or more embodiments of the present disclosure, an electronic device may include a light-emitting diode including: a first electrode; a second electrode on (e.g., arranged on) the first electrode; and at least one functional layer between (e.g., arranged between) the first electrode and the second electrode and including a compound represented by Formula 1.

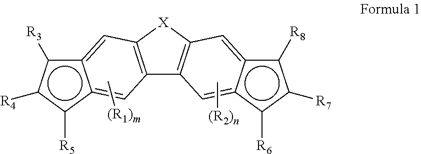

According to one or more embodiments, in Formula 1, X may be O, S, Ga, In, Ge, Sn, Pb, Sb, Bi, Se, or Te,

R₁ to R₈ may each independently be selected from among: hydrogen, deuterium, halogens, a haloalkyl group, a hydroxyl group, a cyano group, a nitro group, a trifluoromethyl group, an amine group, an amidino group, a hydrazino group, a hydrazono group, and an alkoxy group; or be a phenyl group, an alkyl group having 1 to 10 carbons, an alkenyl group having 2 to 10 carbons, an alkynyl group having 2 to 10 carbons, an aryl group having 6 to 30 ring-forming carbons, a heteroaryl group having 2 to 30 ring-forming carbons, or any combination thereof, each substituted or unsubstituted with deuterium, a halogen, a hydroxyl group, a cyano group, a nitro group, a trifluoromethyl group, an amidino group, a hydrazino group, a hydrazono group, an alkoxy group, or any combination thereof (e.g., R₁ to R₈ may each independently be: hydrogen, deuterium, a halogen, a haloalkyl group, a hydroxyl group, a cyano group, a nitro group, a trifluoromethyl group, an amine group, an amidino group, a hydrazino group, a hydrazono group, or an alkoxy group; or a phenyl group, an alkyl group having 1 to 10 carbons, an alkenyl group having 2 to 10 carbons, an alkynyl group having 2 to 10 carbons, an aryl group having 6 to 30 ring-forming carbons, a heteroaryl group having 2 to 30 ring-forming carbons, or any combination thereof, each substituted or unsubstituted with hydrogen, deuterium, halogens, a hydroxyl group, a cyano group, a nitro group, a trifluoromethyl group, an amidino group, a hydrazino group, a hydrazono group, an alkoxy group, or any combination thereof), and

m and n may each independently be an integer between 0 and 2, inclusive.

According to one or more embodiments, the electronic device may be at least one selected from among a plane panel display, a curved display, a television, a billboard, a computer monitor, a medical monitor, a head mounted display, an indoor light, an outdoor light, a signal light, a wearable device, a foldable device, a rollable device, a bendable device, a flexible device, a curved device, an electronic organizer, an electronic book, a portable multimedia player, a personal digital assistance, a laser printer, a telephone, a cellphone, a tablet PC, a portable terminal, a laptop computer, a digital camera, a viewfinder, a camcorder, a 3D display, a virtual reality display, an augmented reality display, a video wall including multiple displays tiled together, a vehicle display device, an outdoor display device, a theater screen, a stadium screen, and a signboard. According to one or more embodiments, at least one of a color filter layer, a color conversion layer, a touch sensor layer, or a polarization layer may be further included on the light-emitting diode.

According to one or more embodiments of the present disclosure, a compound represented by Formula 1 may be provided:

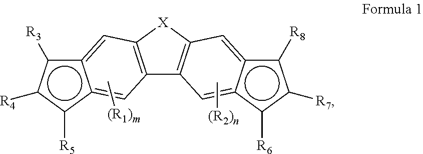

wherein, in Formula 1, X may be O, S, Ga, In, Ge, Sn, Pb, Sb, Bi, Se, or Te,
R₁ to R₈ may each independently be selected from among: hydrogen, deuterium, halogens, a haloalkyl group, a hydroxyl group, a cyano group, a nitro group, a trifluoromethyl group, an amine group, an amidino group, a hydrazino group, a hydrazono group, and an alkoxy group; or may each be a phenyl group, an alkyl group having 1 to 10 carbons, an alkenyl group having 2 to 10 carbons, an alkynyl group having 2 to 10 carbons, an aryl group having 6 to 30 ring-forming carbons, a heteroaryl group having 2 to 30 ring-forming carbons, or any combination thereof, each substituted or unsubstituted with deuterium, a halogen, a hydroxyl group, a cyano group, a nitro group, a trifluoromethyl group, an amidino group, a hydrazino group, a hydrazono group, an alkoxy group, or any combination thereof, and
m and n may each independently be an integer between 0 and 2, inclusive.

According to one or more embodiments, the compound represented by Formula 1 may be represented by Formula 1-1 or Formula 1-2:

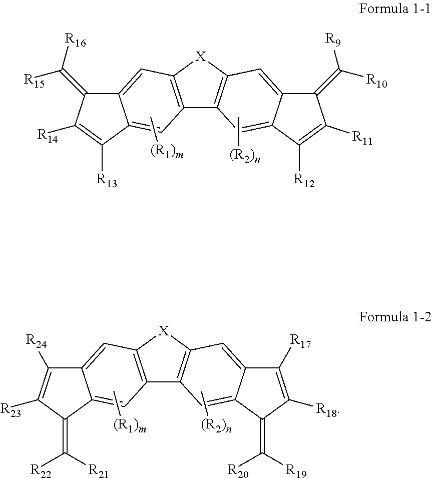

In Formulae 1-1 and 1-2, X may be selected from among O, S, Ga, In, Ge, Sn, Pb, Sb, Bi, Se, and Te,
R₁, R₂, and R₉ to R₂₄ may each independently be selected from among: hydrogen, deuterium, halogens, a haloalkyl group, a hydroxyl group, a cyano group, a nitro group, a trifluoromethyl group, an amine group, an amidino group, a hydrazino group, a hydrazono group, and an alkoxy group; or be a phenyl group, an alkyl group having 1 to 10 carbons, an alkenyl group having 2 to 10 carbons, an alkynyl group having 2 to 10 carbons, an aryl group having 6 to 30 ring-forming carbons, a heteroaryl group having 2 to 30 ring-forming carbons, or any combination thereof, each substituted or unsubstituted with deuterium, a halogen, a haloalkyl group, a hydroxyl group, a cyano group, a nitro group, a trifluoromethyl group, an amine group, an amidino group, a hydrazino group, a hydrazono group, an alkoxy group, or any combination thereof, and
m and n may each independently be an integer between 0 and 2, inclusive.

According to one or more embodiments, the R₁, R₂, R₁₉, R₂₀, R₂₁, and R₂₂ may independently be selected from among: a haloalkyl group, a hydroxyl group, a cyano group, a nitro group, a trifluoromethyl group, an amine group, and an alkoxy group; or be an alkenyl group having 2 to 10 carbons substituted or unsubstituted with a haloalkyl group, a hydroxyl group, a cyano group, a nitro group, a trifluoromethyl group, an amine group, an alkoxy group, or any combination thereof.

According to one or more embodiments, the compound represented by the Formula 1 may be any one selected from among compounds of Compound Group 1 or any one selected from among compounds Compound Group 2:

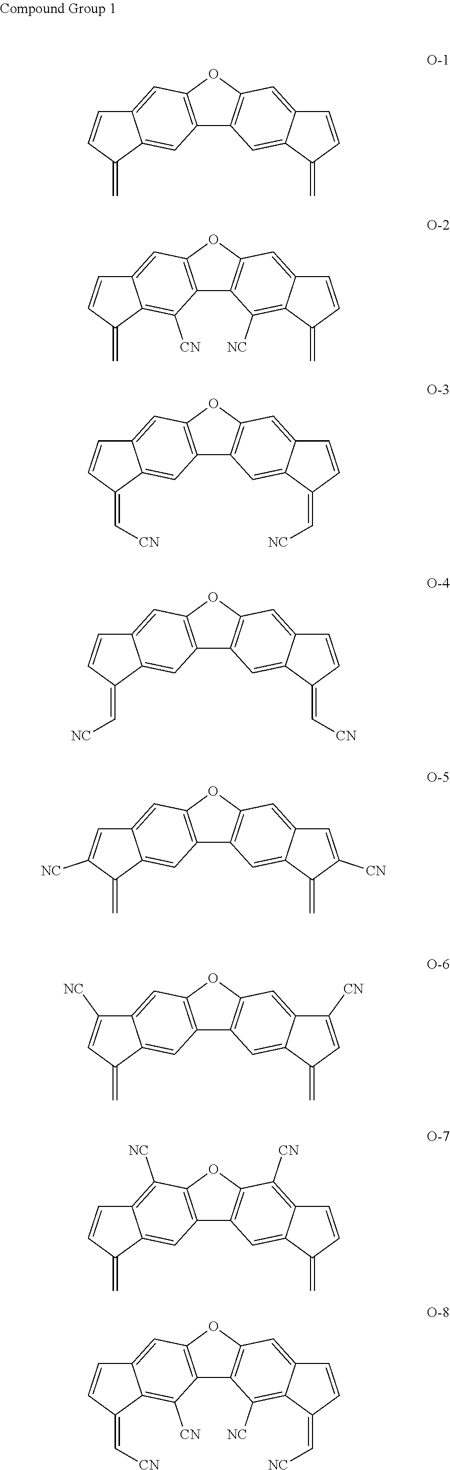

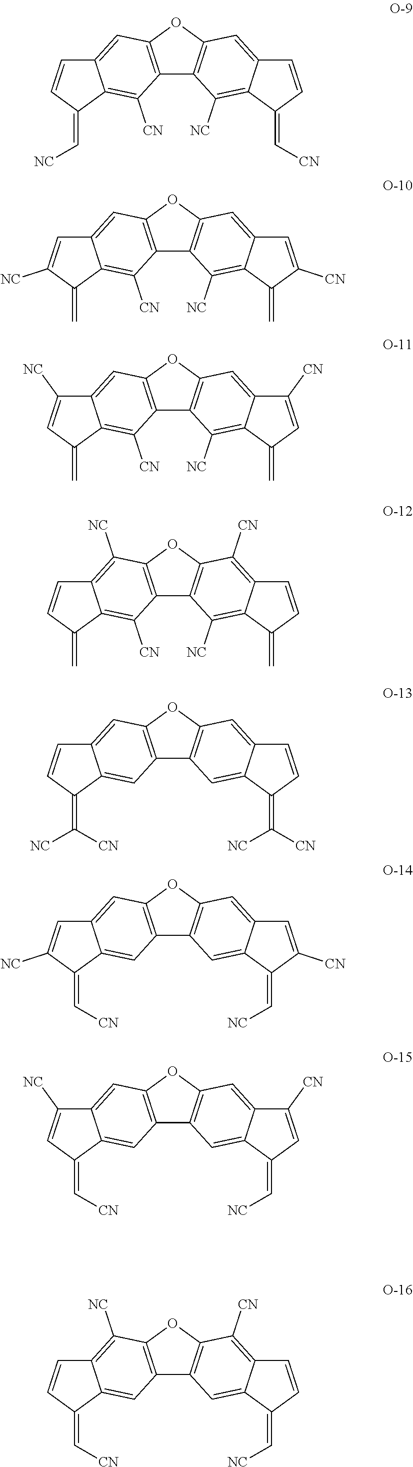

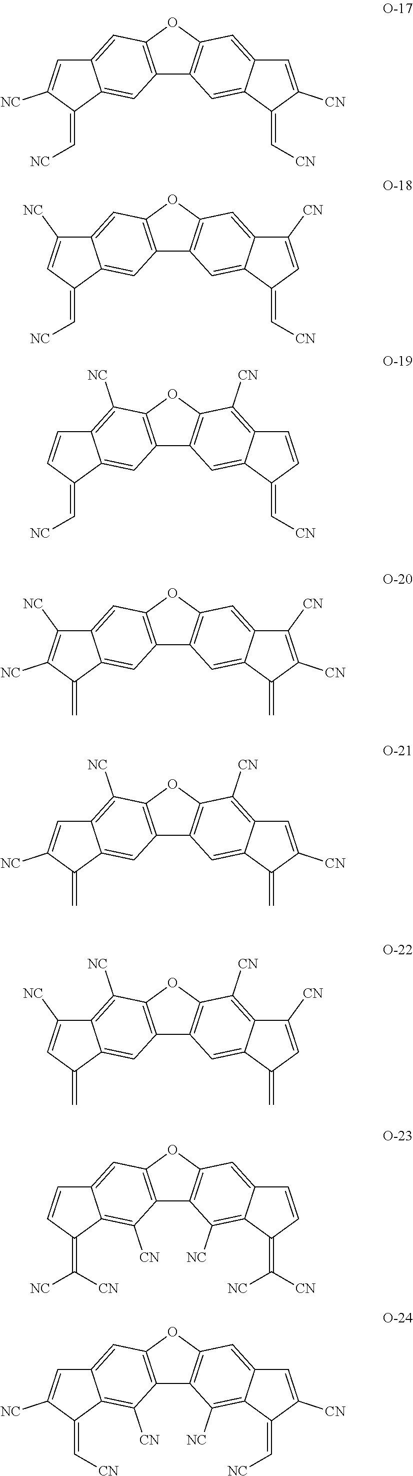

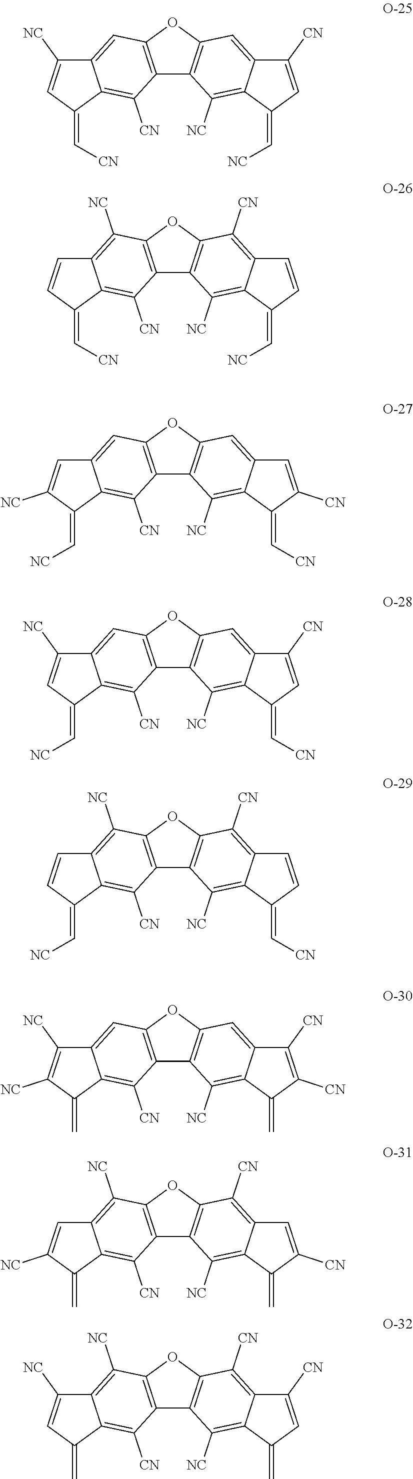

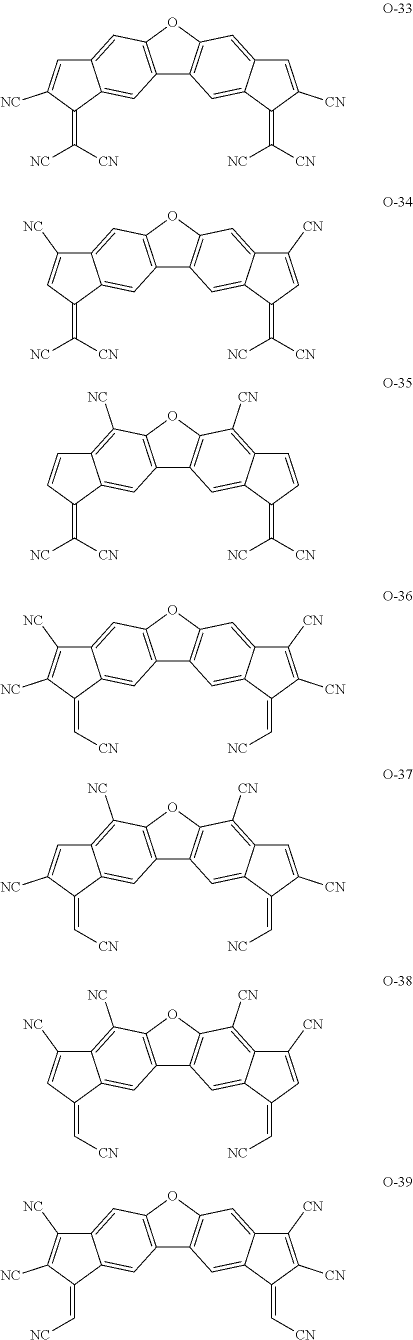

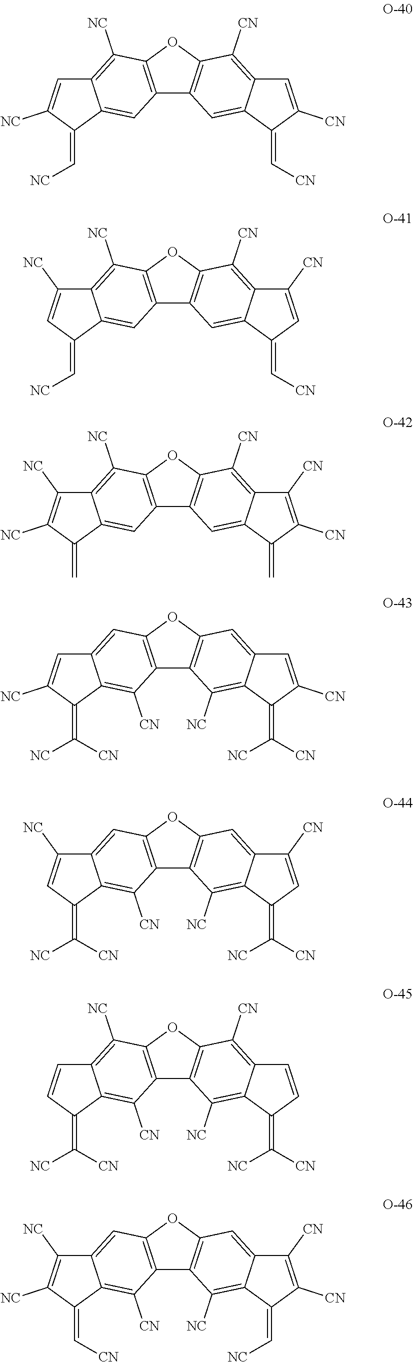

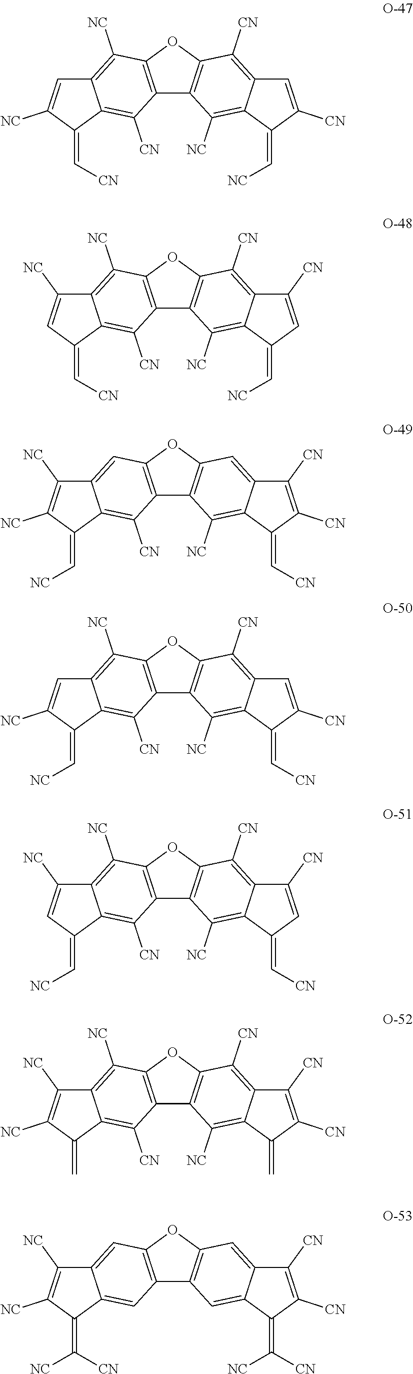

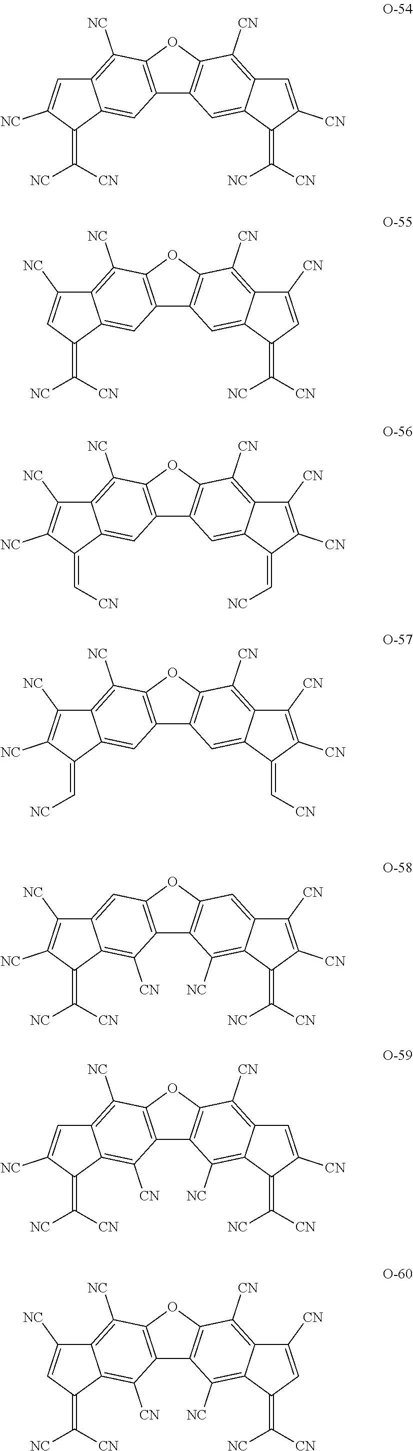

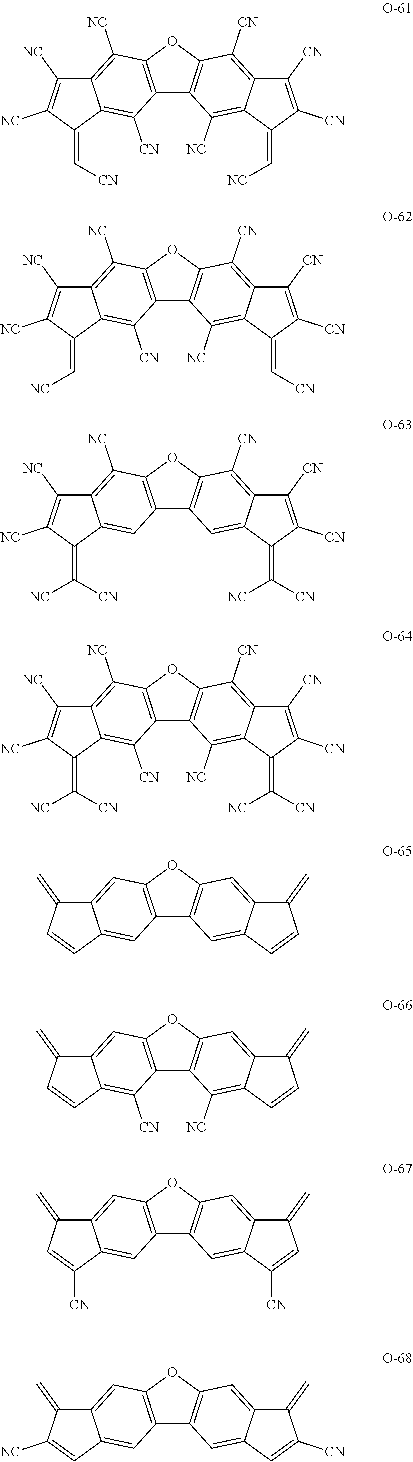

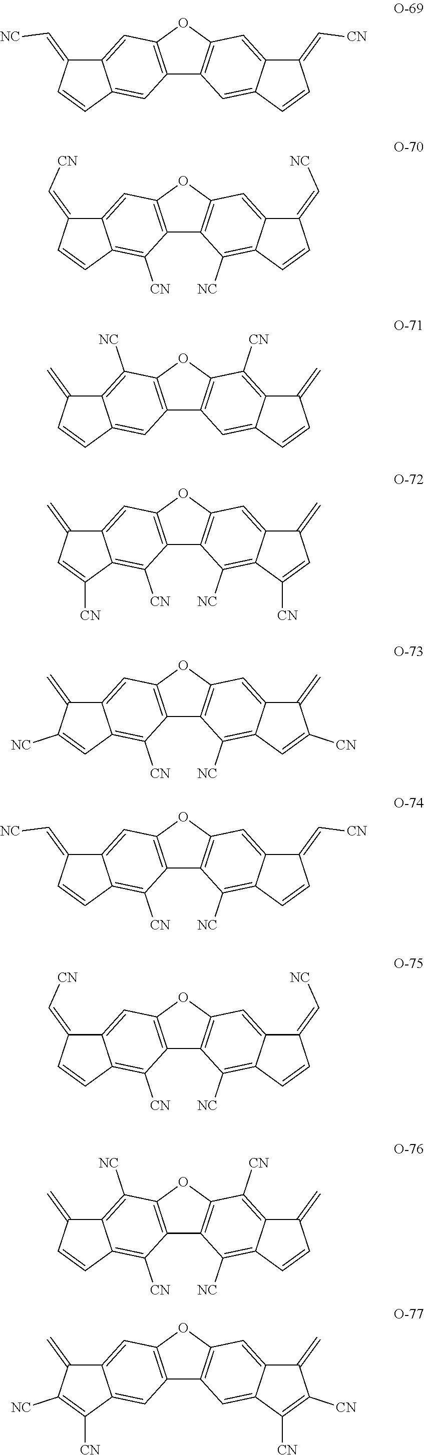

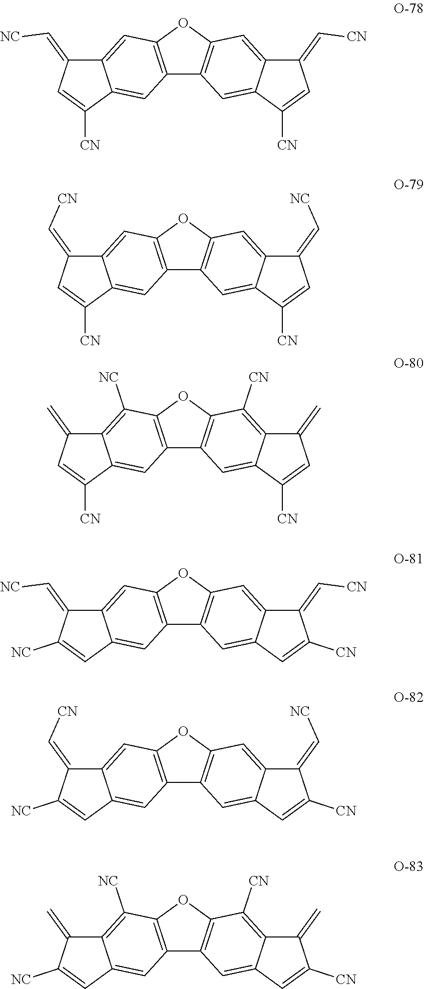

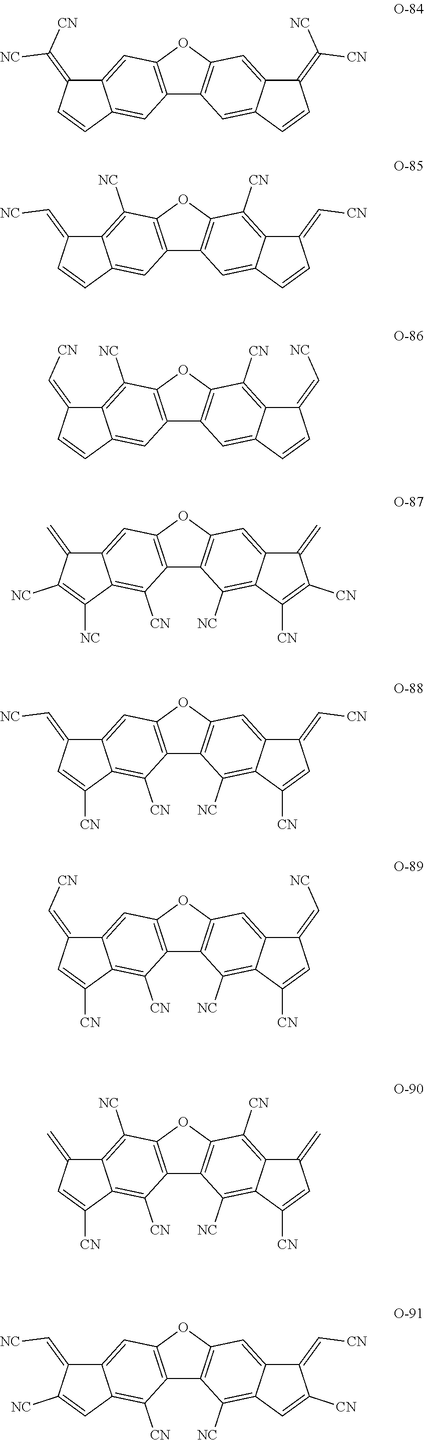

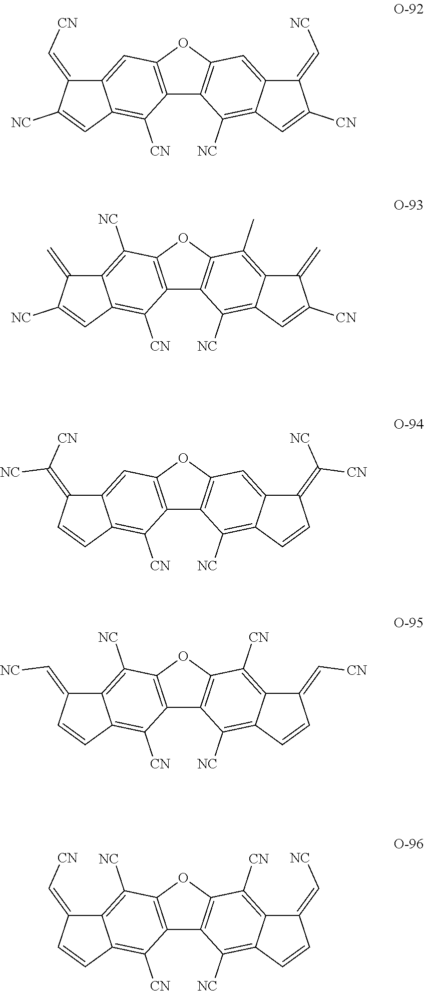 [SMILES: N#C/C=C1/C(C#N)=Cc2c1cc1oc3cc4c(c(C#N)c3c1c2C#N)C=C(C#N)/C4=C/C#N ; C=C1C(C#N)=Cc2c1c(C)c1oc3c(C#N)c4c(c(C#N)c3c1c2C#N)C=C(C#N)C4=C ; N#CC(C#N)=C1C=Cc2c1cc1oc3cc4c(c(C#N)c3c1c2C#N)C=CC4=C(C#N)C#N ; N#C/C=C1\C=Cc2c1c(C#N)c1oc3c(C#N)c4c(c(C#N)c3c1c2C#N)C=C/C4=C\C#N ; N#C/C=C1/C=Cc2c1c(C#N)c1oc3c(C#N)c4c(c(C#N)c3c1c2C#N)C=C/C4=C/C#N]

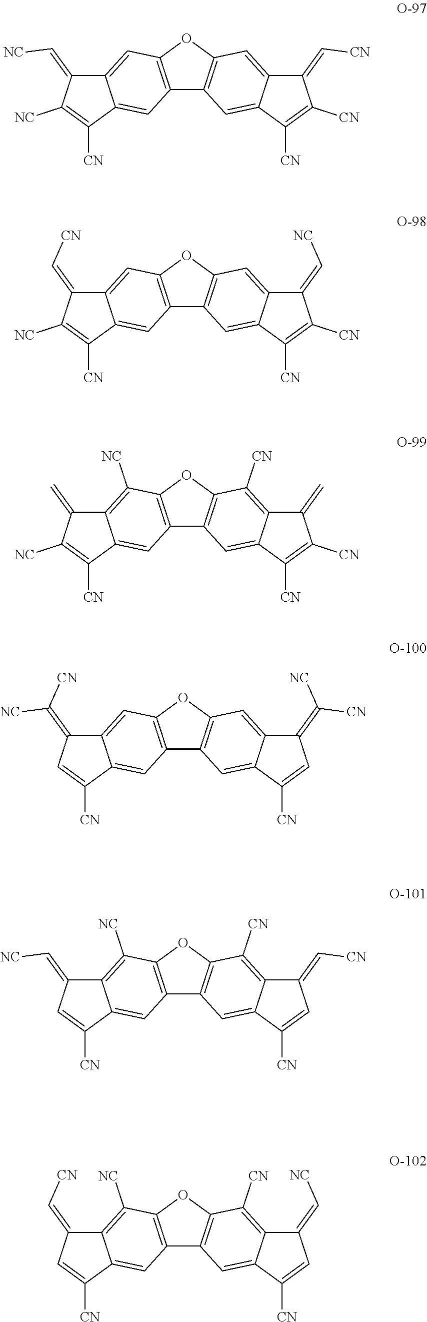 [SMILES: N#C/C=C1\C(C#N)=C(C#N)c2cc3c(cc21)oc1cc2c(cc13)C(C#N)=C(C#N)/C2=C\C#N ; N#C/C=C1/C(C#N)=C(C#N)c2cc3c(cc21)oc1cc2c(cc13)C(C#N)=C(C#N)/C2=C/C#N ; C=C1C(C#N)=C(C#N)c2cc3c(oc4c(C#N)c5c(cc43)C(C#N)=C(C#N)C5=C)c(C#N)c21 ; N#CC1=CC(=C(C#N)C#N)c2cc3oc4cc5c(cc4c3cc21)C(C#N)=CC5=C(C#N)C#N ; N#C/C=C1\C=C(C#N)c2cc3c(oc4c(C#N)c5c(cc43)C(C#N)=C/C5=C\C#N)c(C#N)c21 ; N#C/C=C1/C=C(C#N)c2cc3c(oc4c(C#N)c5c(cc43)C(C#N)=C/C5=C/C#N)c(C#N)c21]

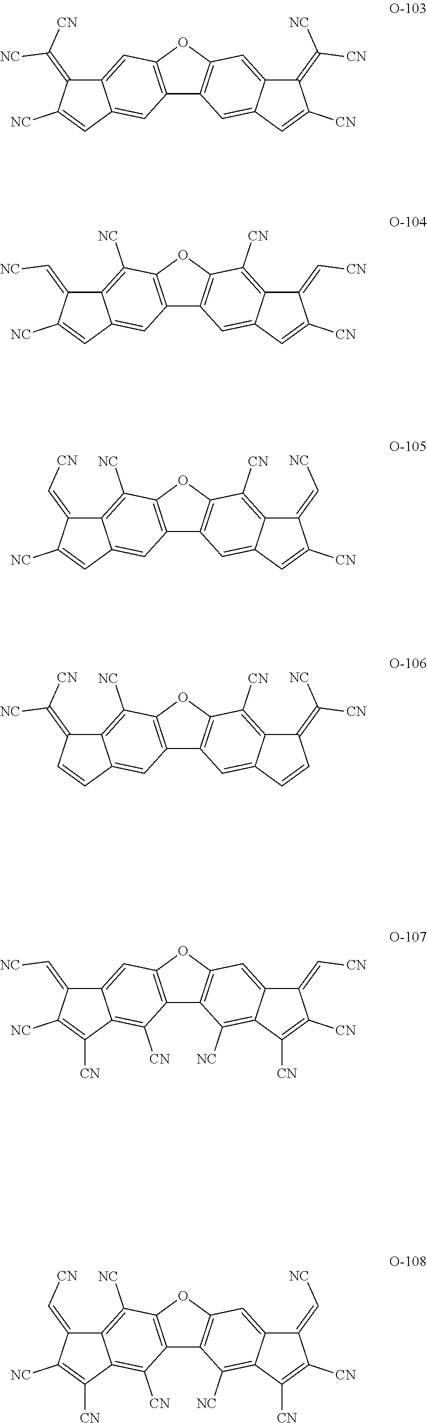 [SMILES: N#CC1=Cc2cc3c(cc2C1=C(C#N)C#N)oc1cc2c(cc13)C=C(C#N)C2=C(C#N)C#N ; N#C/C=C1\C(C#N)=Cc2cc3c(oc4c(C#N)c5c(cc43)C=C(C#N)/C5=C\C#N)c(C#N)c21 ; N#C/C=C1/C(C#N)=Cc2cc3c(oc4c(C#N)c5c(cc43)C=C(C#N)/C5=C/C#N)c(C#N)c21 ; N#CC(C#N)=C1C=Cc2cc3c(oc4c(C#N)c5c(cc43)C=CC5=C(C#N)C#N)c(C#N)c21 ; N#C/C=C1\C(C#N)=C(C#N)c2c1cc1oc3cc4c(c(C#N)c3c1c2C#N)C(C#N)=C(C#N)/C4=C\C#N ; N#C/C=C1/C(C#N)=C(C#N)c2c1cc1oc3c(C#N)c4c(c(C#N)c3c1c2C#N)C(C#N)=C(C#N)/C4=C/C#N]

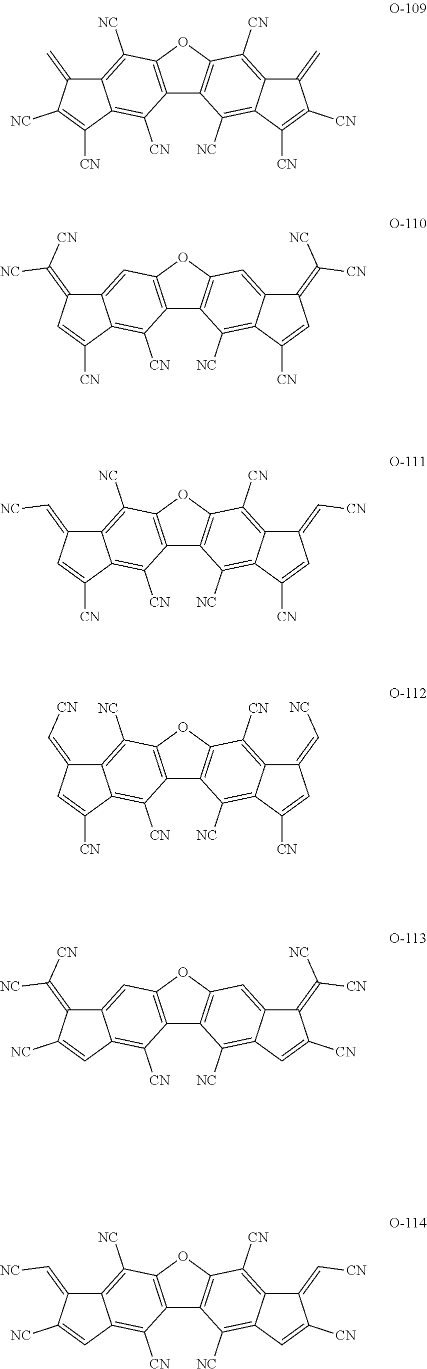 [SMILES: C=C1C(C#N)=C(C#N)c2c1c(C#N)c1oc3c(C#N)c4c(c(C#N)c3c1c2C#N)C(C#N)=C(C#N)C4=C ; N#CC1=CC(=C(C#N)C#N)c2cc3oc4cc5c(c(C#N)c4c3c(C#N)c21)C(C#N)=CC5=C(C#N)C#N ; N#C/C=C1\C=C(C#N)c2c1c(C#N)c1oc3c(C#N)c4c(c(C#N)c3c1c2C#N)C(C#N)=C/C4=C\C#N ; N#C/C=C1/C=C(C#N)c2c1c(C#N)c1oc3c(C#N)c4c(c(C#N)c3c1c2C#N)C(C#N)=C/C4=C/C#N ; N#CC1=Cc2c(cc3oc4cc5c(c(C#N)c4c3c2C#N)C=C(C#N)C5=C(C#N)C#N)C1=C(C#N)C#N ; N#C/C=C1\C(C#N)=Cc2c1c(C#N)c1oc3c(C#N)c4c(c(C#N)c3c1c2C#N)C=C(C#N)/C4=C\C#N]

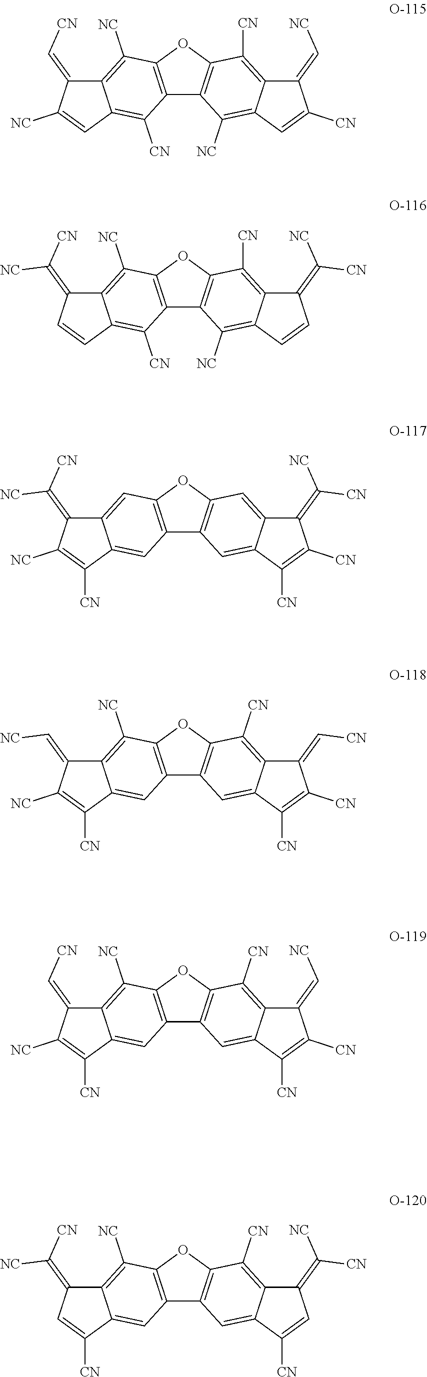 [SMILES: N#C/C=C1/C(C#N)=Cc2c1c(C#N)c1oc3c(C#N)c4c(c(C#N)c3c1c2C#N)C=C(C#N)/C4=C/C#N ; N#CC(C#N)=C1C=Cc2c1c(C#N)c1oc3c(C#N)c4c(c(C#N)c3c1c2C#N)C=CC4=C(C#N)C#N ; N#CC(C#N)=C1C(C#N)=C(C#N)c2cc3c(cc21)oc1cc2c(cc13)C(C#N)=C(C#N)C2=C(C#N)C#N ; N#C/C=C1\C(C#N)=C(C#N)c2cc3c(oc4c(C#N)c5c(cc43)C(C#N)=C(C#N)/C5=C\C#N)c(C#N)c21 ; N#C/C=C1/C(C#N)=C(C#N)c2cc3c(oc4c(C#N)c5c(cc43)C(C#N)=C(C#N)/C5=C/C#N)c(C#N)c21 ; N#CC1=CC(=C(C#N)C#N)c2c1cc1c(oc3c(C#N)c4c(cc31)C(C#N)=CC4=C(C#N)C#N)c2C#N]

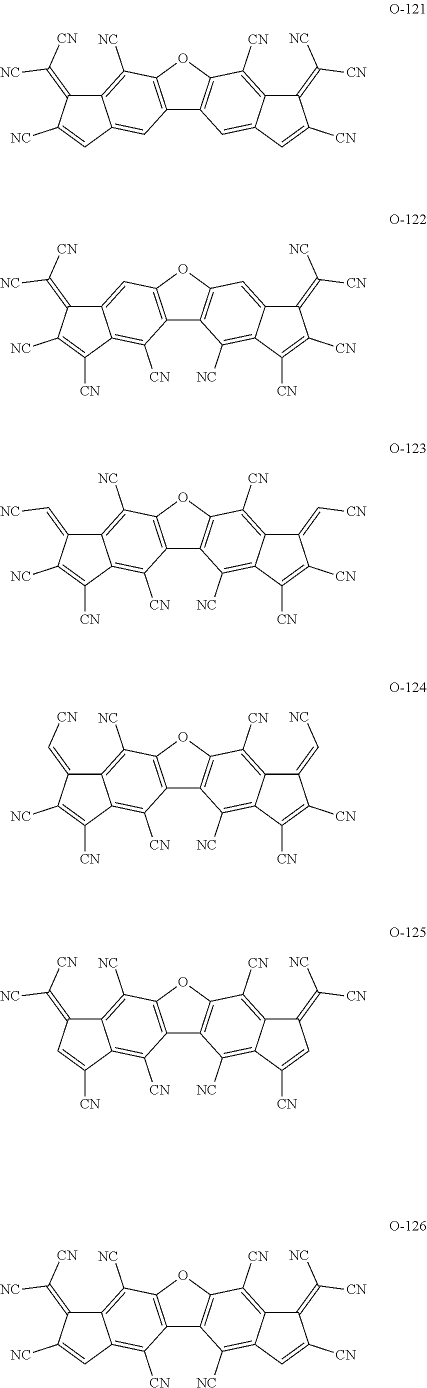

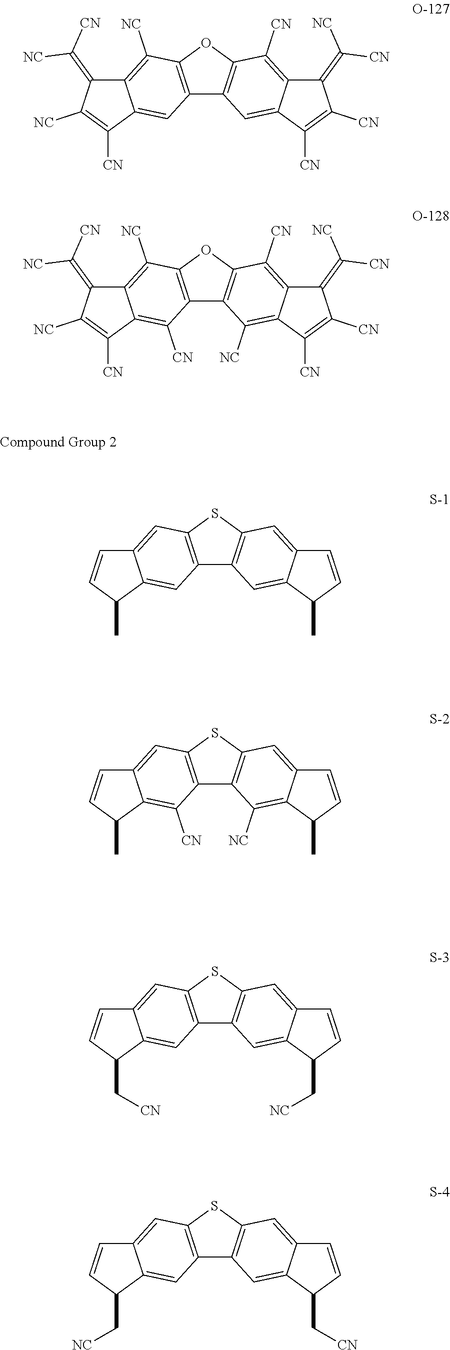 [SMILES: N#CC(C#N)=C1C(C#N)=C(C#N)c2cc3c(oc4c(C#N)c5c(cc43)C(C#N)=C(C#N)C5=C(C#N)C#N)c(C#N)c21 ; N#CC(C#N)=C1C(C#N)=C(C#N)c2c1c(C#N)c1oc3c(C#N)c4c(c(C#N)c3c1c2C#N)C(C#N)=C(C#N)C4=C(C#N)C#N ; C[C@@H]1C=Cc2cc3sc4cc5c(cc4c3cc21)[C@@H](C)C=C5 ; C[C@@H]1C=Cc2cc3sc4cc5c(c(C#N)c4c3c(C#N)c21)[C@@H](C)C=C5 ; N#CC[C@H]1C=Cc2cc3sc4cc5c(cc4c3cc21)[C@H](CC#N)C=C5 ; N#CC[C@H]1C=Cc2cc3sc4cc5c(cc4c3cc21)[C@H](CC#N)C=C5]

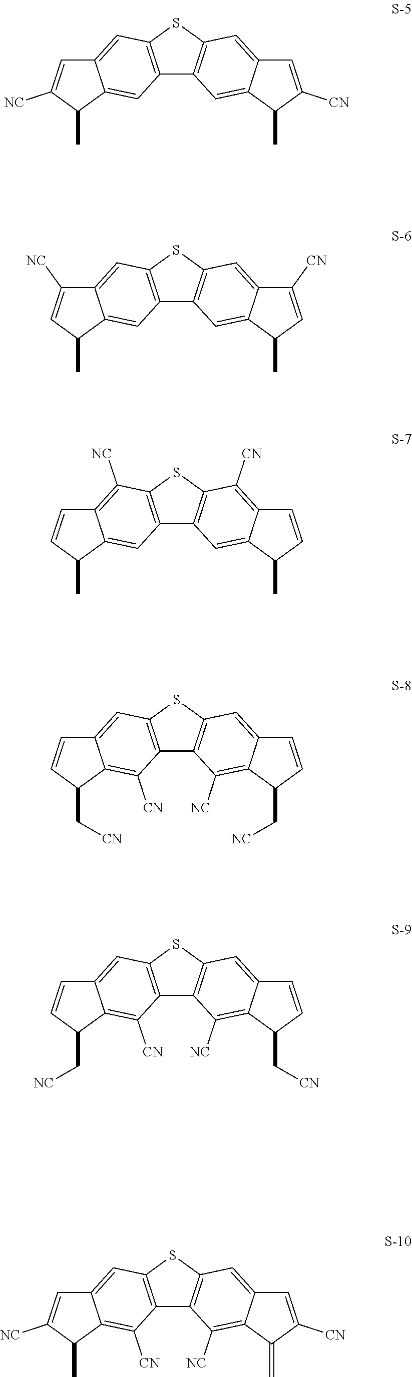 [SMILES: C[C@@H]1C(C#N)=Cc2cc3sc4cc5c(cc4c3cc21)[C@@H](C)C(C#N)=C5 ; C[C@@H]1C=C(C#N)c2cc3sc4cc5c(cc4c3cc21)[C@@H](C)C=C5C#N ; C[C@@H]1C=Cc2c1cc1c(sc3c(C#N)c4c(cc31)[C@@H](C)C=C4)c2C#N ; N#CC[C@H]1C=Cc2cc3sc4cc5c(c(C#N)c4c3c(C#N)c21)[C@H](CC#N)C=C5 ; N#CC[C@H]1C=Cc2cc3sc4cc5c(c(C#N)c4c3c(C#N)c21)[C@H](CC#N)C=C5 ; C=C1C(C#N)=Cc2cc3sc4cc5c(c(C#N)c4c3c(C#N)c21)[C@@H](C)C(C#N)=C5]

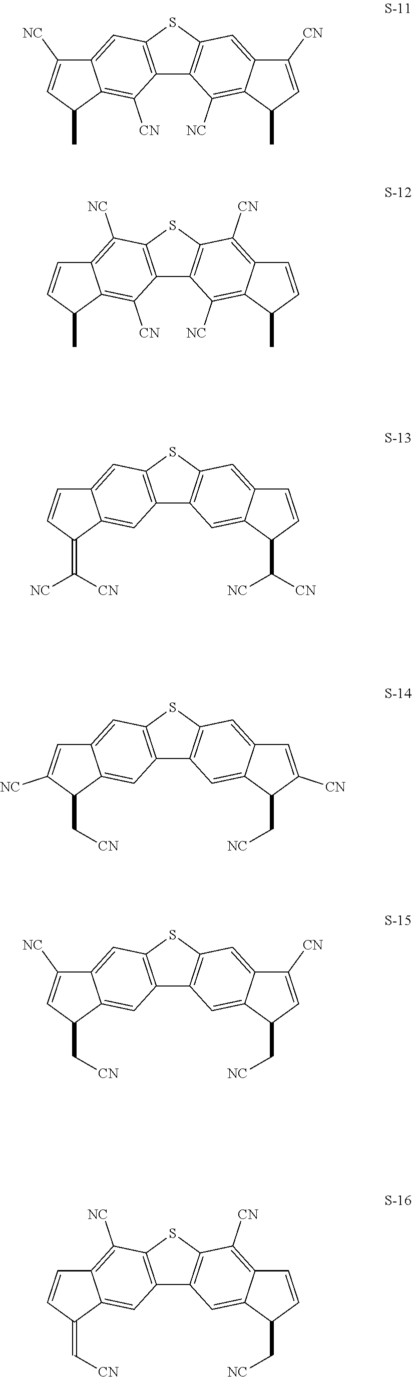 [SMILES: C[C@@H]1C=C(C#N)c2cc3sc4cc5c(c(C#N)c4c3c(C#N)c21)[C@@H](C)C=C5C#N ; C[C@@H]1C=Cc2c1c(C#N)c1c(sc3c(C#N)c4c(c(C#N)c31)[C@@H](C)C=C4)c2C#N ; N#CC(C#N)=C1C=Cc2cc3sc4cc5c(cc4c3cc21)[C@H](C(C#N)C#N)C=C5 ; N#CC[C@@H]1C(C#N)=Cc2cc3sc4cc5c(cc4c3cc21)[C@@H](CC#N)C(C#N)=C5 ; N#CC[C@H]1C=C(C#N)c2cc3sc4cc5c(cc4c3cc21)[C@H](CC#N)C=C5C#N ; N#C/C=C1/C=Cc2c1cc1c(sc3c(C#N)c4c(cc31)[C@H](CC#N)C=C4)c2C#N]

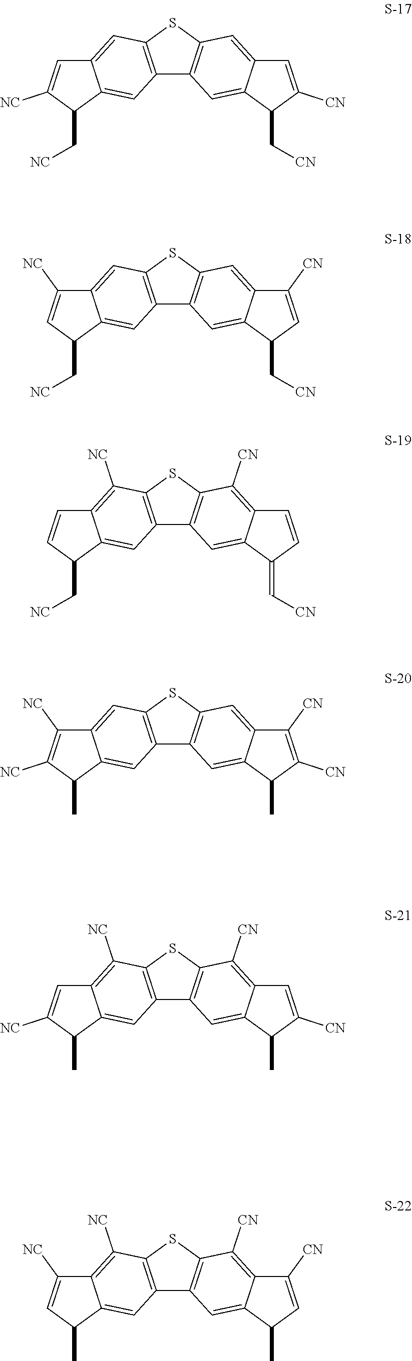 [SMILES: N#CC[C@@H]1C(C#N)=Cc2cc3sc4cc5c(cc4c3cc21)[C@@H](CC#N)C(C#N)=C5 ; N#CC[C@H]1C=C(C#N)c2cc3sc4cc5c(cc4c3cc21)[C@H](CC#N)C=C5C#N ; N#C/C=C1\C=Cc2c1cc1c(sc3c(C#N)c4c(cc31)[C@@H](CC#N)C=C4)c2C#N ; C[C@@H]1C(C#N)=C(C#N)c2cc3sc4cc5c(cc4c3cc21)[C@@H](C)C(C#N)=C5C#N ; C[C@@H]1C(C#N)=Cc2c1cc1c(sc3c(C#N)c4c(cc31)[C@@H](C)C(C#N)=C4)c2C#N ; C[C@@H]1C=C(C#N)c2c1cc1c(sc3c(C#N)c4c(cc31)[C@@H](C)C=C4C#N)c2C#N]

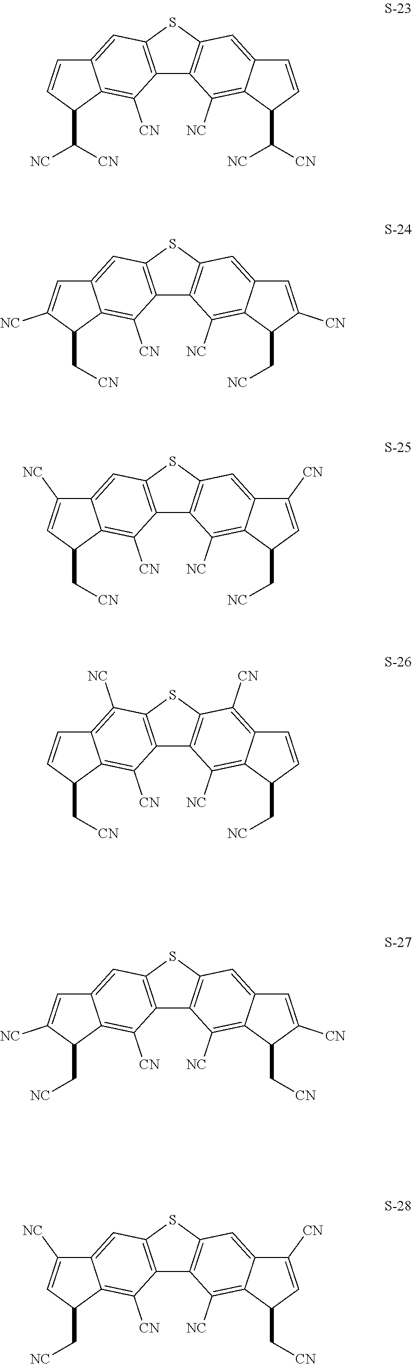 [SMILES: N#Cc1c2c(cc3sc4cc5c(c(C#N)c4c13)[C@@H](C(C#N)C#N)C=C5)C=C[C@H]2C(C#N)C#N ; N#CC[C@@H]1C(C#N)=Cc2cc3sc4cc5c(c(C#N)c4c3c(C#N)c21)[C@@H](CC#N)C(C#N)=C5 ; N#CC[C@H]1C=C(C#N)c2cc3sc4cc5c(c(C#N)c4c3c(C#N)c21)[C@H](CC#N)C=C5C#N ; N#CC[C@H]1C=Cc2c1c(C#N)c1c(sc3c(C#N)c4c(c(C#N)c31)[C@H](CC#N)C=C4)c2C#N ; N#CC[C@@H]1C(C#N)=Cc2cc3sc4cc5c(c(C#N)c4c3c(C#N)c21)[C@@H](CC#N)C(C#N)=C5 ; N#CC[C@H]1C=C(C#N)c2cc3sc4cc5c(c(C#N)c4c3c(C#N)c21)[C@H](CC#N)C=C5C#N]

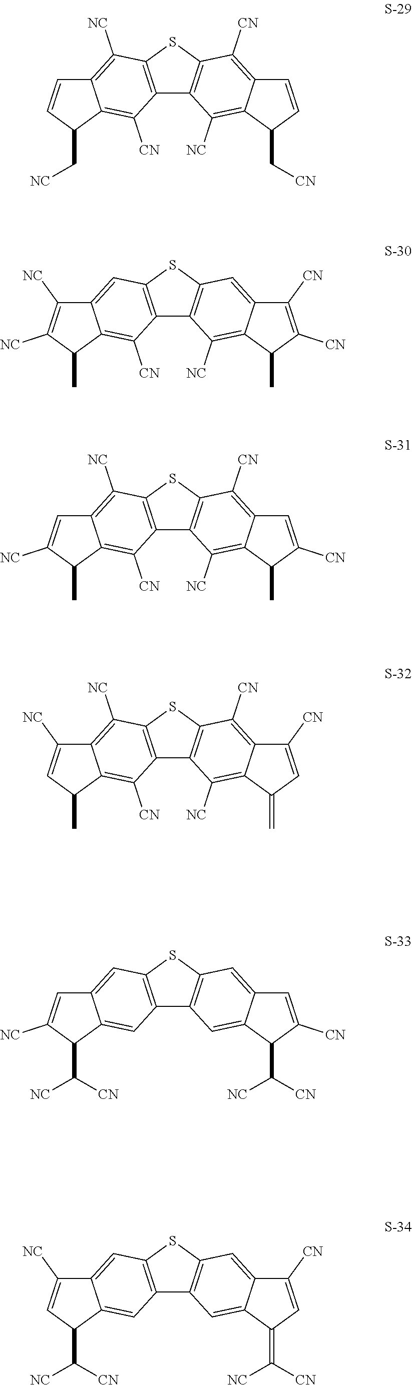 [SMILES: N#CC[C@H]1C=Cc2c1c(C#N)c1c(sc3c(C#N)c4c(c(C#N)c31)[C@H](CC#N)C=C4)c2C#N ; C[C@@H]1C(C#N)=C(C#N)c2cc3sc4cc5c(c(C#N)c4c3c(C#N)c21)[C@@H](C)C(C#N)=C5C#N ; C[C@@H]1C(C#N)=Cc2c1c(C#N)c1c(sc3c(C#N)c4c(c(C#N)c31)[C@@H](C)C(C#N)=C4)c2C#N ; C=C1C=C(C#N)c2c1c(C#N)c1c(sc3c(C#N)c4c(c(C#N)c31)[C@@H](C)C=C4C#N)c2C#N ; N#CC1=Cc2cc3sc4cc5c(cc4c3cc2[C@@H]1C(C#N)C#N)[C@@H](C(C#N)C#N)C(C#N)=C5 ; N#CC1=CC(=C(C#N)C#N)c2cc3c(cc21)sc1cc2c(cc13)[C@@H](C(C#N)C#N)C=C2C#N]

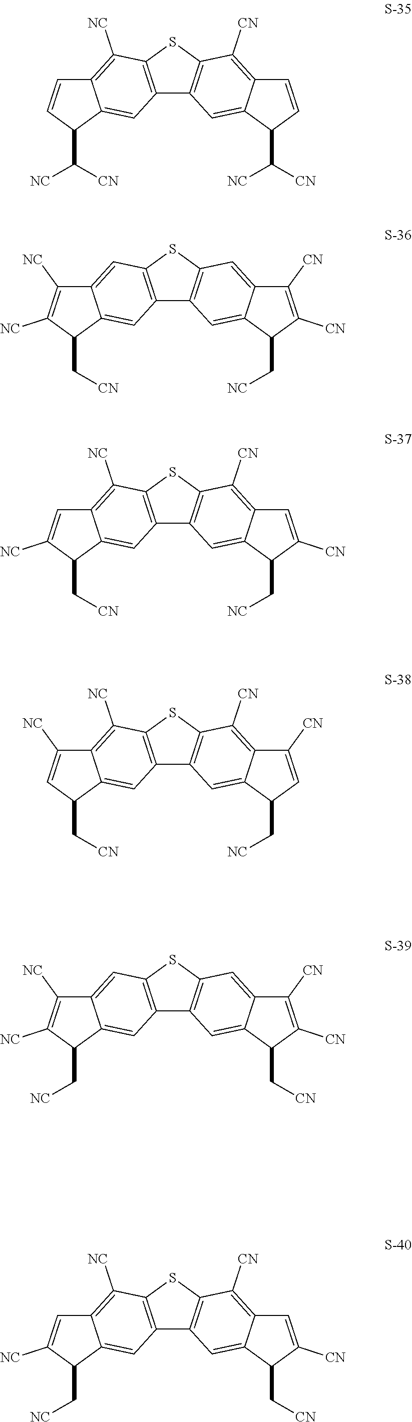 [SMILES: N#Cc1c2c(cc3c1sc1c(C#N)c4c(cc13)[C@@H](C(C#N)C#N)C=C4)[C@H](C(C#N)C#N)C=C2 ; N#CC[C@@H]1C(C#N)=C(C#N)c2cc3sc4cc5c(cc4c3cc21)[C@@H](CC#N)C(C#N)=C5C#N ; N#CC[C@@H]1C(C#N)=Cc2c1cc1c(sc3c(C#N)c4c(cc31)[C@@H](CC#N)C(C#N)=C4)c2C#N ; N#CC[C@H]1C=C(C#N)c2c1cc1c(sc3c(C#N)c4c(cc31)[C@H](CC#N)C=C4C#N)c2C#N ; N#CC[C@@H]1C(C#N)=C(C#N)c2cc3sc4cc5c(cc4c3cc21)[C@@H](CC#N)C(C#N)=C5C#N ; N#CC[C@@H]1C(C#N)=Cc2c1cc1c(sc3c(C#N)c4c(cc31)[C@@H](CC#N)C(C#N)=C4)c2C#N]

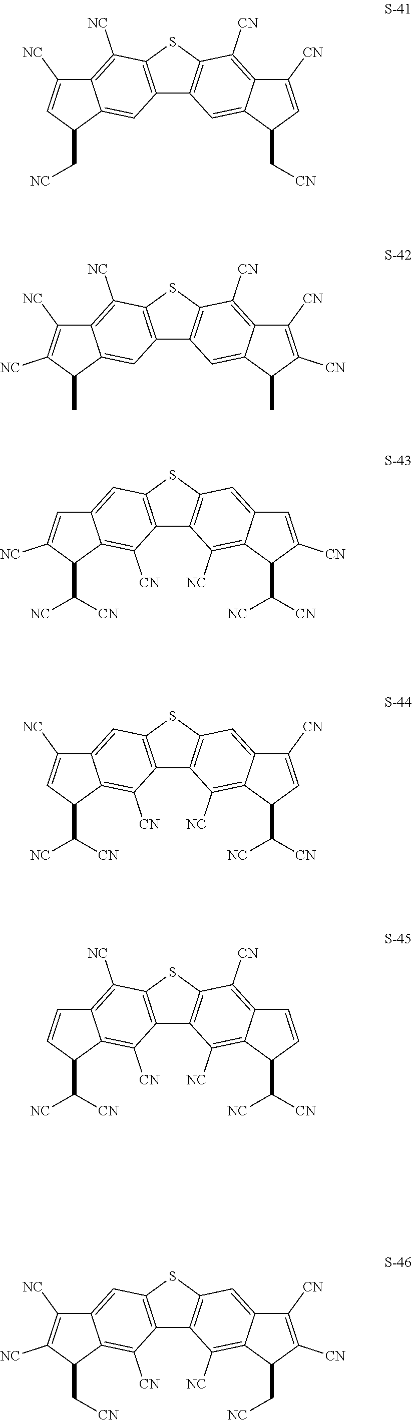 [SMILES: N#CC[C@H]1C=C(C#N)c2c1cc1c(sc3c(C#N)c4c(cc31)[C@H](CC#N)C=C4C#N)c2C#N ; C[C@@H]1C(C#N)=C(C#N)c2c1cc1c(sc3c(C#N)c4c(cc31)[C@@H](C)C(C#N)=C4C#N)c2C#N ; N#CC1=Cc2cc3sc4cc5c(c(C#N)c4c3c(C#N)c2[C@@H]1C(C#N)C#N)[C@@H](C(C#N)C#N)C(C#N)=C5 ; N#CC1=C[C@@H](C(C#N)C#N)c2c1cc1sc3cc4c(c(C#N)c3c1c2C#N)[C@@H](C(C#N)C#N)C=C4C#N ; N#Cc1c2c(c(C#N)c3c1sc1c(C#N)c4c(c(C#N)c13)[C@@H](C(C#N)C#N)C=C4)[C@H](C(C#N)C#N)C=C2 ; N#CC[C@@H]1C(C#N)=C(C#N)c2cc3sc4cc5c(c(C#N)c4c3c(C#N)c21)[C@@H](CC#N)C(C#N)=C5C#N]

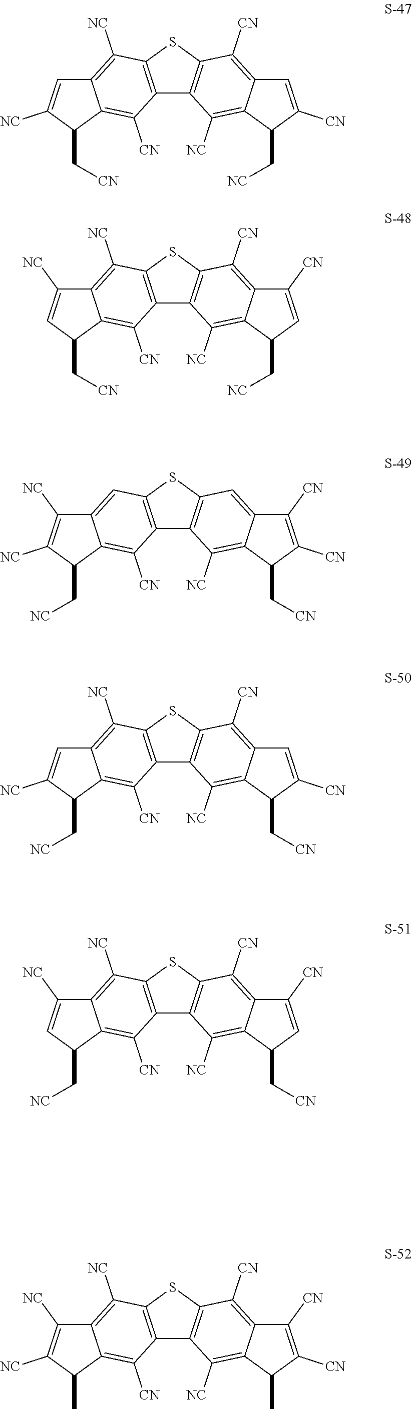

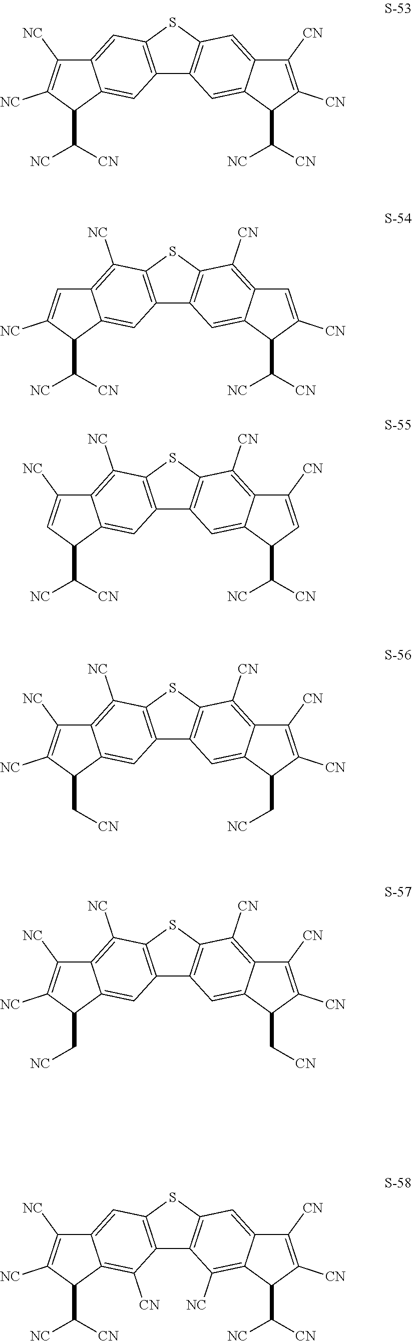

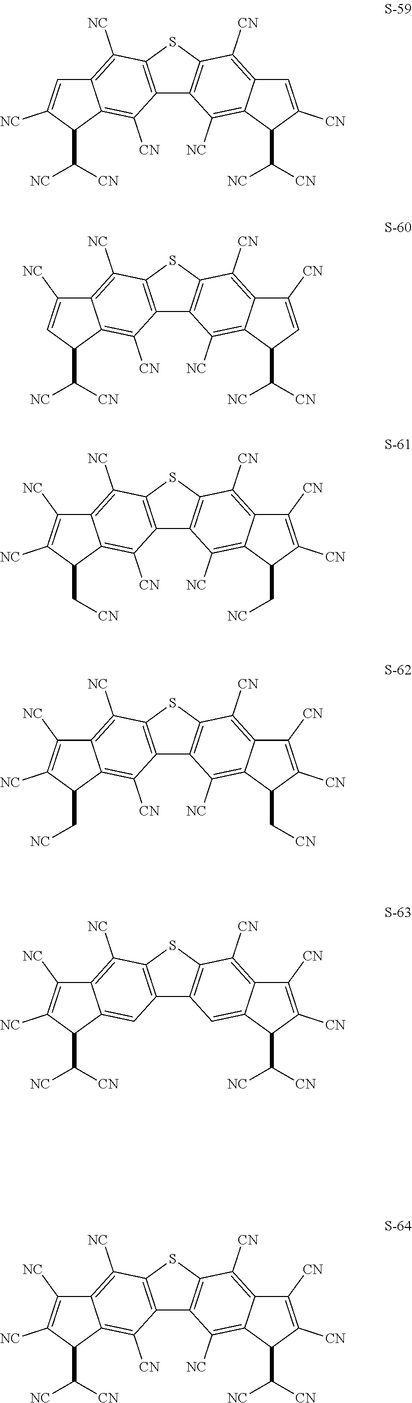

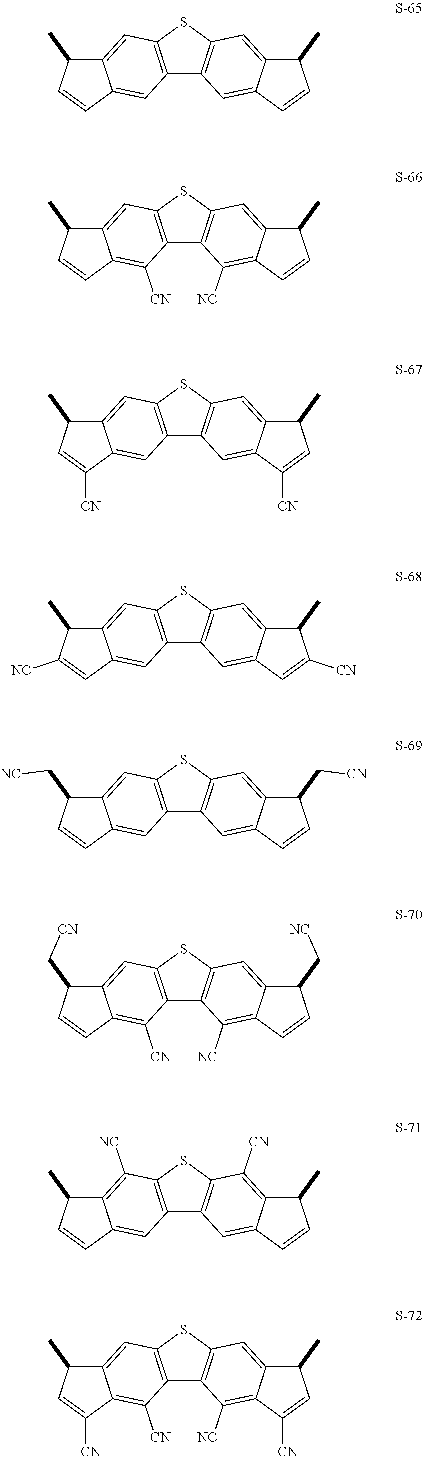

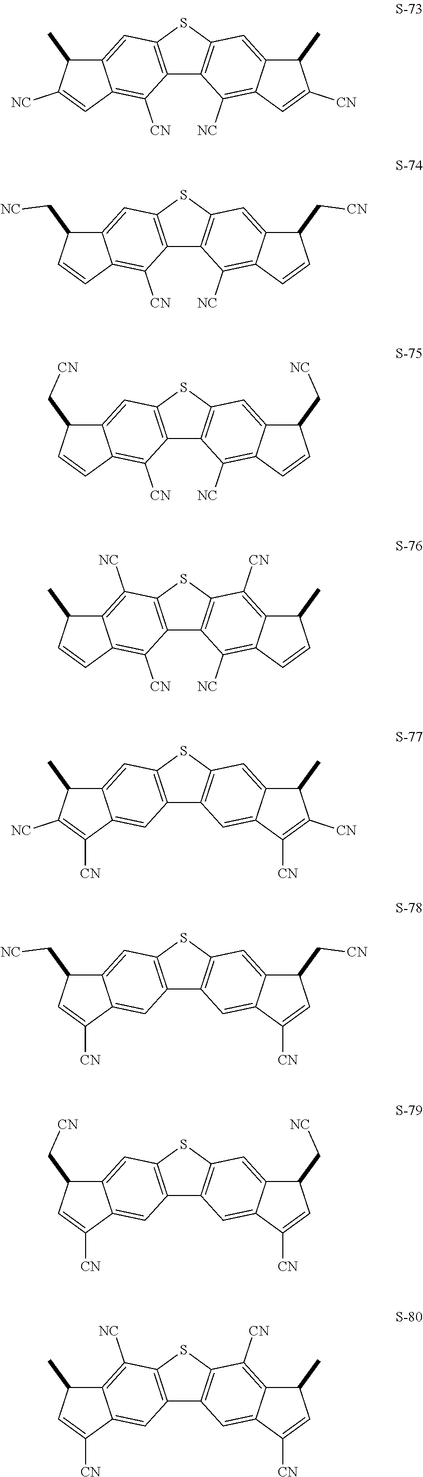

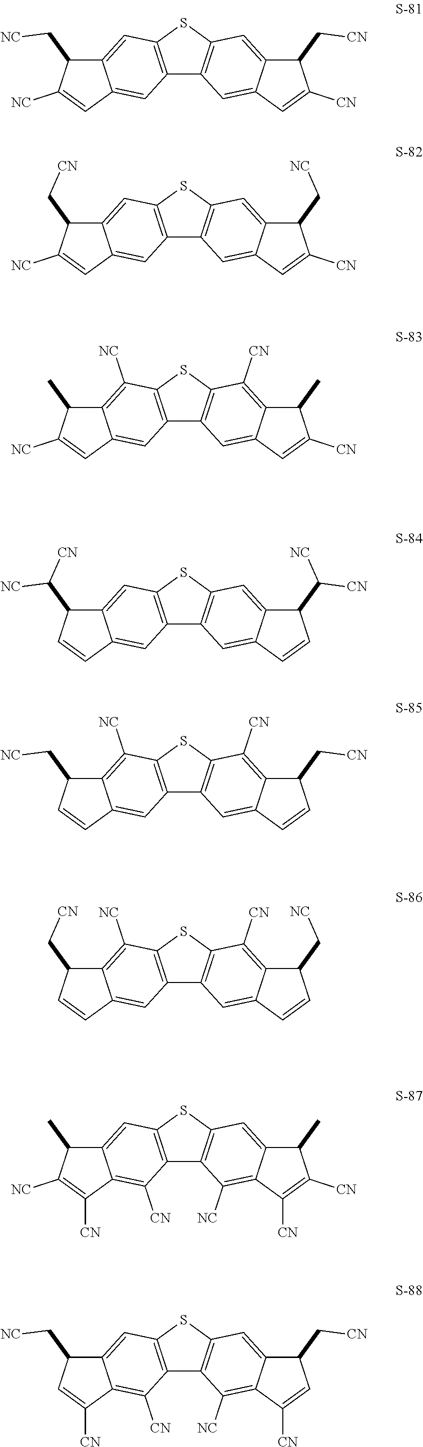

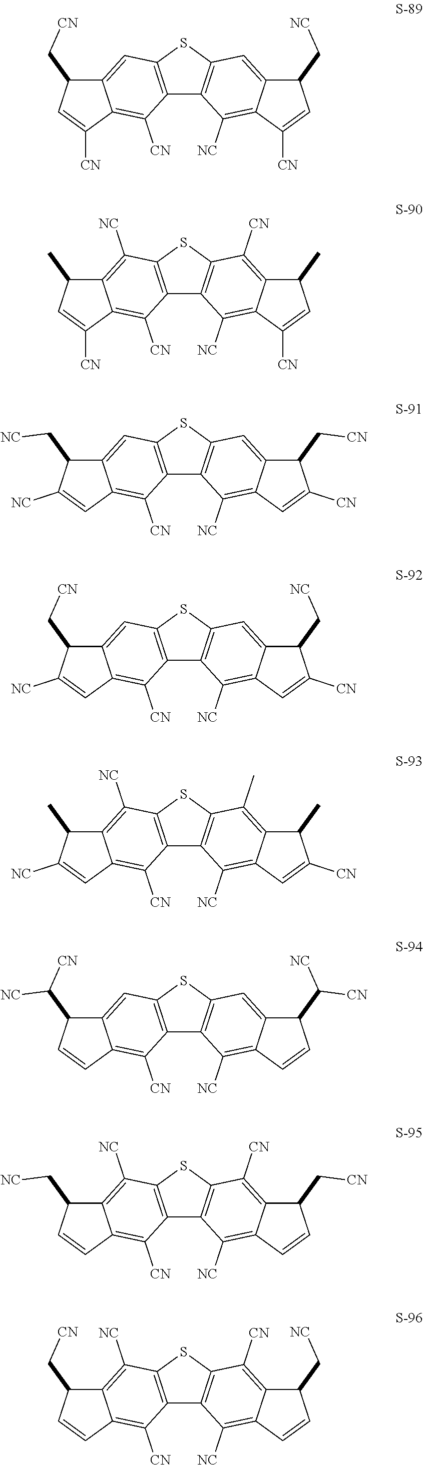

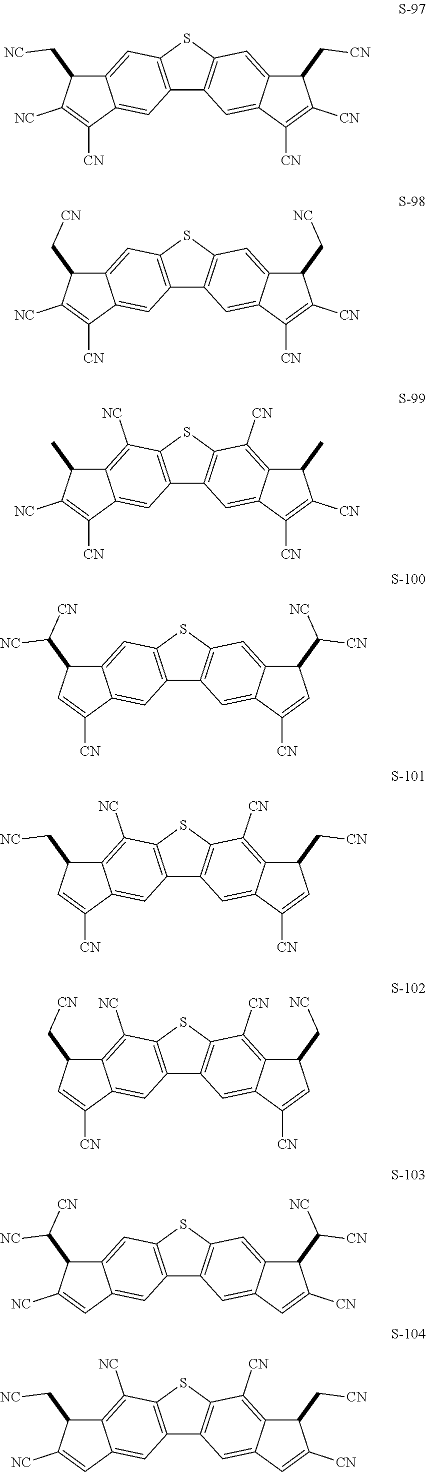

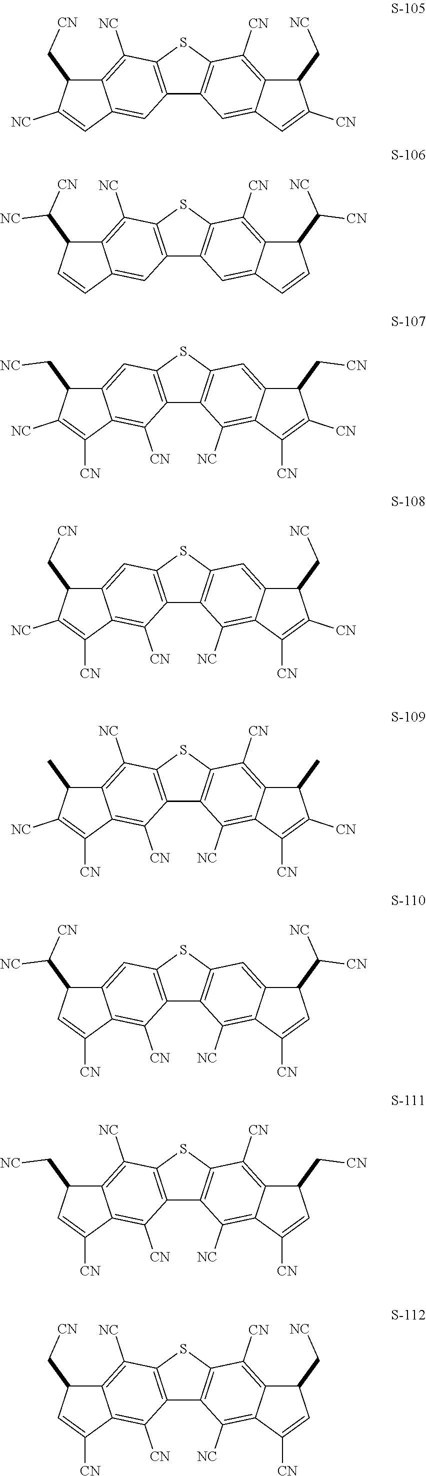

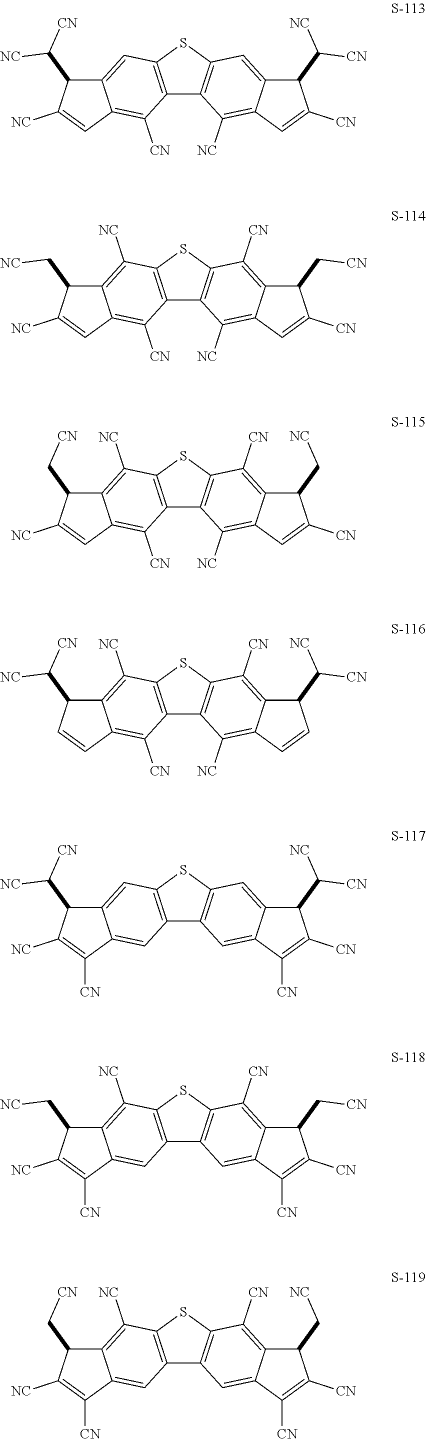

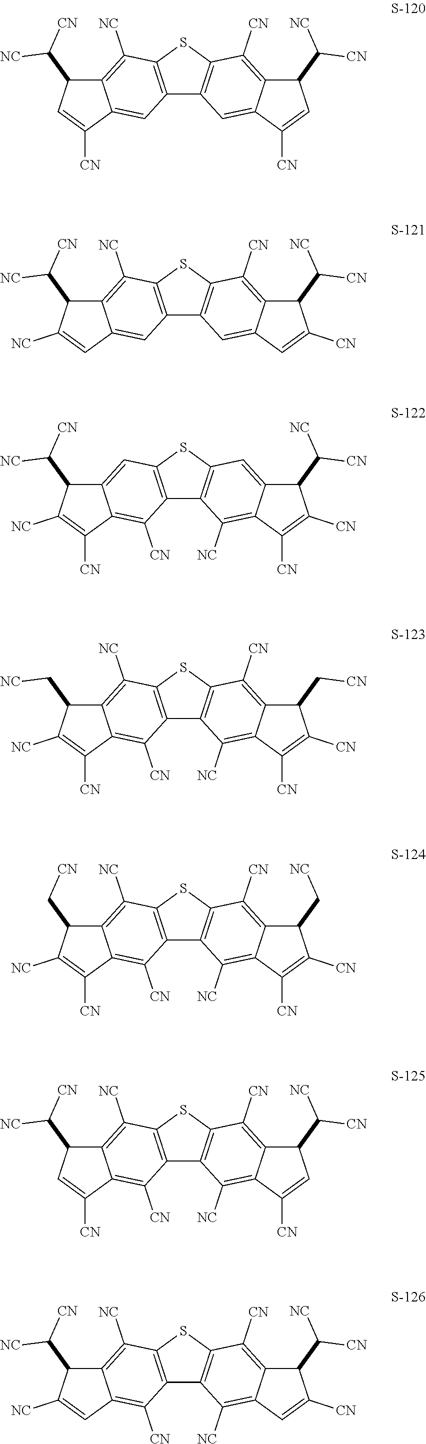

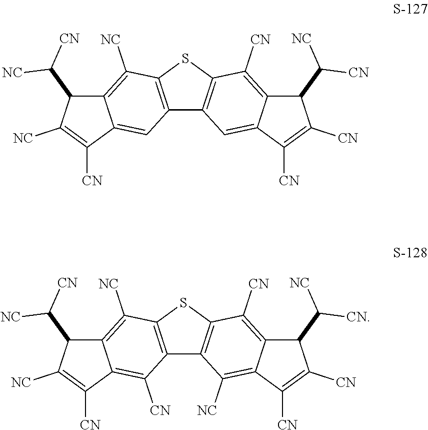 [SMILES: N#CC1=C(C#N)[C@@H](C(C#N)C#N)c2c1cc1c(sc3c(C#N)c4c(cc31)C(C#N)=C(C#N)[C@@H]4C(C#N)C#N)c2C#N ; N#CC1=C(C#N)[C@@H](C(C#N)C#N)c2c1c(C#N)c1c(sc3c(C#N)c4c(c(C#N)c31)C(C#N)=C(C#N)[C@@H]4C(C#N)C#N)c2C#N]

The light-emitting diode according to one or more embodiments may include a compound of one or more embodiments so that a driving voltage is lowered and a maximum quantum efficiency is improved.

The compound of one or more embodiments may contribute to lowering a driving voltage and improving a maximum quantum efficiency of a light-emitting diode by including the compound. An electronic device may be manufactured by utilizing the light-emitting diode. However, aspects of present disclosure are not limited thereto and may be variously expanded without departing from an idea and scope of present disclosure.

### BRIEF DESCRIPTION OF DRAWINGS

The accompanying drawings are included to provide a further understanding of the present disclosure and are incorporated in and constitute a part of this disclosure. The drawings illustrate embodiments of the present disclosure and, together with the description, serve to explain principles of the disclosure. These and/or other features will become apparent and more readily appreciated from the following description of one or more embodiments, taken in conjunction with the accompanying drawings, in which:

FIG. 1 is a plan view illustrating a display device according to one or more embodiments of the disclosure;

FIG. 2 is a cross-sectional view taken along the I-I′ line of FIG. 1;

FIGS. 3 to 6 are each a cross-sectional view illustrating a light-emitting diode according to one or more embodiments of the disclosure;

FIGS. 7 and 8 are each a cross-sectional view illustrating a portion of a display device according to one or more embodiments of the disclosure; and

FIG. 9 and FIG. 10 are each a drawing illustrating electronic devices applied with a display device according to one or more embodiments of the present disclosure.

### DETAILED DESCRIPTION

References will now be made in more detail to certain embodiments, of which examples are illustrated in the accompanying drawings, where like reference numerals refer to like elements throughout the disclosure, and duplicative descriptions thereof may not be provided for conciseness. The presented embodiments may have a variety of forms and permutations, but the present disclosure shall by no means be construed as being limited to the described embodiments. Rather, the present disclosure shall be construed to encompass all forms, permutations, equivalents, and substitutes covered by the technical ideas and scope of the present disclosure. Accordingly, one or more embodiments are merely described, by referring to the drawings, to explain features of the present disclosure and to convey the scope of the present disclosure to those skilled in the art.

Unless otherwise defined, all technical terms and scientific terms used herein have the same meaning as how they are generally understood by those of ordinary skill in the art to which the present disclosure pertains. However, if (e.g., when) the meanings do not match, a description, including a definition, of the present disclosure takes precedence.

Terms such as “first” and “second” may be used in describing one or more suitable elements, but the elements shall not be restricted to the terms. The terms may be used only to distinguish one element from the other. For instance, the first element may be named the second element, and vice versa, without departing the scope of the present disclosure. Unless clearly used otherwise, any expressions in a singular form may include a meaning of a plural form. For example, the singular forms “a,” “an,” “one,” and “the” are intended to include the plural forms as well, unless the context clearly indicates otherwise. The term “and/or” or “or” as used herein shall include the combination of a plurality of listed items or any of the plurality of listed items. Further, the utilization of “may” when describing embodiments of the present disclosure refers to “one or more embodiments of the present disclosure”.

When an element is described to be “on,” “arranged on,” “placed on,” “connected to,” or “coupled to” another element, it shall be construed as being arranged on, placed on, connected to, or coupled to the other element directly but also as possibly having another element therebetween. In contrast, if (e.g., when) one element is described to be “directly on,” “directly arranged on,” “directly placed on,” “directly connected to,” or “directly coupled to” another element, it shall be construed that there is no other element arranged between the element and the another element.

An expression such as “comprise(s)/comprising” “include(s)/including” or “has(have)/having” is intended to designate a characteristic, a number, a step (e.g., act or task), an operation, an element, a part, and/or one or more (e.g., any suitable) combinations thereof, and shall not be construed to preclude any possibility of presence or addition of one or more other characteristics, numbers, steps, operations, elements, parts and/or one or more combinations thereof. Additionally, the terms “comprise(s)/comprising,” “include(s)/including,” “has(have)/having,” or other similar terms include or support the terms “consisting of” and “consisting essentially of,” indicating the presence of stated features, integers, steps, operations, elements, components, and/or groups, without or essentially without the presence of other features, integers, steps, operations, elements, components, and/or groups thereof.

When a component is described to be arranged “on (or below)” an element or “above (or below)” an element, it shall be construed not only as being arranged directly on (or below) the element but also as possibly having another element arranged between the component and the element.

Any reference to “and/or” shall be construed to include one or more combinations that can be defined by relevant elements.

A size and a thickness of each configuration illustrated in a drawing is shown as an example for convenience, and embodiments of the present disclosure are not limited thereto.

In one or more embodiments, as used herein, [symbol] and [symbol] may each refer to a binding site.

As used herein, a direct linkage may refer to a chemical bond, such as a single bond.

As used herein, examples of halogens may include fluorine, chlorine, bromine, and iodine.

As used herein, a “substituted or unsubstituted” group may be a group unsubstituted or substituted with at least one substituent selected from among a group containing deuterium, a halogen, a nitro group, an amine group, a cyano group, a silyl group, an oxy group, a thio group, a sulfinyl group, a sulfonyl group, a carbonyl group, a boron group, an alkyl group, an alkenyl group, an alkynyl group, an alkoxy group, a phosphine sulfide group, a phosphine oxide group, a hydrocarbon ring group, an aryl group, and a heterocyclic group. In addition, the substituents presented as examples above may each be substituted or unsubstituted. For example, a biphenyl group may be construed as an aryl or as a phenyl group substituted with a phenyl group.

As used herein, the phrase “forming a ring by combining with an adjacent group” and/or the like may refer to forming a substituted or unsubstituted hydrocarbon ring, or a substituted or unsubstituted heterocycle by combining with an adjacent group. The hydrocarbon ring includes an aliphatic hydrocarbon ring and/or an aromatic hydrocarbon ring. The heterocycle includes an aliphatic heterocycle and/or an aromatic heterocycle. The carbon ring and the heterocycle may each be a monocycle or a polycycle. In addition, the formed ring may be combined with another ring to form a spiro structure.

As used herein, a fluorenyl group may be substituted, and two substituents may be combined to form a spiro structure with the fluorenyl group.

As used herein, the phrase “an adjacent group” may refer to a substitute connected to an atom which is directly connected to another atom substituted with another substituent; a substituent connected to an atom which is substituted with another substituent; or a substituent sterically positioned at the nearest position to another substituent. For example, two methyl groups in 1,2-dimethylbenzene may be interpreted as an “adjacent group” to each other.

As used herein, an alkyl group may have a linear chain or a branched chain. The number of carbons in the alkyl group may be 1 to 30, 1 to 20, or 1 to 10. Non-limiting examples thereof may include methyl, ethyl, propyl, n-propyl, isopropyl, butyl, n-butyl, isobutyl, tert-butyl, sec-butyl, 1-methyl-butyl, 1-ethyl-butyl, pentyl, n-pentyl, isopentyl, neopentyl, tert-pentyl, hexyl, n-hexyl, 1-methylpentyl, 2-methylpentyl, 3,3-dimethylbutyl, 2-ethylbutyl, heptyl, n-heptyl, 1-methylhexyl, octyl, n-octyl, tert-octyl, 1-methylheptyl, 2-ethylhexyl, 2-propylpentyl, n-nonyl, 2,2-dimethylheptyl, 1-ethyl-propyl, 1,1-dimethyl-propyl, isohexyl, 2-methylpentyl, 4-methylhexyl, and 5-methylhexyl.

As used herein, a cycloalkyl group may refer to a cyclic alkyl group. The number of carbons in the cycloalkyl group may be 3 to 50, 3 to 30, or 3 to 10. Non-limiting examples of the cycloalkyl group may include cyclopropyl, cyclobutyl, cyclopentyl, cyclohexyl, 4-methylcyclohexyl, 4-t-butylcyclohexyl, cycloheptyl, cyclooctyl, cyclononyl, cyclodecyl, norbornyl, 1-adamantyl, 2-adamantyl, isobornyl, and bicycloheptyl.

As used herein, an alkenyl group may refer to a hydrocarbon group including one or more carbon-carbon double bonds in the middle and/or at the terminal of an alkyl group having 2 or more carbons. An alkenyl group may have a linear chain or a branched chain. The number of carbons in the alkenyl group may be, but not limited to, 2 to 30, 2 to 20 or 2 to 10. Non-limiting examples of the alkenyl group may include 1-butenyl, 1-pentenyl, 1,3-butadienyl aryl, and styrenyl.

As used herein, an alkynyl group may refer to a hydrocarbon group including one or more carbon-carbon triple bonds in the middle and/or at the terminal of an alkyl group having 2 or more carbons. The number of carbons in the alkynyl group may be, but not limited to, 2 to 30, 2 to 20 or 2 to 10. Non-limiting examples thereof may include ethynyl and propynyl.

As used herein, a carbocyclic group refers to a monocyclic group or a polycyclic group having 3 to 60 ring-forming carbons including carbon only as a ring-forming atom. The carbocyclic group having 3 to 60 carbons may include an aromatic carbocyclic group and a non-aromatic carbocyclic group, for example, a non-aromatic carbocyclic group. In addition, as used herein, a heterocyclic group is a cyclic group having 1 to 60 ring-forming carbons and further including a heteroatom as a ring-forming atom other than a carbon. The heteroatom may include at least one of B, O, N, P, Si, or S.

As used herein, a hydrocarbon ring group may be an any functional group or a substituent derived from an aliphatic hydrocarbon ring, or any functional group or a substituent derived from an aromatic hydrocarbon ring. The hydrocarbon ring group may have at least one heteroatom selected from among B, O, N, P, Si, and S as ring-forming atom. When two or more heteroatoms are included, the two or more heteroatoms may be identical or different.

As used herein, an aryl group refers to a functional group or a substituent derived from an aromatic hydrocarbon ring. The aryl group may be a monocyclic aryl or a polycyclic aryl. The aryl group may have 6 to 60, 6 to 30, 6 to 20, or 6 to 15 ring-forming carbons. Non-limiting examples of the aryl group may include a phenyl group, a fluorenyl group, an anthracenyl group, a naphthyl group, a terphenyl group, a biphenyl group, a sexiphenyl group, a triphenylenyl group, and a benzofluoranthenyl group.

As used herein, a heteroring group (i.e., a heterocyclic group) may refer to any functional group or substituent derived from a ring including at least one of B, O, N, P, Si, or S as a ring-forming heteroatom. The heteroring group may include an aliphatic heteroring group and/or an aromatic heteroring group. The aromatic heteroring group may be a heteroaryl group. The aliphatic heteroring and the aromatic heteroring may each be a monocyclic or a polycyclic.

As used herein, if (e.g., when) the heteroring group includes two or more heteroatoms, the two or more heteroatoms may be identical or different. The heteroring group may be a monocyclic heteroring or a polycyclic heteroring and interpreted as a concept including a heteroaryl group. The heteroring group may have 2 to 30, 2 to 20, or 2 to 10 ring-forming carbons.

As used herein, an aliphatic heteroring group may include at least one of B, O, N, P, Si, or S as a ring-forming heteroatom. The aliphatic heteroring group may have 2 to 30, 2 to 20, or 2 to 10 ring-forming carbons. Non-limiting examples of the aliphatic heteroring group may include a thiirane group, a pyrrolidine group, a piperidine group, a tetrahydrofuran group, and 1,4-dioxane group.

As used herein, a heteroaryl group may include at least one of B, O, N, P, Si, or S as a ring-forming atom. When the heteroaryl group includes two or more heteroatoms, the two or more heteroatoms may be identical or different. The heteroaryl group may be a monocyclic heteroring or a polycyclic heteroring. The heteroaryl group may have 2 to 60, 2 to 30, 2 to 20, or 2 to 10 ring-forming carbons. Non-limiting examples thereof may include a furan group, a pyrrole group, an imidazole group, a pyridine group, a pyrimidine group, a triazine group, a pyridazine group, a quinoline group, an isoquinoline group, a pyridopyrimidine group, a benzocarbazole group, a benzofuran group, and an oxazole group.

As used herein, the above description of the aryl group may be applied to an arylene group, except that the arylene group is a polyvalent (e.g., a divalent group). The above description of the heteroaryl group may be applied to a heteroarylene group, except that the heteroarylene group is a polyvalent (e.g., a divalent group). However, although it is not limited to example, the polyvalent group may refer to a trivalent or quadrivalent group or be applied with a description of a trivalent or quadrivalent group.

As used herein, a silyl group may include an alkyl silyl group and/or an aryl silyl group. Non-limiting examples of the silyl group may include, a trimethylsilyl group, a triethylsilyl group, a t-butyldimethylsilyl group, a vinyldimethylsilyl group, a propyldimethylsilyl group, a triphenylsilyl group, a diphenylsilyl group, and a phenylsilyl group.

As used herein, a boryl group may include an alkyl boryl and/or an aryl boryl group. Non-limiting examples of the boryl group may include a dimethylboryl group, a diethylboryl group, a t-butylmethylboryl group, a diphenylboryl group, and a phenylboryl group.

As used herein, a thio group may include an alkyl thio group and/or an aryl thio group. A thio group may indicate a group in which a sulfur atom is bonded to an alkyl or aryl group defined above. Non-limiting examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthiol group, and a naphthylthio group.

As used herein, an oxy group may indicate a group in which an oxygen atom is bonded to an alkyl or an aryl group defined above. The oxy group may include an alkoxy group and/or an aryl oxy group. An alkoxy group may be linear, branched, or cyclic. The number of carbons in the alkoxy group is not particularly limited, but may be, for example, 1 to 20, or 1 to 10. Non-limiting examples of the oxy group may include a methoxy, an ethoxy, a n-propoxy, an isopropoxy, a butoxy, a pentyloxy, a hexyloxy, an octyloxy, a nonyloxy, a decyloxy, and a benzyloxy.

As used herein, a boron group may refer to a group in which a boron atom is bonded to an alkyl group or an aryl group defined above. The boron group may include an alkyl boron group and/or an aryl boron group. Non-limiting examples of the boron group may include a dimethyboron group, a diethylboron group, a t-butylmethylboron group, a diphenylboron group, and a phenylboron group.

As used herein, the number of carbons in an amine group is not particularly limited, but may be 1 to 30. The amine group may include an alkyl amine group and/or an aryl amine group. Non-limiting examples of the amine group may include a methylamine group, a dimethylamine group, a phenylamine group, a diphenylamine group, a naphthylamine group, a 9-methyl-anthracenylamine group, and a triphenylamine group.

Hereinafter, certain example embodiments of the present disclosure will be described in more detail with reference to the accompanying drawings.

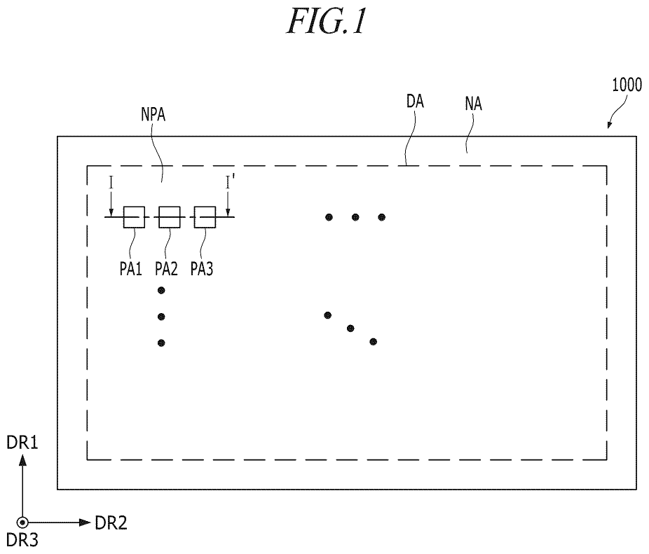

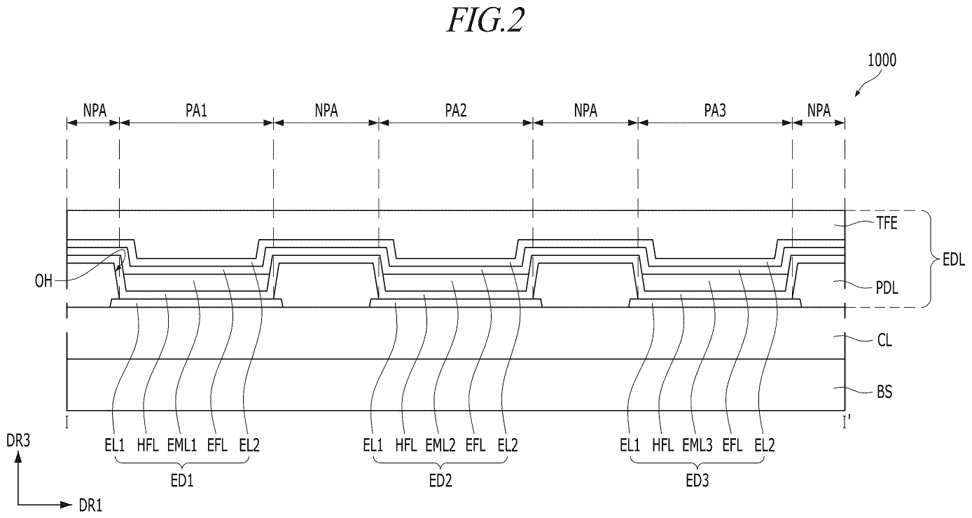

FIG. 1 is a plan view illustrating a display device according to one or more embodiments of the present disclosure, and FIG. 2 is a cross-sectional view of the display device, taken along the I-I′ line of FIG. 1, in accordance with one or more embodiments of the present disclosure.

In one or more embodiments of the present disclosure, first to third directions DR1, DR2, and DR3 may be defined. A first direction DR1 and a second direction DR2 may be directions defined on a plane of the display device 1000 shown in FIG. 1 and intersect with each other in directions. A third direction DR3 may be a direction of thickness of the display device shown in FIG. 2, for example normal to a plane defined by the first direction DR1 and the second direction DR2.

A display device 1000 may include a substrate BS, a circuit layer CL, and a display device layer EDL.

The circuit layer CL and the display device layer EDL may be arranged on the substrate.

The substrate BS may include glass, ceramic, a metal, or a polymer resin polyimide. Yet, embodiments of the present disclosure are not limited thereto, and the substrate BS may be an inorganic layer, an organic layer, or a composite material layer, and may be constituted with a single layer and a multilayer. The circuit layer CL may be arranged on the substrate BS and include a plurality of wires and a plurality of transistors. In one or more embodiments, the circuit layer CL may include pixel transistors configured to drive light-emitting diodes ED1, ED2, and ED3 of the display device layer EDL.

The circuit layer CL may include surrounding transistors arranged on a surrounding area NA and configured to output signals to control pixel transistors. The display device layer EDL may include a pixel defining film PDL, light-emitting diodes ED1, ED2, and ED3, and an encapsulation layer TFE.

The pixel defining film PDL may include at least one organic insulating material selected from the group consisted of a polyimide, a polyamide, an acryl resin, a benzocyclobutene-based resin, and a phenol resin.

The light-emitting didoes ED1, ED2, and ED3 may each include a first electrode EL1, a hole functional layer HFL, a respective light-emitting layer EML1, EML2, or EML3, an electron functional layer EFL, and a second electrode EL2.

The hole functional layer HFL may be configured to facilitate movement of a hole from the first electrode EL1 to the light-emitting layers EML1, EML2, and EML3, and the electron functional layer may be configured to facilitate movement of an electron from the second electrode EL2 to the light-emitting layers EML1, EML2, and EML3. FIG. 2 illustrates that the hole functional layer HFL is arranged between the first electrode EL1 and the light-emitting layer EML1, EML2, and EML3, and the electron functional layer is arranged between the second electrode EL2 and the light-emitting layer EML1, EML2, and EML3. However, embodiments of the present disclosure are not limited thereto, and the positions of the hole functional layer HFL and the electron functional layer EFL may be exchanged based on whether each of the first electrode and the second electrode EL2 is positively charged or negatively charged.

FIG. 2 illustrates one or more embodiments in which the respective light-emitting layer EML1, EML2, and EML3 of the light-emitting diodes ED1, ED2, and ED3 are arranged in an opening part OH defined in the pixel defining film PDL, and the hole functional layer HFL, the electron functional layer EFL, and the second electrode EL2 are each provided on a common layer throughout the light-emitting diode ED1, ED2, and ED3. However, embodiments of the present disclosure are not limited to what is illustrated in FIG. 2, for example, in one or more embodiments unlike what is illustrated in FIG. 2, at least one of the hole functional layer HFL or the electron functional layer EFL may be provided to be patterned through the opening part OH defined in the pixel defining film PDL.

In one or more embodiments, at least some of the light-emitting diodes ED1, ED2, and ED3 may be configured to emit light in a different wavelength range. For example, in one or more embodiments, a first light-emitting diode ED1 may be configured to emit red light, a second light-emitting diode ED2 may be configured to emit green light, and a third light-emitting diode ED3 may be configured to emit blue light. However, embodiments of the present disclosure are not limited to this configuration, for example, first to third light-emitting diodes ED1, ED2, and ED3 may be configured to emit light in substantially the same wavelength range, such as blue light.

A structure of each of the light-emitting diodes ED1, ED2, and ED3 and a material of a layer constituting each of the light-emitting diodes ED1, ED2 and ED3 will be described in more detail below with reference to one or more suitable embodiments.

The encapsulation layer TFE may be configured to seal off the light-emitting diodes ED1, ED2, and ED3 to protect the light-emitting diodes ED1, ED2, and ED3 from moisture, oxygen, and/or foreign substances. In one or more embodiments, the encapsulation layer TFE may be constituted with a single layer. In one or more embodiments, the encapsulation layer TFE may be constituted with multiple layers including an encapsulation organic film and an encapsulation inorganic film.

The encapsulation organic film may include one or more selected from among an acrylic compound, an epoxy compound, and/or the like. In one or more embodiments, the encapsulation organic film may include, but may not be limited to, one or more of photo-polymerizable organic materials.

The encapsulation inorganic film may include, but may not be limited to, silicon nitride, silicon oxynitride, silicon oxide, titanium oxide, aluminum oxide, and/or the like.

Referring to FIG. 1 and FIG. 2, the display device 1000 may include a display area DA and a surrounding area NA around the display area. The display area DA may be an area configured to display an image, and the surrounding area NA may be an area configured not to display an image. In certain embodiments, the surrounding area NA may not be provided.

Pixel areas PA1, PA2, and PA3 and a non-pixel area NPA may be defined in the display area DA. As light-emitting diodes ED1, ED2, and ED3 may be arranged to correspond to the pixel areas PA1, PA2, and PA3, respectively, the pixel areas may be areas configured to display emitted light. The non-pixel area NPA may be an area defined among the pixel areas PA1, PA2, and PA3 and correspond to the pixel defining film PDL.

Although it is illustrated in FIG. 1 and FIG. 2 that the pixel areas PA1, PA2, and PA3 have a same area, embodiments of the present disclosure are not limited to what is illustrated in FIG. 1 and FIG. 2, for example, in one or more embodiments, a portion of the pixel areas PA1, PA2, and PA3 may have a different area from another portion.

In one or more embodiments, the display device 1000 may further include an optical layer arranged on the display device layer EDL. The optical layer may be configured to reduce reflected light of external light. The optical layer may include, but not limited to, a color filter layer, color change layer, a touch-sensor layer, or a light polarization layer.

In one or more embodiments, the display device 1000 may further include a touch-sensor layer arranged on the display device layer EDL. The touch-sensor layer may be configured to determine a coordination of a touch where a touch occurs. The touch-sensor layer may be arranged between the display device layer EDL and the optical layer.

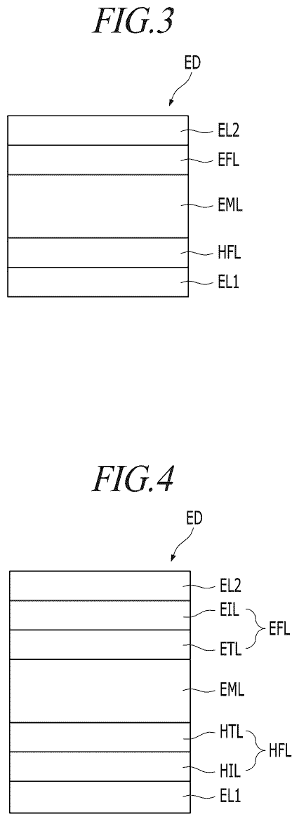

FIG. 3 to FIG. 6 are each a cross-sectional view illustrating a light-emitting diode according to one or more embodiments of the present disclosure. The light-emitting diode ED according to one or more embodiments of the present disclosure illustrated in FIG. 3 may include a first electrode EL1, a hole functional layer HFL, a light-emitting layer EML, an electron functional layer EFL, and a second electrode EL2 that are sequentially laminated (e.g., in the stated order).

In the light-emitting diode ED according to one or more embodiments of the present disclosure illustrated in FIG. 4, the hole functional layer HFL may include a hole injection layer HIL and a hole transport layer HTL, and the electron functional layer EFL may include an electron transport layer ETL and an electron injection layer EIL.

In the light-emitting diode ED according to one or more embodiments of the present disclosure illustrated in FIG. 5, the hole functional layer HFL may include a hole injection layer HIL, a hole transport layer HTL, and an electron bock layer EBL, and the electron functional layer EFL may include a hole block layer HBL, an electron transport layer ETL, and an electron injection layer EIL.

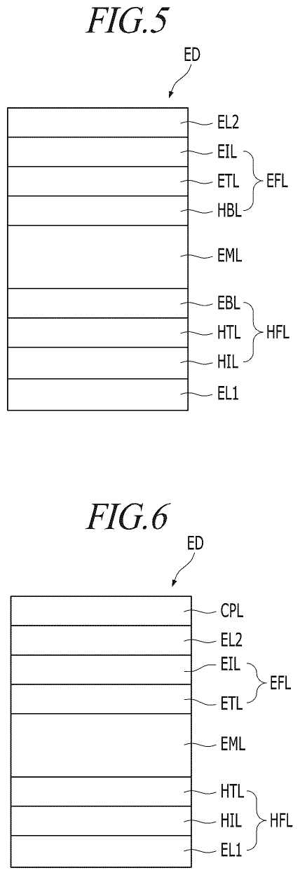

In one or more embodiments of the present disclosure shown in FIG. 6, compared to the structure in FIG. 4, the light-emitting diode ED may further include a capping layer CPL arranged on the second electrode EL2.

The first electrode EL1 may be conductive (e.g., is a conductor). The first electrode EL1 may include a metallic material, a metal alloy, or a conductive compound. The first electrode EL1 may be an anode or a cathode.

The first electrode EL1 may be a reflective electrode, a semi-transmissive electrode, or a transmissive electrode. If (e.g., when) the first electrode EL1 is a transmissive electrode, for example, material(s) such as indium tin oxide (ITO), indium zinc oxide (IZO), zinc oxide (ZnO), or indium tin zinc oxide (ITZO) may be included. If (e.g., when) the first electrode EL1 is a semi-transmissive electrode or a reflective electrode, the first electrode EL1 may include silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), a lamination structure of lithium fluoride (LiF) and Ca (LiF/Ca), a lamination structure of LiF and Al (LiF/Al), molybdenum (Mo), titanium (Ti), tungsten (W), and/or a (e.g., any suitable) combination and/or a (e.g., any suitable) mixture thereof (e.g., a mixture of Ag and Mg). In one or more embodiments, the first electrode EL1 may have a multilayer structure including a reflective film or a semi-transmissive film including one or more of the aforementioned materials, and a transparent conductive film including, for example, indium tin oxide (ITO), indium zinc oxide (IZO), zinc oxide (ZnO), or indium tin zinc oxide (ITZO) and/or the like. For example, in one or more embodiments, the first electrode EL1 may have a triple layer structure of ITO/Ag/ITO or a multiple layer structure of a triple layer structure of ITO/AI/ITO, but embodiments of the present disclosure are not limited to this configuration. The hole functional layer HFL may be provided on the first electrode EL1. The hole functional layer HFL may include at least one of a hole injection layer HIL, a hole transport layer HTL, a buffer layer, a light-emission auxiliary layer, or an electron block layer EBL.

The hole functional layer HFL may have a single layer structure including (e.g., consisted of) a single layer including a single material, a single layer structure including (e.g., consisted of) a single layer including a plurality of different materials or a multilayer structure including (e.g., consisted of) a plurality of layers including a plurality of different materials.

For example, in one or more embodiments, the hole functional layer HFL may have a structure in which a hole injection layer HIL/hole transport layer HTL, a hole injection layer HIL/hole transport layer HTL/buffer layer, a hole injection layer HIL/buffer layer, a hole transport layer HIL/buffer layer, or a hole injection layer HIL/hole transport layer HTL/electron block layer EBL are laminated in order (e.g., in the stated order) from the first electrode EL1. However, embodiments of the present disclosure are not limited thereto. The hole functional layer HFL may be manufactured using one or more suitable methods, such as a vacuum deposition method, a spin coating method, a Langmuir-Blodgett (LB) method, an inkjet printing method, a casting method, a laser printing method, and/or a laser induced thermal imaging (LITI) method. In one or more embodiments, the hole functional layer HFL may include a compound represented by Formula H-1, a compound represented by Formula H-2, and/or a (e.g., any suitable) combination thereof:

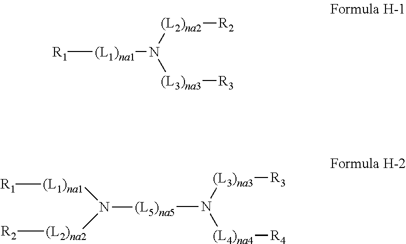

In Formula H-1 and Formula H-2, L₁ to L₅ may independently be a direct linkage, a substituted or unsubstituted arylene group having 6 to 30 ring-forming carbons, or a substituted or unsubstituted heteroarylene group having 2 to 30 ring-forming carbons.

na1 to na4 may independently be an integer between 0 and 5, inclusive.

In Formula H-1 and Formula H-2, R₁ to R₄ may independently be hydrogen, deuterium, a halogen, a substituted or unsubstituted alkyl group having 1 to 20 carbons, a cycloalkyl group having 3 to 10 ring-forming carbons, a substituted or unsubstituted heterocycloalkyl group having 1 to 10 ring-forming carbons, a substituted or unsubstituted cycloalkenyl group having 3 to 10 ring-forming carbons, a substituted or unsubstituted heterocycloalkenyl group having 1 to 10 ring-forming carbons, a substituted or unsubstituted aryl group having 6 to 60 ring-forming carbons, a substituted or unsubstituted aryloxy group having 6 to 60 carbons, a substituted or unsubstituted arylthiol group having 6 to 60 carbons, or a substituted or unsubstituted heteroaryl group having 1 to 60 ring-forming carbons.

For example, in one or more embodiments, R₁ to R₄ may independently be, but not limited to, a phenyl group, a biphenyl group, a terphenyl group, a naphthyl group, a fluorenyl group, a spiro-bifluorenyl group, a benzofluorenyl group, a dibenzofluorenyl group, a phenanthrenyl group, a fluoranthenyl group, triphenylenyl group, a pyrenyl group, a perylenyl group, a pentaphenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, or a pyridinyl group.

In one or more embodiments, R₁ and R₂ may be optionally bonded to each other via a single bond, and/or R₃ and R₄ may be optionally bonded to each other via a single bond.

In one or more embodiments of the present disclosure, compounds represented by Formula H-1 and Formula H-2 may be a carbazole-based compound including a substituted or unsubstituted carbazole group in at least one selected from among R₁ to R₄, or a compound including a substituted or unsubstituted fluorenyl group in at least one selected from among R₁ to R₄.

A compound represented by any formula selected from among Formula H-1 and Formula H-2 may be represented by Compound HT3 or Compound HT40 in a compound provided for a device manufacture example of the present disclosure, however embodiments of the present disclosure are not limited thereto.

In one or more embodiments, the hole functional layer HFL may include at least of 4,4′,4″-tris{N,-(2-naphthyl)-N-phenylamino}-triphenylamine (2-TNATA), Poly(3,4-ethylenedioxythiophene)/Poly(4-styrenesulfonate) (PEDOT/PSS), 4,4′,4″-tris(3-methylphenylphenylamino) triphenylamine (m-MTDATA), 4,4′4″-Tris(N,N-diphenylamino)triphenylamine (TDATA), a phthalocyanine compound, such as copper phthalocyanine, N,N′-diphenyl-N,N′-bis-[4-(phenyl-m-tolyl-amino)-phenyl]-biphenyl-4,4′-diamine (DNTPD), Polyaniline/Dodecylbenzenesulfonic acid (PANI/DBSA), N,N′-di(naphthalen-1-yl)-N,N′-diphenyl-benzidine (NPB), triphenylamine-containing polyetherketone (TPAPEK), 4-Isopropyl-4′-methyldiphenyliodonium [Tetrakis(pentafluorophenyl)borate], or dipyrazino[2,3-f:2′,3′-h]quinoxaline-2,3,6,7,10,11-hexacarbonitrile (HAT-CN).

In one or more embodiments, the hole functional layer HFL may include one or more selected from among a carbazole-based derivative, such as polyvinyl carbazole and/or N-phenyl carbazole, a fluorene-based derivative, a triphenylamine-based derivative, such as 4,4′4″-tris(N-carbazolyl)triphenylamine) (TCTA), N,N′-bis(3-methylphenyl)-N,N′-diphenyl-[1,1′-biphenyl]-4,4′-diamine (TPD), N,N′-di(naphthalen-1-yl)-N,N′-diphenyl-benzidine (NPB), 4,4′-Cyclohexylidene bis[N,N-bis(4-methylphenyl)benzenamine](TAPC), 4,4′-Bis[N,N′-(3-tolyl)amino]-3,3′-dimethylbiphenyl (HMTPD), and/or 1,3-Bis(N-carbazolyl)benzene (mCP).

In one or more embodiments, the hole functional layer HFL may include 1,3-bis(1,8-dimethyl-9H-carbazol-9-yl)benzene (mDCP), 9-(4-tert-Butylphenyl)-3,6-bis(triphenylsilyl)-9H-carbazole (CzSi), or 9-phenyl-9H-3,9′-bicarbazole (CCP).

The hole functional layer HFL may have a thickness of about 50 ångströms (A) to about 10000 Å, e.g., about 100 Å to about 5000 Å. If (e.g., when) the hole functional layer HFL includes a hole injection layer HIL, a hole transport layer HTL, or any combination thereof, the hole injection layer HIL may have a thickness of about 100 Å to about 9000 Å, e.g., about 100 Å to about 1000 Å, and the hole transport layer may have a thickness of about 50 Å to about 2000 Å, e.g., about 100 Å to about 1500 Å. When the thicknesses of the hole functional layer HFL, the hole injection layer HIL, and the hole transport layer HTL satisfy their respective above-described ranges, satisfactory level of hole transport properties may be obtained without a substantial increase in driving voltage.

In one or more embodiments, the hole functional layer HFL may further include, in addition to one or more of the above-described materials, a charge-generation material to increase conductivity. The charge-generation material may be uniformly (e.g., substantially uniformly) or non-uniformly dispersed in the hole functional layer HFL.

As described above, in one or more embodiments, the hole functional layer HFL may include at least one of a buffer layer or an electron block layer EBL, in addition to the hole injection layer HIL and the hole transport layer HTL. The buffer layer may be configured to compensate for a resonance distance according to a wavelength of light emitted from the light-emitting layer EML to increase light emitting efficiency. A material which may be included in the hole functional layer HFL may be used as a material included in the buffer layer.

The electron block layer EBL may be a layer configured to prevent or reduce the injection of electrons from the electron functional layer EFL to the hole functional layer HFL.

The light-emission auxiliary layer is a layer configured to compensate an optical resonance distance according to a wavelength of light emitted from the light-emitting layer to increase light-emitting efficiency, and the electron blocking layer EBL is a layer configured to prevent or reduce leakage of an electron from the light-emitting layer to the hole functional layer HFL. A material that may be included in the described hole functional layer HFL may be included in the emission auxiliary layer and the light blocking layer EBL.

According to one or more embodiments, the light-emitting diode ED may include a compound represented by Formula 1 of one or more embodiments:

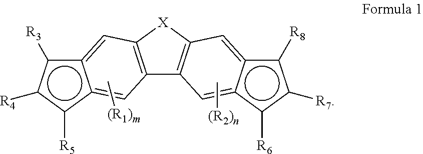

According to one or more embodiments, in Formula 1, X may be O, S, Ga, In, Ge, Sn, Pb, Sb, Bi, Se, or Te, and

R₁ to R₈ may each independently be selected from among: hydrogen, deuterium, halogens, a haloalkyl group, a hydroxyl group, a cyano group, a nitro group, a trifluoromethyl group, an amine group, an amidino group, a hydrazino group, a hydrazono group, and an alkoxy group; or be a phenyl group, an alkyl group having 1 to 10 carbons, an alkenyl group having 2 to 10 carbons, an alkynyl group having 2 to 10 carbons, an aryl group having 6 to 30 ring-forming carbons, a heteroaryl group having 2 to 30 ring-forming carbons, or any combination thereof, each substituted or unsubstituted with deuterium, a halogen, a hydroxyl group, a cyano group, a nitro group, a trifluoromethyl group, an amidino group, a hydrazino group, a hydrazono group, an alkoxy group, or any combination thereof (e.g., R₁ to R₈ may each independently be:
hydrogen, deuterium, a halogen, a haloalkyl group, a hydroxyl group, a cyano group, a nitro group, a trifluoromethyl group, an amine group, an amidino group, a hydrazino group, a hydrazono group, or an alkoxy group; or
a phenyl group, an alkyl group having 1 to 10 carbons, an alkenyl group having 2 to 10 carbons, an alkynyl group having 2 to 10 carbons, an aryl group having 6 to 30 ring-forming carbons, a heteroaryl group having 2 to 30 ring-forming carbons, or any combination thereof, each substituted or unsubstituted with hydrogen, deuterium, halogens, a hydroxyl group, a cyano group, a nitro group, a trifluoromethyl group, an amidino group, a hydrazino group, a hydrazono group, an alkoxy group, or any combination thereof), and
m and n may each independently be an integer between 0 and 2, inclusive.

According to one or more embodiments, the compound represented by Formula 1 may be represented by Formula 1-1 or Formula 1-2:

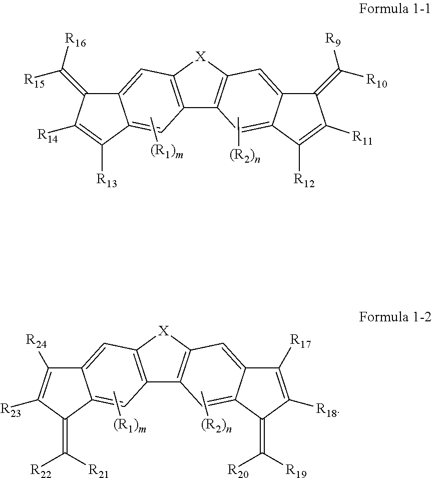

According to one or more embodiments, in Formulae 1-1 and 1-2, X may be selected from among O, S, Ga, In, Ge, Sn, Pb, Sb, Bi, Se, or Te,

R₁, R₂, and R₉ to R₂₄ may each independently be: hydrogen, deuterium, a halogen, a haloalkyl group, a hydroxyl group, a cyano group, a nitro group, a trifluoromethyl group, an amine group, an amidino group, a hydrazino group, a hydrazono group, or an alkoxy group; or be a phenyl group, an alkyl group having 1 to 10 carbons, an alkenyl group having 2 to 10 carbons, an alkynyl group having 2 to 10 carbons, an aryl group having 6 to 30 ring-forming carbons, a heteroaryl group having 2 to 30 ring-forming carbons, or any combination thereof, each substituted or unsubstituted with deuterium, a halogen, a haloalkyl group, a hydroxyl group, a cyano group, a nitro group, a trifluoromethyl group, an amine group, an amidino group, a hydrazino group, a hydrazono group, an alkoxy group, or any combination thereof (e.g., R₁, R₂, and R₉ to R₂₄ may each independently be:
hydrogen, deuterium, a halogen, a haloalkyl group, a hydroxyl group, a cyano group, a nitro group, a trifluoromethyl group, an amine group, an amidino group, a hydrazino group, a hydrazono group, or an alkoxy group; or
a phenyl group, an alkyl group having 1 to 10 carbons, an alkenyl group having 2 to 10 carbons, an alkynyl group having 2 to 10 carbons, an aryl group having 6 to 30 ring-forming carbons, a heteroaryl group having 2 to 30 ring-forming carbons, or any combination thereof, each substituted or unsubstituted with hydrogen, deuterium, halogens, a haloalkyl group, a hydroxyl group, a cyano group, a nitro group, a trifluoromethyl group, an amine group, an amidino group, a hydrazino group, a hydrazono group, an alkoxy group, or any combination thereof), and
m and n may each independently be an integer between 0 and 2, inclusive.

According to one or more embodiments, R₁, R₂, R₁₉, R₂₀, R₂₁, and R₂₂ may each independently be: a haloalkyl group, a hydroxyl group, a cyano group, a nitro group, a trifluoromethyl group, an amine group, or an alkoxy group; or be an alkenyl group having 2 to 10 carbons substituted or unsubstituted with a haloalkyl group, a hydroxyl group, a cyano group, a nitro group, a trifluoromethyl group, an amine group, an alkoxy group, or any combination thereof.

For example, R₁, R₂, R₁₉, R₂₀, R₂₁, and R₂₂ may each independently be:
a haloalkyl group, a hydroxyl group, a cyano group, a nitro group, a trifluoromethyl group, an amine group, or an alkoxy group; or
an alkenyl group having 2 to 10 carbons, substituted or unsubstituted with a haloalkyl group, a hydroxyl group, a cyano group, a nitro group, a trifluoromethyl group, an amine group, an alkoxy group, or any combination thereof.

According to one or more embodiments, X may be O or S. According to one or more embodiments, the compound represented by the Formula 1 may include at least one selected from among compounds of Compound Group 1 and/or at least one selected from among compounds of Compound Group 2:

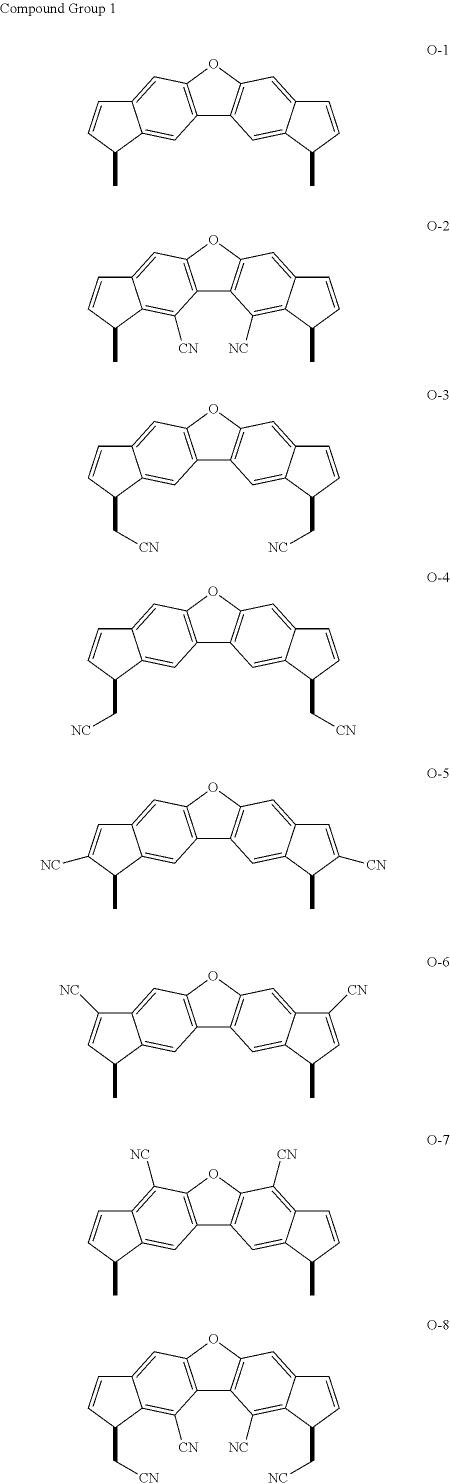

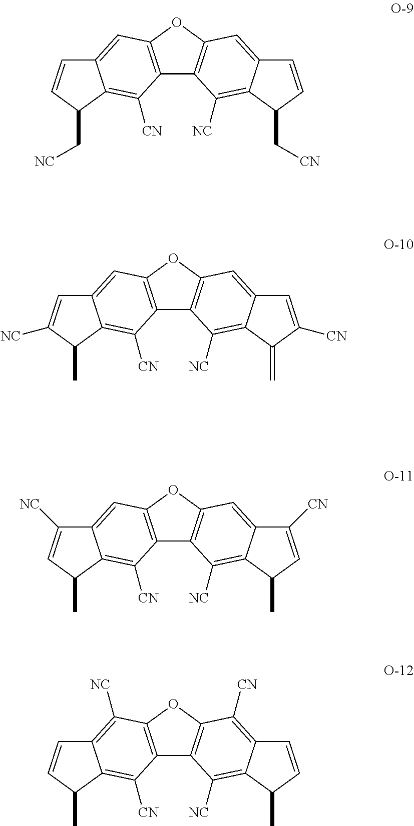 [SMILES: N#CC[C@H]1C=Cc2cc3oc4cc5c(c(C#N)c4c3c(C#N)c21)[C@H](CC#N)C=C5 ; C=C1C(C#N)=Cc2cc3oc4cc5c(c(C#N)c4c3c(C#N)c21)[C@@H](C)C(C#N)=C5 ; C[C@@H]1C=C(C#N)c2cc3oc4cc5c(c(C#N)c4c3c(C#N)c21)[C@@H](C)C=C5C#N ; C[C@@H]1C=Cc2c1c(C#N)c1c(oc3c(C#N)c4c(c(C#N)c31)[C@@H](C)C=C4)c2C#N]

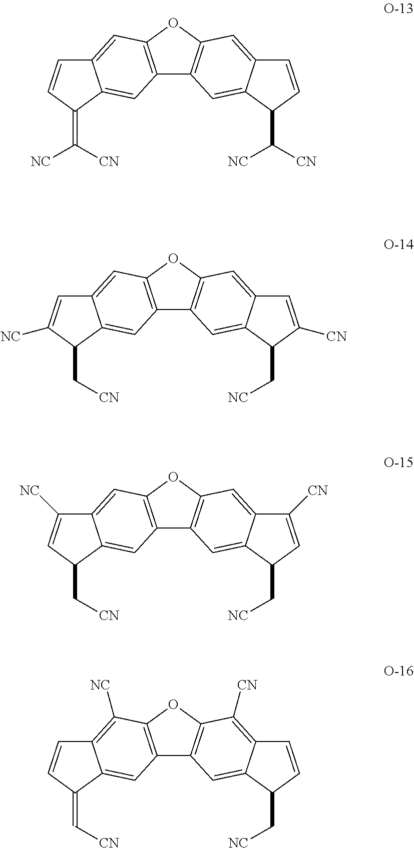 [SMILES: N#CC(C#N)=C1C=Cc2cc3oc4cc5c(cc4c3cc21)[C@H](C(C#N)C#N)C=C5 ; N#CC[C@@H]1C(C#N)=Cc2cc3oc4cc5c(cc4c3cc21)[C@@H](CC#N)C(C#N)=C5 ; N#CC[C@H]1C=C(C#N)c2cc3oc4cc5c(cc4c3cc21)[C@H](CC#N)C=C5C#N ; N#C/C=C1/C=Cc2c1cc1c(oc3c(C#N)c4c(cc31)[C@H](CC#N)C=C4)c2C#N]

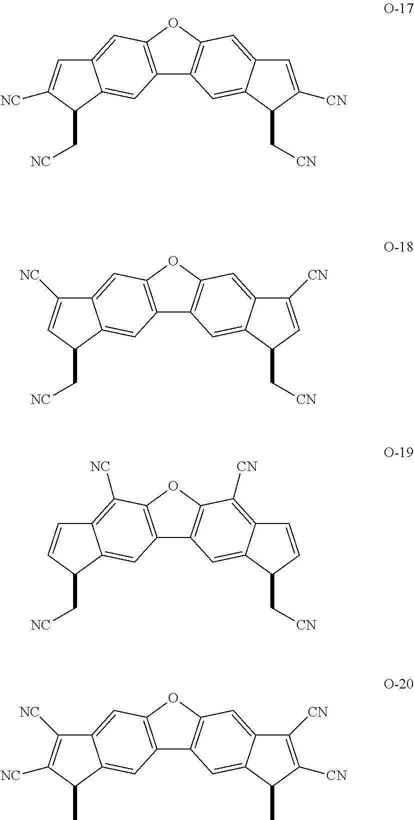 [SMILES: N#CC[C@@H]1C(C#N)=Cc2cc3oc4cc5c(cc4c3cc21)[C@@H](CC#N)C(C#N)=C5 ; N#CC[C@H]1C=C(C#N)c2cc3oc4cc5c(cc4c3cc21)[C@H](CC#N)C=C5C#N ; N#CC[C@H]1C=Cc2c1cc1c(oc3c(C#N)c4c(cc31)[C@H](CC#N)C=C4)c2C#N ; C[C@@H]1C(C#N)=C(C#N)c2cc3oc4cc5c(cc4c3cc21)[C@@H](C)C(C#N)=C5C#N]

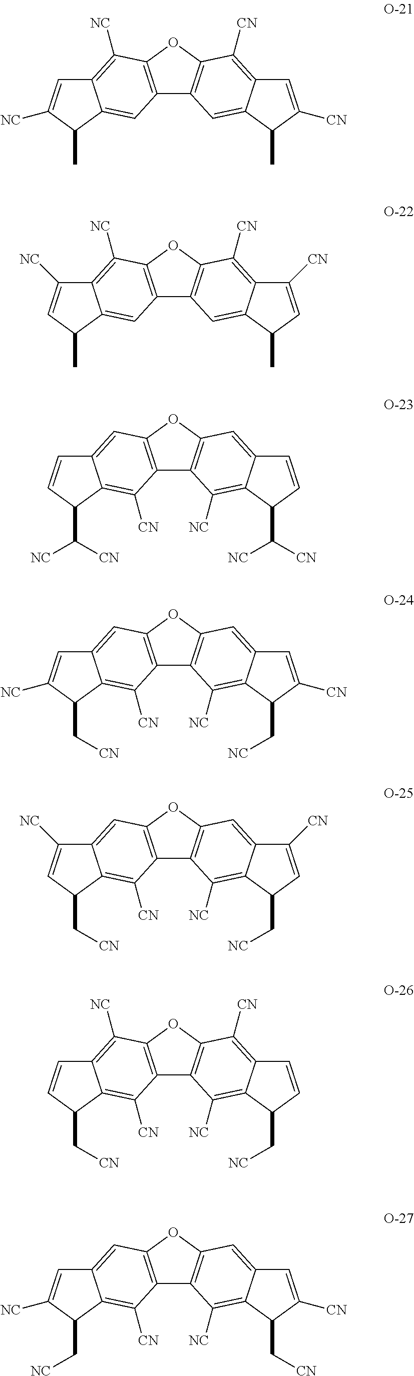

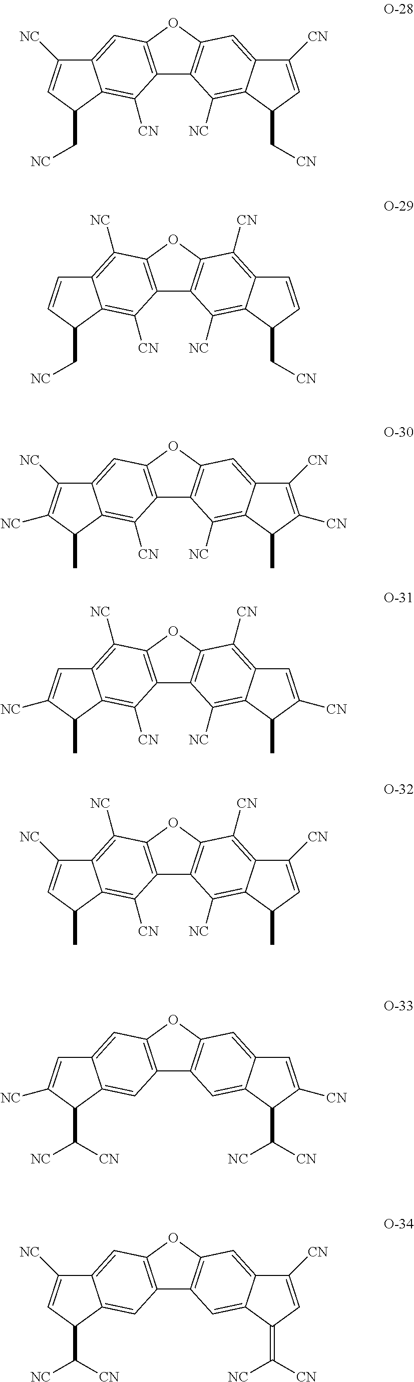

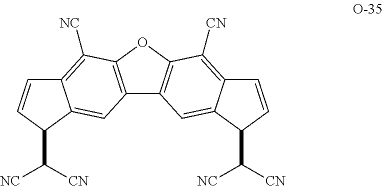 [SMILES: N#Cc1c2c(cc3c1oc1c(C#N)c4c(cc13)[C@@H](C(C#N)C#N)C=C4)[C@H](C(C#N)C#N)C=C2]

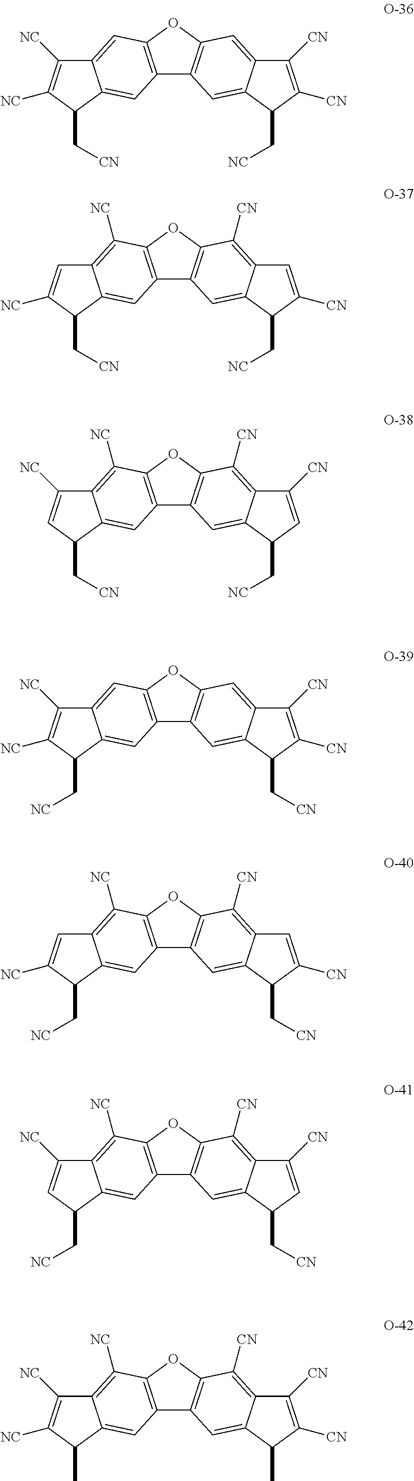

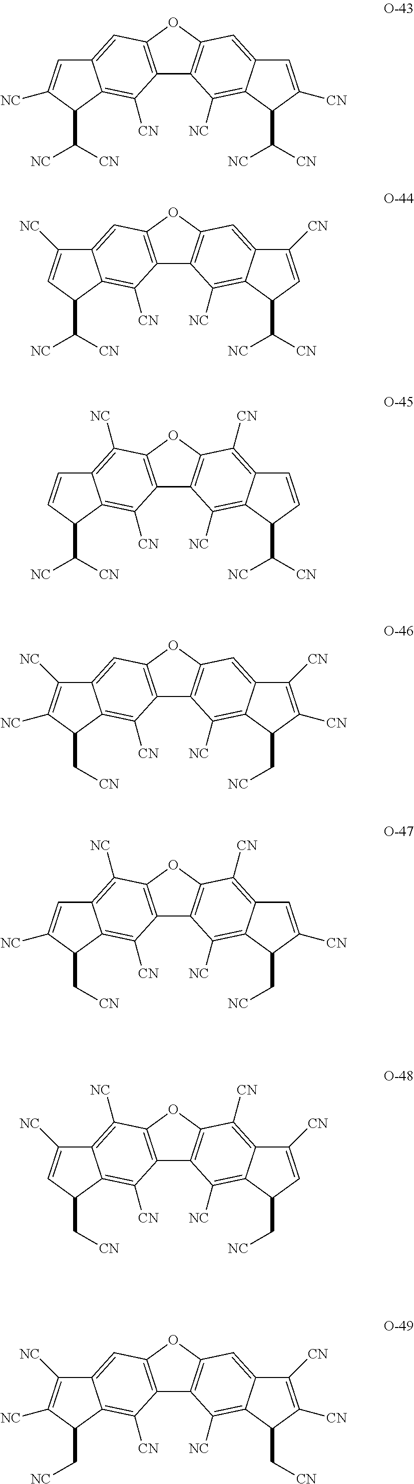

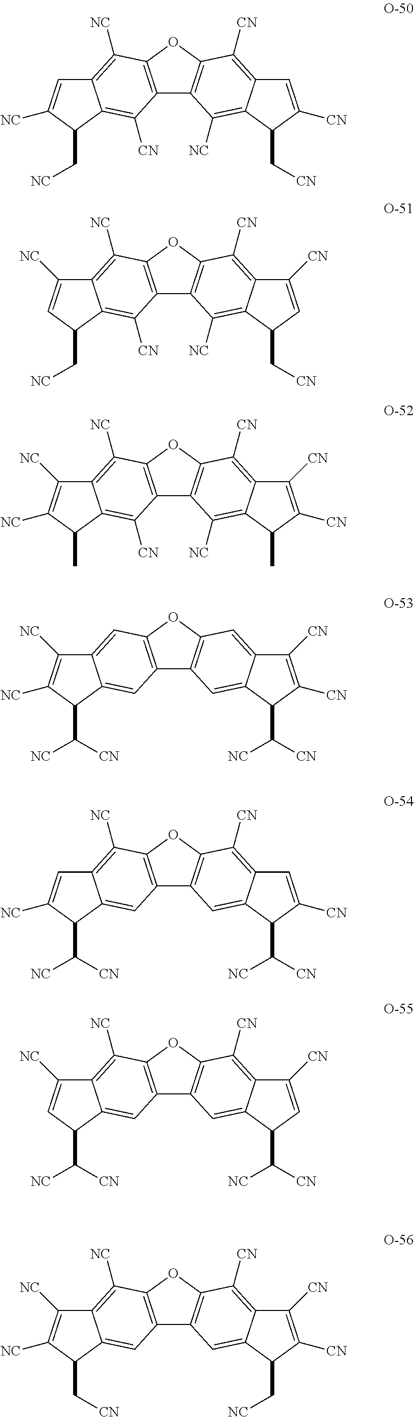

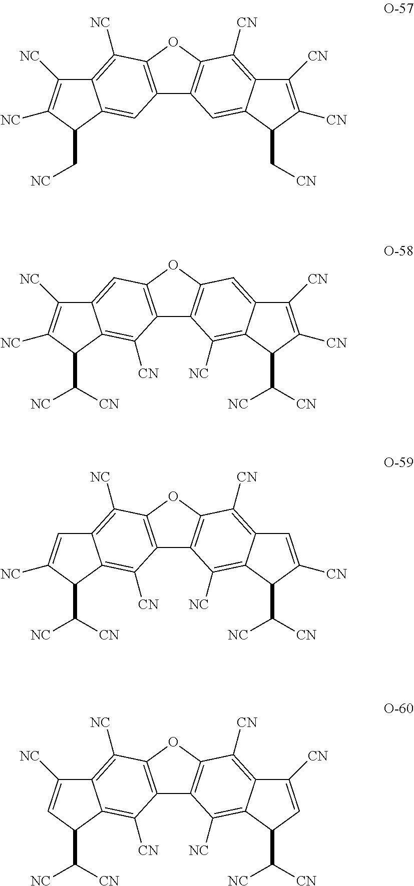 [SMILES: N#CC[C@@H]1C(C#N)=C(C#N)c2c1cc1c(oc3c(C#N)c4c(cc31)[C@@H](CC#N)C(C#N)=C4C#N)c2C#N ; N#CC1=C(C#N)[C@@H](C(C#N)C#N)c2c1cc1oc3cc4c(c(C#N)c3c1c2C#N)[C@@H](C(C#N)C#N)C(C#N)=C4C#N ; N#CC1=Cc2c(c(C#N)c3c(oc4c(C#N)c5c(c(C#N)c43)[C@@H](C(C#N)C#N)C(C#N)=C5)c2C#N)[C@@H]1C(C#N)C#N ; N#CC1=C[C@@H](C(C#N)C#N)c2c1c(C#N)c1oc3c(C#N)c4c(c(C#N)c3c1c2C#N)[C@@H](C(C#N)C#N)C=C4C#N]

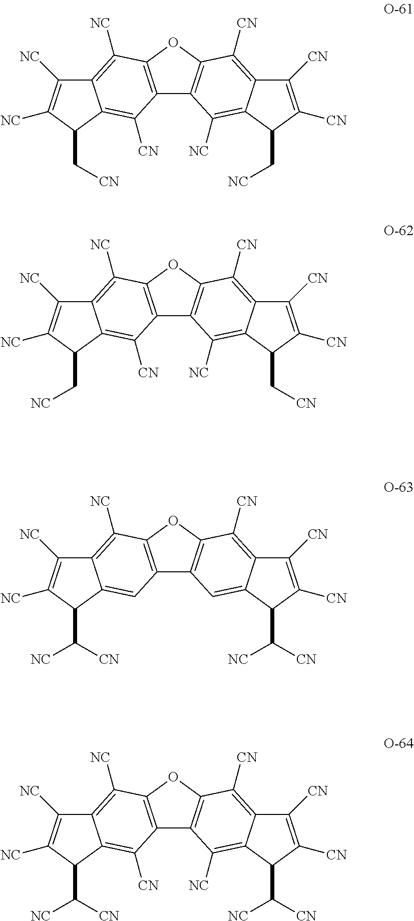 [SMILES: N#CC[C@@H]1C(C#N)=C(C#N)c2c1c(C#N)c1c(oc3c(C#N)c4c(c(C#N)c31)[C@@H](CC#N)C(C#N)=C4C#N)c2C#N ; N#CC[C@@H]1C(C#N)=C(C#N)c2c1c(C#N)c1c(oc3c(C#N)c4c(c(C#N)c31)[C@@H](CC#N)C(C#N)=C4C#N)c2C#N ; N#CC1=C(C#N)[C@@H](C(C#N)C#N)c2cc3c(oc4c(C#N)c5c(cc43)[C@@H](C(C#N)C#N)C(C#N)=C5C#N)c(C#N)c21 ; N#CC1=C(C#N)[C@@H](C(C#N)C#N)c2c1c(C#N)c1oc3c(C#N)c4c(c(C#N)c3c1c2C#N)[C@@H](C(C#N)C#N)C(C#N)=C4C#N]

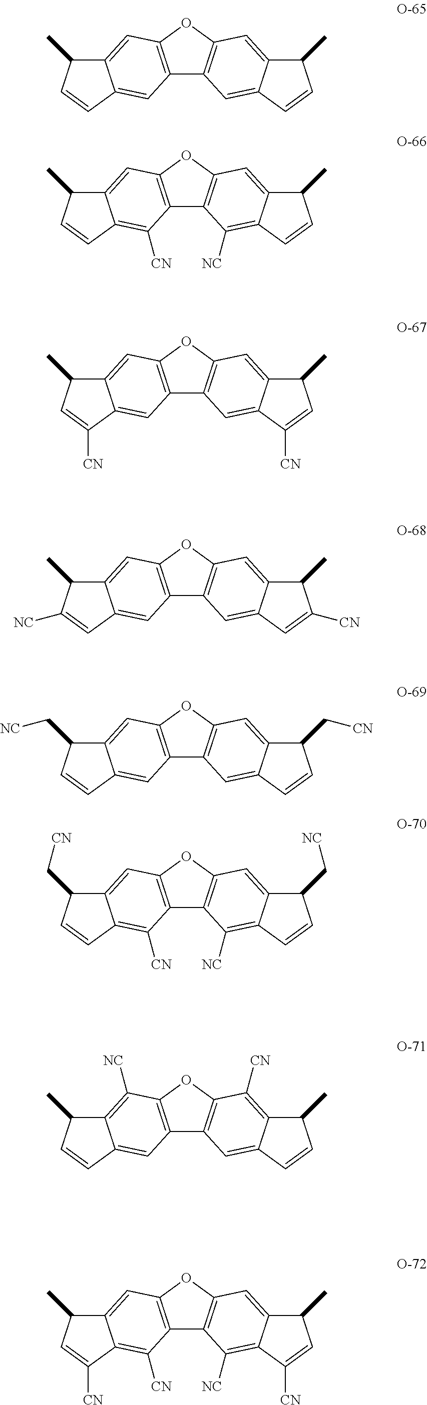

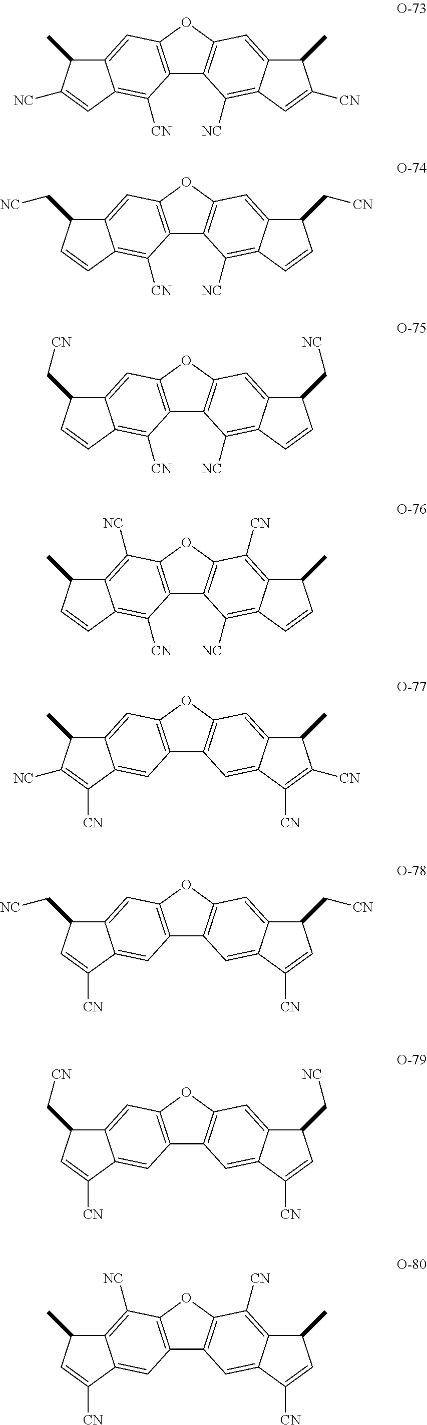

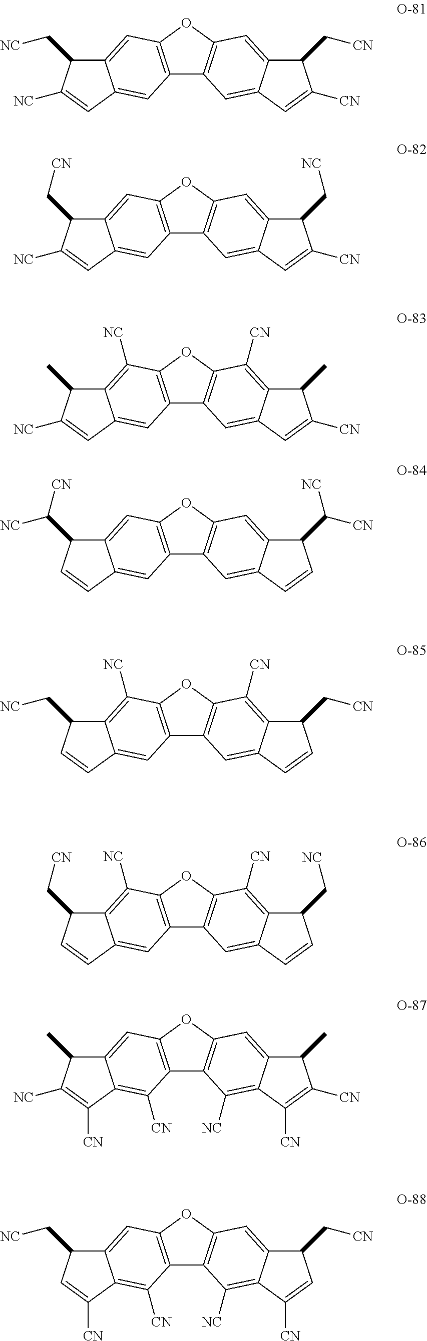

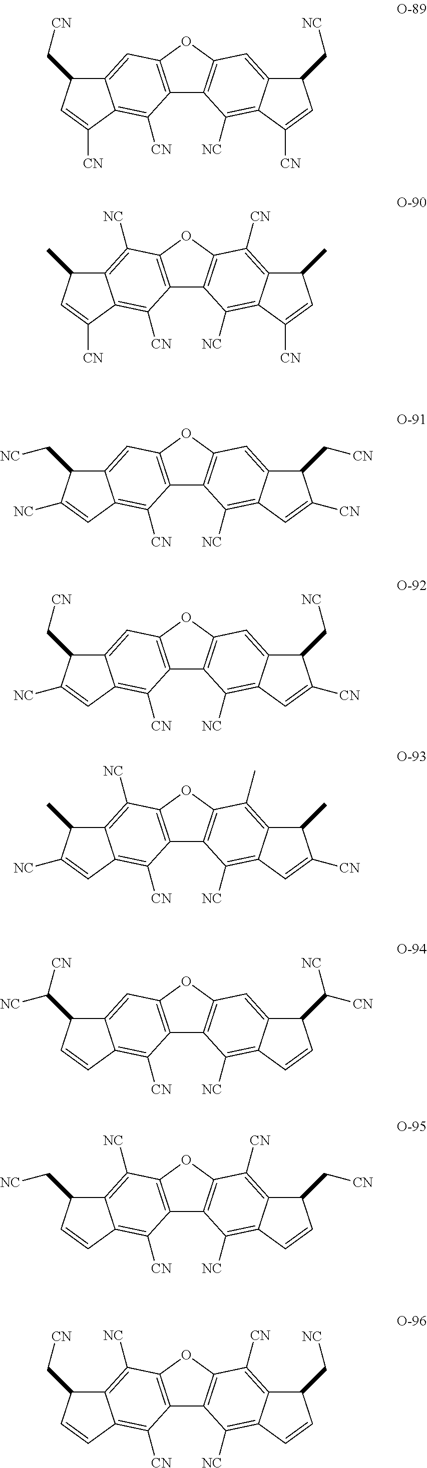

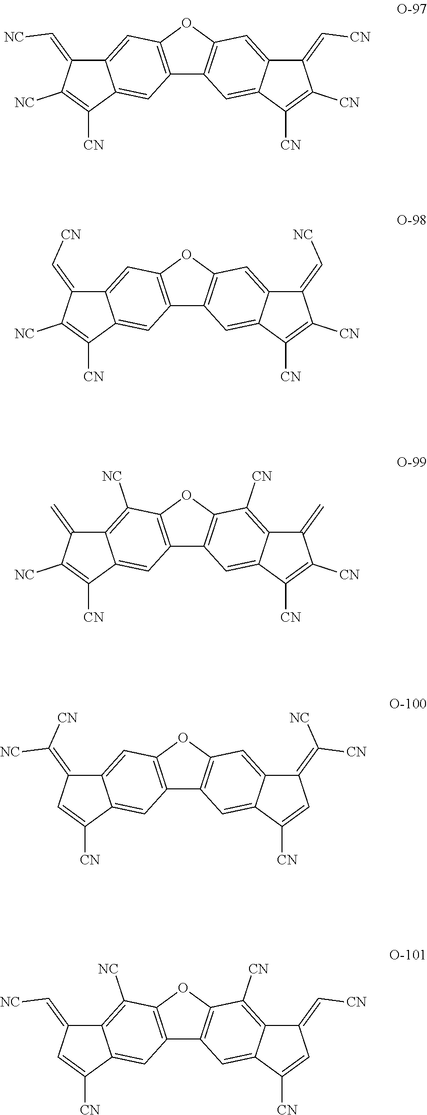 [SMILES: N#C/C=C1\C(C#N)=C(C#N)c2cc3c(cc21)oc1cc2c(cc13)C(C#N)=C(C#N)/C2=C\C#N ; N#C/C=C1/C(C#N)=C(C#N)c2cc3c(cc21)oc1cc2c(cc13)C(C#N)=C(C#N)/C2=C/C#N ; C=C1C(C#N)=C(C#N)c2cc3c(oc4c(C#N)c5c(cc43)C(C#N)=C(C#N)C5=C)c(C#N)c21 ; N#CC1=CC(=C(C#N)C#N)c2cc3oc4cc5c(cc4c3cc21)C(C#N)=CC5=C(C#N)C#N ; N#C/C=C1\C=C(C#N)c2cc3c(oc4c(C#N)c5c(cc43)C(C#N)=C/C5=C\C#N)c(C#N)c21]

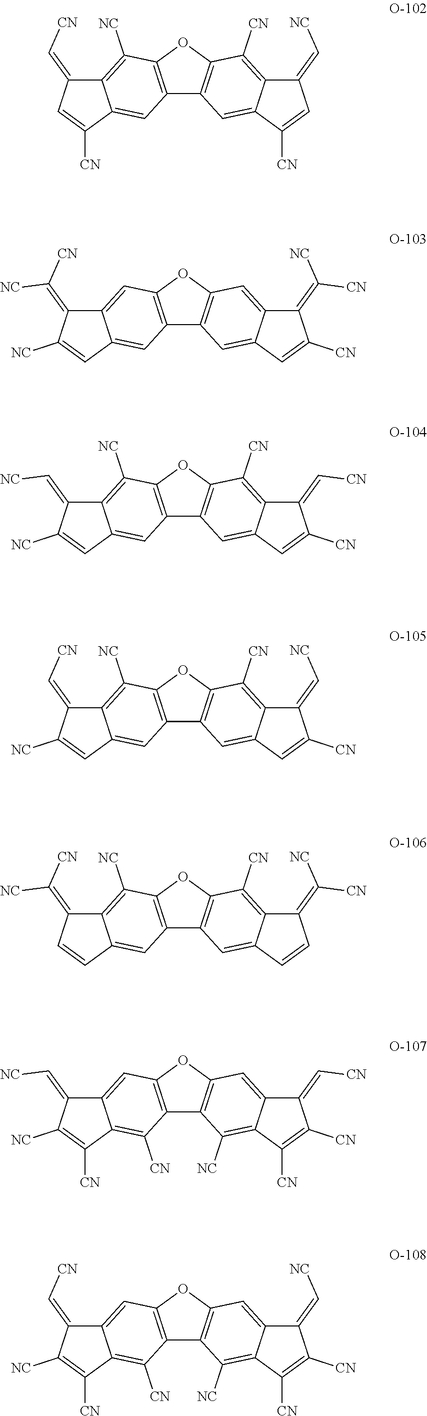

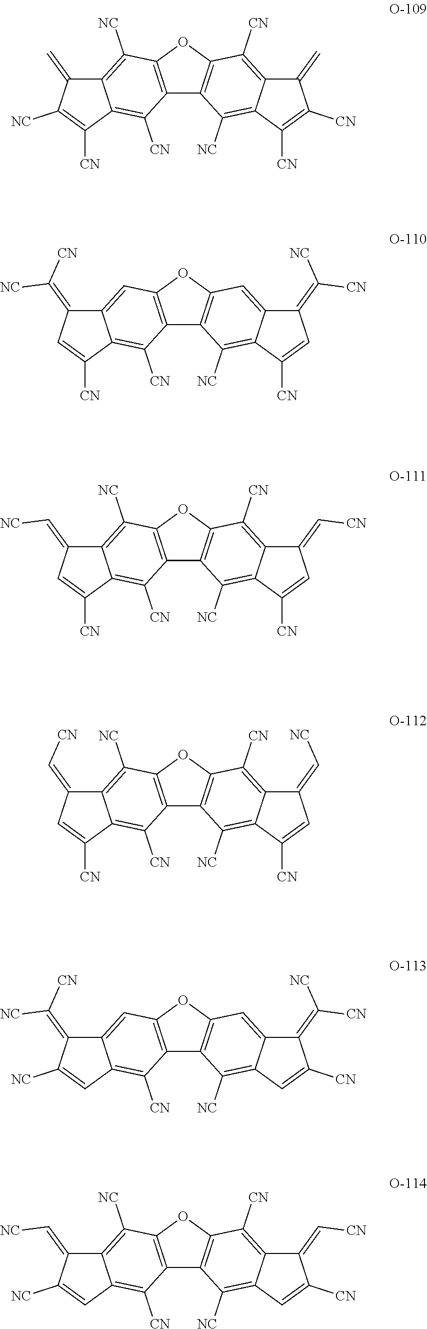 [SMILES: C=C1C(C#N)=C(C#N)c2c1c(C#N)c1oc3c(C#N)c4c(c(C#N)c3c1c2C#N)C(C#N)=C(C#N)C4=C ; N#CC1=CC(=C(C#N)C#N)c2cc3oc4cc5c(c(C#N)c4c3c(C#N)c21)C(C#N)=CC5=C(C#N)C#N ; N#C/C=C1\C=C(C#N)c2c1c(C#N)c1oc3c(C#N)c4c(c(C#N)c3c1c2C#N)C(C#N)=C/C4=C\C#N ; N#C/C=C1/C=C(C#N)c2c1c(C#N)c1oc3c(C#N)c4c(c(C#N)c3c1c2C#N)C(C#N)=C/C4=C/C#N ; N#CC1=Cc2c(cc3oc4cc5c(c(C#N)c4c3c2C#N)C=C(C#N)C5=C(C#N)C#N)C1=C(C#N)C#N ; N#C/C=C1\C(C#N)=Cc2c1c(C#N)c1oc3c(C#N)c4c(c(C#N)c3c1c2C#N)C=C(C#N)/C4=C\C#N]

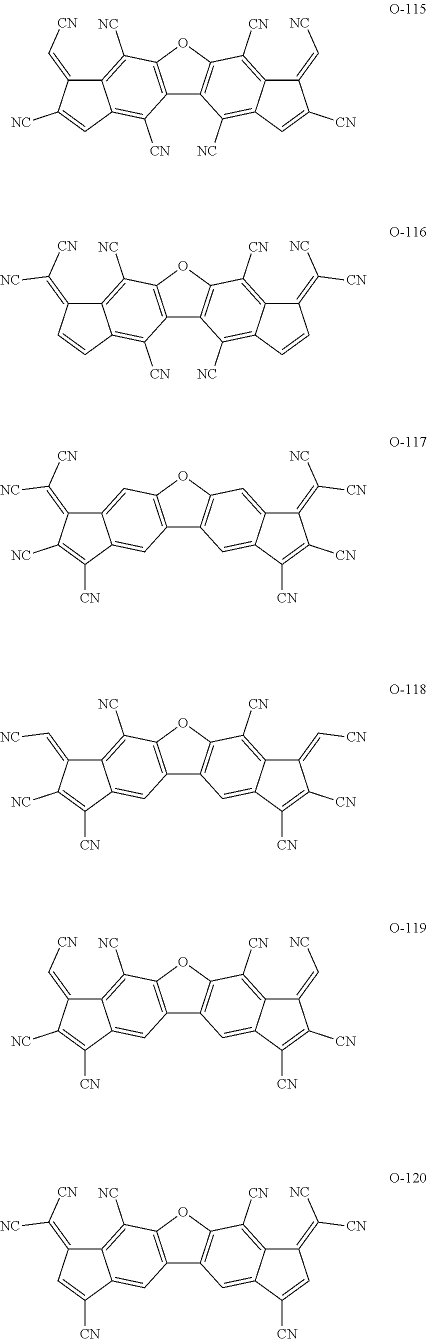 [SMILES: N#C/C=C1/C(C#N)=Cc2c1c(C#N)c1oc3c(C#N)c4c(c(C#N)c3c1c2C#N)C=C(C#N)/C4=C/C#N ; N#CC(C#N)=C1C=Cc2c1c(C#N)c1oc3c(C#N)c4c(c(C#N)c3c1c2C#N)C=CC4=C(C#N)C#N ; N#CC(C#N)=C1C(C#N)=C(C#N)c2cc3c(cc21)oc1cc2c(cc13)C(C#N)=C(C#N)C2=C(C#N)C#N ; N#C/C=C1\C(C#N)=C(C#N)c2cc3c(oc4c(C#N)c5c(cc43)C(C#N)=C(C#N)/C5=C\C#N)c(C#N)c21 ; N#C/C=C1/C(C#N)=C(C#N)c2cc3c(oc4c(C#N)c5c(cc43)C(C#N)=C(C#N)/C5=C/C#N)c(C#N)c21 ; N#CC1=CC(=C(C#N)C#N)c2c1cc1c(oc3c(C#N)c4c(cc31)C(C#N)=CC4=C(C#N)C#N)c2C#N]

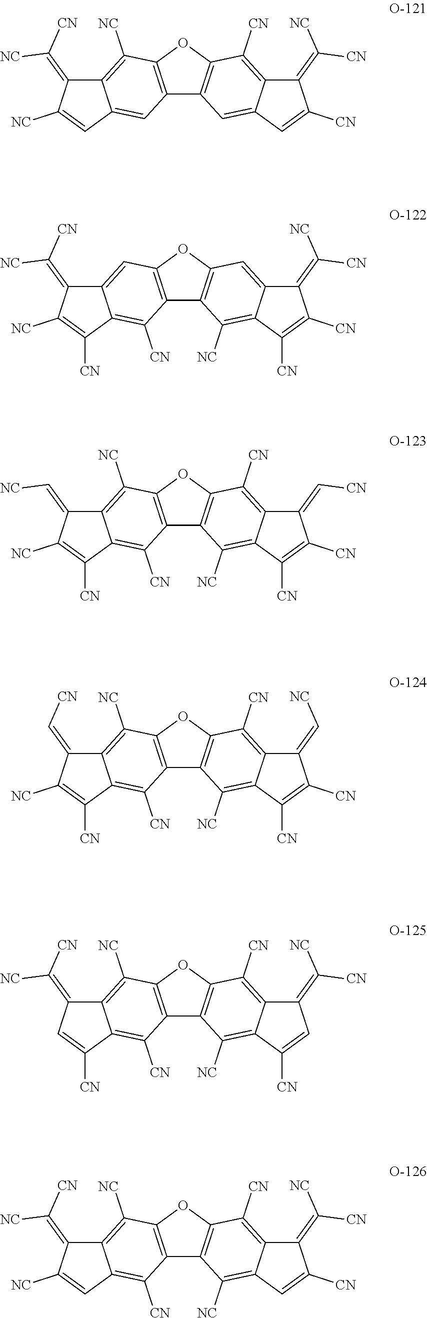

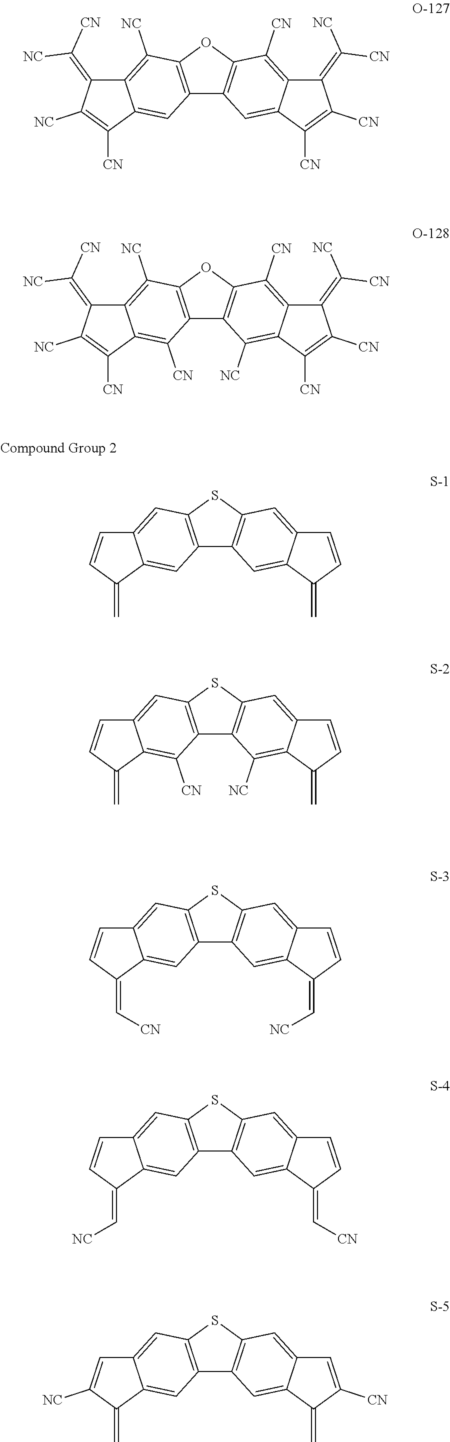

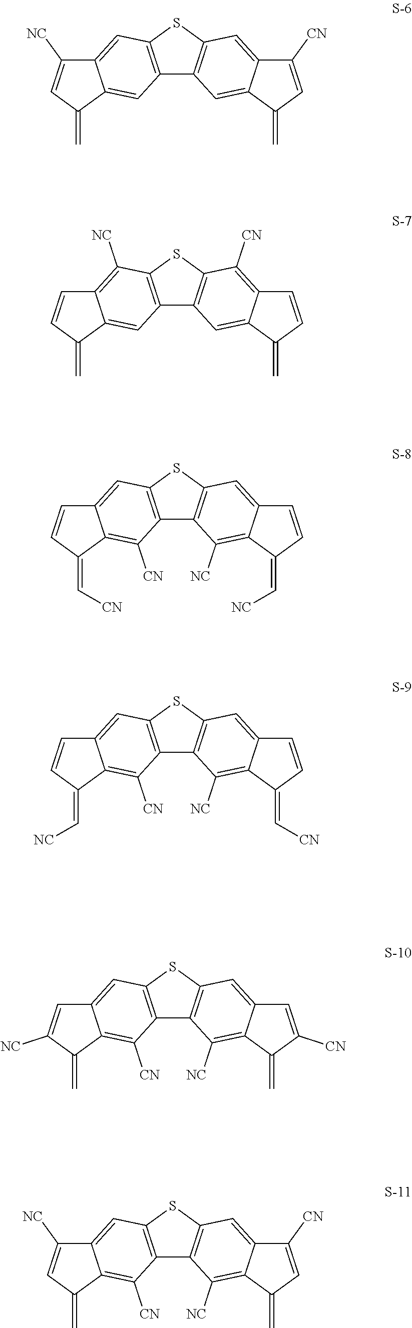 [SMILES: C=C1C=C(C#N)c2cc3sc4cc5c(cc4c3cc21)C(=C)C=C5C#N ; C=C1C=Cc2c1cc1c(sc3c(C#N)c4c(cc31)C(=C)C=C4)c2C#N ; N#C/C=C1/C=Cc2cc3sc4cc5c(c(C#N)c4c3c(C#N)c21)/C(=C\C#N)C=C5 ; N#C/C=C1\C=Cc2cc3sc4cc5c(c(C#N)c4c3c(C#N)c21)/C(=C/C#N)C=C5 ; C=C1C(C#N)=Cc2cc3sc4cc5c(c(C#N)c4c3c(C#N)c21)C(=C)C(C#N)=C5 ; C=C1C=C(C#N)c2cc3sc4cc5c(c(C#N)c4c3c(C#N)c21)C(=C)C=C5C#N]

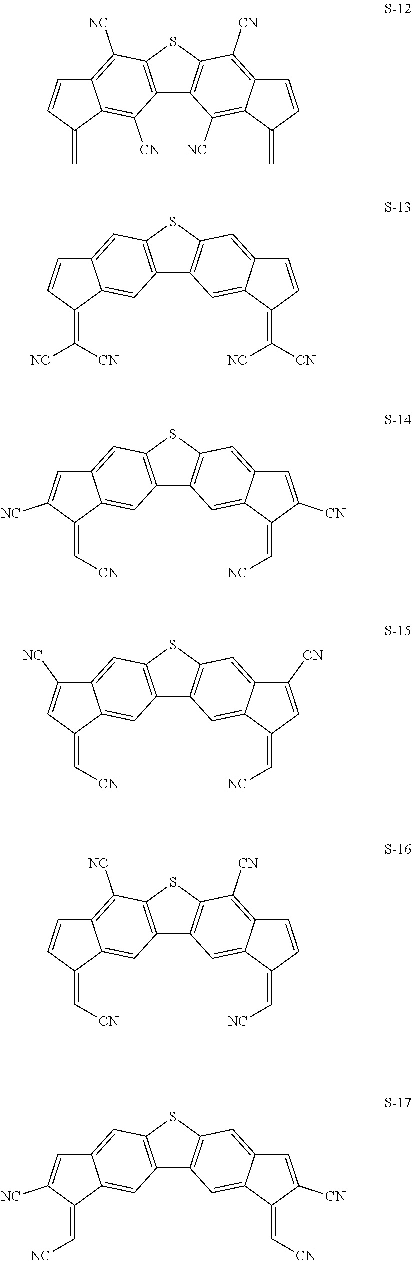 [SMILES: C=C1C=Cc2c1c(C#N)c1c(sc3c(C#N)c4c(c(C#N)c31)C(=C)C=C4)c2C#N ; N#CC(C#N)=C1C=Cc2cc3sc4cc5c(cc4c3cc21)C(=C(C#N)C#N)C=C5 ; N#C/C=C1/C(C#N)=Cc2cc3sc4cc5c(cc4c3cc21)/C(=C\C#N)C(C#N)=C5 ; N#C/C=C1/C=C(C#N)c2cc3sc4cc5c(cc4c3cc21)/C(=C\C#N)C=C5C#N ; N#C/C=C1/C=Cc2c1cc1c(sc3c(C#N)c4c(cc31)/C(=C\C#N)C=C4)c2C#N ; N#C/C=C1\C(C#N)=Cc2cc3sc4cc5c(cc4c3cc21)/C(=C/C#N)C(C#N)=C5]

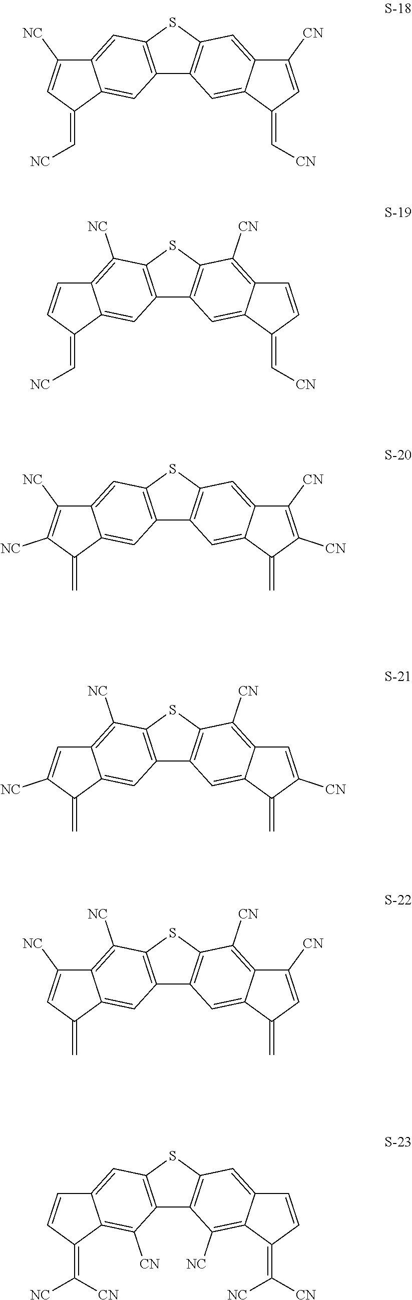 [SMILES: N#C/C=C1\C=C(C#N)c2cc3sc4cc5c(cc4c3cc21)/C(=C/C#N)C=C5C#N ; N#C/C=C1\C=Cc2c1cc1c(sc3c(C#N)c4c(cc31)/C(=C/C#N)C=C4)c2C#N ; C=C1C(C#N)=C(C#N)c2cc3sc4cc5c(cc4c3cc21)C(=C)C(C#N)=C5C#N ; C=C1C(C#N)=Cc2c1cc1c(sc3c(C#N)c4c(cc31)C(=C)C(C#N)=C4)c2C#N ; C=C1C=C(C#N)c2c1cc1c(sc3c(C#N)c4c(cc31)C(=C)C=C4C#N)c2C#N ; N#CC(C#N)=C1C=Cc2cc3sc4cc5c(c(C#N)c4c3c(C#N)c21)C(=C(C#N)C#N)C=C5]

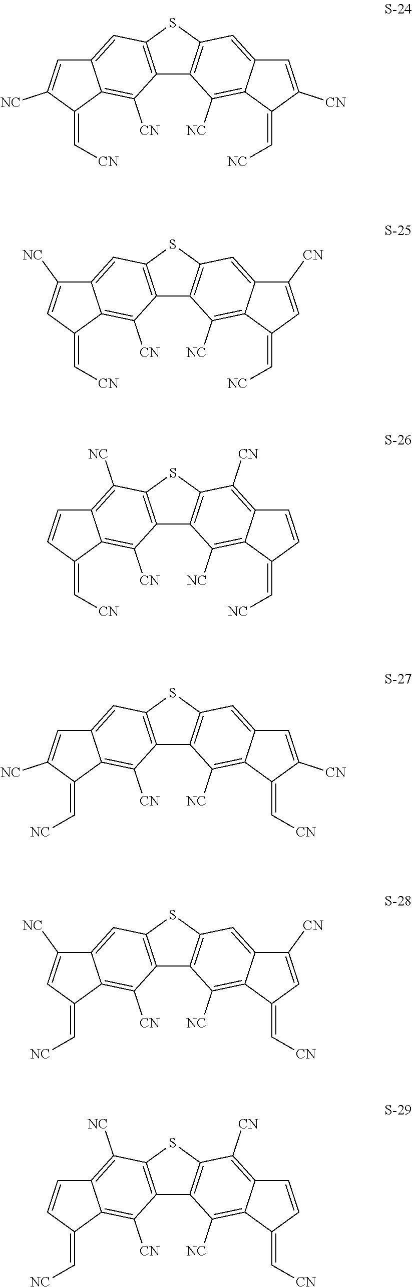 [SMILES: N#C/C=C1/C(C#N)=Cc2cc3sc4cc5c(c(C#N)c4c3c(C#N)c21)/C(=C\C#N)C(C#N)=C5 ; N#C/C=C1/C=C(C#N)c2cc3sc4cc5c(c(C#N)c4c3c(C#N)c21)/C(=C\C#N)C=C5C#N ; N#C/C=C1/C=Cc2c1c(C#N)c1c(sc3c(C#N)c4c(c(C#N)c31)/C(=C\C#N)C=C4)c2C#N ; N#C/C=C1\C(C#N)=Cc2cc3sc4cc5c(c(C#N)c4c3c(C#N)c21)/C(=C/C#N)C(C#N)=C5 ; N#C/C=C1\C=C(C#N)c2cc3sc4cc5c(c(C#N)c4c3c(C#N)c21)/C(=C/C#N)C=C5C#N ; N#C/C=C1\C=Cc2c1c(C#N)c1c(sc3c(C#N)c4c(c(C#N)c31)/C(=C/C#N)C=C4)c2C#N]

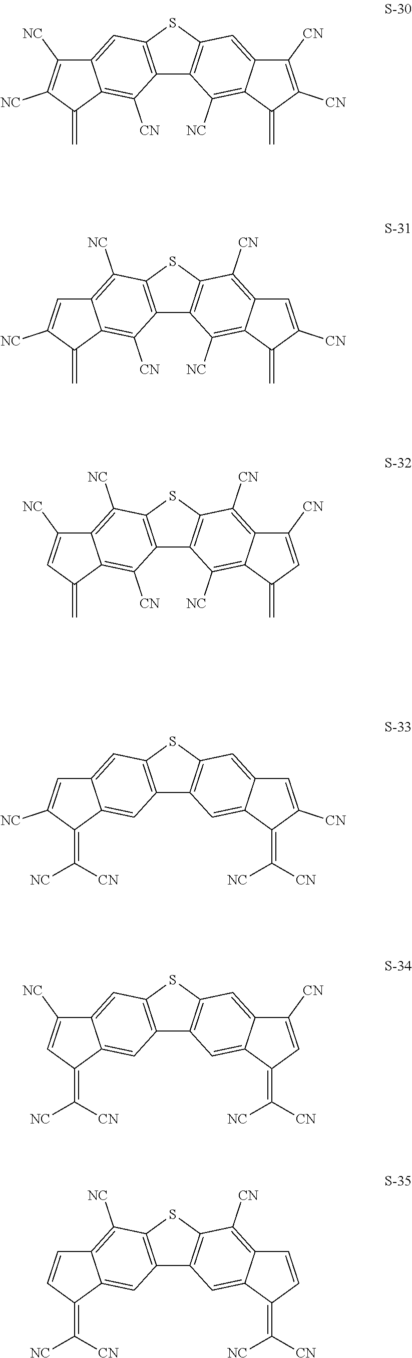 [SMILES: C=C1C(C#N)=C(C#N)c2cc3sc4cc5c(c(C#N)c4c3c(C#N)c21)C(=C)C(C#N)=C5C#N ; C=C1C(C#N)=Cc2c1c(C#N)c1c(sc3c(C#N)c4c(c(C#N)c31)C(=C)C(C#N)=C4)c2C#N ; C=C1C=C(C#N)c2c1c(C#N)c1c(sc3c(C#N)c4c(c(C#N)c31)C(=C)C=C4C#N)c2C#N ; N#CC1=Cc2cc3sc4cc5c(cc4c3cc2C1=C(C#N)C#N)C(=C(C#N)C#N)C(C#N)=C5 ; N#CC1=CC(=C(C#N)C#N)c2cc3c(cc21)sc1cc2c(cc13)C(=C(C#N)C#N)C=C2C#N ; N#CC(C#N)=C1C=Cc2c1cc1c(sc3c(C#N)c4c(cc31)C(=C(C#N)C#N)C=C4)c2C#N]

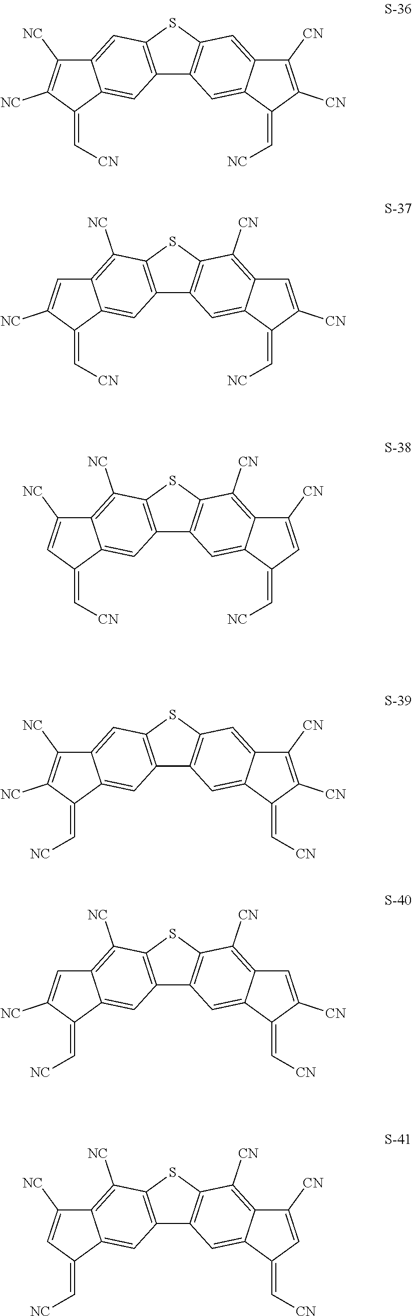 [SMILES: N#C/C=C1/C(C#N)=C(C#N)c2cc3sc4cc5c(cc4c3cc21)/C(=C\C#N)C(C#N)=C5C#N ; N#C/C=C1/C(C#N)=Cc2c1cc1c(sc3c(C#N)c4c(cc31)/C(=C\C#N)C(C#N)=C4)c2C#N ; N#C/C=C1/C=C(C#N)c2c1cc1c(sc3c(C#N)c4c(cc31)/C(=C\C#N)C=C4C#N)c2C#N ; N#C/C=C1\C(C#N)=C(C#N)c2cc3sc4cc5c(cc4c3cc21)/C(=C/C#N)C(C#N)=C5C#N ; N#C/C=C1\C(C#N)=Cc2c1cc1c(sc3c(C#N)c4c(cc31)/C(=C/C#N)C(C#N)=C4)c2C#N ; N#C/C=C1\C=C(C#N)c2c1cc1c(sc3c(C#N)c4c(cc31)/C(=C/C#N)C=C4C#N)c2C#N]

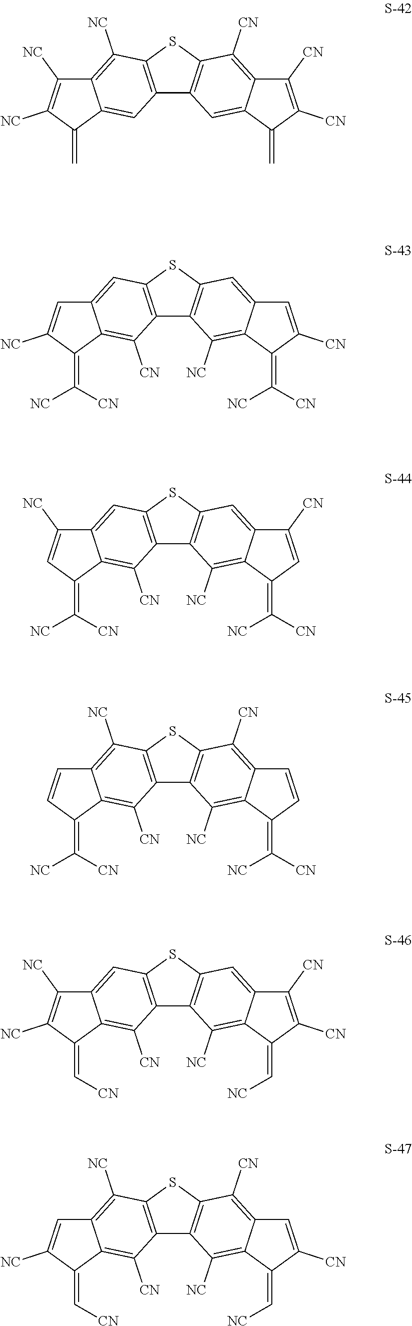 [SMILES: C=C1C(C#N)=C(C#N)c2c1cc1c(sc3c(C#N)c4c(cc31)C(=C)C(C#N)=C4C#N)c2C#N ; N#CC1=Cc2cc3sc4cc5c(c(C#N)c4c3c(C#N)c2C1=C(C#N)C#N)C(=C(C#N)C#N)C(C#N)=C5 ; N#CC1=CC(=C(C#N)C#N)c2c1cc1sc3cc4c(c(C#N)c3c1c2C#N)C(=C(C#N)C#N)C=C4C#N ; N#CC(C#N)=C1C=Cc2c1c(C#N)c1c(sc3c(C#N)c4c(c(C#N)c31)C(=C(C#N)C#N)C=C4)c2C#N ; N#C/C=C1/C(C#N)=C(C#N)c2cc3sc4cc5c(c(C#N)c4c3c(C#N)c21)/C(=C\C#N)C(C#N)=C5C#N ; N#C/C=C1/C(C#N)=Cc2c1c(C#N)c1c(sc3c(C#N)c4c(c(C#N)c31)/C(=C\C#N)C(C#N)=C4)c2C#N]

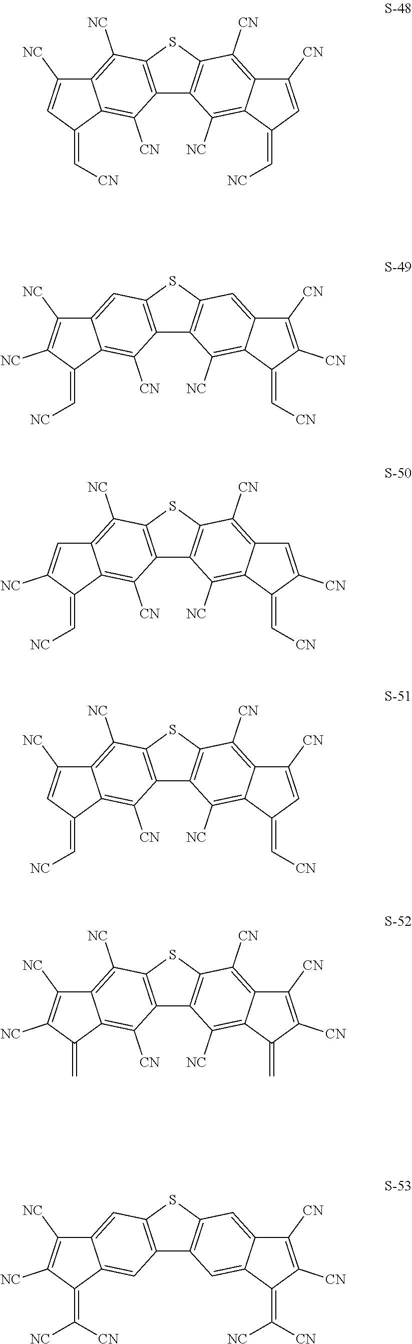 [SMILES: N#C/C=C1/C=C(C#N)c2c1c(C#N)c1c(sc3c(C#N)c4c(c(C#N)c31)/C(=C\C#N)C=C4C#N)c2C#N ; N#C/C=C1\C(C#N)=C(C#N)c2cc3sc4cc5c(c(C#N)c4c3c(C#N)c21)/C(=C/C#N)C(C#N)=C5C#N ; N#C/C=C1\C(C#N)=Cc2c1c(C#N)c1c(sc3c(C#N)c4c(c(C#N)c31)/C(=C/C#N)C(C#N)=C4)c2C#N ; N#C/C=C1\C=C(C#N)c2c1c(C#N)c1c(sc3c(C#N)c4c(c(C#N)c31)/C(=C/C#N)C=C4C#N)c2C#N ; C=C1C(C#N)=C(C#N)c2c1c(C#N)c1c(sc3c(C#N)c4c(c(C#N)c31)C(=C)C(C#N)=C4C#N)c2C#N ; N#CC(C#N)=C1C(C#N)=C(C#N)c2cc3sc4cc5c(cc4c3cc21)C(=C(C#N)C#N)C(C#N)=C5C#N]

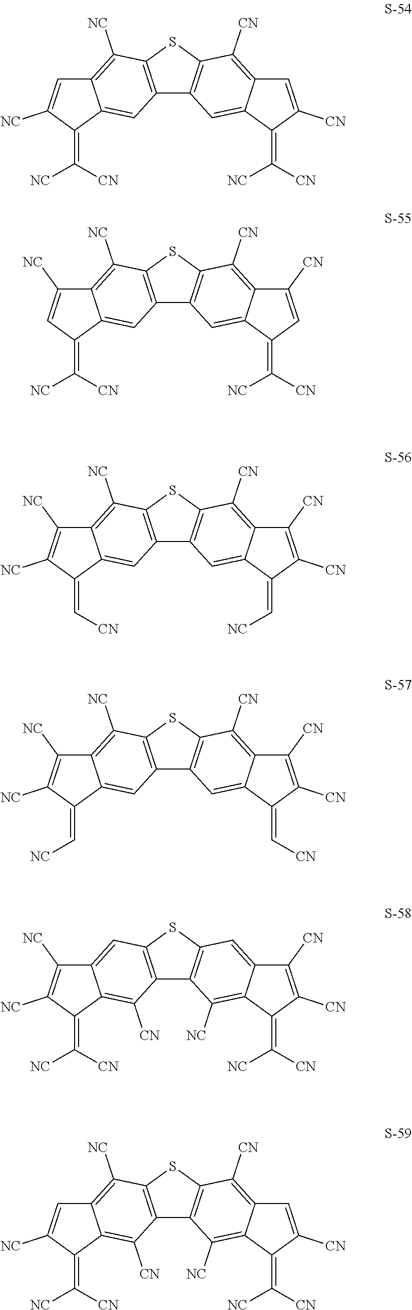 [SMILES: N#CC1=Cc2c(cc3c(sc4c(C#N)c5c(cc43)C(=C(C#N)C#N)C(C#N)=C5)c2C#N)C1=C(C#N)C#N ; N#CC1=CC(=C(C#N)C#N)c2cc3c(sc4c(C#N)c5c(cc43)C(=C(C#N)C#N)C=C5C#N)c(C#N)c21 ; N#C/C=C1/C(C#N)=C(C#N)c2c1cc1c(sc3c(C#N)c4c(cc31)/C(=C\C#N)C(C#N)=C4C#N)c2C#N ; N#C/C=C1\C(C#N)=C(C#N)c2c1cc1c(sc3c(C#N)c4c(cc31)/C(=C/C#N)C(C#N)=C4C#N)c2C#N ; N#CC(C#N)=C1C(C#N)=C(C#N)c2cc3sc4cc5c(c(C#N)c4c3c(C#N)c21)C(=C(C#N)C#N)C(C#N)=C5C#N ; N#CC1=Cc2c(c(C#N)c3c(sc4c(C#N)c5c(c(C#N)c43)C(=C(C#N)C#N)C(C#N)=C5)c2C#N)C1=C(C#N)C#N]

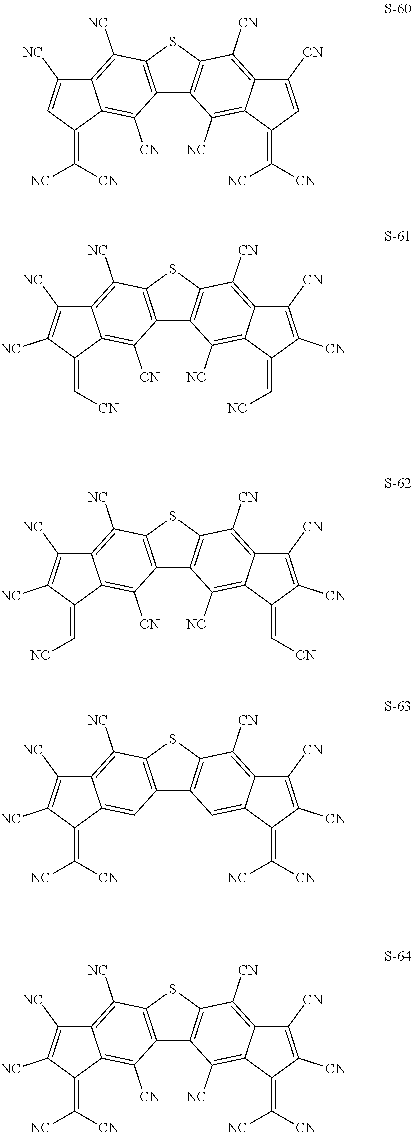 [SMILES: N#CC1=CC(=C(C#N)C#N)c2c1c(C#N)c1sc3c(C#N)c4c(c(C#N)c3c1c2C#N)C(=C(C#N)C#N)C=C4C#N ; N#C/C=C1/C(C#N)=C(C#N)c2c1c(C#N)c1c(sc3c(C#N)c4c(c(C#N)c31)/C(=C\C#N)C(C#N)=C4C#N)c2C#N ; N#C/C=C1\C(C#N)=C(C#N)c2c1c(C#N)c1c(sc3c(C#N)c4c(c(C#N)c31)/C(=C/C#N)C(C#N)=C4C#N)c2C#N ; N#CC(C#N)=C1C(C#N)=C(C#N)c2c1cc1c(sc3c(C#N)c4c(cc31)C(=C(C#N)C#N)C(C#N)=C4C#N)c2C#N ; N#CC(C#N)=C1C(C#N)=C(C#N)c2c1c(C#N)c1c(sc3c(C#N)c4c(c(C#N)c31)C(=C(C#N)C#N)C(C#N)=C4C#N)c2C#N]

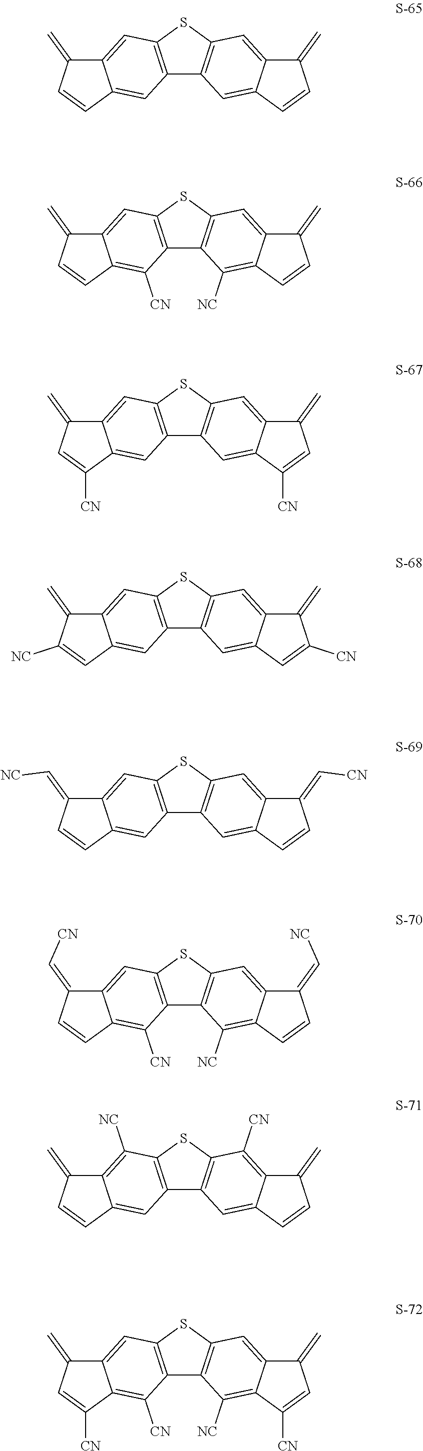

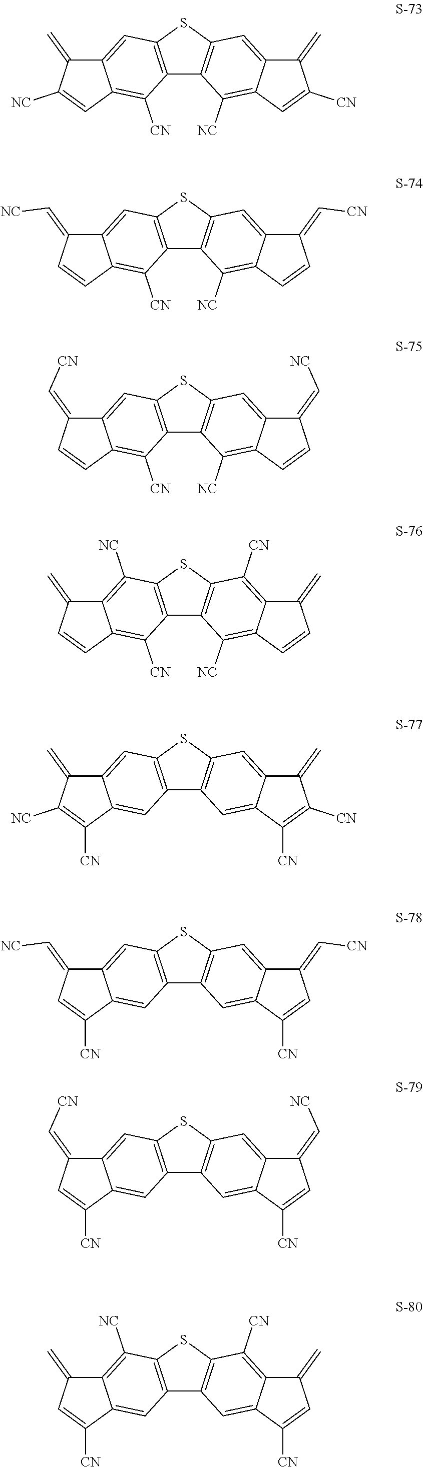

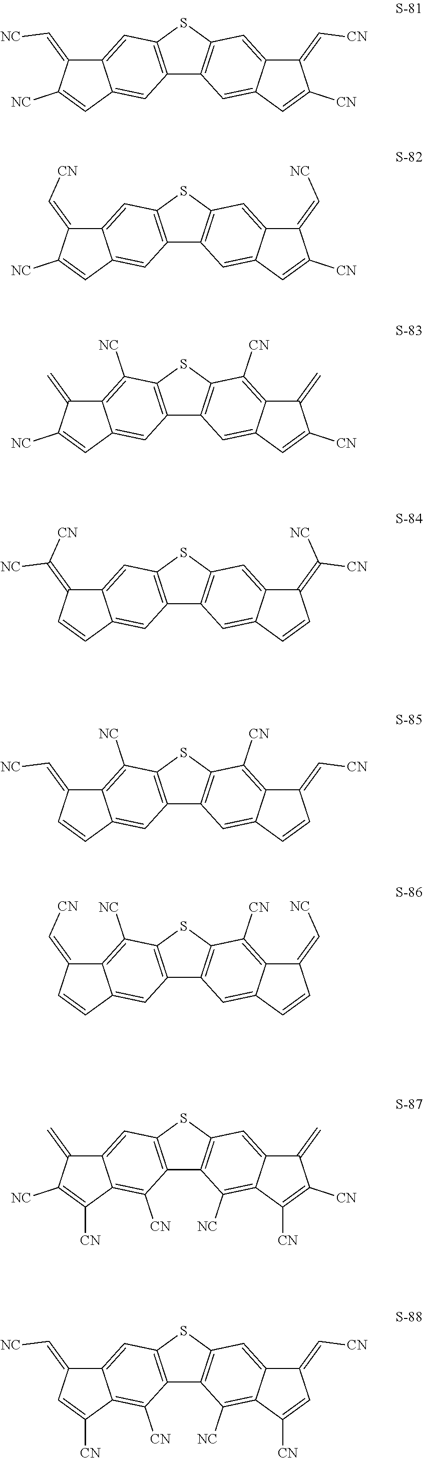

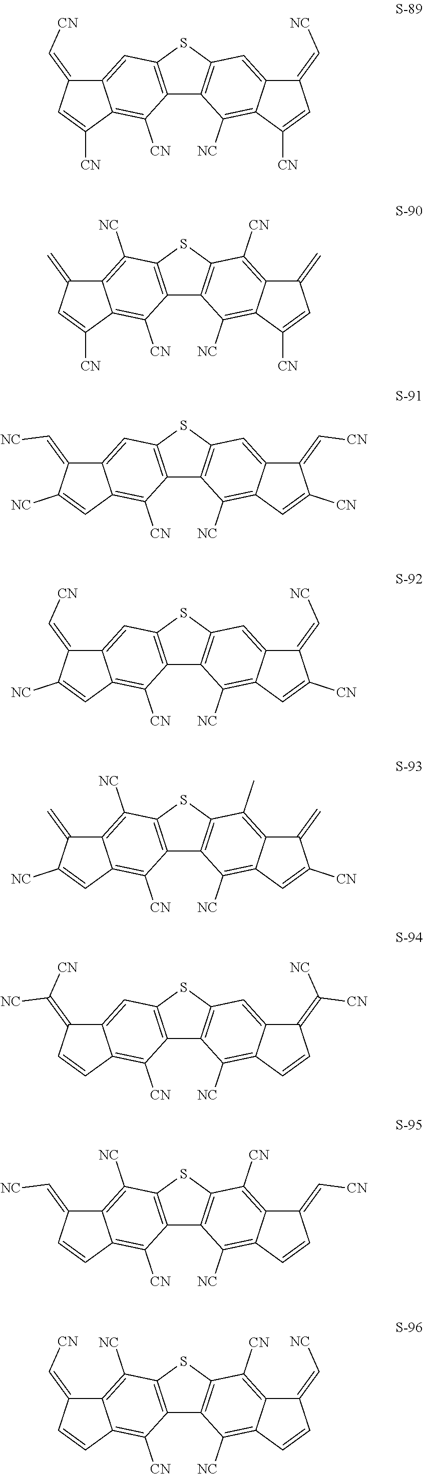

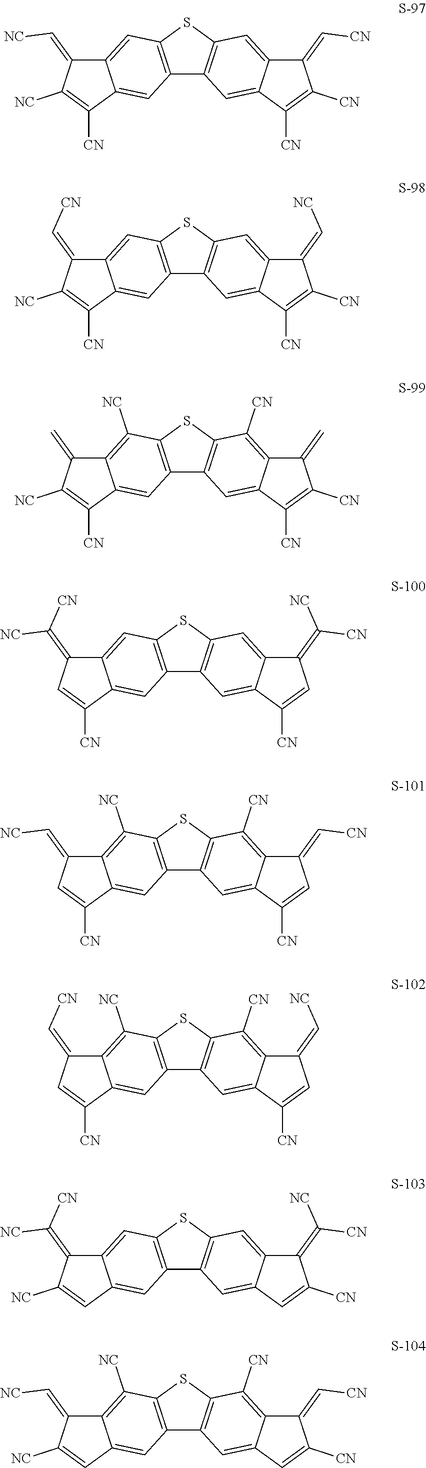

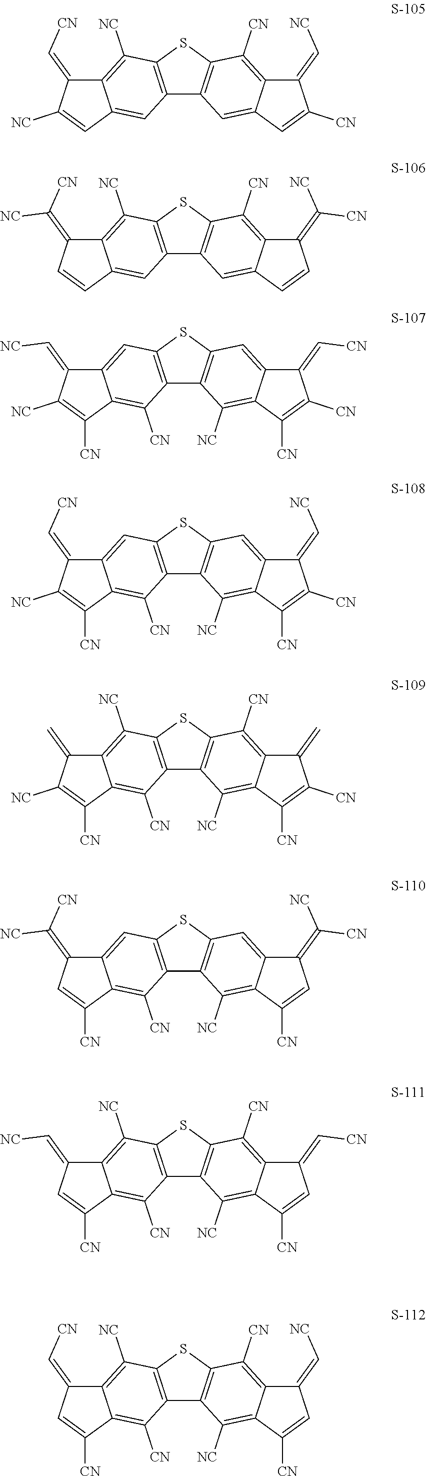

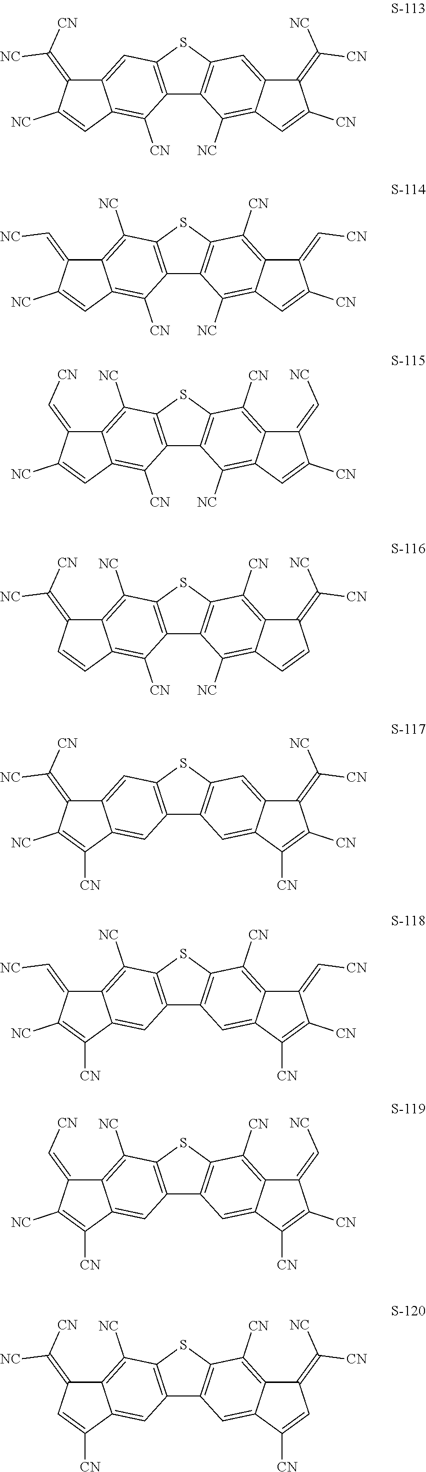

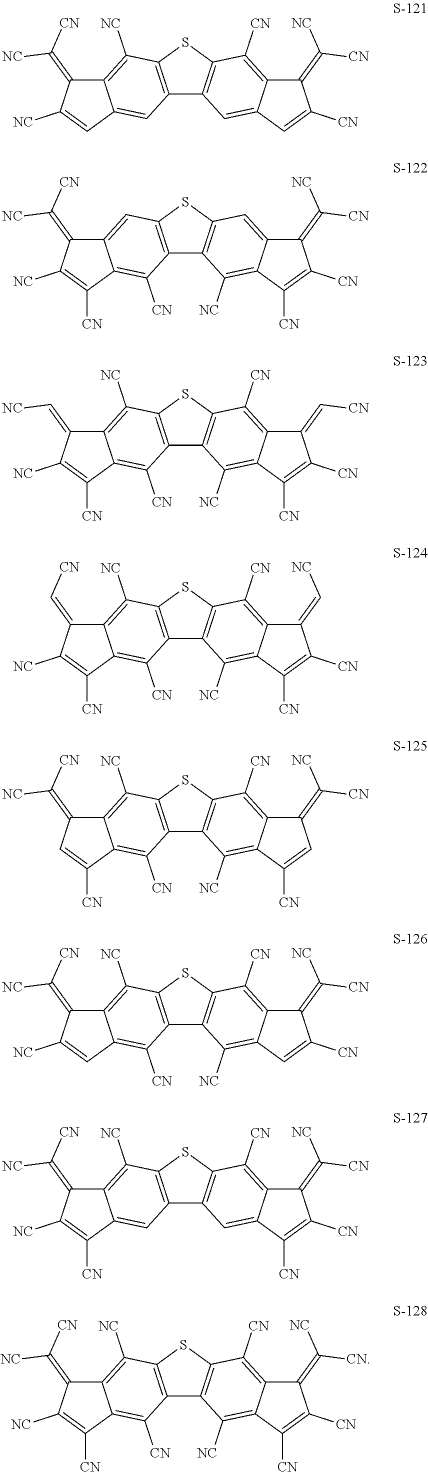

According to one or more embodiments, the light-emitting diode may include at least one functional layer and a charge generation layer. The at least one functional layer may include a hole functional layer arranged on the first electrode and a light-emitting layer arranged on the hole functional layer. At least one of the hole functional layer, the light-emitting layer, or the charge generation layer may include the compound represented by Formula 1.

According to one or more embodiments, the hole functional layer may include a hole injection layer and a hole transport layer, and at least one of the hole injection layer or the hole transport layer may include the compound represented by Formula 1.

According to one or more embodiments, a thickness of the hole injection layer may be about 10 Å to about 500 Å.

According to one or more embodiments, the compound represented by the Formula 1 may be a p-type (kind) dopant. The p-type (kind) dopant is a material added to control an electrical property of a light-emitting diode and uses a generated hole to carry an electric charge. Accordingly, a layer including a p-type (kind) dopant may have increased conductivity. Although it is not limited thereto, the compound represented by the Formula 1 may be included as a p-type (kind) dopant and an electron charge generation material for increasing conductivity of a hole functional layer (e.g., a hole injection layer) and a hole generation layer of the present disclosure. In addition, the p-type (kind) dopant may uniformly (e.g., substantially uniformly) be or non-uniformly be dispersed in the hole functional layer or the charge generation layer. A hole functional layer or a charge generation layer of the present disclosure may further include a compound represented by Formula H-1 or Formula H-2 in addition to a p-type (kind) dopant.

The compound represented by Formula H-1 or Formula H-2 may be selected from among, but not limited to, Compound H3, Compound H40, or any combination thereof.

According to one or more embodiments, the p-type (kind) dopant may be in an amount of about 0.5 parts to about 15 parts by weight based on 100 parts by entire weight of compounds composing the hole functional layer or the charge generation layer. For example, the p-type (kind) dopant may be in an amount of about 0.5 parts to about 15 parts by weight based on 100 parts by an entire weight of compounds composing the hole functional layer. For example, the p-type (kind) dopant may be in an amount of about 0.5 parts to about 15 parts by weight based on 100 parts by an entire weight of compounds composing the charge generation layer. The p-type (kind) doped hole transport material may be applicable to an anode as a hole injection layer and configured to facilitate a hole injection in a material having a more negative number of Highest Occupied Molecular Orbital (HOMO) energy. The p-type (kind) dopant may have no conductivity improvement effects in case that the p-type (kind) dopant is doped to an amount of less than 0.5 parts by weight based on 100 parts by the entire weight of compounds composing the hole functional layer or the electron charge generation layer and weak conductivity improvement effects by the p-dopant in case that the p-type (kind) dopant is doped to an amount of more than 15 parts by weight based on 100 parts by the entire weight of compounds composing the hole functional layer or the electron charge generation layer.

According to one or more embodiments, a Lowest Unoccupied Molecular Orbital (LUMO) energy level of the p-type (kind) dopant may be −4.8 eV or less.

According to one or more embodiments, an electron mobility of the p-type (kind) dopant may be about 1.0×10⁻⁵ cm²/(Vs) to about 1.0×10⁻² cm²/(Vs). A light-emitting diode of the present disclosure may be configured to balance a hole mobility and an electron mobility to adjust a light-emitting area and reduce a decrease in a lifespan.

According to one or more embodiments, an electron mobility of the p-type (kind) dopant may be about 1.0×10⁻⁶ cm²/(Vs) to about 1.0×10⁻¹ cm²/(Vs).

The light-emitting layer EML may be provided on the hole functional layer HFL. The light-emitting layer EML may have a single layer including (e.g., consisting of) a single material, a single layer including (e.g., consisting of) a plurality of different materials, or a multilayer structure having a plurality of layers including (e.g., consisting of) a plurality of different materials. In one or more embodiments, the light-emitting layer EML may include a compound represented by Formula HTH-1:

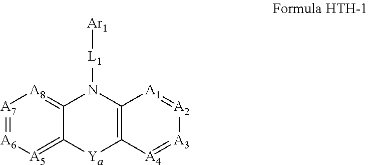

In one or more embodiments, in Formula HTH-1, A₁ to A₈ may each independently be N or CR₁. For example, in one or more embodiments, all (e.g., each of) A₁ to A₈ may be CR₁. In one or more embodiments, at least one selected from among A₁ to A₈ may be N, and the rest may be CR₁.

In one or more embodiments, in Formula HTH-1, Yₐ may be a direct linkage, O, S, CR₂R₃, SiR₄R₅, NR₆, or BR₇. For example, it may refer to that two 6-membered rings (e.g., two benzene rings) coupled to the nitrogen atom of Formula HTH-1 may be connected via a direct linkage,

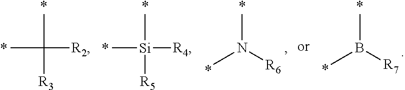

In Formula HTH-1, if (e.g., when) Yₐ is a direct linkage, the compound represented by Formula HTH-1 may include a carbazole moiety.

In one or more embodiments, in Formula HTH-1, L₁ may be a direct linkage, a substituted or unsubstituted arylene group of 6 to 50 ring-forming carbons, or a substituted or unsubstituted heteroarylene group of 2 to 50 ring-forming carbons. For example, in one or more embodiments, L₁ may be a direct linkage, a substituted or unsubstituted phenylene group, a divalent carbazole group, or a divalent biphenyl group, but embodiments of the present disclosure are not limited to thereto.

In one or more embodiments, in Formula HTH-1, Ar₁ may be a substituted or unsubstituted aryl group of 6 to 30 ring-forming carbons or a substituted or unsubstituted heteroarylene group of 2 to 30 ring-forming carbons. For example, in one or more embodiments, Ar₁ may be a substituted or unsubstituted phenyl group, a biphenyl group, a carbazole group, a dibenzothiophene group, or a dibenzofuran group, but embodiments of the present disclosure are not limited thereto.

In one or more embodiments, in Formula HTH-1, R₁ to R₇ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbons, a substituted or unsubstituted alkenyl group of 2 to 20 carbons, a substituted or unsubstituted aryl group of 6 to 50 ring-forming carbons, or a substituted or unsubstituted heteroaryl group of 2 to 50 ring-forming carbons. In one or more embodiments, one or more selected from among R₁ to R₇ may bond to an adjacent group to form a ring. For example, in one or more embodiments, R₁ to R₇ may each independently be hydrogen, deuterium, an unsubstituted methyl group, or an unsubstituted phenyl group.

In one or more embodiments, the light-emitting layer EML may further include a compound represented by Formula EHT-1;

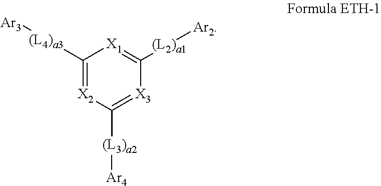

In one or more embodiments, in Formula ETH-1, X₁ may be N or CR₉, X₂ may be N or CR₁₀, X₃ may be N or CR₁₁, and at least one selected from among X₁ to X₃ may be N, and R₉ to R₁₁ may each independently be deuterium, hydrogen, a halogen, a hydroxyl group, a cyano group, a nitro group, a substituted or unsubstituted alkyl group of 1 to 20 carbons, a substituted or unsubstituted alkenyl group of 2 to 20 carbons, a substituted or unsubstituted alkoxy group of 1 to 20 carbons, a substituted or unsubstituted alkynyl group of 2 to 20 carbons, a substituted or unsubstituted aryl group of 6 to 50 ring-forming carbons, or a substituted or unsubstituted heteroaryl group of 2 to 50 ring-forming carbons.

In one or more embodiments, in Formula ETH-1, L₂ to L₄ may be independently a direct linkage, a substituted or unsubstituted arylene group of 6 to 30 ring-forming carbons, or a substituted or unsubstituted heteroarylene group of 2 to 30 ring-forming carbons. If (e.g., when) a1 to a3 may each be an integer of 2 or greater, L₂ to L₄ may each independently be a substituted or unsubstituted arylene group of 6 to 30 ring-forming carbons or a substituted or unsubstituted heteroarylene group of 2 to 30 ring-forming carbons.

In one or more embodiments, in Formula ETH-1, a1 to a3 may each independently be an integer between 0 and 10, inclusive.

In one or more embodiments, in Formula ETH-1, Ar₂ to Ar₄ may each independently be deuterium, hydrogen, a substituted or unsubstituted alkyl group of 1 to 20 carbons, a substituted or unsubstituted aryl group of 6 to 30 ring-forming carbons, or a substituted or unsubstituted heteroaryl group of 2 to 30 ring-forming carbons. For example, in one or more embodiments, Ar₂ to Ar₄ may be a substituted or unsubstituted phenyl group or a substituted or unsubstituted carbazole group.

In one or more embodiments, the host for electron transport represented by Formula ETH-1 in the light-emitting layer EML may be represented as Compound H126 among the compounds shown in embodiments of manufactured light-emitting diodes of the disclosure, but embodiments of the present disclosure are not limited thereto.

In one or more embodiments, the light-emitting layer EML in a light-emitting diode of one or more embodiments may include at least one of an anthracene derivative, a fluoranthene derivative, a chrysene derivative, a pyrene derivative, a dihydrobenzanthracene derivative, or a triphenylene derivative. For example, in one or more embodiments, the light-emitting layer EML may include an anthracene derivative and/or a pyrene derivative.

In one or more embodiments, a compound represented by the Formula EM-1 may be used as a fluorescence host material.

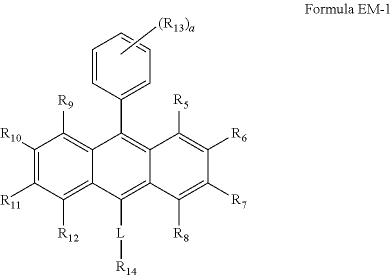

In one or more embodiments, in Formula EM-1, L may be a direct linkage, a substituted or unsubstituted arylene group of 6 to 30 ring-forming carbons, or a substituted or unsubstituted heteroarylene group of 2 to 30 ring-forming carbons. Examples thereof may be a phenylene group, a biphenylene group, a terphenylene group, a naphthalene group, a phenanthrene group, a pyrene group, a spirofluorenylene group, a fluorenylene group, a dibenzofuranylene group, a dibenzothiophenylene group, or a carbazolylene group, but embodiments of the present disclosure may not be limited thereto.

In one or more embodiments, in Formula EM-1, R₅ to R₁₄ may each independently be hydrogen, deuterium, a halogen, a substituted or unsubstituted oxy group, a substituted or unsubstituted thio group, a substituted or unsubstituted silyl group, a substituted or unsubstituted alkyl group of 1 to 30 carbons, a substituted or unsubstituted alkenyl group of 2 to 30 carbons, a substituted or unsubstituted aryl group of 6 to 30 ring-forming carbons, or a substituted or unsubstituted heteroaryl group of 2 to 30 ring-forming carbons, and/or bonded to an adjacent group to form a ring.

In one or more embodiments, in Formula EM-1, a may be an integer between 0 and 5, inclusive.

In one or more embodiments, the compound represented by Formula EM-1 may be any compound of (e.g., selected from among) Formulae E1 to E11, but embodiments of the present disclosure are not limited thereto.

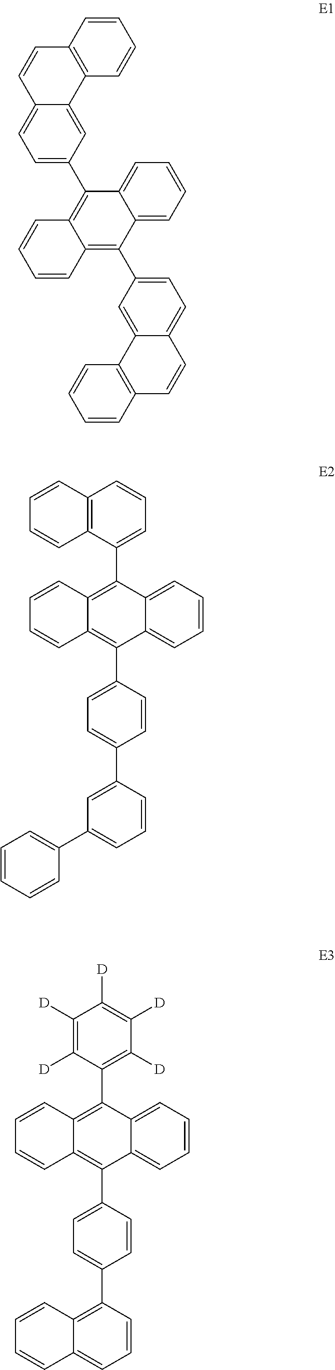

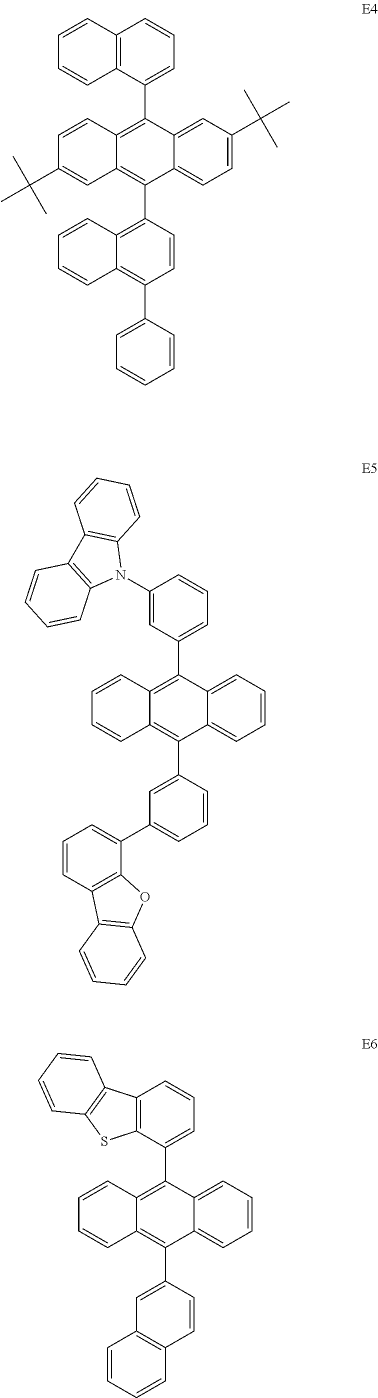

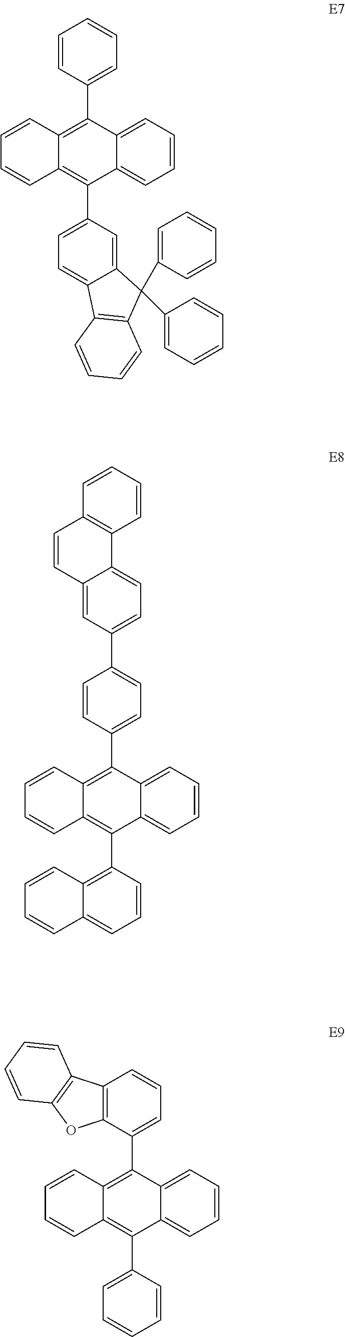

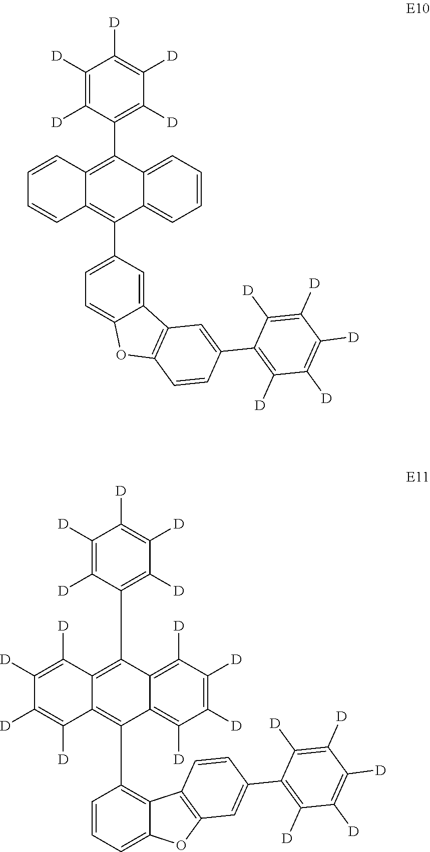 [SMILES: [2H]c1c([2H])c([2H])c(-c2ccc3oc4ccc(-c5c6ccccc6c(-c6c([2H])c([2H])c([2H])c([2H])c6[2H])c6ccccc56)cc4c3c2)c([2H])c1[2H] ; [2H]c1c([2H])c([2H])c(-c2ccc3c(c2)oc2cccc(-c4c5c([2H])c([2H])c([2H])c([2H])c5c(-c5c([2H])c([2H])c([2H])c([2H])c5[2H])c5c([2H])c([2H])c([2H])c([2H])c45)c23)c([2H])c1[2H]]

In one or more embodiments, the light emitting layer EML may further include a compound represented by Formula EM-2 or Formula EM-3. The compound represented by any formula selected from among Formula EM-2 and Formula EM-3 may be further included as a phosphorescence host material.

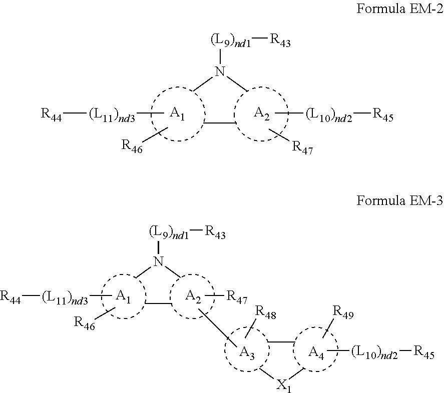

In one or more embodiments, in Formula EM-2 and Formula EM-3, ring A₁ to ring A₄ may each independently be a substituted or unsubstituted aryl group of 6 to 30 ring-forming carbons or a substituted or unsubstituted heteroaryl group of 2 to 30 ring-forming carbons. Non-limiting examples thereof may include a benzene group, a naphthalene group, a phenanthrene group, a fluoranthene group, a triphenylene group, a pyrene group, a pyridine group, a pyrimidine group, an indene group, a fluorene group, a spiro-bifluorene group, a benzofluorene group, a dibenzofluorene group, an indole group, a carbazole group, a benzocarbazole group, a dibenzocarbazole group, a furan group, a benzofuran group, a dibenzofuran group, a benzonaphthofuran group, a benzothiophene group, a dibenzothiophene group, a benzonaphthothiophene group, and a dinaphthothiophene group.

In one or more embodiments, in Formula EM-2 and Formula EM-3, nd1 to nd3 may be independently 0, 1, or 2, and X₁ may be O, S, N-L₁₂-R₅₀, CR₅₁R₅₂, or SiR₅₃R₅₄, in Formula EM-2 and Formula EM-3, L₉ to L₁₂ may each independently be a direct linkage, a substituted or unsubstituted arylene group of 6 to 30 ring-forming carbons, or a substituted or unsubstituted heteroarylene group of 2 to 30 ring-forming carbons.

In one or more embodiments, in Formula EM-2 and Formula EM-3, R₄₃ to R₄₉ and R₅₀ to R₅₄ may each independently be hydrogen, deuterium, a halogen, a substituted or unsubstituted amine group, a substituted or unsubstituted thio group, a substituted or unsubstituted oxy group, a substituted or unsubstituted alkyl group of 1 to 20 carbons, a substituted or unsubstituted alkenyl group of 2 to 20 carbons, a substituted or unsubstituted aryl group of 6 to 30 ring-forming carbons, or substituted or unsubstituted heteroaryl group of 2 to 30 ring-forming carbons.

In one or more embodiments, the host material for electron transport represented by Formula EM-2 or EM-3 and included in the light-emitting layer EML may be represented by, but not limited to, Compound H125 among compounds presented in a manufactured embodiment of the disclosure. In one or more embodiments, the light-emitting layer EML may further include a material generally suitable in the field as a host material.

In one or more embodiments, for example, the light-emitting layer EML may include at least one of bis(4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), Bis[2-(diphenylphosphino)phenyl]ether oxide (DPEPO), 4,4′-bis(N-carbazolyl)-1,1′-biphenyl), mCP(1,3-Bis(carbazol-9-yl)benzene (CBP), 2,8-Bis(diphenylphosphoryl)dibenzo[b,d]furan (PPF), 4,4′,4″-Tris(carbazol-9-yl)-triphenylamine (TCTA), or 1,3,5-tris(1-phenyl-1H-benzo[d]imidazol-2-yl)benzene (TPBi) as a host material. However, embodiments of the present disclosure are not limited thereto, and for example, a host material, such as tris(8-hydroxyquinolinato)aluminum (Alq₃), 9,10-di(naphthalen-2-yl)anthracene (AND), 2-tert-butyl-9,10-di(naphth-2-yl)anthracene (TBADN), distyrylarylene (DSA), 4,4′-bis(9-carbazolyl)-2,2′-dimethylbiphenyl (CDBP), 2-Methyl-9,10-bis(naphthalen-2-yl)anthracene (MADN), Hexaphenyl cyclotriphosphazene (CP1), 1,4-Bis(triphenylsilyl)benzene (UGH2), Hexaphenylcyclotrisiloxane (DPSiO3), and/or Octaphenylcyclotetrasiloxane (DPSiO4), may be used.

In one or more embodiments, the light-emitting layer EML may include a compound represented by Formula M-a or Formula M-b.

The compound represented by the Formula M-a or Formula M-b may be used as a phosphorescence dopant material.

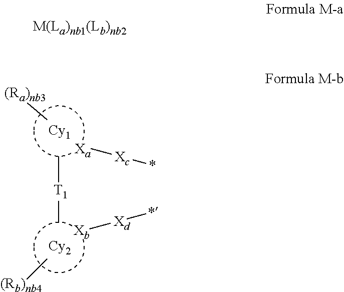

In one or more embodiments, in Formulae M-a, M may be a transition metal (e.g., iridium (Ir), platinum (Pt), gold (Au), titanium (Ti), hafnium (Hf), tantalum (Ta), tungsten (W), rhenium (Re), or osmium (Os)), and Lₐ may be a ligand represented by Formula M-b.

In one or more embodiments, nb1 may be 1, 2 or 3, and in case that nb1 is 2 or greater, then two or more Lₐ(s) may be the same as or different from each other, and L_{b} may be, but not limited to, an organic ligand, such as a halogen ligand (e.g., Cl and F), a diketone ligand (e.g., acetylacetonate, 1,3-diphenyl-1,3-propanedionate, 2,2,6,6-tetramethyl-3,5-heptanedionate, and/or hexafluoroacetonate), or a carboxyl acid ligand (e.g. picolinate, dimethyl-3-pyrazolcarboxylate, and/or benzoate), and/or the like.

In one or more embodiments, nb2 may be 0, 1, 2, 3 or 4, and in case that nb2 is 2 or greater, then the 2 or more L_{b}(s) may be identical to or different from each other. T₁ may be a direct linkage, *—O—*, *—S—*, *—N(Q₁)*-C(═O)—*, *C(Q₁)=C(Q₂)-*, *—C(Q₁)=*, *—C(Q₁)(Q₂)-* or *═C(Q₁)-*.

In one or more embodiments, Xₐ and X_{b} may each independently be C or N, and X_{c} and X_{d} may each independently be a chemical linkage (e.g., a coordinate bond or a covalent bond), O, S, N(Q₃), B(Q₃), P(Q₃), C(Q₃)(Q₄), or Si(Q₃)(Q₄). a ring Cy₁ and a ring Cy₂ may each independently be selected from among a substituted or unsubstituted carbocyclic ring of 3 to 60 ring-forming carbons and a substituted or unsubstituted heterocyclic ring of 1 to 60 ring-forming carbons.

In one or more embodiments, Ra and Rb may each independently be hydrogen, deuterium, a halogen, a hydroxyl group, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbons, a substituted or substituted alkenyl group of 2 to 20 carbons, a substituted or unsubstituted aryl group of 6 to 60 ring-forming carbons, or a substituted or unsubstituted heteroaryl group of 2 to 60 ring-forming carbons.

In one or more embodiments, Q₁ to Q₄ may each independently be hydrogen, deuterium, a halogen, a hydroxyl group, a cyano group, a nitro group, a substituted or unsubstituted alkyl group of 1 to 30 carbons, a substituted or unsubstituted alkenyl group of 1 to 30 carbons, a substituted or unsubstituted alkynyl group of 2 to 30 carbons, a substituted or unsubstituted alkoxy group of 1 to 30 carbons, a substituted or unsubstituted aryl group of 6 to 60 ring-forming carbons, or a substituted or unsubstituted heteroaryl group of 2 to 60 ring-forming carbons.

In one or more embodiments, nb3 and nb4 may each independently be an integer between 0 and 10, inclusive.

In one or more embodiments, in Formula M-a and M-b, if (e.g., if (e.g., when)) nb1 is 2 or greater, two rings Cy₁ among two or more Lₐ(s) may be optionally linked to each other via T₂, which is a linking group, and/or two rings Cy₂ may be optionally linked to each other via T₃, which is a linking group. T₂ and T₃ may each be the same as described with reference to T₁.

In one or more embodiments, in Formula M-b, * and *′ may each be a binding site to M of Formula M-a. Compounds represented by Formulae M-a and Formula M-b may be shown as Compound D1 among the compounds shown as an example of manufactured light-emitting diodes of the present disclosure, but embodiments of the present disclosure are not limited thereto.

In one or more embodiments, the light-emitting layer EML may include a compound represented by Formula F-a. The compound represented by Formula F-a may be a fluorescent dopant material or a delayed fluorescent material.

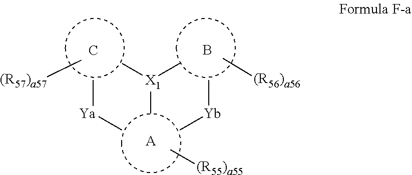

In one or more embodiments, in Formula F-a, ring A to ring C may each independently be a substituted or unsubstituted aromatic cyclic hydrocarbon of 6 to 60 ring-forming carbons or a substituted or unsubstituted aromatic heterocycle of 2 to 60 ring-forming carbons.

In one or more embodiments, in Formula F-a, Yₐ and Y_{b} may each independently be selected from among O, S, Se, CR₅₈R₅₉, NR₆₀, and SiR₆₁R₆₂.

In one or more embodiments, in Formula F-a, X₁ may be any one selected from among B, P, and P═O, and in one or more embodiments, in Formula F-a, X₁ may be a boron (B).

In one or more embodiments, in Formula F-a, R₅₅ to R₆₂ may be the same or different, and each may independently be any one selected from among hydrogen, deuterium, a substituted or unsubstituted alkyl group of 1 to 30 carbons, a substituted or unsubstituted aryl group of 6 to 60 ring-forming carbons, a substituted or unsubstituted cycloalkyl group of 3 to 30 ring-forming carbons, a substituted or unsubstituted heteroaryl group of 2 to 60 ring-forming carbons, a substituted or unsubstituted alkoxy group of 1 to 30 carbons, a substituted or unsubstituted aryloxy group of 6 to 30 carbons, a substituted or unsubstituted arylthiol group of 6 to 30 carbons, a substituted or unsubstituted arylamine group of 5 to 30 carbons, a substituted or unsubstituted alkylsilyl group of 1 to 30 carbons, a substituted or unsubstituted arylsilyl group of 5 to 30 carbons, a nitro group, a cyano group, and halogens.

In one or more embodiments, in Formula F-a, a55 to a57 may independently be an integer between 0 and 20, inclusive.

In one or more embodiments, the light-emitting layer EML of may further include one or more selected from among perylene and derivatives thereof (e.g., 2,5,8,11-Tetra-t-butylperylene (TBP)), pyrene and derivatives thereof (e.g. 1,1-dipyrene, 1,4-dipyrenylbenzene, and 1,4-Bis(N,N-Diphenylamino)pyrene), and/or a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (NBDAVBi), and 4′-bis[2-(4-(N,N-diphenylamino)phenyl)vinyl]biphenyl(DPAVBi)), and the like, as a dopant material.

In one or more embodiments, the light-emitting layer EML may further include a suitable phosphorescence dopant material. For example, a metal complex including iridium (Ir), platinum (Pt), osmium (Os), gold (Au), titanium (Ti), zirconium (Zr), hafnium (Hf), europium (Eu), terbium (Tb), or thulium (Tm) may be used. For example, iridium(III) bis(4,6-difluorophenylpyridinato-N,C2′)picolinate (Flrpic), Bis(2,4-difluorophenylpyridinato)-tetrakis(1-pyrazolyl)borate iridium(III) (Fir6), or platinum octaethyl porphyrin (PtOEP) may be used as a phosphorescence dopant. Nonetheless, embodiments of the present disclosure are not limited thereto. In one or more embodiments, the light-emitting layer may be a quantum dot (EL-QD).

In one or more embodiments, a quantum dot may refer to a crystal of a semiconductor compound and may have selected color of emitted light based on the size of the crystal. Accordingly, the quantum dot may have one or more suitable colors of emitted light, such as blue, red, or green.

In one or more embodiments, a diameter of the quantum dot may be, for example, in a range of 1 nanometer (nm) to 10 nm.

In the present disclosure, when quantum dots or quantum dot particles are spherical, “diameter” indicates a particle diameter or an average particle diameter, and when the particles are non-spherical, the “diameter” indicates a major axis length or an average major axis length. The diameter of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter is referred to as D50. D50 refers to the average diameter of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

In addition, the quantum dot may be spherical nanoparticles, pyramidal nanoparticles, multi-arm nanoparticles, cubic nanoparticles, nanotubes, nanowires, nanofibers, nanoplates, and/or the like.

In one or more embodiments, the quantum dot may be selected from among a Group III-VI compound, a Group II-VI compound, a Group III-V compound, a Group I-III-VI compound, a Group IV-VI compound, a Group IV element, a Group IV compound, and/or a (e.g., any suitable) combination thereof.

In one or more embodiments, in the light-emitting diode ED of one or more embodiments illustrated in FIG. 3 to FIG. 6, the electron functional layer EFL may be provided on the light-emitting layer EML.

In one or more embodiments, the electron functional layer EFL may include at least one of a hole block layer HBL, an electron transport layer ETL, or an electron injection layer EIL, but embodiments of the present disclosure are not limited to what is illustrated in the drawings.

In one or more embodiments, the electron functional layer EFL may have a single layer including (e.g., consisting of) a single material, a single layer including (e.g., consisting of) a plurality of different materials, or a multilayer structure having a plurality of layers including (e.g., consisting of) a plurality of different materials.

In one or more embodiments, for example, the electron functional layer EFL may have a single layer structure of an electron injection layer EIL or an electron transport layer ETL, or a single layer structure including (e.g., consisting of) an electron injection material and/or an electron transport material. In one or more embodiments, the electron functional layer EFL may have a single layer structure including (e.g., consisting of) a plurality of different materials, or a structure, in which constituting layers are sequentially stacked from the light-emitting layer EML, of an electron transport layer ETL/electron injection layer EIL or a hole blocking layer HBL/electron transport layer ETL/electron injection layer EIL, but embodiments of the present disclosure are not limited thereto. A thickness of the electron functional layer EFL may be, for example, from about 1000 Å to about 1500 Å.

In one or more embodiments, the electron functional layer EFL may be manufactured by utilizing a method selected from among vacuum deposition, spin coating, Langmuir-Blodgett (LB) casting, ink-jet printing, laser induced thermal imaging (LITI), and/or the like.

In one or more embodiments, the electron functional layer EFL may include a compound represented by Formula ET-1.

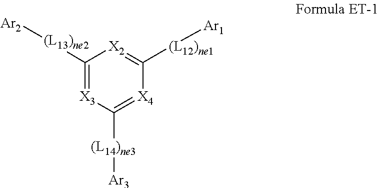

In one or more embodiments, in Formula ET-1, Ar₁ to Ar₃ may each independently be hydrogen, deuterium, a substituted or unsubstituted alkyl group of 1 to 20 carbons, a substituted or unsubstituted aryl group of 6 to 60 ring-forming carbons, or a substituted or unsubstituted heteroaryl group of 2 to 60 ring-forming carbons. Examples thereof may be a phenyl group, a naphthyl group, a biphenyl group, a phenanthrene group, a fluorene group, a spirofluorene group, a terphenyl group, a pyridine group, a carbazole group, and an isoquinoline group, but embodiments of the present disclosure are not limited thereto.

In one or more embodiments, in Formula ET-1, at least one of X₂, X₃, or X₄ is N, and the rest are CR_{c}.

In one or more embodiments, in Formula ET-1, Re may be hydrogen, deuterium, a halogen, a substituted or unsubstituted alkyl group of 1 to 20 carbons, a substituted or unsubstituted aryl group of 6 to 30 ring-forming carbons, or a substituted and/or unsubstituted heteroaryl group of 2 to 30 ring-forming carbons.

In one or more embodiments, in Formula ET-1, ne1 to ne3 may each independently be an integer between 0 and 5, inclusive. In Formula ET-1, L₁₂ to L₁₄ may each independently be a direct linkage, a substituted or unsubstituted arylene group of 6 to 30 ring-forming carbons, or a substituted or unsubstituted heteroarylene group of 2 to 30 ring-forming carbons.

In one or more embodiments, the compound represented by Formula ET-1 in the electron functional layer EFL and/or the light-emitting layer EML may be represented by Compound ET37 or Compound ET46 among the compounds provided in the device manufacturing embodiments of the present disclosure, but embodiments of the present disclosure are not limited thereto.

In one or more embodiments, the electron functional layer EFL may include an anthracene-based compound. However, embodiments of the present disclosure are not limited thereto, and the electron functional layer EFL may include, for example, 2,9-Dimethyl-4,7-diphenyl-1,10-phenanthroline (BCP), Tris(8-hydroxyquinolinato)aluminum (Alq₃), Bis(2-methyl-8-quinolinolato-N1,O8)-(1,1′-Biphenyl-4-olato)aluminum (BAlq), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzimidazol-1-yl)phenyl)-9,10-dinaphthylanthracene, 1,3,5-Tri(1-phenyl-1H-benzo[d]imidazol-2-yl)benzene (TPBi), 4,7-Diphenyl-1,10-phenanthroline (Bphen), 3-(Biphenyl-4-yl)-4-phenyl-5-tert-butylphenyl-1,2,4-triazole (TAZ), 4-(Naphthalen-1-yl)-3,5-diphenyl-4H-1,2,4-triazole (NTAZ), 2-(Biphenyl-4-yl)-5-(4-tert-butylphenyl)-1,3,4-oxadiazole (tBu-PBD), berylliumbis(benzoquinolin-10-olate) (Bebq2), 9,10-di(naphthalen-2-yl)anthracene (AND), 1,3-Bis[3,5-di(pyridin-3-yl)phenyl]benzene (BmPyPhB), or any combination thereof.

In one or more embodiments, the electron functional layer EFL (e.g., an electron transport layer ETL among the electron functional layer EFL) may be represented by, but not limited to, Compound ET 46 among the compounds provided in manufacturing embodiments of the present disclosure.

In one or more embodiments, the electron functional layer EFL (e.g., the electron transport layer ETL in the electron functional layer EFL) may include a metal-containing material in addition to one or more of the afore-described materials.

In one or more embodiments, for example, the metal-containing material may include a L₁ complex. The L₁ complex may include, for example, a compound ET-D1 (LiQ) or ET-D2:

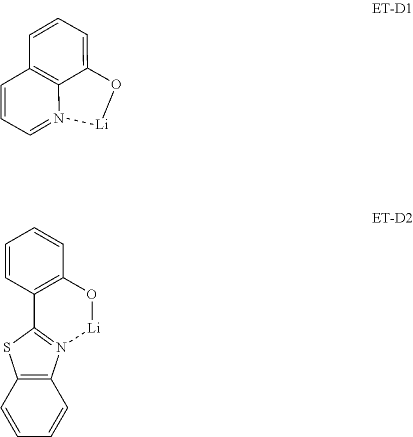

In one or more embodiments, the electron functional layer EFL may include an electron injection layer EIL configured to allow easy injection of an electron from the second electrode EL2. The electron injection layer may make direct contact with the second electrode.

The electron functional layer EFL (e.g., electron injection layer EIL) may have a single layer including (e.g., consisting of) a single material, a single layer including (e.g., consisting of) a plurality of different materials, or a multilayer structure having a plurality of layers including (e.g., consisting of) a plurality of different materials.

The electron functional layer EFL (e.g., electron injection layer EIL) may include an alkaline earth metal, a rare earth metal, an alkali metal, an alkaline earth metal-containing compound, a rare earth metal-containing compound, an alkali metal-containing compound, an alkaline earth metal complex, a rare earth metal complex, an alkali metal complex, or any combination thereof, or further include an organic material (e.g. a compound represented by Formula EM-2 or Formula EM-3).

An alkaline earth metal may include magnesium (Mg), calcium (Ca), strontium (Sr), barium (Ba), or any combination thereof.

A rare earth metal may include scandium (Sc), yttrium (Y), cerium (Ce), terbium (Tb), ytterbium (Yb), gadolinium (Gd), or any combination thereof. An alkali metal may include lithium (Li), Sodium (Na), potassium (K), rubidium (Rb), cesium (Cs), or any combination thereof.

In one or more embodiments, the electron functional layer EFL may include a halogenated metal, such as LiF, NaCl, CsF, RbCl, RbI, CuI, and/or KI, a lanthanide metal such as Yb, or a co-deposition material of a halogenated metal and a lanthanide metal. For example, the co-deposition material of a halogenated metal and a lanthanide metal may include KI:Y_{b}, RbI:Y_{b}, and/or LiF:Y_{b}. In one or more embodiments, a metal oxide, such as Li₂O and/or BaO, 8-hydroxyl-Lithium quinolinolate (Liq), and/or the like may be used for the electron functional layer EFL, but embodiments of the present disclosure are not limited thereto. In one or more embodiments, the electron functional layer EFL may also be consisting of a mixture material of an electron transport material and an insulating organo-metal salt. The insulating organo-metal salt may be a material having an energy band gap of about 4 eV or greater. For example, the insulating organo-metal salt may include, for example, a metal acetate, a metal benzoate, a metal acetoacetate, a metal acetylacetonate, and/or a metal stearate.

In one or more embodiments, the electron functional layer EFL may include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to one or more of the materials described above, but embodiments of the present disclosure are not limited thereto.

In one or more embodiments, the electron functional layer EFL may include one or more of the compounds of the electron functional layer EFL described above in at least one of an electron injection layer EIL, an electron transport layer ETL, or a hole blocking layer HBL.

In one or more embodiments, if (e.g., when) the electron functional layer EFL may include an electron transport layer ETL, the electron transport layer ETL may have a thickness of about 100 Å to about 1000 Å, such as about 150 Å to about 500 Å. If (e.g., when) the thickness of the electron transport layer ETL satisfies the range described above, satisfactory level of electron transport properties may be obtained without a substantial increase in a driving voltage.

In one or more embodiments, if (e.g., when) the electron functional layer EFL includes an electron injection layer EIL, the electron injection layer EIL may have a thickness of about 1 Å to about 100 Å, such as about 3 Å to about 90 Å. If (e.g., when) the thickness of the electron injection layer EIL satisfies the range described above, satisfactory level of electron injection properties may be obtained without a substantial increase in a driving voltage.

In one or more embodiments, the second electrode EL2 may be provided on the electron functional layer EFL. In one or more embodiments, the second electrode EL2 may be a common electrode. The second electrode EL2 may be a cathode or an anode, but embodiments of the present disclosure are not limited thereto. For example, if (e.g., when) the first electrode EL1 is an anode, the second electrode EL2 may be a cathode, and if (e.g., when) the first electrode EL1 is a cathode, the second electrode EL2 may be an anode. Here, at least one of an alloy, a metal, an electrically conductive compound, or any combination thereof, each having a low-work function, may be utilized as a material for the second electrode EL2.

In one or more embodiments, the second electrode EL2 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode EL2 may be a transmissive electrode, a semi-transmissive electrode, or a reflective electrode.

In one or more embodiments, the second electrode EL2 may be connected with an auxiliary electrode. If (e.g., when) the second electrode EL2 is connected with the auxiliary electrode, a resistance of the second electrode EL2 may decrease.

In one or more embodiments, the second electrode EL2 may have a single layer structure of a single layer or a multiple layer structure of a plurality of layers.

In one or more embodiments, a first capping layer may be arranged outside of (e.g., on) the first electrode EL1, and/or a second capping layer may be arranged outside of (e.g., on) the second electrode EL2.

In one or more embodiments, light generated from the light-emitting layer of the light-emitting diode ED may be extracted toward the outside through the first electrode EL1, which is a semi-transmissive electrode or a transmissive electrode, and the first capping layer; in one or more embodiments, light generated from the light-emitting layer of the light-emitting diode ED may be extracted toward the outside through the second electrode EL2, which is a semi-transmissive electrode or a transmissive electrode, and the second capping layer.

In one or more embodiments, the capping layer CPL may independently be an organic capping layer including an organic material, an inorganic capping layer including an inorganic material, or a composite capping layer including an organic material and an inorganic material.

In one or more embodiments, the capping layer CPL may be an organic layer or an inorganic layer. For example, if (e.g., when) the capping layer CPL includes an inorganic material, the inorganic material may include an alkali metal compound, such as LiF, an alkaline earth metal compound, such as MgF₂, SiON, SiNₓ, SiO_{y}, and/or the like.

In one or more embodiments, for example, if (e.g., when) the capping layer CPL includes an organic material, the organic material may include an amine compound, such as a monoamine and/or a diamine. For example, in one or more embodiments, the organic material may include TPD, α-NPD, β-NPB, m-MTDATA, N4,N4,N4′,N4′-tetra (biphenyl-4-yl)biphenyl-4,4′-diamine (TPD15), 4,4′4″-Tris(carbazol-9-yl)triphenylamine (TCTA), and/or the like. However, embodiments of the present disclosure are not limited thereto, for example, in one or more embodiments, the capping layer CPL may include Alq₃, CuPc, an epoxy resin, or an acrylate, such as a methacrylate.

In one or more embodiments, the capping layer CPL may include at least one of (e.g., selected from among) Compounds CP1 to CP4, but embodiments of the present disclosure are not limited thereto. In a manufacturing embodiment of the device of the present disclosure, the capping layer includes the compound CP4.

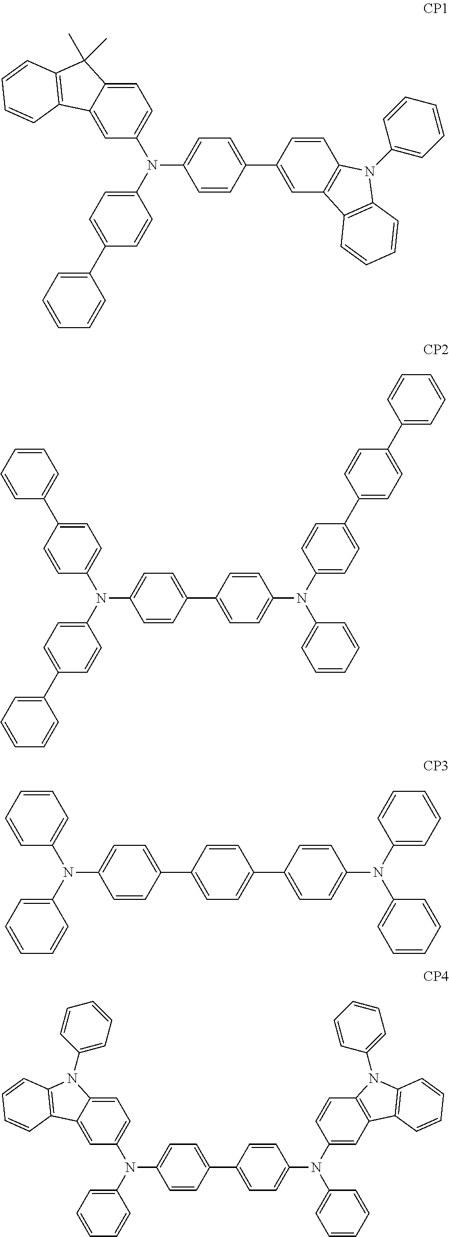 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

In one or more embodiments, the capping layer CPL may have a refractive index of 1.6 or more. For example, the refractive index of the capping layer CPL with respect to light in a wavelength range of 550 nm to 660 nm may be 1.6 or more, 1.8 or more, or 2.0 or more.

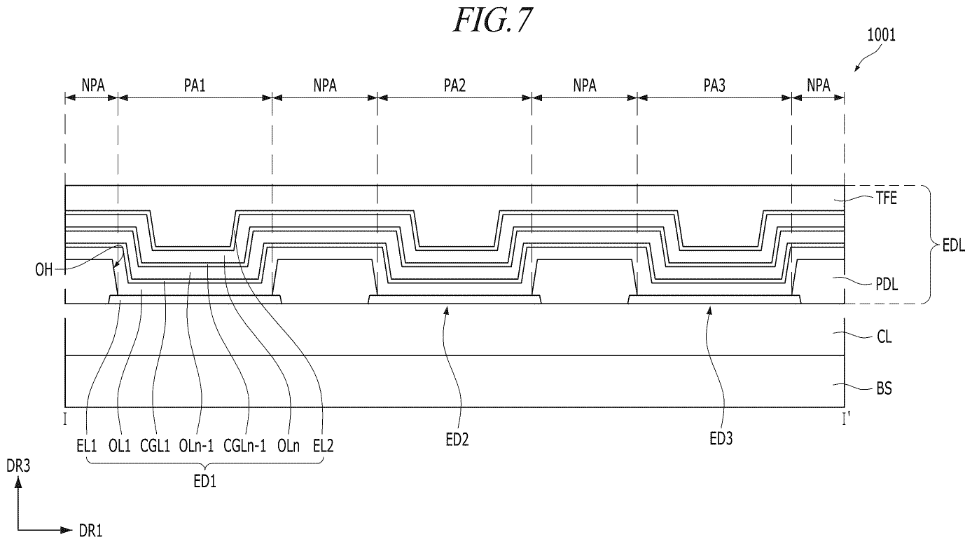

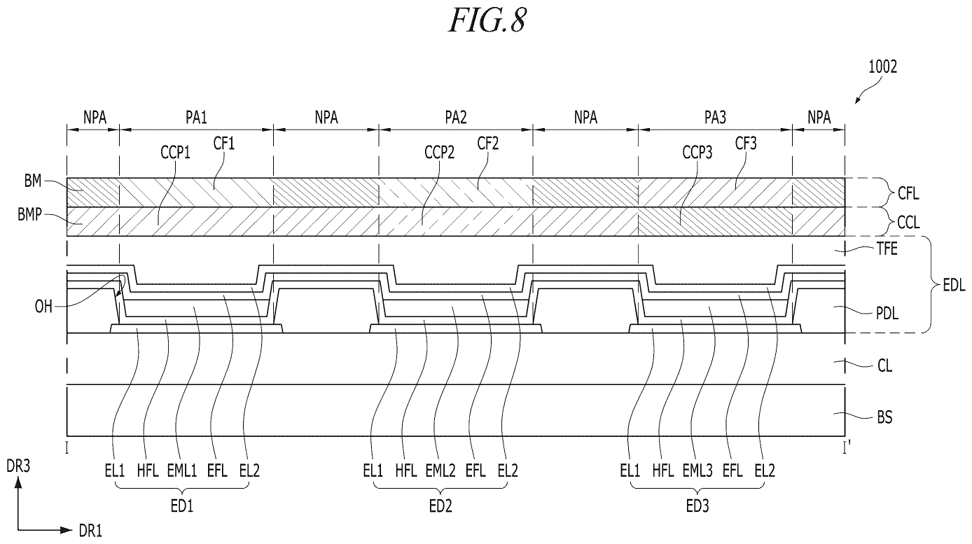

FIG. 7 is a cross-sectional view illustrating a portion of a display device in accordance with one or more embodiments of the present disclosure.

A display device 1001 will be described with reference to a first light-emitting diode ED1 among a plurality of light-emitting diodes ED1, ED2, and ED3. The first light-emitting diode ED1 may include n light-emitting structures (OL1, . . . , OLn−1, and OLn) laminated between a first electrode EL1 and a second electrode EL2, and n−1 charge generation layers (CGL1, . . . , and CGLn−1). Here, n may be a natural number.

Light-emitting structures OL1, . . . , OLn−1, and OLn may each include a hole functional layer HFL and an electron functional layer EFL. Light-emitting layer EML1 (in FIG. 2) may be arranged between the hole functional layer HFL and the electron functional layer EFL.

In one or more embodiments, for example, the first light-emitting diode ED1 included in the display device 1001 of one or more embodiments may be a light-emitting diode having a tandem structure including a plurality of light-emitting layers.

In one or more embodiments, the charge generation layers CGL1, . . . , and CGLn−1 may be each respectively interposed between neighboring light-emitting structures OL1, . . . , OLn−1, and OLn. The charge generation layers CGL1, . . . , and CGLn−1 may each include a p-type (kind) charge generation layer and/or an n-type (kind) charge generation layer. FIG. 7 illustrates the display device 1001 including three light-emitting structures OL1, OLn−1, and OLn and two charge generation layers CGL1 and CGLn−1 if (e.g., when) n is 3. Unlike what is illustrated in FIG. 7, in one or more embodiments, if (e.g., when) n is 1, the n−1-th light-emitting structure OLn−1 and n−1-th charge generation layer CGLn−1 may not be provided, and n-th light-emitting structure OLn may make direct contact with the first charge generation layer CGL1. In addition, unlike what is illustrated in FIG. 7, in one or more embodiments, if (e.g., when) n is 3 or greater, a light-emitting structure and a charge generation layer may be sequentially added between the first charge generation layer CGL1 and n−1-th light-emitting structure OLn−1.

In one or more embodiments, the light-emitting structures OL1, . . . , OLn−1, and OLn included in the first light-emitting diode ED1 may be to emit light in substantially the same wavelength range. However, embodiments of the present disclosure are not limited thereto, and at least some selected from among the light-emitting structures OL1, . . . , OLn−1, and OLn included in the first light-emitting diode ED1 may be to emit light with a different wavelength from the others.

In one or more embodiments, each of the light-emitting structures OL1, . . . , OLn−1, and OLn may allow each of the light-emitting diodes ED1, ED2, and ED3 including the light-emitting structures OL1, . . . , OLn−1, and OLn, respectively, to emit light in different ranges of wavelength. For example, the first light-emitting structure OL1 included in the first light-emitting diode ED1 and the first light-emitting structure OL1 included in the second light-emitting diode ED2 may be to emit light in different ranges of wavelength. However, embodiments of the present disclosure are not limited thereto, for example, each of the light-emitting structures OL1, . . . , OLn−1, and OLn may allow each of the light-emitting diodes ED1, ED2, and ED3 including the light-emitting structures OL1, . . . , OLn−1, and OLn, respectively, to emit light in substantially the same wavelength range.

Although it is illustrated in FIG. 7 that all (e.g., each) of the light-emitting diodes ED1, ED2, and ED3 have the same structure, embodiments of the present disclosure are not limited to what is illustrated in the drawing. In one or more embodiments, some of the light-emitting diodes ED1, ED2, and ED3 may include k light-emitting structures (k is a natural number), and the others may include m light-emitting structures (m is a natural number different from k).

FIG. 8 is a cross-sectional view illustrating a portion of a display device in accordance with one or more embodiments of the present disclosure.

A display device 1002 according to one or more embodiments in FIG. 8 will be described based on a difference from the display device 1000 described with reference to FIG. 2. An undescribed configuration follows the descriptions of FIG. 2.

The display device 1002 may further include a light controlling layer CCL and a color filter layer CFL each arranged on the display device layer EDL.

In one or more embodiments, the light controlling layer CCL may include a plurality of light controlling parts CCP1, CCP2, and CCP3. FIG. 8 illustrates that the light controlling parts CCP1, CCP2, and CCP3 may be separated from one another and a partition pattern BMP may be arranged between the light controlling parts. Nonetheless, embodiments of the present disclosure are not limited to what is illustrated in FIG. 8, for example, in one or more embodiments, edges of the light controlling parts may overlap with one another or edges of the light controlling parts may overlap with the partition pattern.

In one or more embodiments, the light controlling layer CCL may include a first to a third light controlling parts CCP1 to CCP3 overlapping with the first to the third light-emitting diodes ED1 to ED3, respectively.

In one or more embodiments, at least one selected from among the first to the third light controlling parts CCP1 to CCP3 may transform a wavelength of incident light (e.g., blue light) and then emit light of different color (e.g., red light or green light). In addition, at least one selected from among the first to the third light controlling parts CCP1 to CCP3 may be to transmit incident light (e.g., blue light) without transforming its wavelength.

In one or more embodiments, at least one selected from among the first to the third light controlling parts CCP1 to CCP3 may include a light converter, such as a quantum dot or a phosphor. The light converter may transform the wavelength of light provided and then emit the transformed (converted) light. The first to the third light controlling parts CCP1 to CCP3 may each further include a scatter and a base resin configured to disperse the scatter. In one or more embodiments, the light controlling layer CCL may further include a barrier layer configured to prevent or reduce penetration of moisture and/or oxygen.

In one or more embodiments, the color filter layer CFL may be arranged on the light controlling layer CCL.

The color filter layer CFL may include a plurality of color filters CF1, CF2, and CF3. FIG. 8 illustrates that the color filters CF1, CF2, and CF3 are spaced and/or apart (e.g., spaced apart or separated) and have a blocking part BM arranged between the color filters. However, embodiments of the present disclosure are not limited to what is illustrated in FIG. 8, and in one or more embodiments, edges of the color filters may overlap with one another, and edges of the color filters may overlap with the blocking part.

The color filter layer CFL may include a first to a third color filters CF1 to CF3 overlapping with the first to the third light-emitting diodes ED1 to ED3, respectively. The first to the third color filters CF1 to CF3 may selectively pass light with a selected color. However, embodiments of the present disclosure are not limited thereto, and at least one selected from among the first to the third color filters CF1 to CF3 may be provided as transparent or translucent.

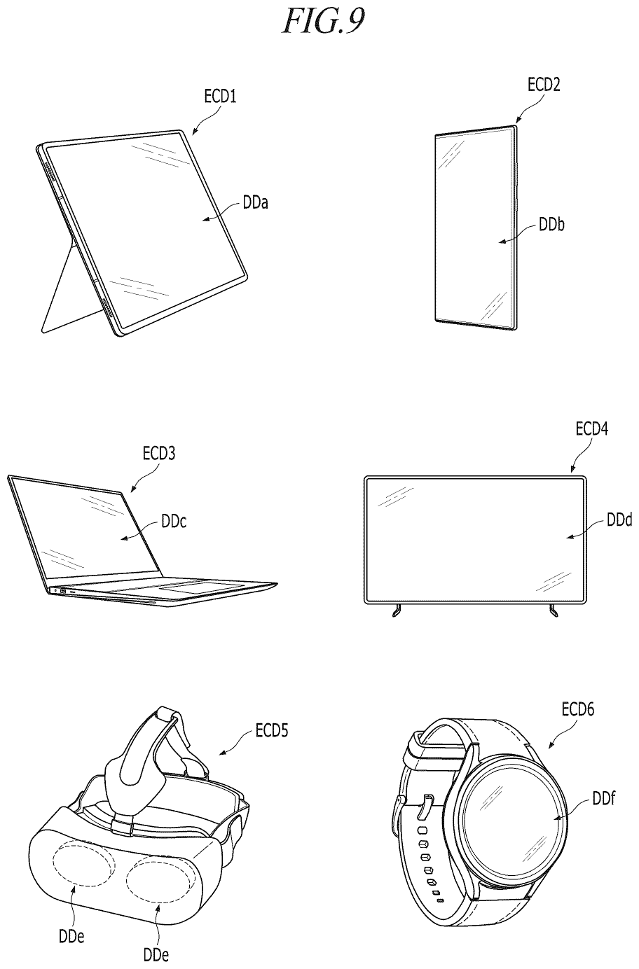

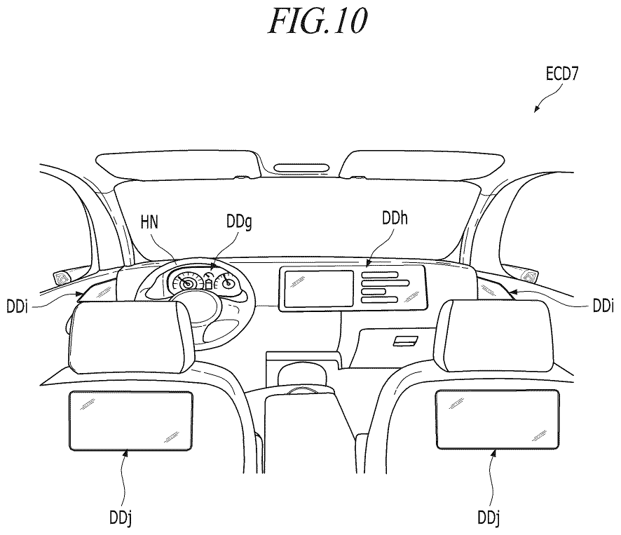

FIG. 9 and FIG. 10 are each a drawing illustrating electronic devices applied with the display device according to one or more embodiments of the present disclosure.

Referring to FIG. 9, a first electronic device ECD1 is illustrated as a tablet PC including a first display device DDa. A second electronic device ECD2 is illustrated as a portable terminal including a second display device DDb. A third electronic device ECD3 is illustrated as a laptop including a third display device DDc. A fourth electronic device ECD4 is illustrated as a TV including a fourth display device DDd.

A fifth electronic device ECD5 is illustrated as a head mounted display device including a fifth display device DDe.

A sixth electronic device ECD6 is illustrated as a digital watch including a sixth display device DDf. Referring to FIG. 10, a seventh electronic device ECD7 is illustrated as a transportation vehicle including a seventh to a tenth display device DDg to DDj. The seventh electronic device ECD7 is illustrated as an automobile. However, embodiments of the present disclosure are not limited thereto, and the transportation vehicle may include a bicycle, a motorcycle, a train, a ship, a plane, and/or the like.

The seventh display device DDg may be arranged in front of a steering wheel HN in a driver's sight for utilization in showing instrument panel information such as a driving speed of the vehicle. The eighth display device DDh may be arranged on a dashboard of the vehicle, apart from the seventh display device DDg, and utilized in showing information about a vehicle control interface, audio, temperature, road condition, and/or video. The nineth display device DDi may be arranged on a side mirror of a driver seat or a passenger seat and utilized as a digital side mirror. The nineth display device DDi may display an image of filming outside of the vehicle. The tenth display device DDi may be arranged behind a driver seat or a passenger seat and utilized in displaying, for example, an image, which is recognized by a passenger in a rear seat.

At least one selected from among the first to the tenth display devices DDa to DDj may include the light-emitting diode ED described with reference to FIG. 3 to FIG. 6.

In addition to the electronic devices shown in FIGS. 9 and 10, the display device according to one or more embodiments is not limited to the example electronic devices and may be applicable to one or more suitable electronic devices, such as a plane panel display, a curved display, a television, a billboard, a computer monitor, a medical monitor, a head mounted display, an indoor light, an outdoor light, a signal light, a wearable device, a foldable device, a rollable device, a bendable device, a flexible device, a curved device, an electronic organizer, an electronic book, a portable multimedia player, a personal digital assistance, a laser printer, a telephone, a cellphone, a tablet PC, a portable terminal, a laptop computer, a digital camera, a viewfinder, a camcorder, a 3D display, a virtual reality display, an augmented reality display, a video wall including multiple displays tiled together, a vehicle display device, an outdoor display device, a theater screen, a stadium screen, and/or a signboard.

Hereinafter, Examples and Comparative Examples will be described in more detail. The compound according to one or more embodiments and the light-emitting diode of one or more embodiments will be specifically described. However, Examples shown are shown to assist the understanding of the present disclosure, and the scope of the present disclosure is not limited thereto.

### SYNTHESIS EXAMPLE

### Synthesis Examples 1 to 9

A method for synthesizing a compound according to one or more embodiments is not limited to the Examples.

### Synthesis Example 1: Synthesis of O-120

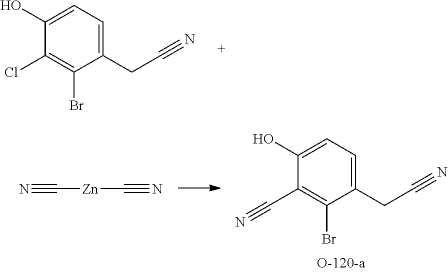

Dimethylacetamide (DMA) was mixed with a concentration condition of tris(dibenzylideneacetone)dipalladium(0) (Pd₂(dba)₃) 2 mol %, 1,1′-bis(diphenylphosphino)ferrocene (dppf) 4 mol %, and Zn 12 mol %, and 2-(2-bromo-3-chloro-4-hydroxyphenyl)acetonitrile (10.00 g, 37 mmol) and Zn(CN)₂ (5.23 g, 45 mmol) were added thereto and stirred to react at 120° C. After completion of the rection, it was washed with ethyl acetate (EtOAc) and H₂O, moisture was removed with anhydrous MgSO₄, and solvent was removed under a reduced pressure, and then the resultant was purified through a column chromatography to obtain 8.3 g of intermediate O-120-a. (yield: 94.4%)

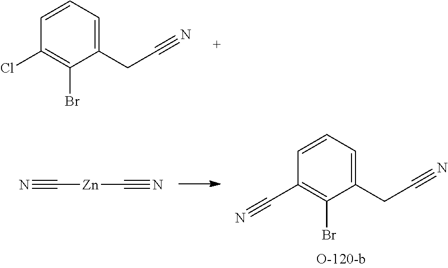

2-(2-Bromo-3-chlorophenyl)acetonitrile (10.00 g, 43 mmol) and Zn(CN)₂ (6.11 g, 52 mmol) were reacted through substantially the same method as the synthesis of 0-120-a to obtain 8.55 g of intermediate O-120-b. (yield: 89.1%)

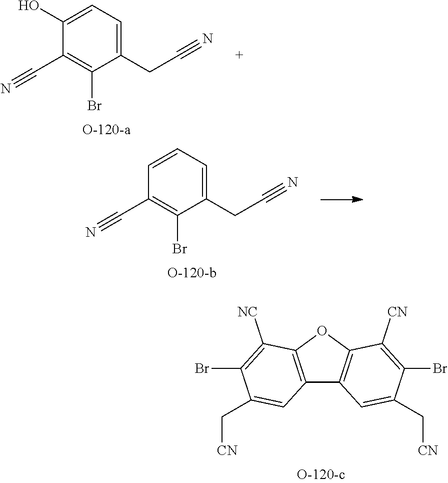 [SMILES: N#CCc1ccc(O)c(C#N)c1Br ; N#CCc1cccc(C#N)c1Br ; N#CCc1cc2c(oc3c(C#N)c(Br)c(CC#N)cc32)c(C#N)c1Br]

A phosphate buffer solution (pH 6.0, 0.2 M) was added with a AbL laccase catalyst, and the obtained O-120-a (8.00 g, 34 mmol) and O-120-b (8.21 g, 37 mmol) were added and stirred to react. After completion of the reaction, it was washed with EtOAc and H₂O, moisture was removed with anhydrous MgSO₄, and solvent was removed under a reduced pressure, and then the resultant was purified through a column chromatography to obtain 10.2 g of intermediate O-120-c. (yield: 66.6%)

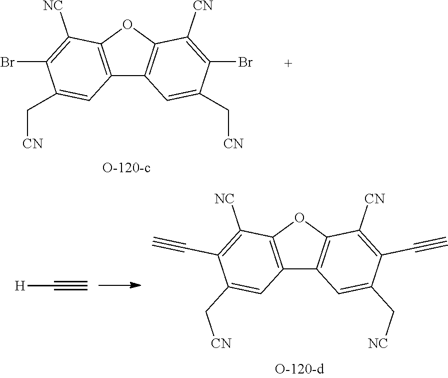

Under an environment of an inert gas, ethyne (1.14 g, 44 mmol), PdCl₂(PPh₃)₂ (1.11 g, 2 mmol), CuI (0.30 g, 2 mmol), PPh₃ (0.52 g, 2 mmol), and diisopropylamine (4.01 g, 40 mmol) were mixed, and the intermediate of O-120-c (9.00 g, 20 mmol) was added to react for 24 hours under a temperature condition of 50° C. After completion of the reaction, it was washed with EtOAc and H₂O, moisture was removed with anhydrous MgSO₄, and solvent was removed under a reduced pressure, and then the resultant was purified through a column chromatography to obtain 4.9 g of intermediate O-120-d. (yield: 71.8%)

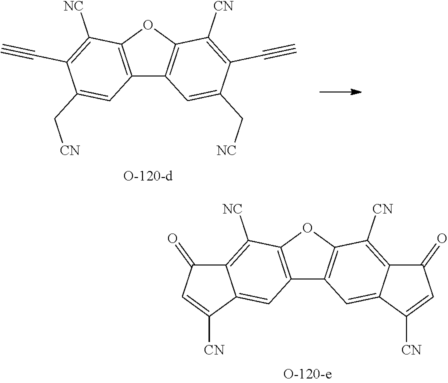 [SMILES: C#Cc1c(CC#N)cc2c(oc3c(C#N)c(C#C)c(CC#N)cc32)c1C#N ; N#Cc1cc(=O)c2c(C#N)c3oc4c(C#N)c5c(=O)cc(C#N)c5cc4c3cc12]

The intermediate O-120-d (4.50 g, 13 mmol), PdCl₂ (0.46 g, 3 mmol), AgSbF₆ (1.35 g, 4 mmol), and Ph₂SO (15.86 g, 78 mmol) were added in 150 mL of 1,2-dichloroethylene and a heat reflux stirring was performed under a temperature condition of 60° C. for 24 hours. Cs₂CO₃ (10.65 g, 33 mmol) was added to react for 18 more hours, CH₂Cl₂ was used for extraction, solvent was removed under a reduced pressure, and 15 mL of HCl was added to react for 2 more hours. CH₂Cl₂ and NH₄Cl were used for extraction, moisture of an organic layer was removed with anhydrous MgSO₄, and solvent was removed under a reduced pressure, and then the resultant was purified through a column chromatography to obtain 2.35 g of intermediate O-120-e. (yield: 48.3

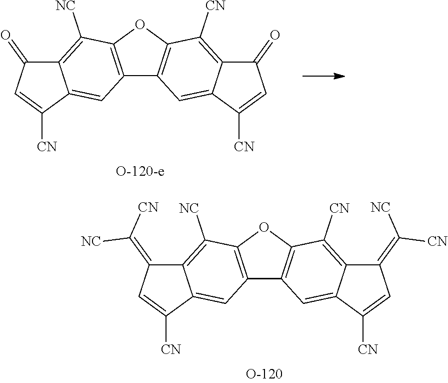 [SMILES: N#Cc1cc(=O)c2c(C#N)c3oc4c(C#N)c5c(=O)cc(C#N)c5cc4c3cc12 ; N#CC1=CC(=C(C#N)C#N)c2c1cc1c(oc3c(C#N)c4c(cc31)C(C#N)=CC4=C(C#N)C#N)c2C#N]

The intermediate O-120-e (2.10 g, 6 mmol), malononitrile (2.24 g, 34 mmol), and pyridine (5.35 g, 68 mmol) were added in 300 mL of CH₂Cl₂ to be dissolved, and TiCl₄ (6.42 g, 34 mmol) was added and stirred at a room temperature to react for 4 hours. After water was added to terminate the reaction, CH₂Cl₂ was used for extraction, brine was used for washing, moisture was removed with anhydrous MgSO₄, and solvent was removed under a reduced pressure. The resultant was dissolved in a small amount of CH₂Cl₂ and purified with a silica filter to obtain 1.8 g of Compound O-120 of a Synthesis Example 1. (yield: 68.1%)

### Synthesis Example 2: Synthesis of O-117

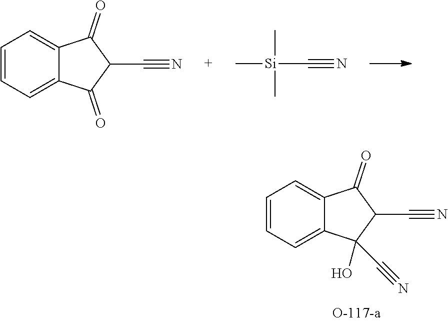

Under an inert gas atmosphere, in a dichloromethane (DCM) (0.5 M) solvent, trimethylsilyl cyanide (TMSCN) (6.96 g, 70 mmol) and TiCl₄ (2.22 g, 12 mmol) were successively added in a solution being stirred after adding 1,3-dioxo-2,3-dihydro-1H-indene-2-carbonitrile (10.00 g, 58 mmol) to react at a room temperature. In the solution being stirred, acetonitrile (0.2 M) and HCl (2 M) were added and stirred for 1 hour at a room temperature to continuously react, and then diluted with water. The solution was extracted with EtOAc, an organic layer was washed with brine, moisture was removed with anhydrous Na₂SO₄, and solvent was removed under a vacuum condition. 9.15 g of intermediate O-117-a was obtained through flash column chromatography. (yield: 79.0%)

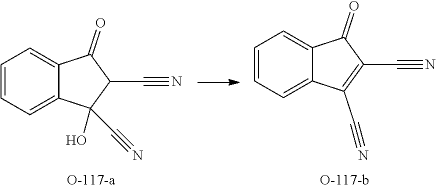 [SMILES: N#CC1C(=O)c2ccccc2C1(O)C#N ; N#CC1=C(C#N)c2ccccc2C1=O]

10.00 g of O-117-a was dissolved in 5 mL of 1,2-dichloroethane, and then 15.01 g of SOCl₂ was slowly added. It was stirred for one hour under a condition of 60° C. to react, and water was added to terminate the reaction. It was extracted with DCM, and solvent was evaporated to obtain 7.65 g of intermediate O-117-b. (yield: 84.1%)

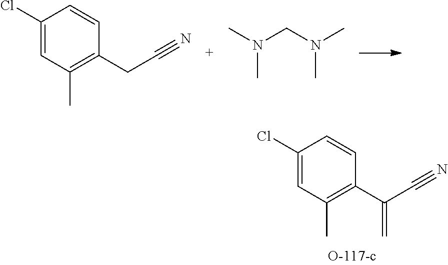

In a solution of acetic anhydride (Ac₂O) dissolved with N,N,N′,N′-tetramethyldiaminomethane (TMDAM) (44.19 g, 432 mmol), 2-(4-chloro-2 iodophenyl)acetonitrile (100 g, 360 mmol) was added to react. Solvent was removed under a vacuum environment to obtain 63.5 g of intermediate O-117-c. (yield: 60.9%)

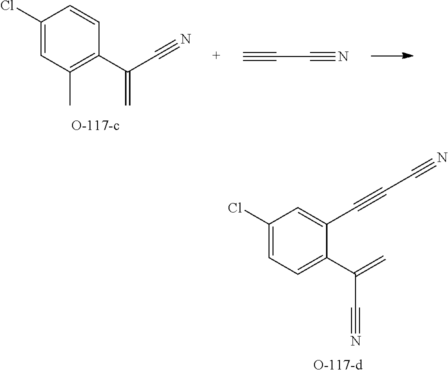

After dissolving the intermediate O-117-c (60 g, 207 mmol), PdCl₂(PPh₃)₂ (4.36 g, 6 mmol), and CuI (2.37 g, 12 mmol) in triethylamine (Et₃N), oxygen was removed by using a freeze-pump-thaw method. The solution was stirred by maintaining 60° C. in a nitrogen environment, and propiolonitrile (17.99 g, 352 mmol) was added three times at an interval of 1 hour. Subsequently, it was concentrated under a vacuum environment. After dissolving in CH₂Cl₂, it was filtered with silica gel and then re-concentrated to obtain 42 g of intermediate O-117-d through column chromatography. (yield: 95.3%)

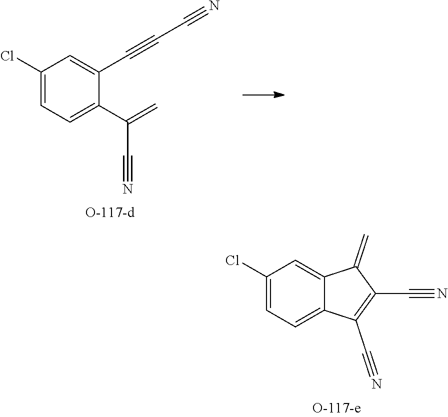

In Toluene, InCl₃ (13.20 g, 19 mmol) and O-117-d (40.00 g, 188 mmol) was dissolved and stirred at 80° C. for 1 hour to react. After cooling the solution to a room temperature, the solution was concentrated under a vacuum environment. the resultant was purified through flash column chromatography in silica gel to obtain 33.5 g of intermediate O-117-e. (yield: 83.8%)

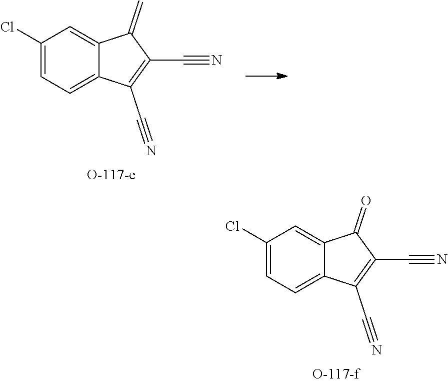

Polyethylene glycol dimethyl ether and O-117-e (30.00 g, 141 mmol) were added, dissolved, and stirred for 8 hours by maintaining 110° C. in an oxygen environment. The solution was cooled to obtain 26.65 g of intermediate O-117-f through a silica gel column chromatography method. (yield: 88%)

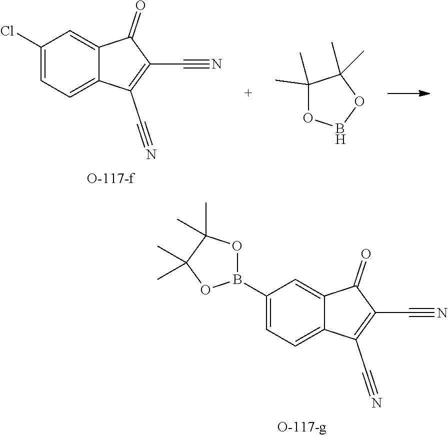

After adding and dissolving bis(diphenylphosphino)ferrocene]dichloropalladium(II) (PdCl₂(dppf)) (2.81 g, 4 mmol) in dioxane, O-117-f (25.00 g, 116 mmol), Et₃N (49.20 g, 384 mmol), and pinacolborane (23.85 g, 186 mmol) were added. After stirring the solution for 3 hours at 80° C. to react, it was extracted with benzene and washed with water. After removing moisture with anhydrous MgSO₄ and concentrating the solution, 26.5 g of O-117-g was obtained through a Kugelrohr distillation method. (yield: 74.3%)

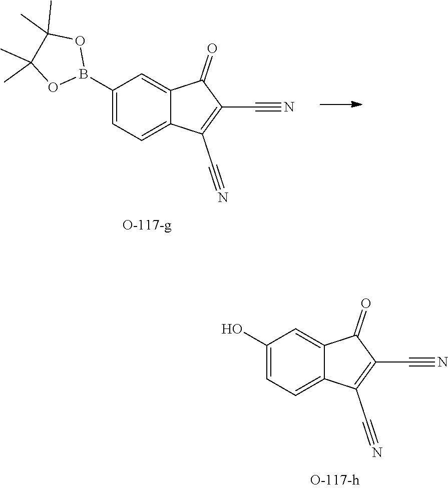 [SMILES: CC1(C)OB(c2ccc3c(c2)C(=O)C(C#N)=C3C#N)OC1(C)C ; N#CC1=C(C#N)c2ccc(O)cc2C1=O]

Dimethylformamide (DMF) was added with O-117-g (26.50 g, 87 mmol), L-histidine (0.78 g), and triethylamine (1.01 mg) and heated at 90° C. for 24 hours to react. After completion of the reaction, the solution was diluted with ethyl acetate and water and extracted with ethyl acetate. The remaining organic layer was washed with brine, and moisture was removed with anhydrous Na₂SO₄, and pressure was reduced to remove solvent, and 11.55 g of intermediate O-117-h was obtained through a silica gel column chromatography. (yield 68.0%)

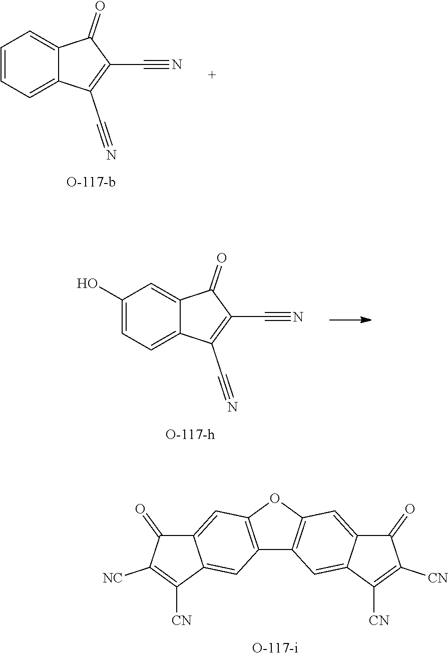 [SMILES: N#CC1=C(C#N)c2ccccc2C1=O ; N#CC1=C(C#N)c2ccc(O)cc2C1=O ; N#Cc1c(C#N)c2cc3c(cc2c1=O)oc1cc2c(=O)c(C#N)c(C#N)c2cc13]

The two intermediates O-117-b (7.50 g, 42 mmol) and O-117-h (8.98 g, 46 mmol) were added and mixed in phosphate buffer (pH 7.4). catecholase (2.16 mL, 125 μM) was added and stirred for 24 hours at a room temperature. The solution was extracted with chloroform and washed with water. An organic layer was washed with brine, and moisture was removed with anhydrous MgSO₄. Subsequently, a pressure was reduced for evaporation. 8.85 g of intermediate O-117-i was obtained through a silica gel flash chromatography method. (yield: 57.1%)

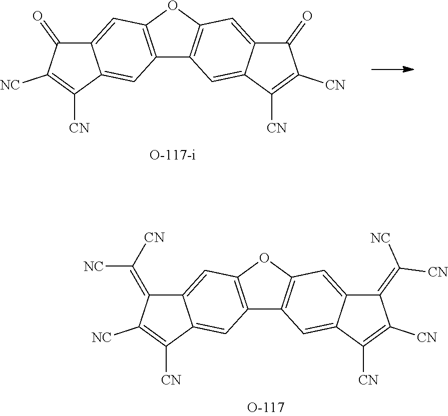 [SMILES: N#Cc1c(C#N)c2cc3c(cc2c1=O)oc1cc2c(=O)c(C#N)c(C#N)c2cc13 ; N#CC(C#N)=C1C(C#N)=C(C#N)c2cc3c(cc21)oc1cc2c(cc13)C(C#N)=C(C#N)C2=C(C#N)C#N]

The intermediates O-117-i was processed through substantially the same method as the synthesis of Compound O-120 from the intermediate O-120-e to obtain 5.65 g of Compound O-117 of Synthesis Example 2. (yield: 59.9%) Synthesis Example 3: Synthesis of O-34-1

In acetic acid, silver acetate (12.69 g, 76 mmol) and palladium acetate (0.16 g, 1 mmol) were added and stirred, and then 2-chloro-5-fluoroaniline (10.00 g, 69 mmol) and (E)-4-oxobut-2-enoic acid (7.56 g, 76 mmol) were added and stirred for 30 minutes at 110° C. After cooling to a room temperature, it was diluted with ethyl acetate, filtered through a filter, and concentrated under a vacuum environment. Through a column chromatography, 14.4 g of an intermediate O-34-a was obtained. (yield: 92.9%)

In the synthesis method of O-34-a, 10 g of 2-chloro-5-fluorophenol was instead used as a starting material to obtain 12.5 g of O-34-b. (yield: 81.2%)

In CHCl₃, trifluoroacetic anhydride (TFAA) (78.19 g, 372 mmol) was mixed and O-34-b (12.00 g, 53 mmol) was dissolved to react for 30 minutes at a room temperature. After cooling with an ice, basifying with K₂CO₃, and extracting with CH₂Cl₂, moisture was removed with anhydrous MgSO₄, and a vacuum filtration was performed. 10.2 g of intermediate O-34-c was obtained through a silica gel chromatography method. (yield: 91.9%)

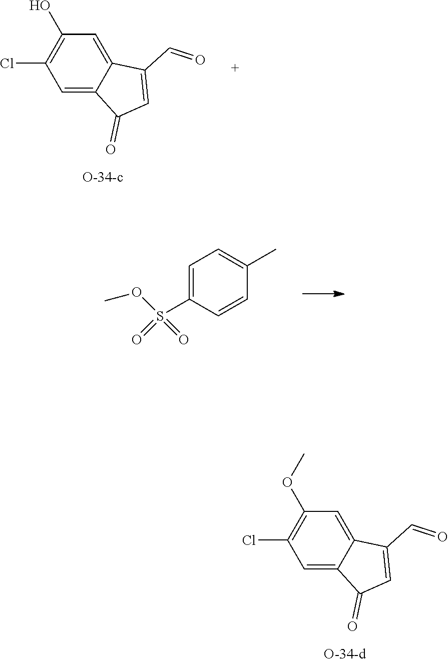

In DMF, the intermediate O-34-c (10.00 g, 48 mmol) was stirred and dissolved, and methyl 4-methylbenzenesulfonate (11.61 g, 62 mmol) and K₂CO₃ (15.46 g, 110 mmol) was added. Subsequently, it was heated for 1 hour at 70° C. under a nitrogen environment and then cooled to a room temperature. After adding EtOAc and washing with water, moisture was removed with anhydrous Na₂SO₄, and the solution was concentrated. Subsequently, it was washed with diethyl ether (Et₂O), and the remaining material was dried to obtain 9.25 g of intermediate O-34-d. (yield: 86.7%)

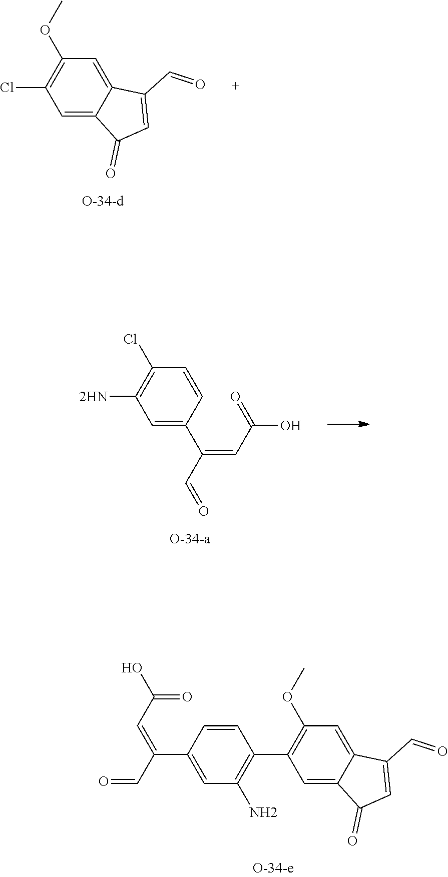

In an aqueous solution of 1,4-dioxane, O-34-d (9.00 g, 40 mmol), O-34-a (13.68 g, 61 mmol), tetrakis(triphenylphosphine) palladium (0.44 g, 2 mmol), and Ba(OH)₂ (20.78 g, 121 mmol) were dissolved, and the solution was purged three times with nitrogen. After hotplate stirring for 12 hours, the solution was cooled to a room temperature and filtered with celite, and the obtained material was extracted with EtOAc. After drying with anhydrous Na₂SO₄ and concentrating under a vacuum environment, 12.65 g of intermediate O-34-e was obtained through column chromatography. (yield: 82.9%)

After dissolving the intermediate O-34-e (12.00 g, 32 mmol) in CH₃SO₃H and stirring for 3 hours, the solution was cooled with iced water. After suctioning, 9.45 g of intermediate O-34-f was obtained through re-crystallization. (yield: 82.7%)

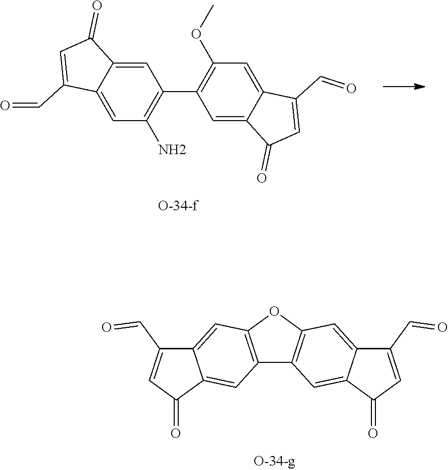 [SMILES: COc1cc2c(cc1-c1cc3c(cc1N)C(C=O)=CC3=O)C(=O)C=C2C=O ; O=Cc1cc(=O)c2cc3c(cc12)oc1cc2c(C=O)cc(=O)c2cc13]

After dissolving the intermediate O-34-f (9.00 g, 25 mmol) in water, stirring at a room temperature, and titrating with 4.85 g of sulfuric acid by a small amount, the solution was cooled to 0° C., and a solution of sodium nitrite was titrated to react for 3 hours. Then, a temperature of the solution was increased to a room temperature, and the solution was stirred. The solution was re-crystallized by adding water and filtered. The filtrate was extracted with dichloromethane to obtain 6.6 g of intermediate O-34-g through a column chromatography method. (yield: 80.3%)

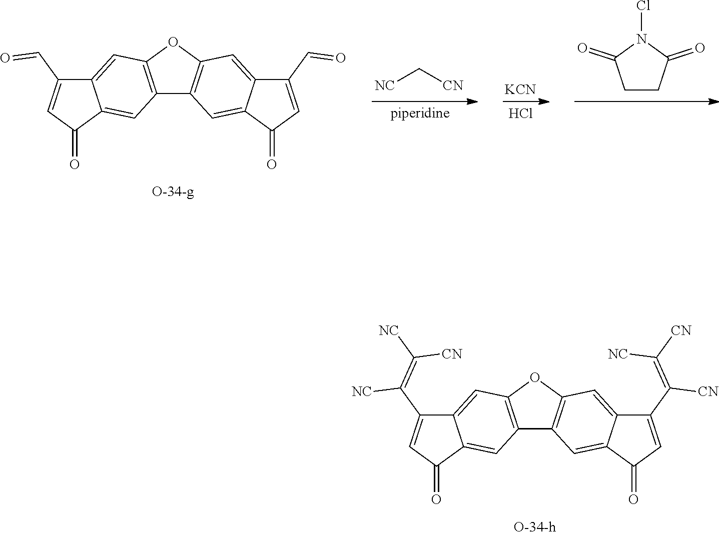

The intermediate O-34-g (9.00 g, 27 mmol), malononitrile (7.24 g, 110 mmol), and piperidine (110 mmol) were added in ethanol (EtOH) to be reflux stirred for 1 hour. After cooling to a room temperature, a produced precipitate was filtered and dissolved in a solution of 50% EtOH solution along with KCN (7.14 g, 110 mmol). Subsequently, an excessive amount of HCl was added to react for 2 hours at a temperature of 0° C. A compound obtained by filtering the precipitate, washing the precipitate with water, and drying the precipitate and N-chlorosuccinimide (NCS) (9.82 g, 110 mmol) was added in diethyl ether to react for 2 hours at a room temperature. Subsequently, it was added in cold water to complete the reaction. A pressure was reduced to remove solvent, and hexane was used for re-crystallization to obtain 4.65 g of intermediate O-34-h. (yield: 35.8%) Subsequently, the intermediate O-34-h (4.50 g, 9 mmol) was processed through a same method as the intermediate O-120-e to obtain 2.25 g of Compound O-34-1 of Synthesis Example 3. (yield: 41.6%)

### Synthesis Example 4: Synthesis of O-63-1

In a nitrogen gas environment, 3,5-dichloro-2-fluorobenzonitrile (10.00 g, 53 mmol), 4-formylbenzonitrile (7.59 g, 58 mmol) was added in DCM (0.1 M) and stirred. After preparing 1,3-dimethylimidazolium iodide (2.36 g, 11 mmol) and Cs₂CO₃ (25.88 g, 79 mmol) in a different tube, the above solution was added and additionally stirred for 18 hours. After completion of the reaction, a silica gel column chromatography method was used to obtain 14.8 g of intermediate O-63-a. (yield: 93.4%)

Through substantially the same method, 3,5-dichloro-2,6-difluorobenzonitrile (10.00 g, 48 mmol) was used to obtain 13.2 g of intermediate O-63-a′. (yield: 86%)

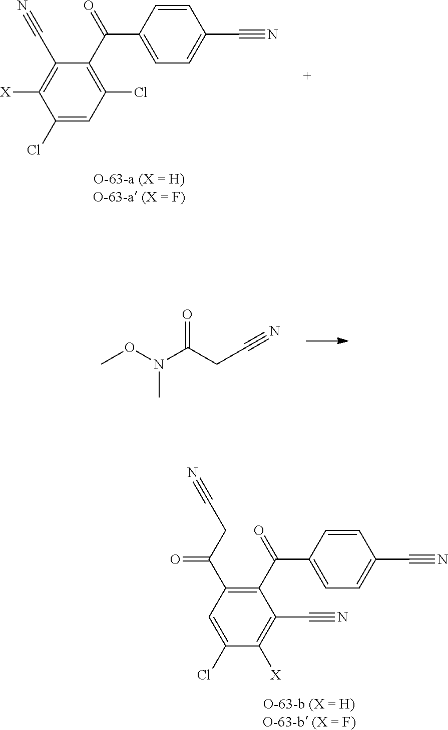

A solution was prepared by dissolving the intermediate O-63-a (12.00 g, 40 mmol) in tetrahydrofuran. After dissolving t-BuLi (3.06 g, 48 mmol) in pentane to obtain a concentration of 1.7 M, the above prepared O-63-a solution was added dropwise at a temperature of −78° C. After stirring the mixed solution for 30 minutes at 0° C., it was stirred for 30 minutes again at a room temperature. Cannula was used to slowly add 2-cyano-N-methoxy-N-methylacetamide (2.55 g, 20 mmol) in the solution, and the reaction was stirred at a room temperature until the reaction completes. After washing with a saturated NH₄Cl solution and diluting with water, extraction was performed with ethyl acetate (AcOEt). After washing an organic layer with brine, moisture was removed with anhydrous Na₂SO₄, and 10.2 g of intermediate O-63-b was obtained through a silica gel chromatography method. (yield: 76.7%)

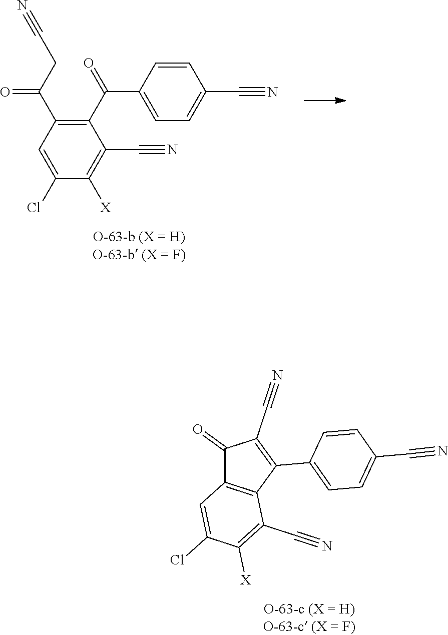

A small amount of ReBr(CO)₅ was added to the intermediate O-63-b (10.00 g, 30 mmol) and hot-plate stirred. Through vacuum filtration, 8.25 g of intermediate O-63-c was obtained. (yield: 87.2%)

Through substantially the same process, O-63-b′ (9.00 g, 26 mmol) was used as a starting material, and 7.1 g of intermediate O-63-c′ was obtained. (yield: 83.1%)

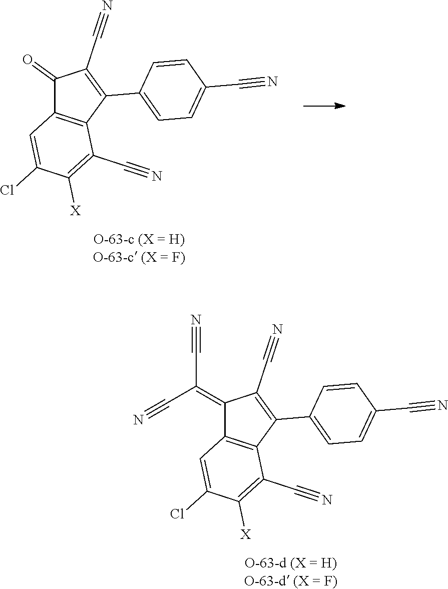

Substantially the same process as obtaining O-120 from O-120-e was used with O-63-c (8.00 g, 25 mmol) as a starting material to obtain 8.25 g of intermediate 0-63-d. (yield: 89.5%)

Through substantially the same process, O-63-c′ (7.00 g, 21 mmol) was used as a starting material, and 7.1 g of intermediate O-63-d′ was obtained. (yield: 88.7%)

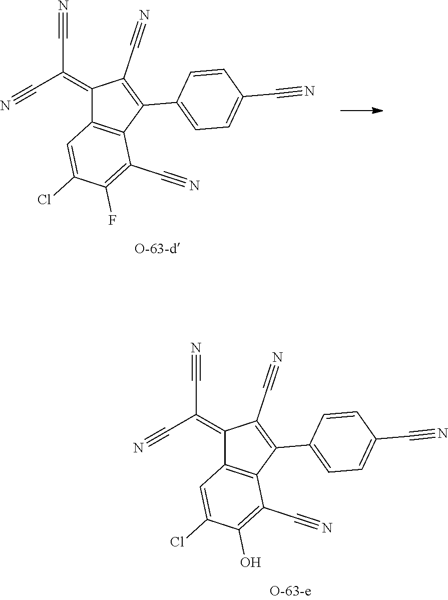 [SMILES: N#CC(C#N)=C1C(C#N)=C(c2ccc(C#N)cc2)c2c1cc(Cl)c(F)c2C#N ; N#CC(C#N)=C1C(C#N)=C(c2ccc(C#N)cc2)c2c1cc(Cl)c(O)c2C#N]

In a shrink tube with an argon environment, O-63-d′ (7.00 g, 18 mmol), Cu(OH)₂ (90 mg, 1 mmol), glycolic acid (420 mg, 6 mmol), NaOH (4.40 g, 110 mmol) and dimethyl sulfoxide (DMSO) was added to be stirred for 6 hours at a temperature of 120° C. After cooling it to a room temperature, 500 mL of water was added, and 2 M HCl was used to obtain pH=1. After extraction with EtOAc, it was washed with H₂O and brine and dried to obtain 6.8 g of intermediate O-63-e through a column chromatography method. (yield: 97.7%)

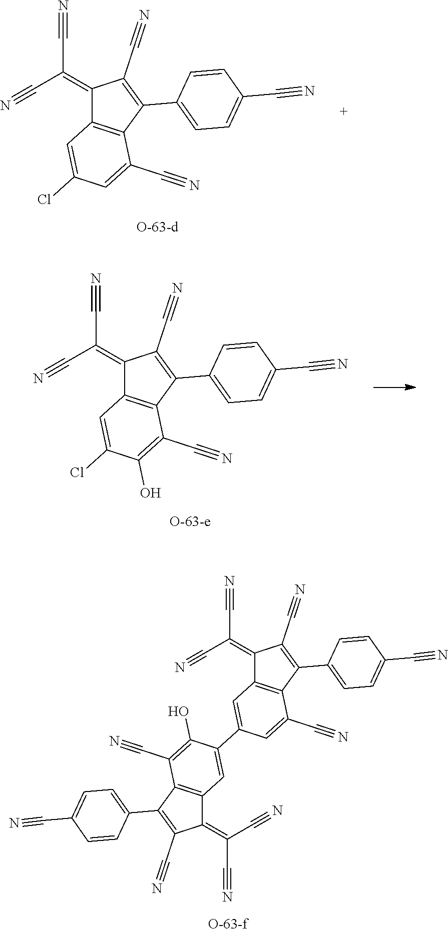 [SMILES: N#CC(C#N)=C1C(C#N)=C(c2ccc(C#N)cc2)c2c(C#N)cc(Cl)cc21 ; N#CC(C#N)=C1C(C#N)=C(c2ccc(C#N)cc2)c2c1cc(Cl)c(O)c2C#N ; N#CC(C#N)=C1C(C#N)=C(c2ccc(C#N)cc2)c2c(C#N)cc(-c3cc4c(c(C#N)c3O)C(c3ccc(C#N)cc3)=C(C#N)C4=C(C#N)C#N)cc21]

O-63-d (6.00 g, 16 mmol), O-63-e (6.26 g, 16 mmol), bis(dibenzylideneacetone)palladium(0) (Pd(dba)₂) (240 mg), and t-Bu₃PHBF₄ (240 mg) were mixed and heated to a temperature of 160° C. for 20 minutes. After addition of 0.1 M HCl, it was extracted with CH₂Cl₂, and 9.1 g of intermediate O-63-f was obtained through a flash column chromatography method. (yield: 82%)

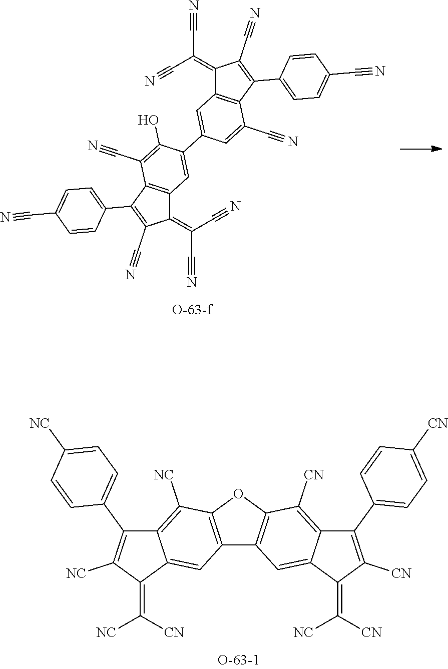 [SMILES: N#CC(C#N)=C1C(C#N)=C(c2ccc(C#N)cc2)c2c(C#N)cc(-c3cc4c(c(C#N)c3O)C(c3ccc(C#N)cc3)=C(C#N)C4=C(C#N)C#N)cc21 ; N#CC(C#N)=C1C(C#N)=C(c2ccc(C#N)cc2)c2c1cc1c(oc3c(C#N)c4c(cc31)C(=C(C#N)C#N)C(C#N)=C4c1ccc(C#N)cc1)c2C#N]

Subsequently, through substantially the same method as obtaining O-34-c from O-34-b, O-63-f (9.00 g, 13 mmol) was used as a starting material to obtain 7.9 g of Compound O-63-1 of Synthesis Example 4. (yield: 88%) Synthesis Example: Synthesis of O-122-1

In a mixture of 2,5-dichlorobenzonitrile (10.00 g, 58 mmol) and 2-hydroxyacetonitrile (0.66 g, 12 mmol), hexafluoroisopropanol 30 mL and triflic acid 10 μL was added to be stirred for 24 hours at a temperature of 80° C. NaHCO₃ and EtOAc were used for extraction, and brine was used for washing an organic layer. Then, it was dried to obtain 8.85 g of intermediate O-122-a. (yield: 72.1%)

Through substantially the same process, 2,5-dichloro-3-fluorobenzonitrile (10.00 g, 53 mmol) was used to obtain 8.6 g of intermediate O-122-a′. (yield: 71.3%)

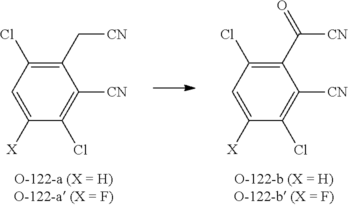

In a nitrogen environment, the intermediate O-122-a (8.50 g, 40 mmol) was dissolved in 5% vanadyl acetate, and t-BuOOH (7.26 g, 81 mmol) was added to be stirred for 24 hours at a room temperature. After completion of the reaction, it was washed with H₂O and extracted with dichloromethane. Subsequently, 8.2 g of intermediate O-122-b was obtained through a column chromatography method. (yield: 90.5%)

Through substantially the same process, the intermediate O-122-a′ (8.50 g, 37 mmol) was used as a starting material to obtain 7.1 g of intermediate O-122-b′. (yield: 85%)

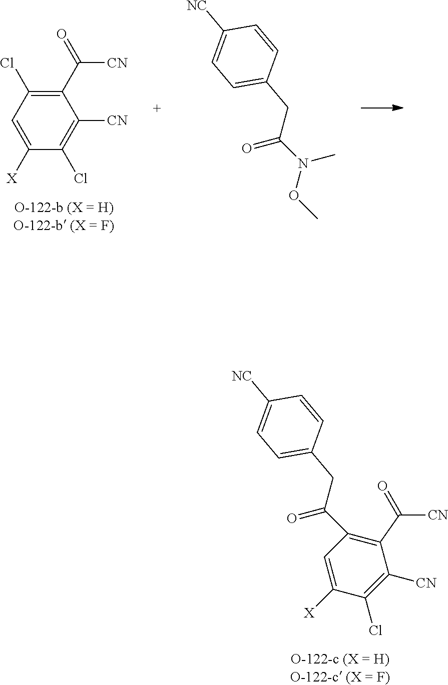

In a subsequent step, O-122-b/b′ was used instead of O-63-a/a′, and 2-(4-cyanophenyl)-N-methoxy-N-methylacetamide was used instead of 2-cyano-N-methoxy-N-methylacetamide to obtain 9.5 g of Compound O-122-1 of Synthesis Example 5 through substantially the same processes as obtaining Compound O-63-1. (yield: 37.5 Synthesis Examples 6 to 9: Synthesis of O-53, O-58, S-58, and S-117

In the synthesis method of O-117, 2-(5-chloro-2-iodophenyl)acetonitrile was used instead of 2-(4-chloro-2-iodophenyl)acetonitrile to obtain Compound O-53 of Synthesis Example 6.

Similarly, 5-chloro-3-(cyanomethyl)-2-iodobenzonitrile was used to obtain Compound O-58 of Synthesis Example 7.

In synthesis from g to h of a synthesis method of O-58, thiol-histidine was used instead of histidine to obtain Compound S-58 of Synthesis Example 8.

In synthesis from O-117-g to O-117-h of the synthesis method of O-117, thiol-histidine was used instead of histidine to obtain Compound S-117 of Synthesis Example 9.

The proton nuclear magnetic resonance (¹H NMR) spectroscopy and mass spectroscopy/fast atom bombardment (MS/FAB) of each of the synthesized compounds of Synthesis Examples 1 to 9 were shown in Table 1. Referring to the above synthesis pathways and raw materials, a person ordinarily skilled in the art may recognize a synthesis method of other compounds.

TABLE 1

| | | MS/FAB | |
|---|---|---|---|
| Synthesis | | Found | |
| Example | ¹H NMR (CDCl₃, 500 MHz) | [M + l] | calc. |
| Synthesis | 7.76 (s, 2H) | 467.30 | 468.05 |
| Example 1 | | | |
| Synthesis | 7.48 (s, 2H), 7.41 (s, 2H) | 467.20 | 468.05 |
| Example 2 | | | |
| Synthesis | 7.48 (s, 2H), 7.41 (s, 2H), 6.60 (s, 2H) | 569.10 | 570.07 |
| Example 3 | | | |
| Synthesis | 7.87 (d, 4H), 7.76 (s, 2H), 7.52 (d, 4H) | 669.60 | 670.10 |
| Example 4 | | | |
| Synthesis | 7.92 (d, 4H), 7.74 (s, 2H), 7.64 (d, 4H) | 669.40 | 670.10 |
| Example 5 | | | |
| Synthesis | 7.48 (s, 2H), 7.41 (s, 2H) | 467.30 | 468.05 |
| Example 6 | | | |
| Synthesis | 7.69 (s, 2H) | 517.10 | 518.04 |
| Example 7 | | | |
| Synthesis | 8.13 (s, 2H) | 533.10 | 534.02 |
| Example 8 | | | |
| Synthesis | 7.85 (s, 2H), 7.82 (s, 2H) | 483.10 | 484.03 |
| Example 9 | | | |

### Examples 1 to 9. Manufacture of Light-Emitting Diode

As an anode, a glass substrate (product of Corning Inc.) having an ITO electrode with 15 Ω/cm² (1,300 Å) was cut into a size of 50 mm×50 mm×0.7 mm, washed by ultrasonic waves with isopropyl alcohol and then pure water for 5 minutes each, and cleaned by irradiating ultraviolet rays for 30 minutes and then exposing to ozone. Then, the ITO glass substrate was installed in a vacuum deposition apparatus. On the anode, a hole injection layer having a thickness of 100 Å was manufactured by vacuum depositing a compound of Synthesis Examples 1 to 9, as a p-dopant, and Compound HT3 in a weight ratio of 3:97, and Compound HT40 was vacuum deposited on the hole injection layer to form a hole transport layer of a thickness of 1,250 Å.

Compound H125, Compound H126, and Compound D1 were vacuum deposited on the hole transport layer in a weight ratio of 45:45:10 to form a light-emitting layer of a thickness of 300 Å.

Compound ET37 was vacuum deposited on the light-emitting layer to form a buffer layer of a thickness of 50 Å, and Compound ET46 and LiQ were vacuum deposited on the buffer layer in a weight ratio of 5:5 to form an electron transport layer of a thickness of 310 Å. Thereafter, Yb was vacuum deposited on the electron transport layer to form an electron injection layer of a thickness of 15 Å, and Ag and Mg were vacuum deposited in a weight ratio of 5:5 to form a cathode of a thickness of 1,000 Å.

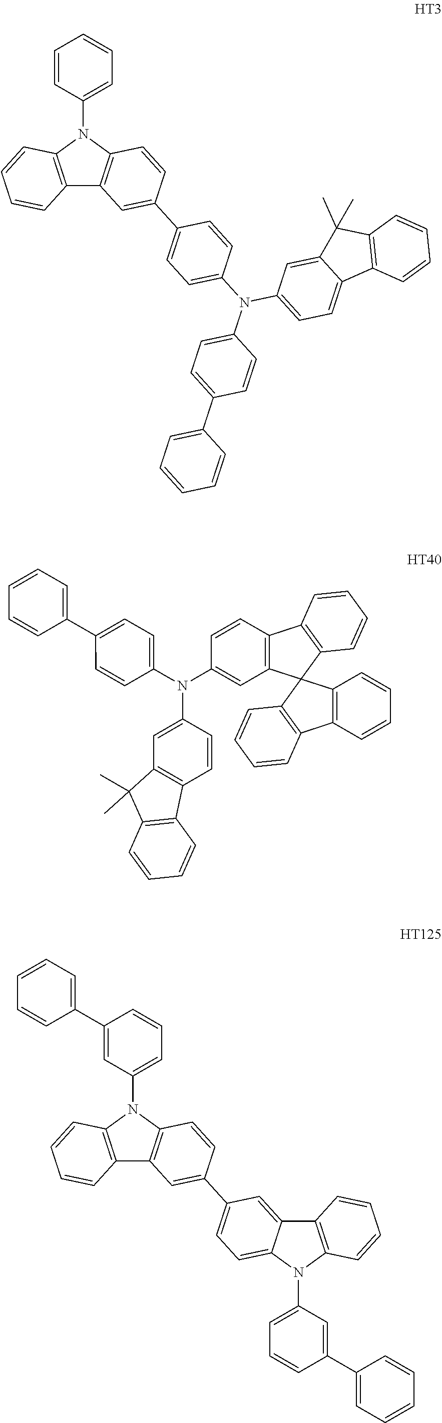 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccc(-c4ccccc4)cc3)c3ccc4c(c3)C3(c5ccccc5-c5ccccc53)c3ccccc3-4)cc21 ; c1ccc(-c2cccc(-n3c4ccccc4c4cc(-c5ccc6c(c5)c5ccccc5n6-c5cccc(-c6ccccc6)c5)ccc43)c2)cc1]

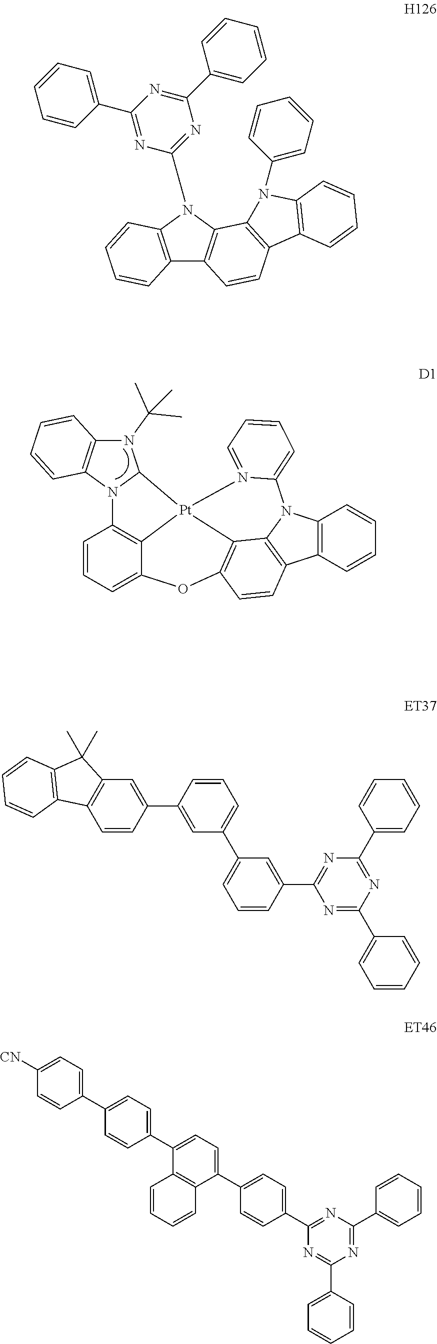

### COMPARATIVE EXAMPLE

Compounds of Comparative Examples 1 to 3, instead of Example Compounds 1 to 9, are respectively utilized for a hole functional layer, a charge generation layer, or a light-emitting layer. Except for the above, the same method as in Examples 1 to 9 was utilized to manufacture a light-emitting diode.

### Comparative Example 1

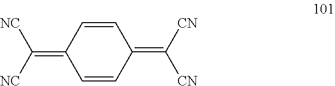 [SMILES: N#CC(C#N)=c1ccc(=C(C#N)C#N)cc1]

### Comparative Example 2

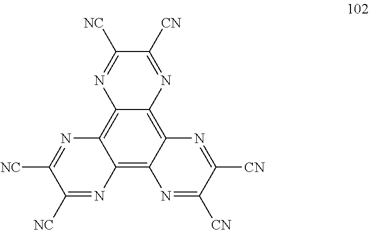 [SMILES: N#Cc1nc2c3nc(C#N)c(C#N)nc3c3nc(C#N)c(C#N)nc3c2nc1C#N]

### Comparative Example 3

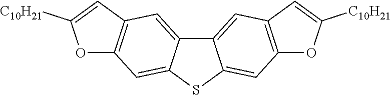

### Result

### Experimental Example 1. Evaluation of Physical Properties

HOMO energy level, LUMO energy level, hole mobility, electron mobility, and glass transition temperature of each of synthesized compounds of Synthesis Examples 1 to 9 are shown in Table 2. A person ordinarily skilled in the art may refer to the above synthesis pathway and raw materials to easily recognize synthesis methods of other compounds. 1) HOMO energy level evaluation method: Cyclic voltammetry (CV) (electrolyte: 0.1 M Bu₄NPF₆/solvent: DMF (dimethylformamide)/electrode: 3 electrode system (working electrode: glassy carbon (GC), reference electrode: Ag/AgCl, auxiliary electrode: Pt)) was utilized to obtain a voltage (V)-electric current (A) graph of each compound, and the HOMO energy level of each compound was calculated from an oxidation onset of the graph. 2) LUMO energy level evaluation method: Cyclic voltammetry (CV) (electrolyte: 0.1 M Bu₄NPF₆/solvent: DMF (dimethylformamide)/electrode: 3 electrode system (working electrode: GC, reference electrode: Ag/AgCl, auxiliary electrode: Pt)) was utilized to obtain a voltage (V)-electric current (A) graph of each compound, and the LUMO energy level of each compound was calculated from an reduction onset of the graph.

3) Hole mobility and electron mobility evaluation method: A method of space-charge-limited current (SOLO) described in “Hole mobility of N,N′-bis(naphthalen-1-yl)-N,N′-bis(phenyl)benzidine investigated by using space-charge-limited currents, “Appl. Phys. Lett. 90, 203512 (2007)” entire content of which is incorporated herein by reference, was used for evaluation.

TABLE 2

| Synthesis | | HOMO | LUMO | Hole Mobility | Electron Mobility | Glass Transition |
|---|---|---|---|---|---|---|
| Example | Compound | (eV) | (eV) | (cm²/Vs) | (cm²/Vs) | Temperature (° C.) |
| Synthesis | O-120 | −7.85 | −5.04 | 2.06e−6 | 6.07e−4 | 129.86 |
| Example 1 | | | | | | |
| Synthesis | O-117 | −7.81 | −5.12 | 1.79e−2 | 1.03e−2 | 132.29 |
| Example 2 | | | | | | |
| Synthesis | O-34-1 | −7.44 | −5.10 | 1.94e−3 | 9.67e−4 | 129.85 |
| Example 3 | | | | | | |
| Synthesis | O-63-1 | −7.66 | −5.03 | 9.16e−3 | 2.86e−3 | 142.21 |
| Example 4 | | | | | | |
| Synthesis | O-122-1 | −7.67 | −5.04 | 2.33e−3 | 1.11e−3 | 143.09 |
| Example 5 | | | | | | |
| Synthesis | O-53 | −7.63 | −5.10 | 7.74e−3 | 2.40e−3 | 130.87 |
| Example 6 | | | | | | |
| Synthesis | O-58 | −8.02 | −5.29 | 1.63e−3 | 6.26e−4 | 132.24 |
| Example 7 | | | | | | |
| Synthesis | S-58 | −7.97 | −5.24 | 3.50e−3 | 9.26e−4 | 129.32 |
| Example 8 | | | | | | |
| Synthesis | S-117 | −7.56 | −5.11 | 1.16e−2 | 9.55e−3 | 142.65 |
| Example 9 | | | | | | |

### Experimental Example 2. Evaluation of Light-Emitting Diode

In order to evaluate a property of each of the organic light-emitting diodes manufactured in Examples 1 to 9 and Comparative Examples 1 to 3, a driving voltage and electric current efficiency under a current density of 10 mA/cm² were measured and shown in Table 3. A driving voltage of the light-emitting diode was measured by utilizing a source measuring unit (Keithley, 2400 series), and an electric current efficiency was measured by utilizing a luminance measurement unit (Konica Minolta, CS-2000). In addition, a lifespan of a light-emitting diode was measured based on a time to reach 95% of an initial luminance. Every evaluation result is based on Comparative Example 1 to compare Comparative Examples 2, 3, and Examples 1 to 9, and the compared measurements are calculated and shown in Table 3.

TABLE 3

| | | Driving | Efficiency | Lifespan |
|---|---|---|---|---|
| Example | Compound | Voltage (%) | (%) | (%) |
| Example 1 | O-120 | 83.626 | 100.05 | 108.43 |
| Example 2 | O-117 | 72.904 | 100.05 | 119.84 |
| Example 3 | O-34-1 | 75.572 | 100.06 | 118.66 |
| Example 4 | O-63-1 | 92.281 | 100.04 | 105.59 |
| Example 5 | O-122-1 | 89.154 | 100.05 | 108.44 |
| Example 6 | O-53 | 75.634 | 100.06 | 118.83 |
| Example 7 | O-58 | 65.887 | 99.999 | 122.1 |
| Example 8 | S-58 | 66.516 | 100 | 121.92 |
| Example 9 | S-117 | 74.073 | 100.05 | 119.38 |
| Comparative | 101 | 100 | 100 | 100 |
| Example 1 | | | | |
| Comparative | 102 | 81.092 | 100.07 | 115.47 |
| Example 2 | | | | |
| Comparative | 103 | 103.31 | 99.803 | 94.586 |
| Example 3 | | | | |

Based on Table 3, it can be confirmed that each of the light-emitting diodes according to Examples 1 through 9 exhibited a lower driving voltage, higher efficiency, and a superior lifespan, compared to those according to Comparative Examples 1 through 3.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

In the context of the present application and unless otherwise defined, the terms “use,” “using,” and “used” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this disclosure, including the claims, to expressly recite any sub-range subsumed within the ranges expressly recited herein.

The light emitting element, the display apparatus/device, the electronic apparatus, a device for manufacturing the same, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

In the present disclosure, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

While certain embodiments of the present disclosure have been described above, anyone ordinarily skilled in the art to which the present disclosure pertains shall appreciate that there may be a variety of modifications and permutations of the present disclosure without departing from the technical ideas and scopes of the present disclosure that are defined in the appended claims.

Therefore, the technical scope of the present disclosure should be interpreted by the scope of the claims and equivalents thereof, instead of being restricted the disclosed description in Detailed Description.

What is claimed is:

1. A light-emitting diode, comprising:
a first electrode;
a second electrode opposite to the first electrode; and
at least one functional layer between the first electrode and a second electrode,
wherein the at least one functional layer comprises a compound represented by Formula 1: 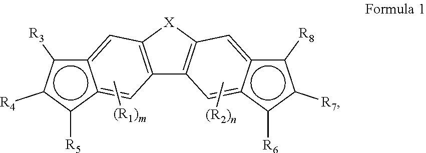
wherein, in Formula 1,
X is O, S, Ga, In, Ge, Sn, Pb, Sb, Bi, Se, or Te,
R₁ to R₈ are each independently:
hydrogen, deuterium, a halogen, a haloalkyl group, a hydroxyl group, a cyano group, a nitro group, a trifluoromethyl group, an amine group, an amidino group, a hydrazino group, a hydrazono group, or an alkoxy group; or
a phenyl group, an alkyl group having 1 to 10 carbons, an alkenyl group having 2 to 10 carbons, an alkynyl group having 2 to 10 carbons, an aryl group having 6 to 30 ring-forming carbons, a heteroaryl group having 2 to 30 ring-forming carbons, or any combination thereof, each substituted or unsubstituted with deuterium, a halogen, a hydroxyl group, a cyano group, a nitro group, a trifluoromethyl group, an amidino group, a hydrazino group, a hydrazono group, an alkoxy group, or any combination thereof, and
m and n are each independently an integer between 0 and 2, inclusive.

2. The light-emitting diode of claim 1,
wherein the compound is represented by Formula 1-1 or Formula 1-2: 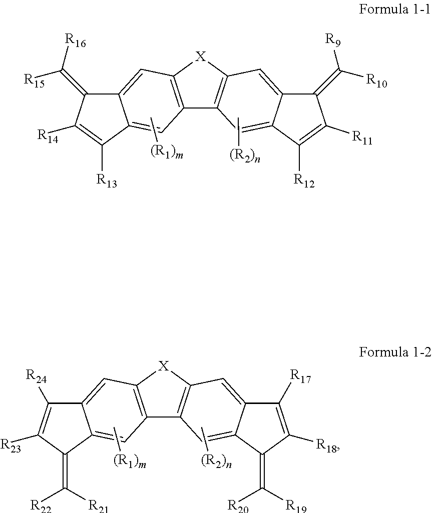
and
wherein, in Formula 1-1 and Formula 1-2,
X is selected from among O, S, Ga, In, Ge, Sn, Pb, Sb, Bi, Se, and Te,
R₁, R₂, and R₉ to R₂₄ are each independently:
hydrogen, deuterium, a halogen, a haloalkyl group, a hydroxyl group, a cyano group, a nitro group, a trifluoromethyl group, an amine group, an amidino group, a hydrazino group, a hydrazono group, or an alkoxy group; or
a phenyl group, an alkyl group having 1 to 10 carbons, an alkenyl group having 2 to 10 carbons, an alkynyl group having 2 to 10 carbons, an aryl group having 6 to 30 ring-forming carbons, a heteroaryl group having 2 to 30 ring-forming carbons, or any combination thereof, each substituted or unsubstituted with deuterium, a halogen, a haloalkyl group, a hydroxyl group, a cyano group, a nitro group, a trifluoromethyl group, an amine group, an amidino group, a hydrazino group, a hydrazono group, an alkoxy group, or any combination thereof, and
m and n are each independently an integer between 0 and 2, inclusive.

3. The light-emitting diode of claim 2,
wherein R₁, R₂, R₁₉, R₂₀, R₂₁, and R₂₂ are each independently:
a haloalkyl group, a hydroxyl group, a cyano group, a nitro group, a trifluoromethyl group, an amine group, or an alkoxy group; or
an alkenyl group having 2 to 10 carbons substituted or unsubstituted with a haloalkyl group, a hydroxyl group, a cyano group, a nitro group, a trifluoromethyl group, an amine group, an alkoxy group, or any combination thereof.

4. The light-emitting diode of claim 1,
wherein X is O or S.

5. The light-emitting diode of claim 1,
wherein the compound represented by Formula 1 comprises at least one selected from among compounds of Compound Group 1 and/or at least one selected from among compounds of Compound Group 2:

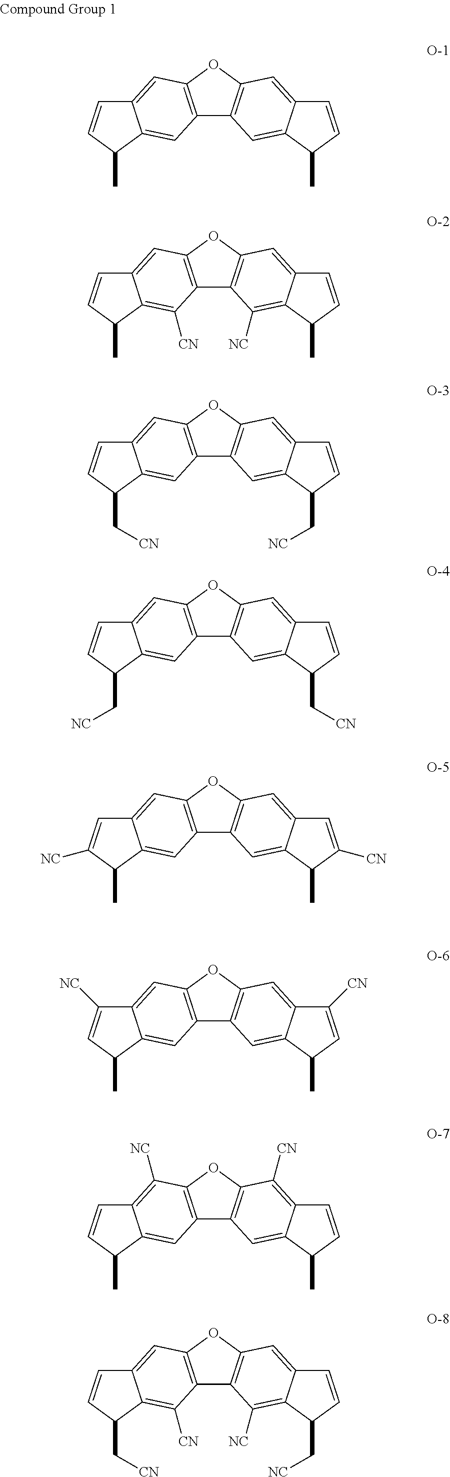

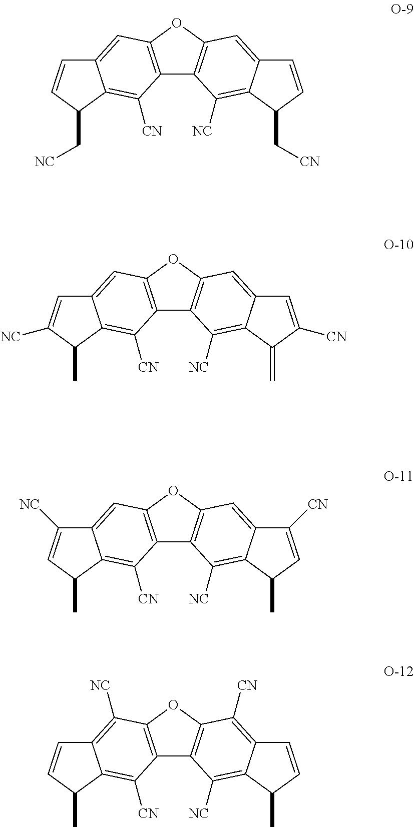 [SMILES: N#CC[C@H]1C=Cc2cc3oc4cc5c(c(C#N)c4c3c(C#N)c21)[C@H](CC#N)C=C5 ; C=C1C(C#N)=Cc2cc3oc4cc5c(c(C#N)c4c3c(C#N)c21)[C@@H](C)C(C#N)=C5 ; C[C@@H]1C=C(C#N)c2cc3oc4cc5c(c(C#N)c4c3c(C#N)c21)[C@@H](C)C=C5C#N ; C[C@@H]1C=Cc2c1c(C#N)c1c(oc3c(C#N)c4c(c(C#N)c31)[C@@H](C)C=C4)c2C#N]

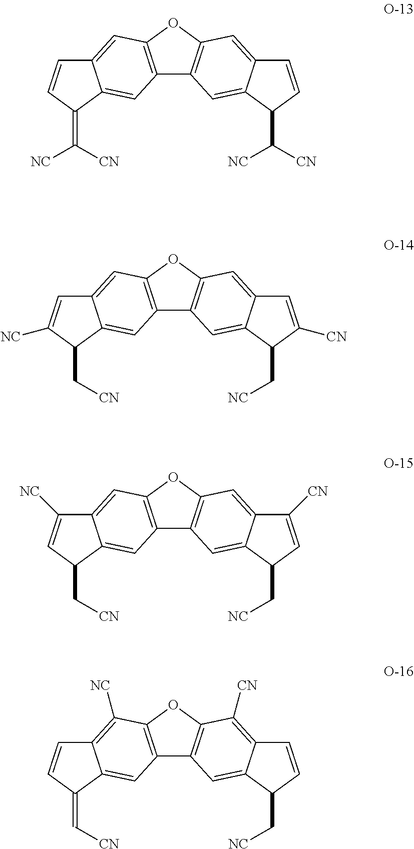 [SMILES: N#CC(C#N)=C1C=Cc2cc3oc4cc5c(cc4c3cc21)[C@H](C(C#N)C#N)C=C5 ; N#CC[C@@H]1C(C#N)=Cc2cc3oc4cc5c(cc4c3cc21)[C@@H](CC#N)C(C#N)=C5 ; N#CC[C@H]1C=C(C#N)c2cc3oc4cc5c(cc4c3cc21)[C@H](CC#N)C=C5C#N ; N#C/C=C1/C=Cc2c1cc1c(oc3c(C#N)c4c(cc31)[C@H](CC#N)C=C4)c2C#N]

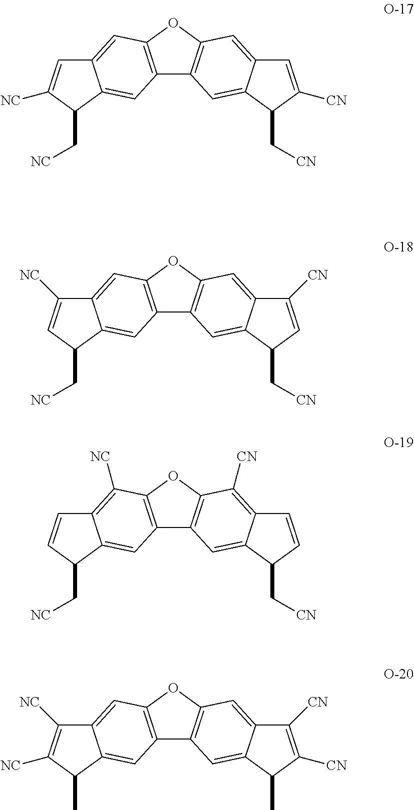 [SMILES: N#CC[C@@H]1C(C#N)=Cc2cc3oc4cc5c(cc4c3cc21)[C@@H](CC#N)C(C#N)=C5 ; N#CC[C@H]1C=C(C#N)c2cc3oc4cc5c(cc4c3cc21)[C@H](CC#N)C=C5C#N ; N#CC[C@H]1C=Cc2c1cc1c(oc3c(C#N)c4c(cc31)[C@H](CC#N)C=C4)c2C#N ; C[C@@H]1C(C#N)=C(C#N)c2cc3oc4cc5c(cc4c3cc21)[C@@H](C)C(C#N)=C5C#N]

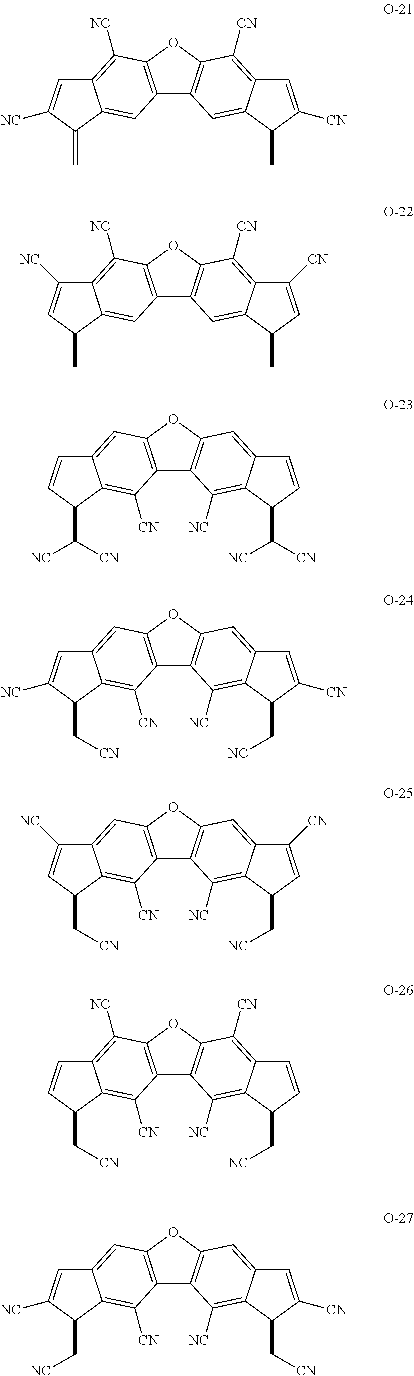

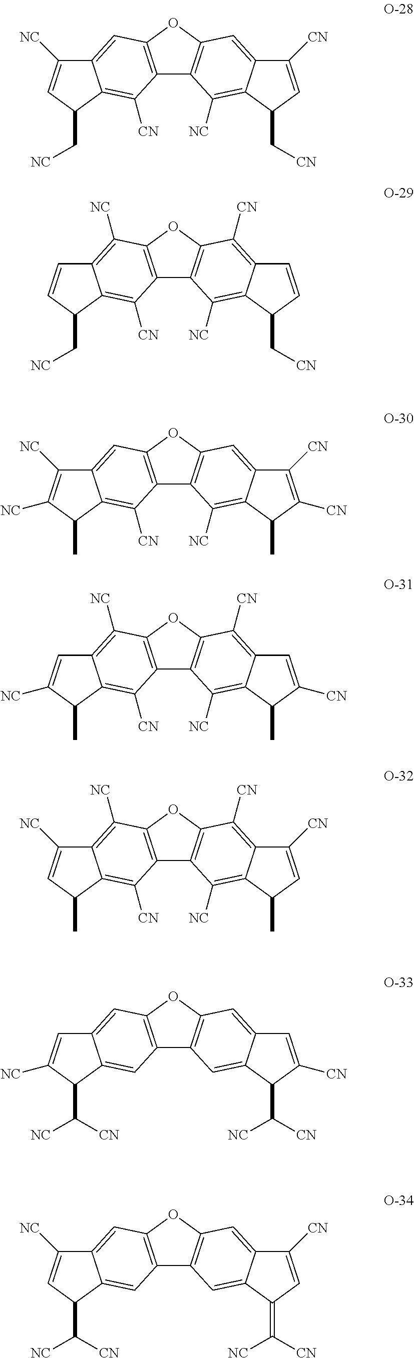

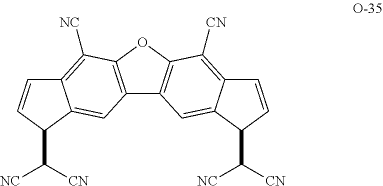 [SMILES: N#Cc1c2c(cc3c1oc1c(C#N)c4c(cc13)[C@@H](C(C#N)C#N)C=C4)[C@H](C(C#N)C#N)C=C2]

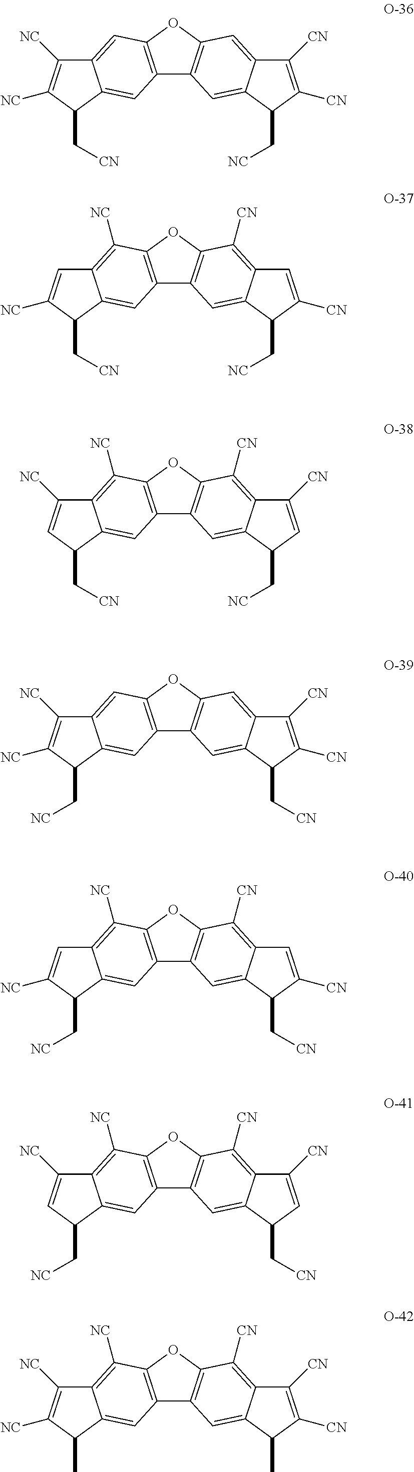

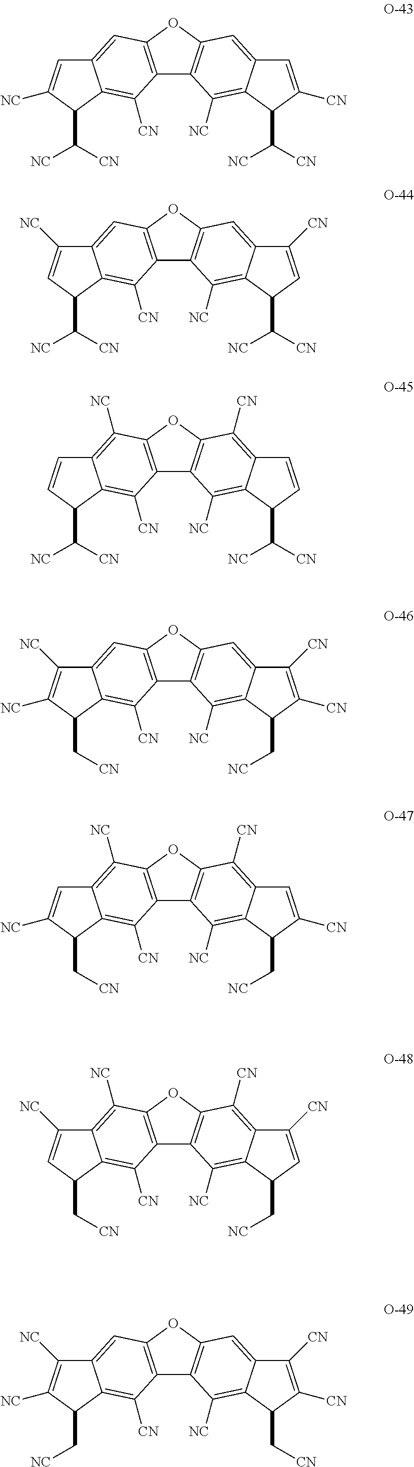

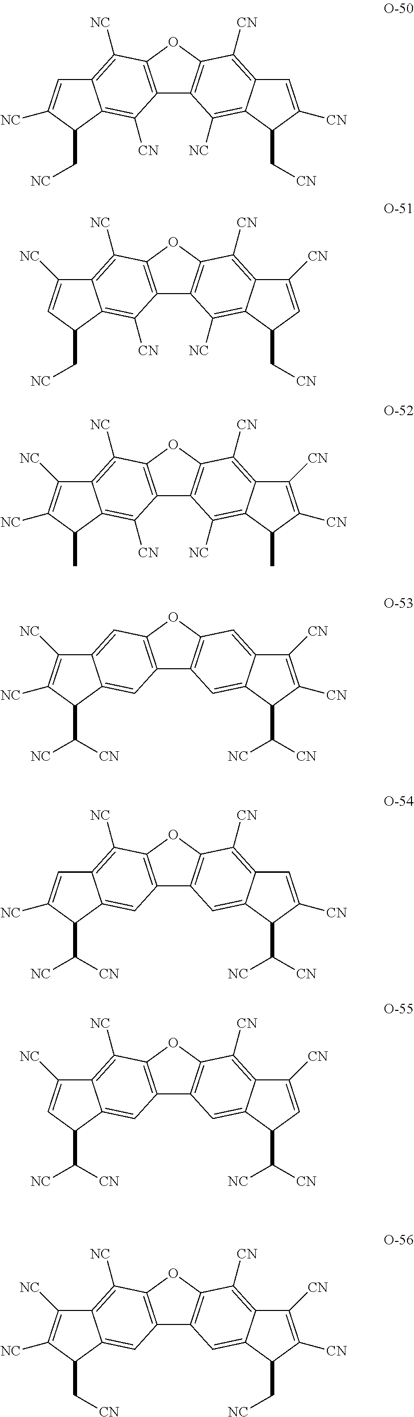

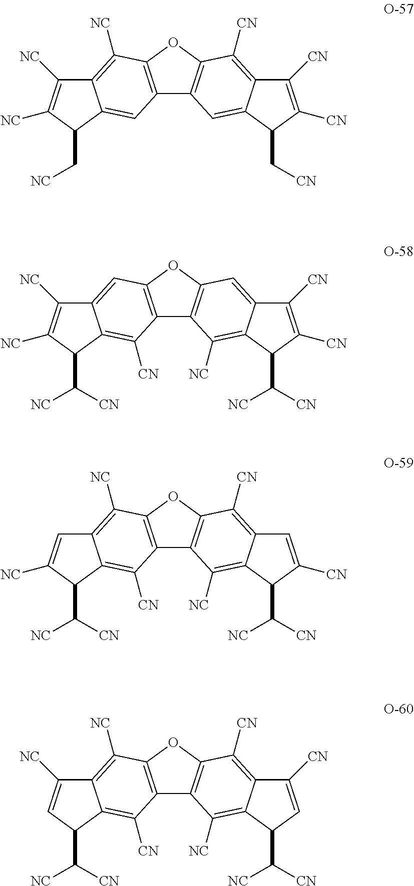 [SMILES: N#CC[C@@H]1C(C#N)=C(C#N)c2c1cc1c(oc3c(C#N)c4c(cc31)[C@@H](CC#N)C(C#N)=C4C#N)c2C#N ; N#CC1=C(C#N)[C@@H](C(C#N)C#N)c2c1cc1oc3cc4c(c(C#N)c3c1c2C#N)[C@@H](C(C#N)C#N)C(C#N)=C4C#N ; N#CC1=Cc2c(c(C#N)c3c(oc4c(C#N)c5c(c(C#N)c43)[C@@H](C(C#N)C#N)C(C#N)=C5)c2C#N)[C@@H]1C(C#N)C#N ; N#CC1=C[C@@H](C(C#N)C#N)c2c1c(C#N)c1oc3c(C#N)c4c(c(C#N)c3c1c2C#N)[C@@H](C(C#N)C#N)C=C4C#N]

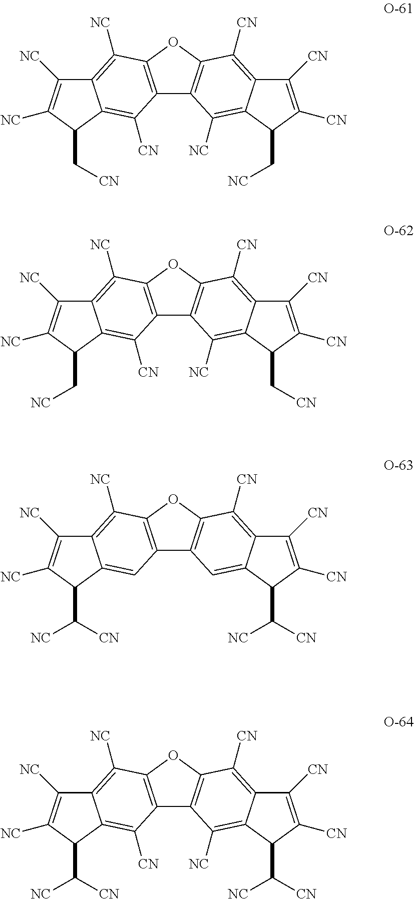 [SMILES: N#CC[C@@H]1C(C#N)=C(C#N)c2c1c(C#N)c1c(oc3c(C#N)c4c(c(C#N)c31)[C@@H](CC#N)C(C#N)=C4C#N)c2C#N ; N#CC[C@@H]1C(C#N)=C(C#N)c2c1c(C#N)c1c(oc3c(C#N)c4c(c(C#N)c31)[C@@H](CC#N)C(C#N)=C4C#N)c2C#N ; N#CC1=C(C#N)[C@@H](C(C#N)C#N)c2cc3c(oc4c(C#N)c5c(cc43)[C@@H](C(C#N)C#N)C(C#N)=C5C#N)c(C#N)c21 ; N#CC1=C(C#N)[C@@H](C(C#N)C#N)c2c1c(C#N)c1oc3c(C#N)c4c(c(C#N)c3c1c2C#N)[C@@H](C(C#N)C#N)C(C#N)=C4C#N]

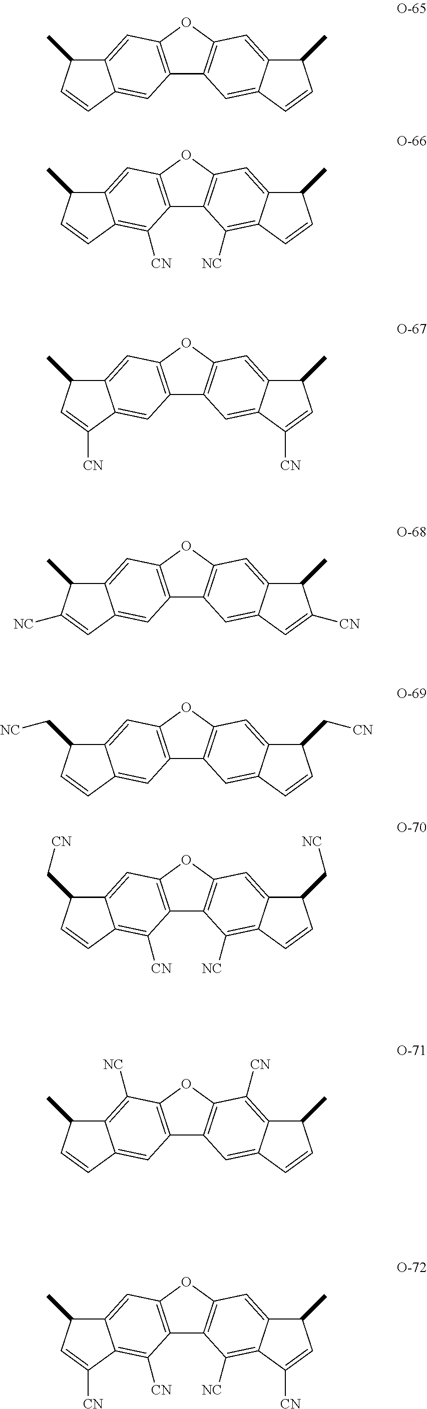

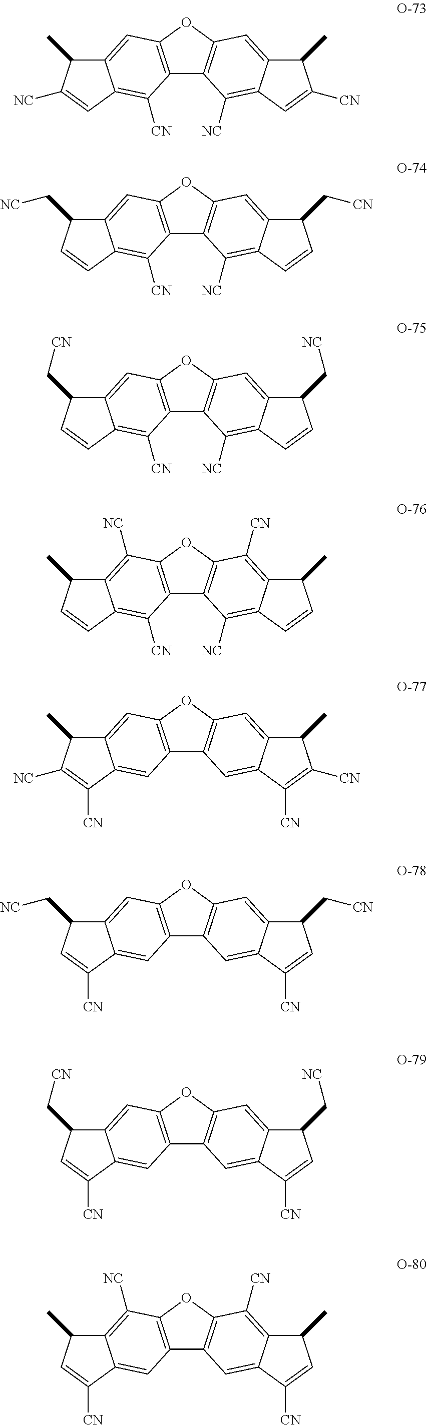

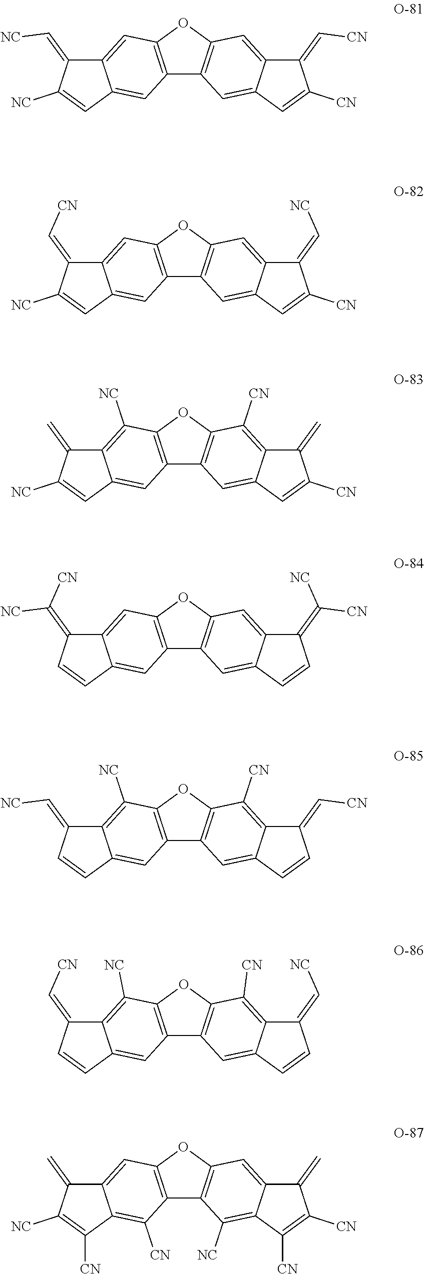

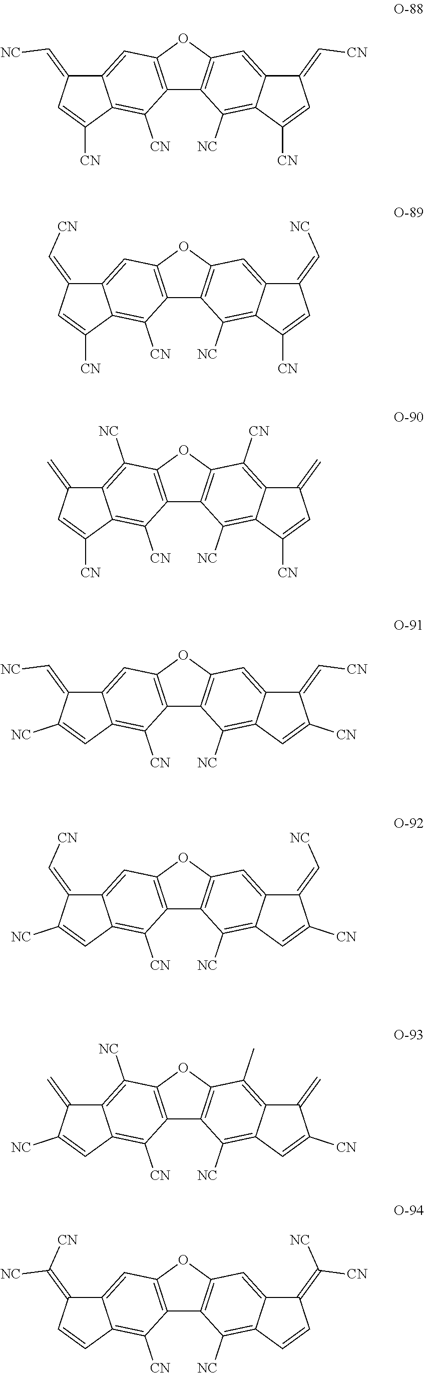

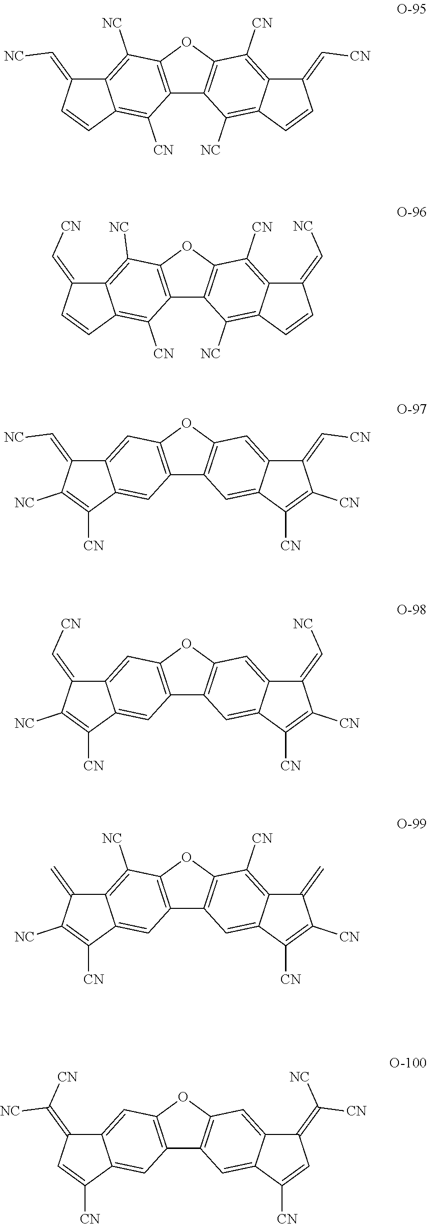 [SMILES: N#C/C=C1\C=Cc2c1c(C#N)c1oc3c(C#N)c4c(c(C#N)c3c1c2C#N)C=C/C4=C\C#N ; N#C/C=C1/C=Cc2c1c(C#N)c1oc3c(C#N)c4c(c(C#N)c3c1c2C#N)C=C/C4=C/C#N ; N#C/C=C1\C(C#N)=C(C#N)c2cc3c(cc21)oc1cc2c(cc13)C(C#N)=C(C#N)/C2=C\C#N ; N#C/C=C1/C(C#N)=C(C#N)c2cc3c(cc21)oc1cc2c(cc13)C(C#N)=C(C#N)/C2=C/C#N ; C=C1C(C#N)=C(C#N)c2cc3c(oc4c(C#N)c5c(cc43)C(C#N)=C(C#N)C5=C)c(C#N)c21 ; N#CC1=CC(=C(C#N)C#N)c2cc3oc4cc5c(cc4c3cc21)C(C#N)=CC5=C(C#N)C#N]

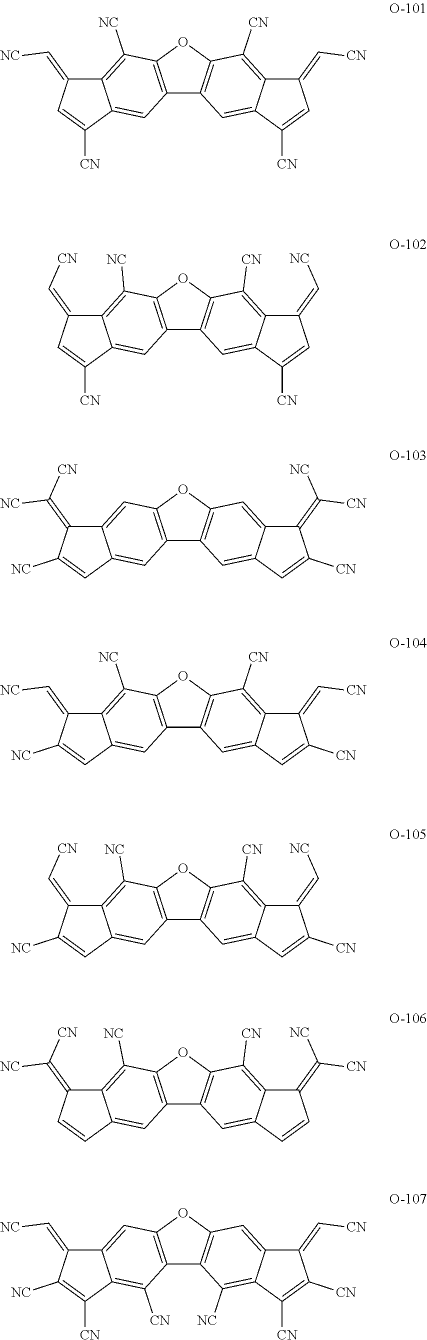

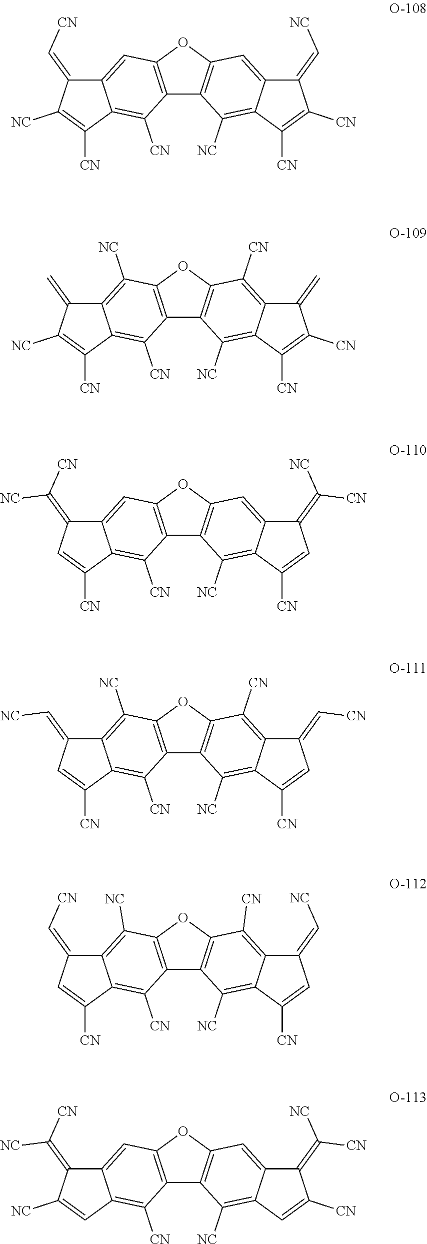 [SMILES: N#C/C=C1/C(C#N)=C(C#N)c2c1cc1oc3cc4c(c(C#N)c3c1c2C#N)C(C#N)=C(C#N)/C4=C/C#N ; C=C1C(C#N)=C(C#N)c2c1c(C#N)c1oc3c(C#N)c4c(c(C#N)c3c1c2C#N)C(C#N)=C(C#N)C4=C ; N#CC1=CC(=C(C#N)C#N)c2cc3oc4cc5c(c(C#N)c4c3c(C#N)c21)C(C#N)=CC5=C(C#N)C#N ; N#C/C=C1\C=C(C#N)c2c1c(C#N)c1oc3c(C#N)c4c(c(C#N)c3c1c2C#N)C(C#N)=C/C4=C\C#N ; N#C/C=C1/C=C(C#N)c2c1c(C#N)c1oc3c(C#N)c4c(c(C#N)c3c1c2C#N)C(C#N)=C/C4=C/C#N ; N#CC1=Cc2c(cc3oc4cc5c(c(C#N)c4c3c2C#N)C=C(C#N)C5=C(C#N)C#N)C1=C(C#N)C#N]

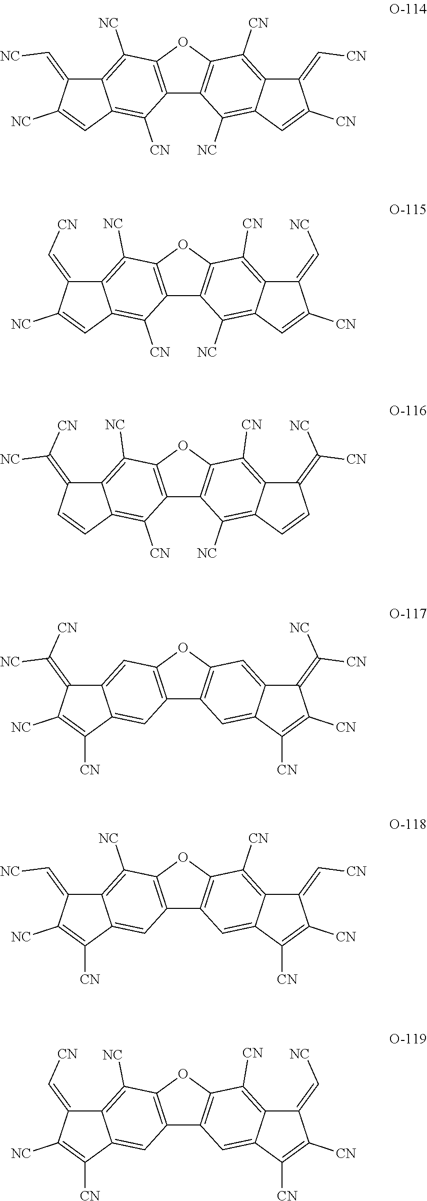 [SMILES: N#C/C=C1\C(C#N)=Cc2c1c(C#N)c1oc3c(C#N)c4c(c(C#N)c3c1c2C#N)C=C(C#N)/C4=C\C#N ; N#C/C=C1/C(C#N)=Cc2c1c(C#N)c1oc3c(C#N)c4c(c(C#N)c3c1c2C#N)C=C(C#N)/C4=C/C#N ; N#CC(C#N)=C1C=Cc2c1c(C#N)c1oc3c(C#N)c4c(c(C#N)c3c1c2C#N)C=CC4=C(C#N)C#N ; N#CC(C#N)=C1C(C#N)=C(C#N)c2cc3c(cc21)oc1cc2c(cc13)C(C#N)=C(C#N)C2=C(C#N)C#N ; N#C/C=C1\C(C#N)=C(C#N)c2cc3c(oc4c(C#N)c5c(cc43)C(C#N)=C(C#N)/C5=C\C#N)c(C#N)c21 ; N#C/C=C1/C(C#N)=C(C#N)c2cc3c(oc4c(C#N)c5c(cc43)C(C#N)=C(C#N)/C5=C/C#N)c(C#N)c21]

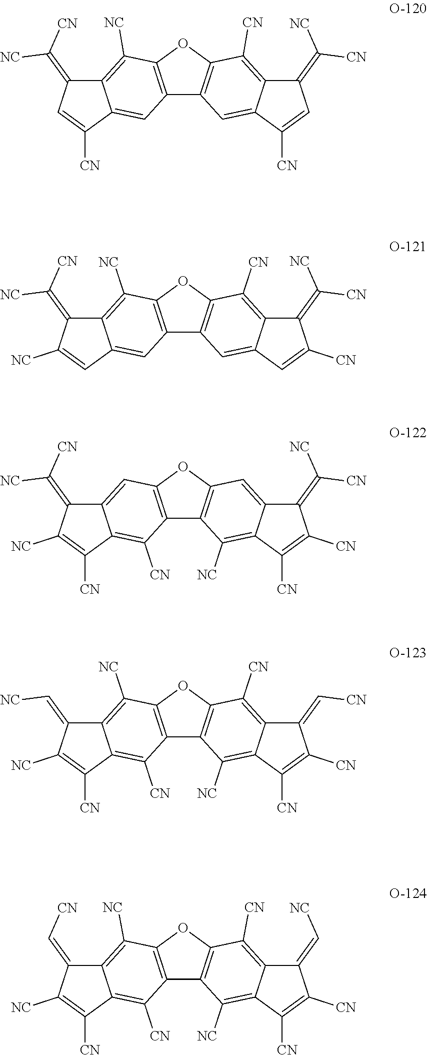 [SMILES: N#CC1=CC(=C(C#N)C#N)c2c1cc1c(oc3c(C#N)c4c(cc31)C(C#N)=CC4=C(C#N)C#N)c2C#N ; N#CC1=Cc2cc3c(oc4c(C#N)c5c(cc43)C=C(C#N)C5=C(C#N)C#N)c(C#N)c2C1=C(C#N)C#N ; N#CC(C#N)=C1C(C#N)=C(C#N)c2c1cc1oc3cc4c(c(C#N)c3c1c2C#N)C(C#N)=C(C#N)C4=C(C#N)C#N ; N#C/C=C1\C(C#N)=C(C#N)c2c1c(C#N)c1oc3c(C#N)c4c(c(C#N)c3c1c2C#N)C(C#N)=C(C#N)/C4=C\C#N ; N#C/C=C1/C(C#N)=C(C#N)c2c1c(C#N)c1oc3c(C#N)c4c(c(C#N)c3c1c2C#N)C(C#N)=C(C#N)/C4=C/C#N]

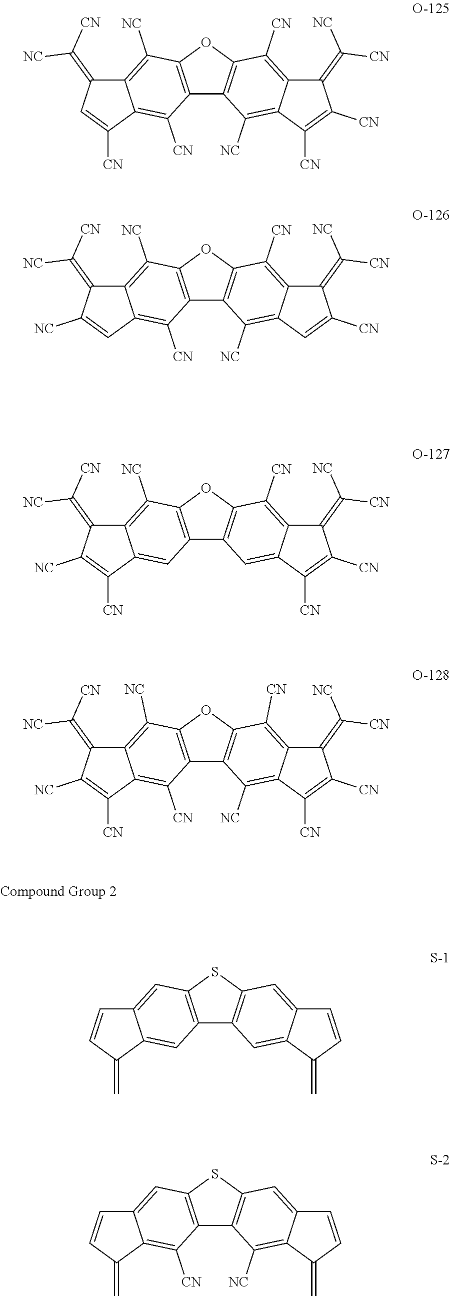 [SMILES: N#CC1=CC(=C(C#N)C#N)c2c1c(C#N)c1c(oc3c(C#N)c4c(c(C#N)c31)C(C#N)=C(C#N)C4=C(C#N)C#N)c2C#N ; N#CC1=Cc2c(c(C#N)c3oc4c(C#N)c5c(c(C#N)c4c3c2C#N)C=C(C#N)C5=C(C#N)C#N)C1=C(C#N)C#N ; N#CC(C#N)=C1C(C#N)=C(C#N)c2cc3c(oc4c(C#N)c5c(cc43)C(C#N)=C(C#N)C5=C(C#N)C#N)c(C#N)c21 ; N#CC(C#N)=C1C(C#N)=C(C#N)c2c1c(C#N)c1oc3c(C#N)c4c(c(C#N)c3c1c2C#N)C(C#N)=C(C#N)C4=C(C#N)C#N ; C=C1C=Cc2cc3sc4cc5c(cc4c3cc21)C(=C)C=C5 ; C=C1C=Cc2cc3sc4cc5c(c(C#N)c4c3c(C#N)c21)C(=C)C=C5]

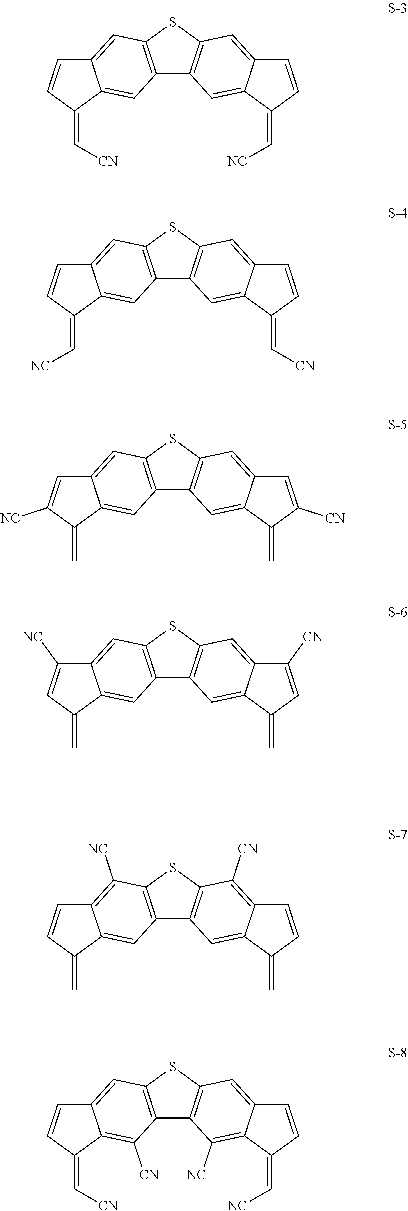 [SMILES: N#C/C=C1/C=Cc2cc3sc4cc5c(cc4c3cc21)/C(=C\C#N)C=C5 ; N#C/C=C1\C=Cc2cc3sc4cc5c(cc4c3cc21)/C(=C/C#N)C=C5 ; C=C1C(C#N)=Cc2cc3sc4cc5c(cc4c3cc21)C(=C)C(C#N)=C5 ; C=C1C=C(C#N)c2cc3sc4cc5c(cc4c3cc21)C(=C)C=C5C#N ; C=C1C=Cc2c1cc1c(sc3c(C#N)c4c(cc31)C(=C)C=C4)c2C#N ; N#C/C=C1/C=Cc2cc3sc4cc5c(c(C#N)c4c3c(C#N)c21)/C(=C\C#N)C=C5]

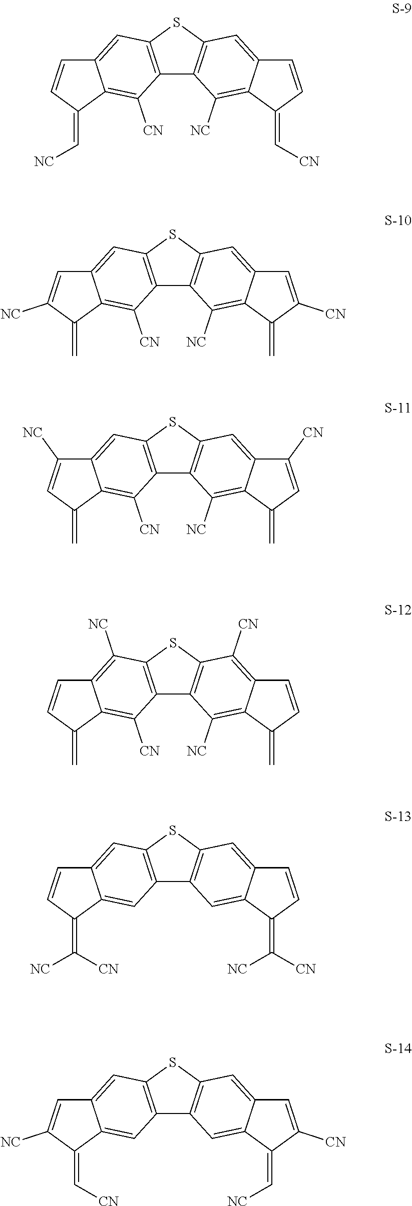 [SMILES: N#C/C=C1\C=Cc2cc3sc4cc5c(c(C#N)c4c3c(C#N)c21)/C(=C/C#N)C=C5 ; C=C1C(C#N)=Cc2cc3sc4cc5c(c(C#N)c4c3c(C#N)c21)C(=C)C(C#N)=C5 ; C=C1C=C(C#N)c2cc3sc4cc5c(c(C#N)c4c3c(C#N)c21)C(=C)C=C5C#N ; C=C1C=Cc2c1c(C#N)c1c(sc3c(C#N)c4c(c(C#N)c31)C(=C)C=C4)c2C#N ; N#CC(C#N)=C1C=Cc2cc3sc4cc5c(cc4c3cc21)C(=C(C#N)C#N)C=C5 ; N#C/C=C1/C(C#N)=Cc2cc3sc4cc5c(cc4c3cc21)/C(=C\C#N)C(C#N)=C5]

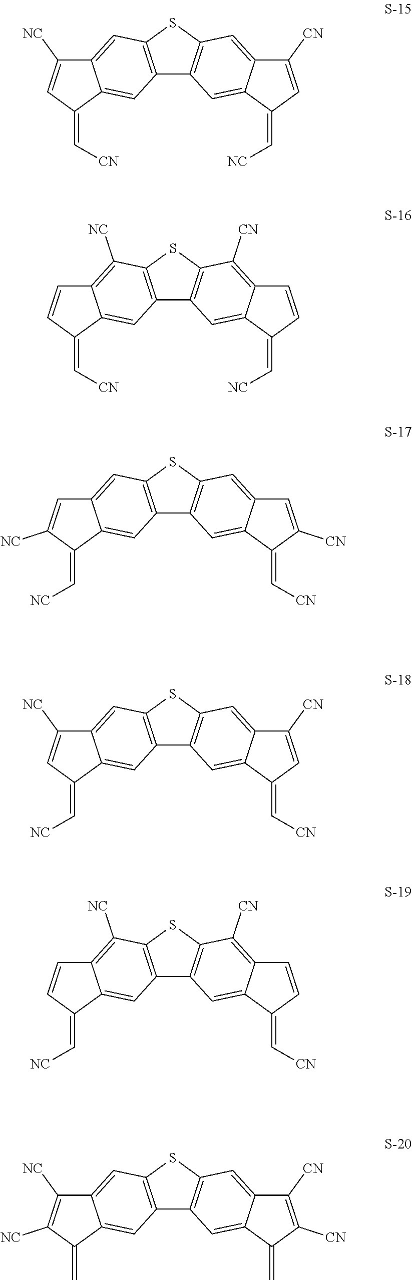 [SMILES: N#C/C=C1/C=C(C#N)c2cc3sc4cc5c(cc4c3cc21)/C(=C\C#N)C=C5C#N ; N#C/C=C1/C=Cc2c1cc1c(sc3c(C#N)c4c(cc31)/C(=C\C#N)C=C4)c2C#N ; N#C/C=C1\C(C#N)=Cc2cc3sc4cc5c(cc4c3cc21)/C(=C/C#N)C(C#N)=C5 ; N#C/C=C1\C=C(C#N)c2cc3sc4cc5c(cc4c3cc21)/C(=C/C#N)C=C5C#N ; N#C/C=C1\C=Cc2c1cc1c(sc3c(C#N)c4c(cc31)/C(=C/C#N)C=C4)c2C#N ; C=C1C(C#N)=C(C#N)c2cc3sc4cc5c(cc4c3cc21)C(=C)C(C#N)=C5C#N]

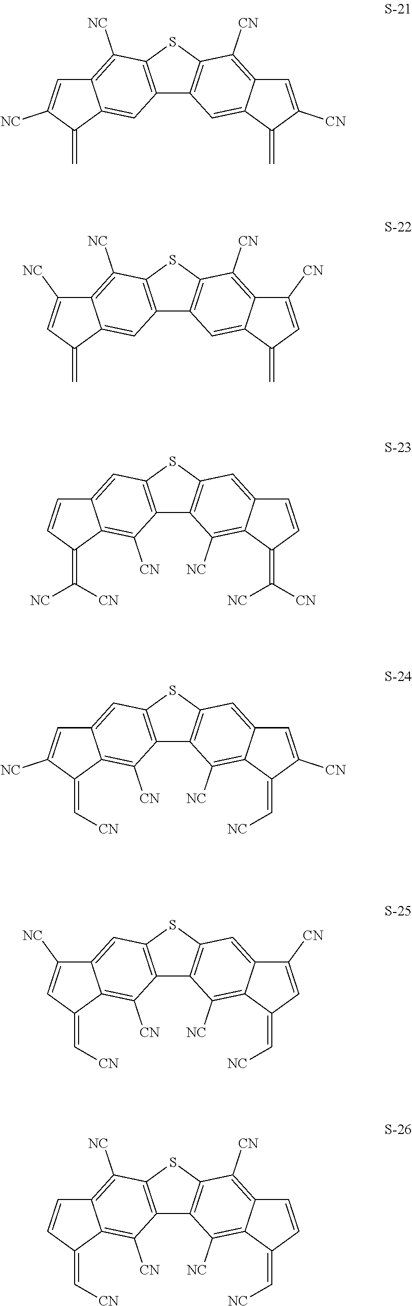 [SMILES: C=C1C(C#N)=Cc2c1cc1c(sc3c(C#N)c4c(cc31)C(=C)C(C#N)=C4)c2C#N ; C=C1C=C(C#N)c2c1cc1c(sc3c(C#N)c4c(cc31)C(=C)C=C4C#N)c2C#N ; N#CC(C#N)=C1C=Cc2cc3sc4cc5c(c(C#N)c4c3c(C#N)c21)C(=C(C#N)C#N)C=C5 ; N#C/C=C1/C(C#N)=Cc2cc3sc4cc5c(c(C#N)c4c3c(C#N)c21)/C(=C\C#N)C(C#N)=C5 ; N#C/C=C1/C=C(C#N)c2cc3sc4cc5c(c(C#N)c4c3c(C#N)c21)/C(=C\C#N)C=C5C#N ; N#C/C=C1/C=Cc2c1c(C#N)c1c(sc3c(C#N)c4c(c(C#N)c31)/C(=C\C#N)C=C4)c2C#N]

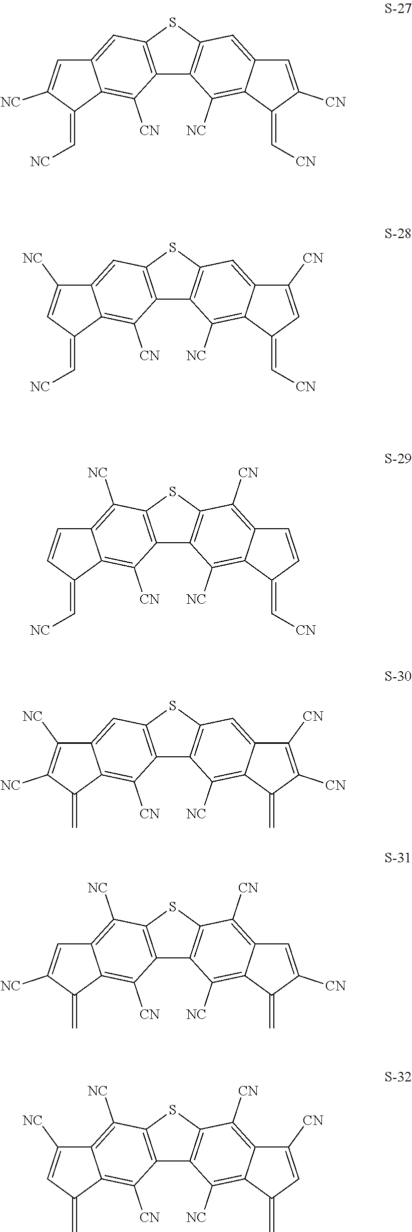 [SMILES: N#C/C=C1\C(C#N)=Cc2cc3sc4cc5c(c(C#N)c4c3c(C#N)c21)/C(=C/C#N)C(C#N)=C5 ; N#C/C=C1\C=C(C#N)c2cc3sc4cc5c(c(C#N)c4c3c(C#N)c21)/C(=C/C#N)C=C5C#N ; N#C/C=C1\C=Cc2c1c(C#N)c1c(sc3c(C#N)c4c(c(C#N)c31)/C(=C/C#N)C=C4)c2C#N ; C=C1C(C#N)=C(C#N)c2cc3sc4cc5c(c(C#N)c4c3c(C#N)c21)C(=C)C(C#N)=C5C#N ; C=C1C(C#N)=Cc2c1c(C#N)c1c(sc3c(C#N)c4c(c(C#N)c31)C(=C)C(C#N)=C4)c2C#N ; C=C1C=C(C#N)c2c1c(C#N)c1c(sc3c(C#N)c4c(c(C#N)c31)C(=C)C=C4C#N)c2C#N]

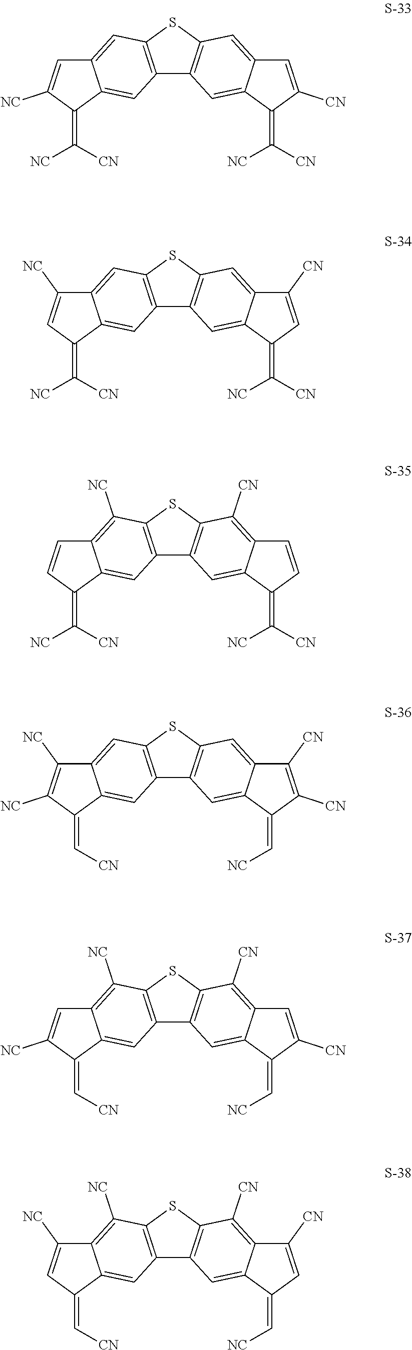 [SMILES: N#CC1=Cc2cc3sc4cc5c(cc4c3cc2C1=C(C#N)C#N)C(=C(C#N)C#N)C(C#N)=C5 ; N#CC1=CC(=C(C#N)C#N)c2cc3c(cc21)sc1cc2c(cc13)C(=C(C#N)C#N)C=C2C#N ; N#CC(C#N)=C1C=Cc2c1cc1c(sc3c(C#N)c4c(cc31)C(=C(C#N)C#N)C=C4)c2C#N ; N#C/C=C1/C(C#N)=C(C#N)c2cc3sc4cc5c(cc4c3cc21)/C(=C\C#N)C(C#N)=C5C#N ; N#C/C=C1/C(C#N)=Cc2c1cc1c(sc3c(C#N)c4c(cc31)/C(=C\C#N)C(C#N)=C4)c2C#N ; N#C/C=C1/C=C(C#N)c2c1cc1c(sc3c(C#N)c4c(cc31)/C(=C\C#N)C=C4C#N)c2C#N]

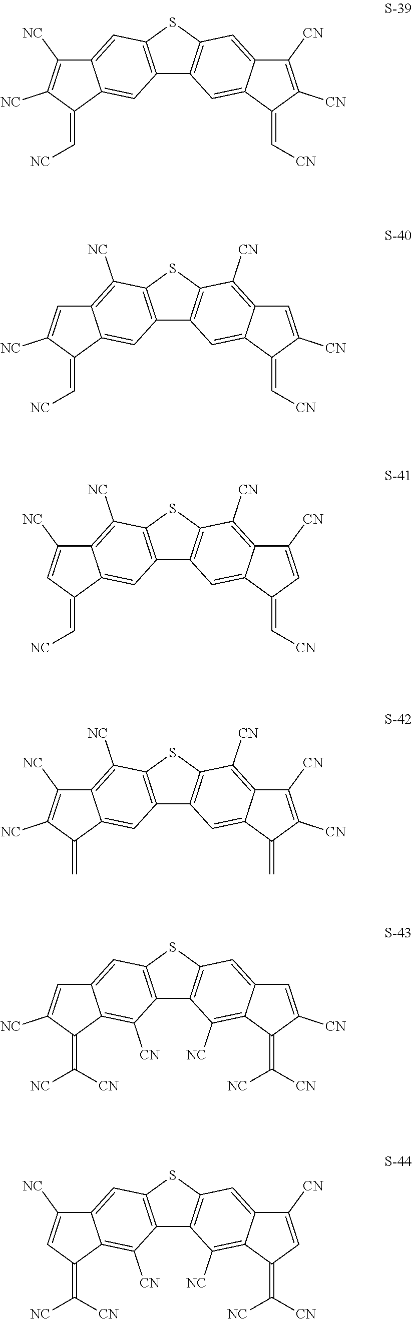 [SMILES: N#C/C=C1\C(C#N)=C(C#N)c2cc3sc4cc5c(cc4c3cc21)/C(=C/C#N)C(C#N)=C5C#N ; N#C/C=C1\C(C#N)=Cc2c1cc1c(sc3c(C#N)c4c(cc31)/C(=C/C#N)C(C#N)=C4)c2C#N ; N#C/C=C1\C=C(C#N)c2c1cc1c(sc3c(C#N)c4c(cc31)/C(=C/C#N)C=C4C#N)c2C#N ; C=C1C(C#N)=C(C#N)c2c1cc1c(sc3c(C#N)c4c(cc31)C(=C)C(C#N)=C4C#N)c2C#N ; N#CC1=Cc2cc3sc4cc5c(c(C#N)c4c3c(C#N)c2C1=C(C#N)C#N)C(=C(C#N)C#N)C(C#N)=C5 ; N#CC1=CC(=C(C#N)C#N)c2c1cc1sc3cc4c(c(C#N)c3c1c2C#N)C(=C(C#N)C#N)C=C4C#N]

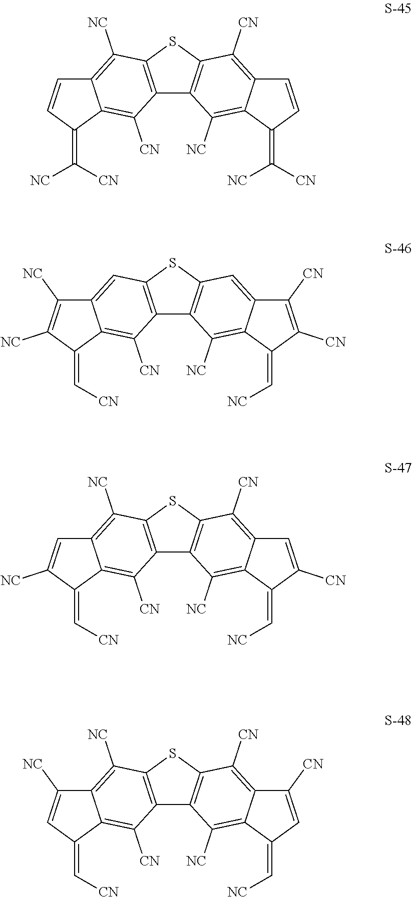 [SMILES: N#CC(C#N)=C1C=Cc2c1c(C#N)c1c(sc3c(C#N)c4c(c(C#N)c31)C(=C(C#N)C#N)C=C4)c2C#N ; N#C/C=C1/C(C#N)=C(C#N)c2cc3sc4cc5c(c(C#N)c4c3c(C#N)c21)/C(=C\C#N)C(C#N)=C5C#N ; N#C/C=C1/C(C#N)=Cc2c1c(C#N)c1c(sc3c(C#N)c4c(c(C#N)c31)/C(=C\C#N)C(C#N)=C4)c2C#N ; N#C/C=C1/C=C(C#N)c2c1c(C#N)c1c(sc3c(C#N)c4c(c(C#N)c31)/C(=C\C#N)C=C4C#N)c2C#N]

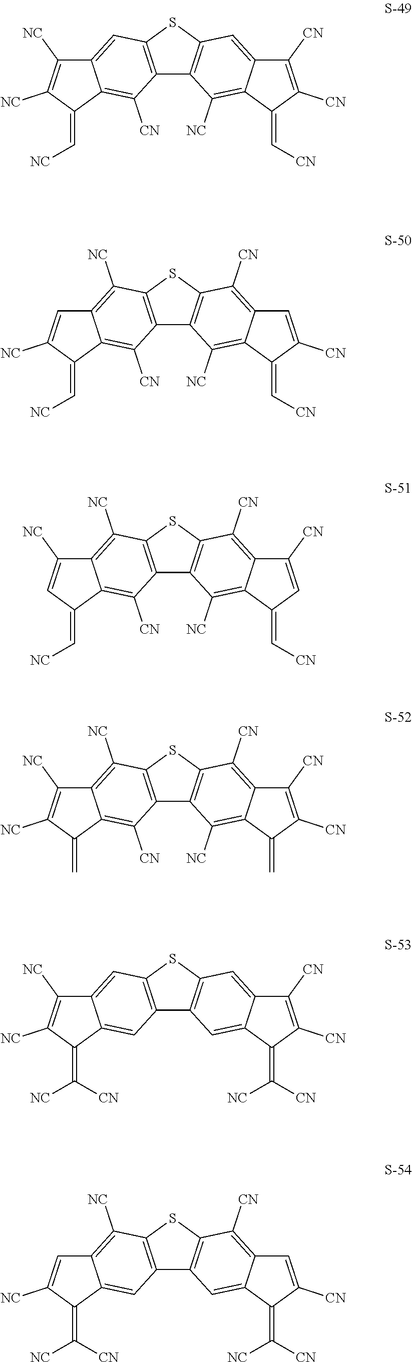 [SMILES: N#C/C=C1\C(C#N)=C(C#N)c2cc3sc4cc5c(c(C#N)c4c3c(C#N)c21)/C(=C/C#N)C(C#N)=C5C#N ; N#C/C=C1\C(C#N)=Cc2c1c(C#N)c1c(sc3c(C#N)c4c(c(C#N)c31)/C(=C/C#N)C(C#N)=C4)c2C#N ; N#C/C=C1\C=C(C#N)c2c1c(C#N)c1c(sc3c(C#N)c4c(c(C#N)c31)/C(=C/C#N)C=C4C#N)c2C#N ; C=C1C(C#N)=C(C#N)c2c1c(C#N)c1c(sc3c(C#N)c4c(c(C#N)c31)C(=C)C(C#N)=C4C#N)c2C#N ; N#CC(C#N)=C1C(C#N)=C(C#N)c2cc3sc4cc5c(cc4c3cc21)C(=C(C#N)C#N)C(C#N)=C5C#N ; N#CC1=Cc2c(cc3c(sc4c(C#N)c5c(cc43)C(=C(C#N)C#N)C(C#N)=C5)c2C#N)C1=C(C#N)C#N]

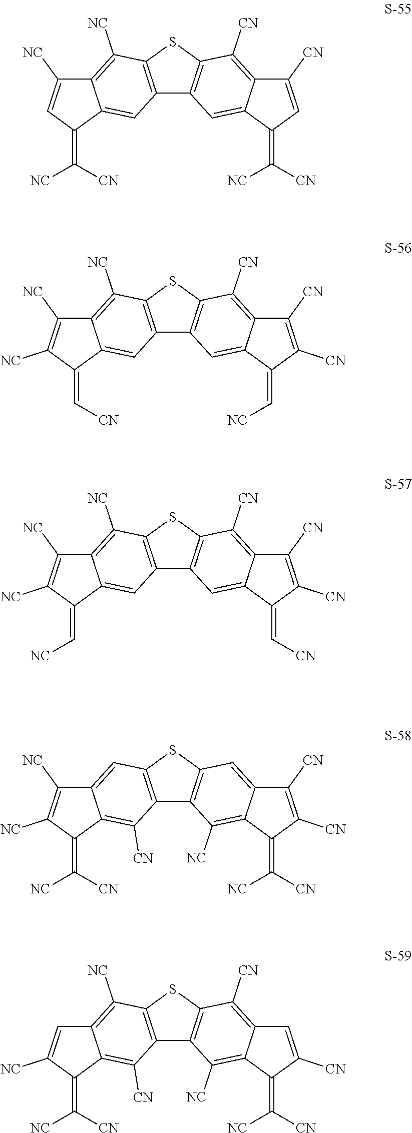 [SMILES: N#CC1=CC(=C(C#N)C#N)c2cc3c(sc4c(C#N)c5c(cc43)C(=C(C#N)C#N)C=C5C#N)c(C#N)c21 ; N#C/C=C1/C(C#N)=C(C#N)c2c1cc1c(sc3c(C#N)c4c(cc31)/C(=C\C#N)C(C#N)=C4C#N)c2C#N ; N#C/C=C1\C(C#N)=C(C#N)c2c1cc1c(sc3c(C#N)c4c(cc31)/C(=C/C#N)C(C#N)=C4C#N)c2C#N ; N#CC(C#N)=C1C(C#N)=C(C#N)c2cc3sc4cc5c(c(C#N)c4c3c(C#N)c21)C(=C(C#N)C#N)C(C#N)=C5C#N ; N#CC1=Cc2c(c(C#N)c3c(sc4c(C#N)c5c(c(C#N)c43)C(=C(C#N)C#N)C(C#N)=C5)c2C#N)C1=C(C#N)C#N]

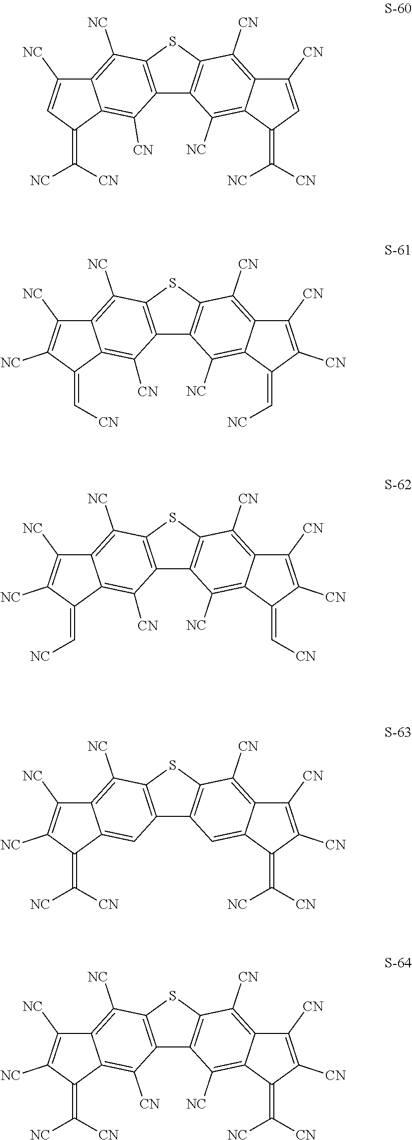 [SMILES: N#CC1=CC(=C(C#N)C#N)c2c1c(C#N)c1sc3c(C#N)c4c(c(C#N)c3c1c2C#N)C(=C(C#N)C#N)C=C4C#N ; N#C/C=C1/C(C#N)=C(C#N)c2c1c(C#N)c1c(sc3c(C#N)c4c(c(C#N)c31)/C(=C\C#N)C(C#N)=C4C#N)c2C#N ; N#C/C=C1\C(C#N)=C(C#N)c2c1c(C#N)c1c(sc3c(C#N)c4c(c(C#N)c31)/C(=C/C#N)C(C#N)=C4C#N)c2C#N ; N#CC(C#N)=C1C(C#N)=C(C#N)c2c1cc1c(sc3c(C#N)c4c(cc31)C(=C(C#N)C#N)C(C#N)=C4C#N)c2C#N ; N#CC(C#N)=C1C(C#N)=C(C#N)c2c1c(C#N)c1c(sc3c(C#N)c4c(c(C#N)c31)C(=C(C#N)C#N)C(C#N)=C4C#N)c2C#N]

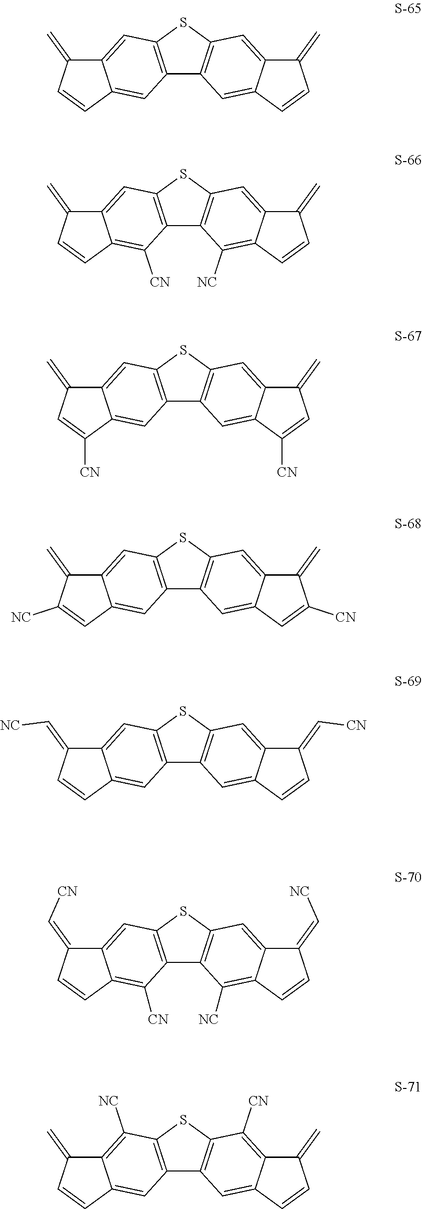

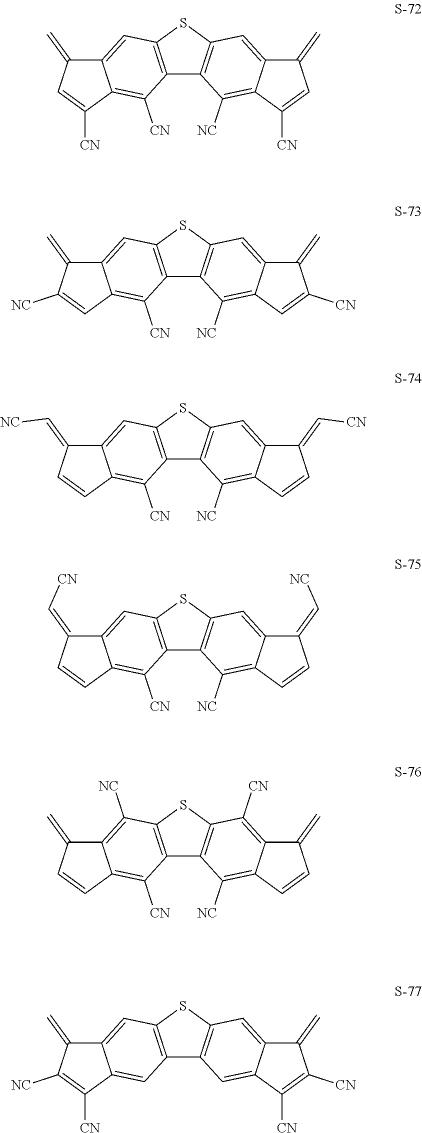

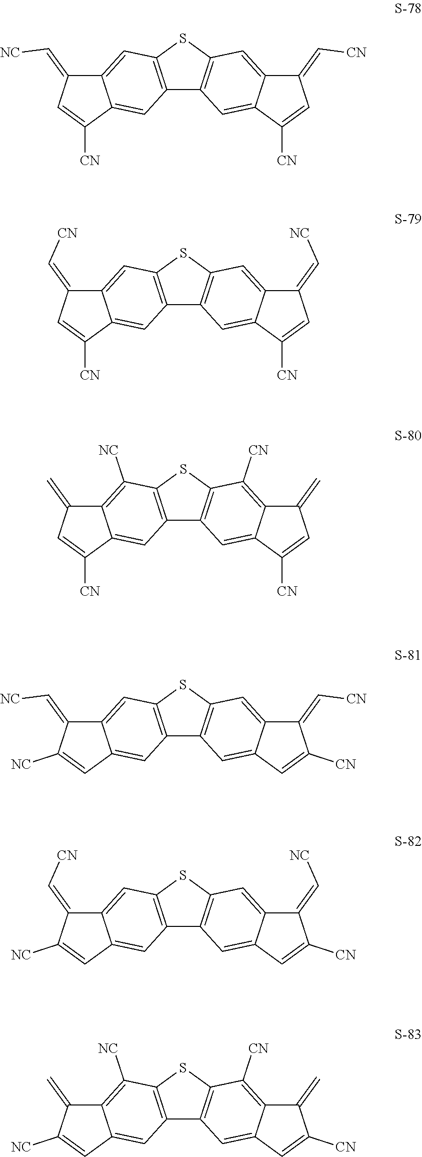

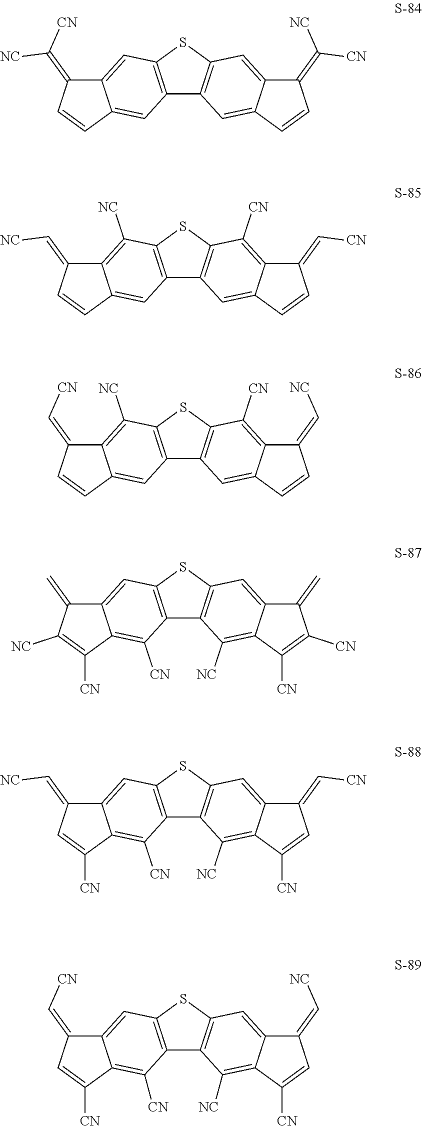 [SMILES: N#CC(C#N)=C1C=Cc2cc3c(cc21)sc1cc2c(cc13)C=CC2=C(C#N)C#N ; N#C/C=C1\C=Cc2cc3c(sc4c(C#N)c5c(cc43)C=C/C5=C\C#N)c(C#N)c21 ; N#C/C=C1/C=Cc2cc3c(sc4c(C#N)c5c(cc43)C=C/C5=C/C#N)c(C#N)c21 ; C=C1C(C#N)=C(C#N)c2c1cc1sc3cc4c(c(C#N)c3c1c2C#N)C(C#N)=C(C#N)C4=C ; N#C/C=C1\C=C(C#N)c2c1cc1sc3cc4c(c(C#N)c3c1c2C#N)C(C#N)=C/C4=C\C#N ; N#C/C=C1/C=C(C#N)c2c1cc1sc3cc4c(c(C#N)c3c1c2C#N)C(C#N)=C/C4=C/C#N]

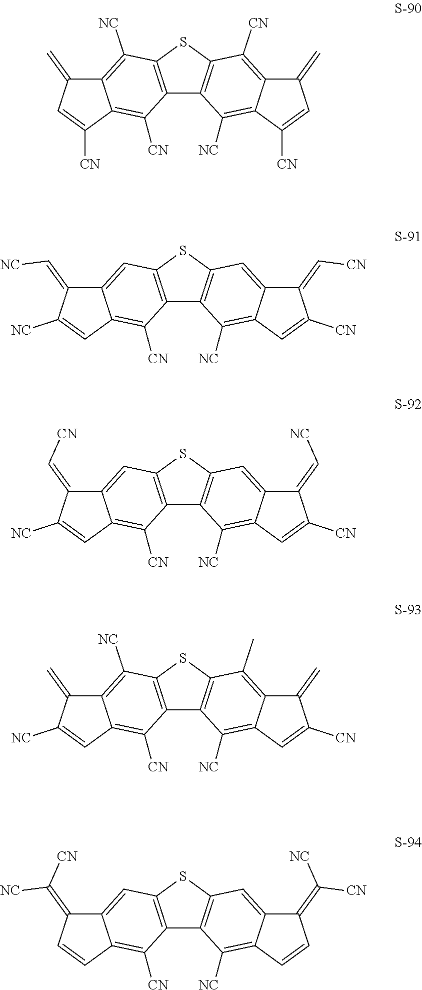

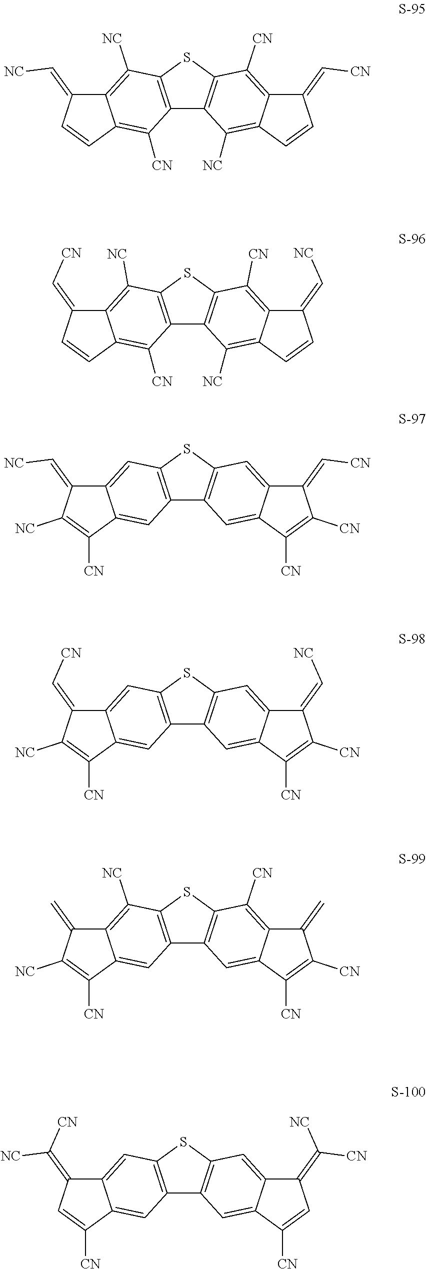 [SMILES: N#C/C=C1\C=Cc2c1c(C#N)c1sc3c(C#N)c4c(c(C#N)c3c1c2C#N)C=C/C4=C\C#N ; N#C/C=C1/C=Cc2c1c(C#N)c1sc3c(C#N)c4c(c(C#N)c3c1c2C#N)C=C/C4=C/C#N ; N#C/C=C1\C(C#N)=C(C#N)c2cc3c(cc21)sc1cc2c(cc13)C(C#N)=C(C#N)/C2=C\C#N ; N#C/C=C1/C(C#N)=C(C#N)c2cc3c(cc21)sc1cc2c(cc13)C(C#N)=C(C#N)/C2=C/C#N ; C=C1C(C#N)=C(C#N)c2cc3c(sc4c(C#N)c5c(cc43)C(C#N)=C(C#N)C5=C)c(C#N)c21 ; N#CC1=CC(=C(C#N)C#N)c2cc3sc4cc5c(cc4c3cc21)C(C#N)=CC5=C(C#N)C#N]

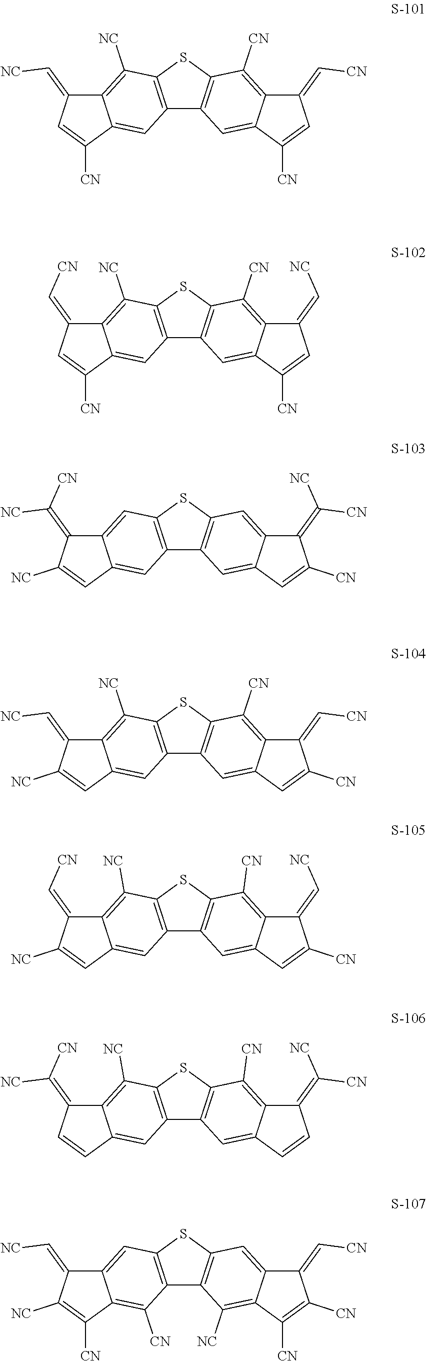

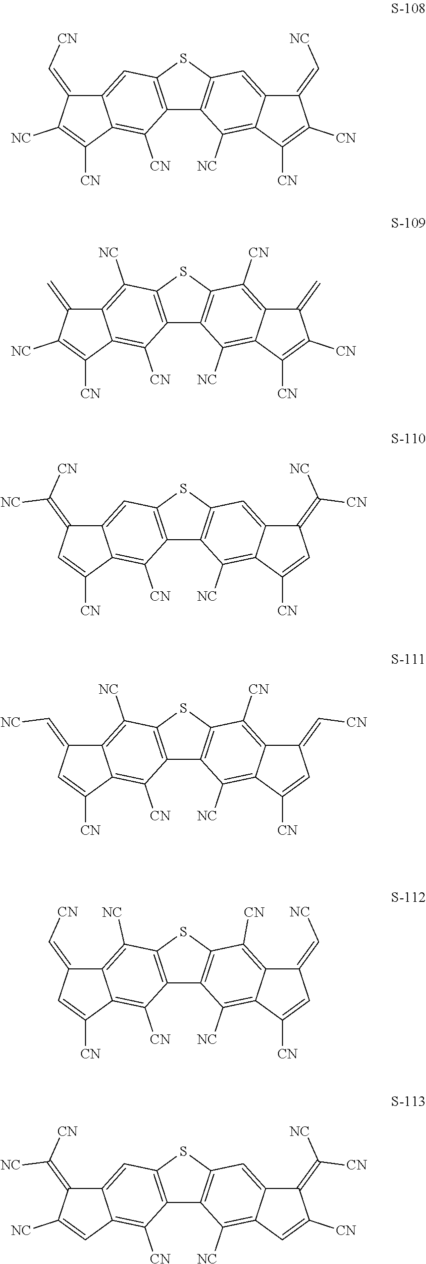 [SMILES: N#C/C=C1/C(C#N)=C(C#N)c2c1cc1sc3cc4c(c(C#N)c3c1c2C#N)C(C#N)=C(C#N)/C4=C/C#N ; C=C1C(C#N)=C(C#N)c2c1c(C#N)c1sc3c(C#N)c4c(c(C#N)c3c1c2C#N)C(C#N)=C(C#N)C4=C ; N#CC1=CC(=C(C#N)C#N)c2cc3sc4cc5c(c(C#N)c4c3c(C#N)c21)C(C#N)=CC5=C(C#N)C#N ; N#C/C=C1\C=C(C#N)c2c1c(C#N)c1sc3c(C#N)c4c(c(C#N)c3c1c2C#N)C(C#N)=C/C4=C\C#N ; N#C/C=C1/C=C(C#N)c2c1c(C#N)c1sc3c(C#N)c4c(c(C#N)c3c1c2C#N)C(C#N)=C/C4=C/C#N ; N#CC1=Cc2c(cc3sc4cc5c(c(C#N)c4c3c2C#N)C=C(C#N)C5=C(C#N)C#N)C1=C(C#N)C#N]

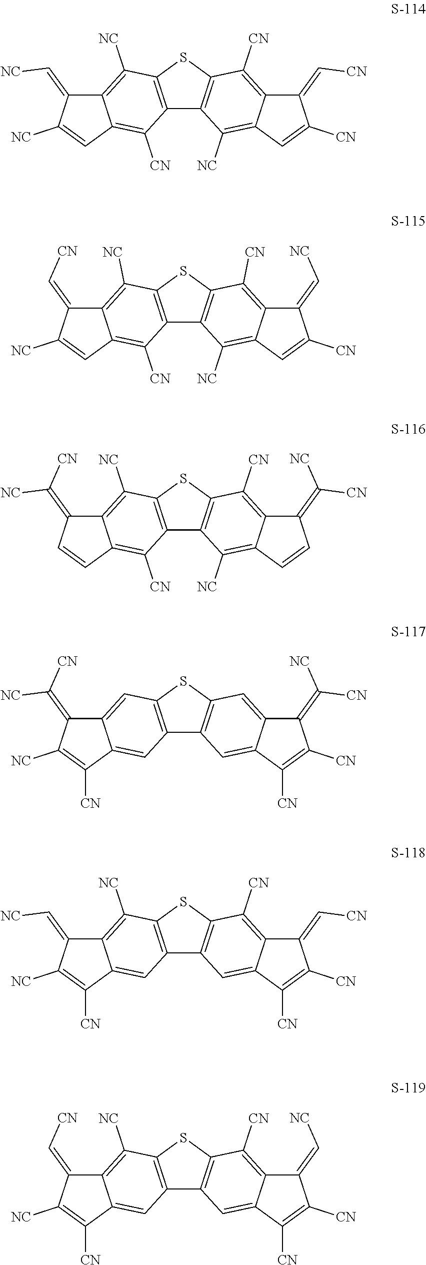 [SMILES: N#C/C=C1\C(C#N)=Cc2c1c(C#N)c1sc3c(C#N)c4c(c(C#N)c3c1c2C#N)C=C(C#N)/C4=C\C#N ; N#C/C=C1/C(C#N)=Cc2c1c(C#N)c1sc3c(C#N)c4c(c(C#N)c3c1c2C#N)C=C(C#N)/C4=C/C#N ; N#CC(C#N)=C1C=Cc2c1c(C#N)c1sc3c(C#N)c4c(c(C#N)c3c1c2C#N)C=CC4=C(C#N)C#N ; N#CC(C#N)=C1C(C#N)=C(C#N)c2cc3c(cc21)sc1cc2c(cc13)C(C#N)=C(C#N)C2=C(C#N)C#N ; N#C/C=C1\C(C#N)=C(C#N)c2cc3c(sc4c(C#N)c5c(cc43)C(C#N)=C(C#N)/C5=C\C#N)c(C#N)c21 ; N#C/C=C1/C(C#N)=C(C#N)c2cc3c(sc4c(C#N)c5c(cc43)C(C#N)=C(C#N)/C5=C/C#N)c(C#N)c21]

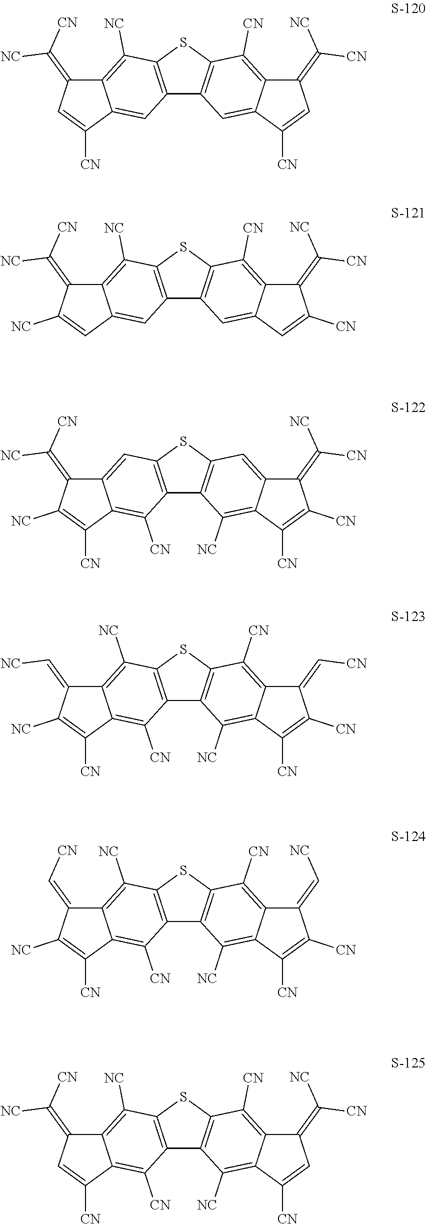 [SMILES: N#CC1=CC(=C(C#N)C#N)c2c1cc1c(sc3c(C#N)c4c(cc31)C(C#N)=CC4=C(C#N)C#N)c2C#N ; N#CC1=Cc2cc3c(sc4c(C#N)c5c(cc43)C=C(C#N)C5=C(C#N)C#N)c(C#N)c2C1=C(C#N)C#N ; N#CC(C#N)=C1C(C#N)=C(C#N)c2c1cc1sc3cc4c(c(C#N)c3c1c2C#N)C(C#N)=C(C#N)C4=C(C#N)C#N ; N#C/C=C1\C(C#N)=C(C#N)c2c1c(C#N)c1sc3c(C#N)c4c(c(C#N)c3c1c2C#N)C(C#N)=C(C#N)/C4=C\C#N ; N#C/C=C1/C(C#N)=C(C#N)c2c1c(C#N)c1sc3c(C#N)c4c(c(C#N)c3c1c2C#N)C(C#N)=C(C#N)/C4=C/C#N ; N#CC1=CC(=C(C#N)C#N)c2c1c(C#N)c1c(sc3c(C#N)c4c(c(C#N)c31)C(C#N)=CC4=C(C#N)C#N)c2C#N]

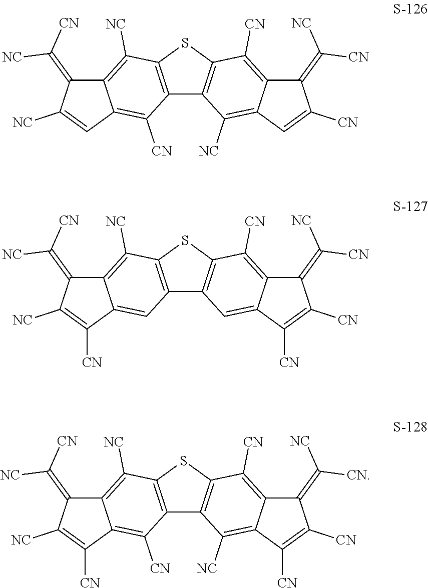 [SMILES: N#CC1=Cc2c(c(C#N)c3sc4c(C#N)c5c(c(C#N)c4c3c2C#N)C=C(C#N)C5=C(C#N)C#N)C1=C(C#N)C#N ; N#CC(C#N)=C1C(C#N)=C(C#N)c2cc3c(sc4c(C#N)c5c(cc43)C(C#N)=C(C#N)C5=C(C#N)C#N)c(C#N)c21 ; N#CC(C#N)=C1C(C#N)=C(C#N)c2c1c(C#N)c1sc3c(C#N)c4c(c(C#N)c3c1c2C#N)C(C#N)=C(C#N)C4=C(C#N)C#N]

6. The light-emitting diode of claim 1,
wherein the light-emitting diode comprises the at least one functional layer and a charge generation layer,
wherein the at least one functional layer comprises:
a hole functional layer on the first electrode; and
a light-emitting layer on the hole functional layer, and
wherein at least one selected from among the hole functional layer, the light-emitting layer, and the charge generation layer comprises the compound.

7. The light-emitting diode of claim 6,
wherein the hole functional layer comprises a hole injection layer and a hole transport layer, and
wherein at least one of the hole injection layer or the hole transport layer comprises the compound.

8. The light-emitting diode of claim 7,
wherein a thickness of the hole injection layer is about 10 Å to about 500 Å.

9. The light-emitting diode of claim 7,
wherein the compound is a p-type dopant.

10. The light-emitting diode of claim 9,
wherein:
the p-type dopant is in an amount of about 0.5 parts to about 15 parts by weight based on 100 parts by an entire weight of compounds composing the hole functional layer; and/or
the p-type dopant is in an amount of about 0.5 parts to about 15 parts by weight based on 100 parts by an entire weight of compounds composing the charge generation layer.

11. The light-emitting diode of claim 9,
wherein a LUMO energy level of the p-type dopant is −4.8 eV or less.

12. The light-emitting diode of claim 9,
wherein an electron mobility of the p-type dopant is about 1.0×10⁻⁵ cm²/(Vs) to about 1.0×10⁻² cm²/(Vs).

13. The light-emitting diode of claim 9,
wherein a hole mobility of the p-type dopant is 1.0×10⁻⁶ cm²/(Vs) to 1.0×10⁻¹ cm²/(Vs).

14. An electronic device comprising a light-emitting diode comprising:
a first electrode;
a second electrode opposite to the first electrode; and
at least one functional layer between the first electrode and the second electrode,
wherein the at least one functional layer comprises a compound represented by Formula 1: 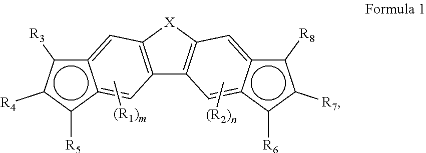
wherein, in Formula 1,
X is O, S, Ga, In, Ge, Sn, Pb, Sb, Bi, Se, or Te,
R₁ to R₈ are each independently:
hydrogen, deuterium, a halogen, a haloalkyl group, a hydroxyl group, a cyano group, a nitro group, a trifluoromethyl group, an amine group, an amidino group, a hydrazino group, a hydrazono group, or an alkoxy group; or
a phenyl group, an alkyl group having 1 to 10 carbons, an alkenyl group having 2 to 10 carbons, an alkynyl group having 2 to 10 carbons, an aryl group having 6 to 30 ring-forming carbons, a heteroaryl group having 2 to 30 ring-forming carbons, or any combination thereof, each substituted or unsubstituted with deuterium, a halogen, a hydroxyl group, a cyano group, a nitro group, a trifluoromethyl group, an amidino group, a hydrazino group, a hydrazono group, an alkoxy group, or any combination thereof, and
m and n are each independently an integer between 0 and 2, inclusive.

15. The electronic device of claim 14,
wherein the electronic device is at least one selected from among a plane panel display, a curved display, a television, a billboard, a computer monitor, a medical monitor, a head mounted display, an indoor light, an outdoor light, a signal light, a wearable device, a foldable device, a rollable device, a bendable device, a flexible device, a curved device, an electronic organizer, an electronic book, a portable multimedia player, a personal digital assistance, a laser printer, a telephone, a cellphone, a tablet PC, a portable terminal, a laptop computer, a digital camera, a viewfinder, a camcorder, a 3D display, a virtual reality display, an augmented reality display, a video wall comprising multiple displays tiled together, a vehicle display device, an outdoor display device, a theater screen, a stadium screen, and a signboard.

16. The electronic device of claim 14,
wherein the light-emitting diode further comprises at least one of a color filter layer, a color conversion layer, a touch sensor layer, or a polarization layer.

17. A compound represented by Formula 1: 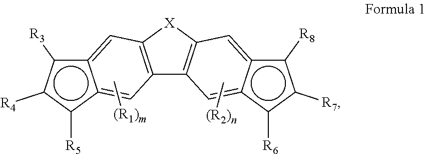
wherein, in Formula 1,
X is O, S, Ga, In, Ge, Sn, Pb, Sb, Bi, Se, or Te,
R₁ to R₈ are each independently:
hydrogen, deuterium, a halogen, a haloalkyl group, a hydroxyl group, a cyano group, a nitro group, a trifluoromethyl group, an amine group, an amidino group, a hydrazino group, a hydrazono group, or an alkoxy group; or
a phenyl group, an alkyl group having 1 to 10 carbons, an alkenyl group having 2 to 10 carbons, an alkynyl group having 2 to 10 carbons, an aryl group having 6 to 30 ring-forming carbons, a heteroaryl group having 2 to 30 ring-forming carbons, or any combination thereof, each substituted or unsubstituted with deuterium, a halogen, a hydroxyl group, a cyano group, a nitro group, a trifluoromethyl group, an amidino group, a hydrazino group, a hydrazono group, an alkoxy group, or any combination thereof, and
m and n are each independently an integer between 0 and 2, inclusive.

18. The compound of claim 17,
wherein the compound is represented by Formula 1-1 or Formula 1-2: 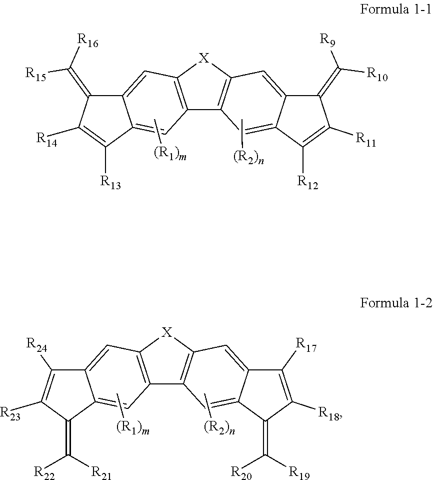
wherein, in Formula 1-1 and Formula 1-2,
X is selected from among O, S, Ga, In, Ge, Sn, Pb, Sb, Bi, Se, and Te,
R₁, R₂, and R₉ to R₂₄ are each independently:
hydrogen, deuterium, a halogen, a haloalkyl group, a hydroxyl group, a cyano group, a nitro group, a trifluoromethyl group, an amine group, an amidino group, a hydrazino group, a hydrazono group, or an alkoxy group; or
a phenyl group, an alkyl group having 1 to 10 carbons, an alkenyl group having 2 to 10 carbons, an alkynyl group having 2 to 10 carbons, an aryl group having 6 to 30 ring-forming carbons, a heteroaryl group having 2 to 30 ring-forming carbons, or any combination thereof, each substituted or unsubstituted with deuterium, a halogen, a haloalkyl group, a hydroxyl group, a cyano group, a nitro group, a trifluoromethyl group, an amine group, an amidino group, a hydrazino group, a hydrazono group, an alkoxy group, or any combination thereof, and
m and n are each independently an integer between 0 and 2, inclusive.

19. The compound of claim 18,
wherein R₁, R₂, R₁₉, R₂₀, R₂₁, and R₂₂ are each independently:
a haloalkyl group, a hydroxyl group, a cyano group, a nitro group, a trifluoromethyl group, an amine group, or an alkoxy group; or
an alkenyl group having 2 to 10 carbons substituted or unsubstituted with a haloalkyl group, a hydroxyl group, a cyano group, a nitro group, a trifluoromethyl group, an amine group, an alkoxy group, or any combination thereof.

20. The compound of claim 17,
wherein the compound represented by Formula 1 is any one selected from among compounds of Compound Group 1 or any one selected from among compounds of Compound Group 2: 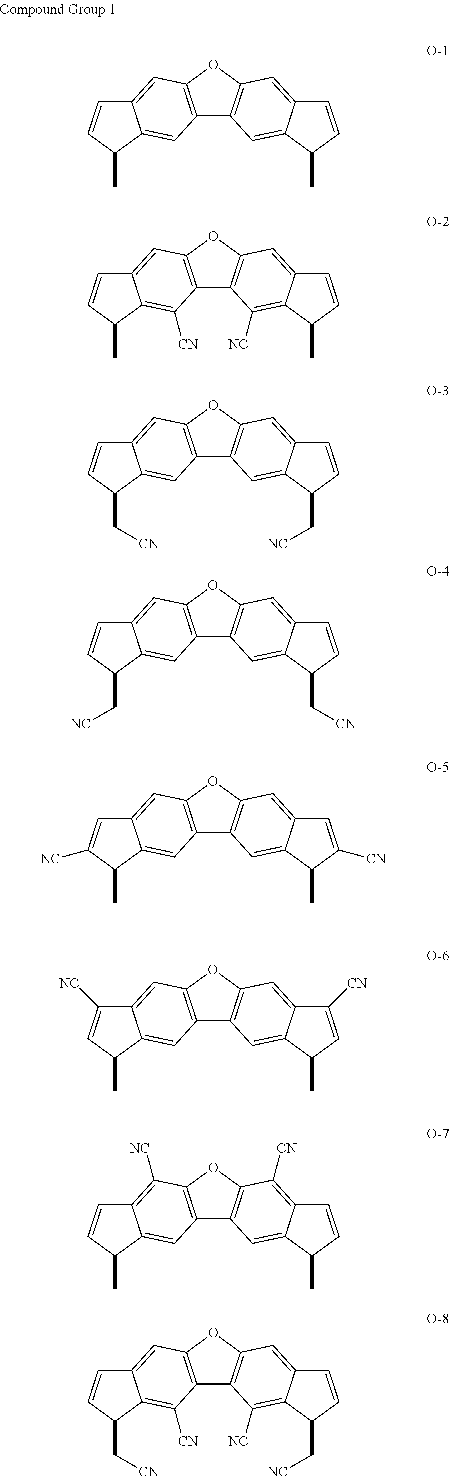 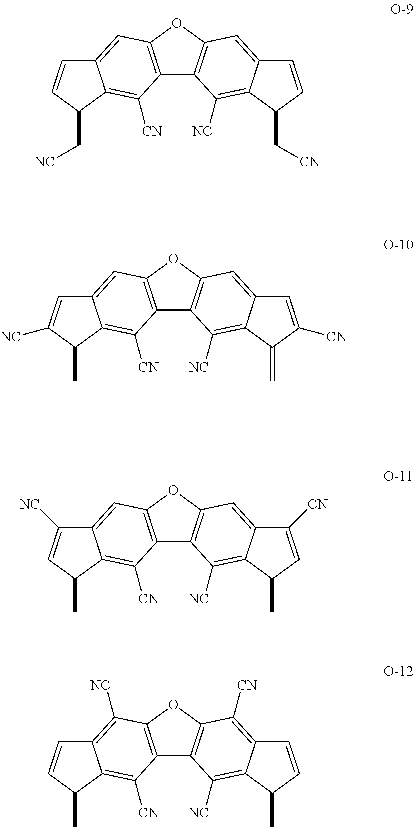 [SMILES: N#CC[C@H]1C=Cc2cc3oc4cc5c(c(C#N)c4c3c(C#N)c21)[C@H](CC#N)C=C5 ; C=C1C(C#N)=Cc2cc3oc4cc5c(c(C#N)c4c3c(C#N)c21)[C@@H](C)C(C#N)=C5 ; C[C@@H]1C=C(C#N)c2cc3oc4cc5c(c(C#N)c4c3c(C#N)c21)[C@@H](C)C=C5C#N ; C[C@@H]1C=Cc2c1c(C#N)c1c(oc3c(C#N)c4c(c(C#N)c31)[C@@H](C)C=C4)c2C#N] 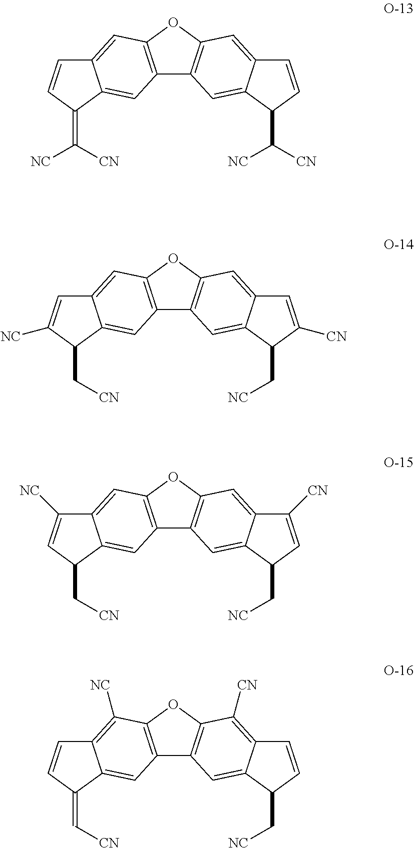 [SMILES: N#CC(C#N)=C1C=Cc2cc3oc4cc5c(cc4c3cc21)[C@H](C(C#N)C#N)C=C5 ; N#CC[C@@H]1C(C#N)=Cc2cc3oc4cc5c(cc4c3cc21)[C@@H](CC#N)C(C#N)=C5 ; N#CC[C@H]1C=C(C#N)c2cc3oc4cc5c(cc4c3cc21)[C@H](CC#N)C=C5C#N ; N#C/C=C1/C=Cc2c1cc1c(oc3c(C#N)c4c(cc31)[C@H](CC#N)C=C4)c2C#N] 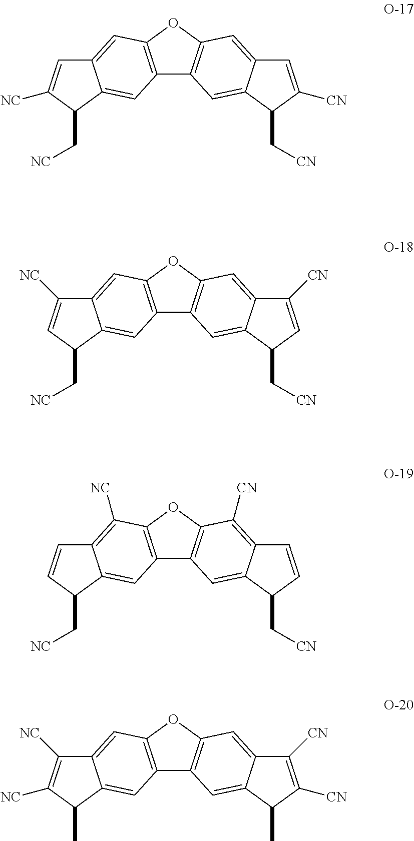 [SMILES: N#CC[C@@H]1C(C#N)=Cc2cc3oc4cc5c(cc4c3cc21)[C@@H](CC#N)C(C#N)=C5 ; N#CC[C@H]1C=C(C#N)c2cc3oc4cc5c(cc4c3cc21)[C@H](CC#N)C=C5C#N ; N#CC[C@H]1C=Cc2c1cc1c(oc3c(C#N)c4c(cc31)[C@H](CC#N)C=C4)c2C#N ; C[C@@H]1C(C#N)=C(C#N)c2cc3oc4cc5c(cc4c3cc21)[C@@H](C)C(C#N)=C5C#N] 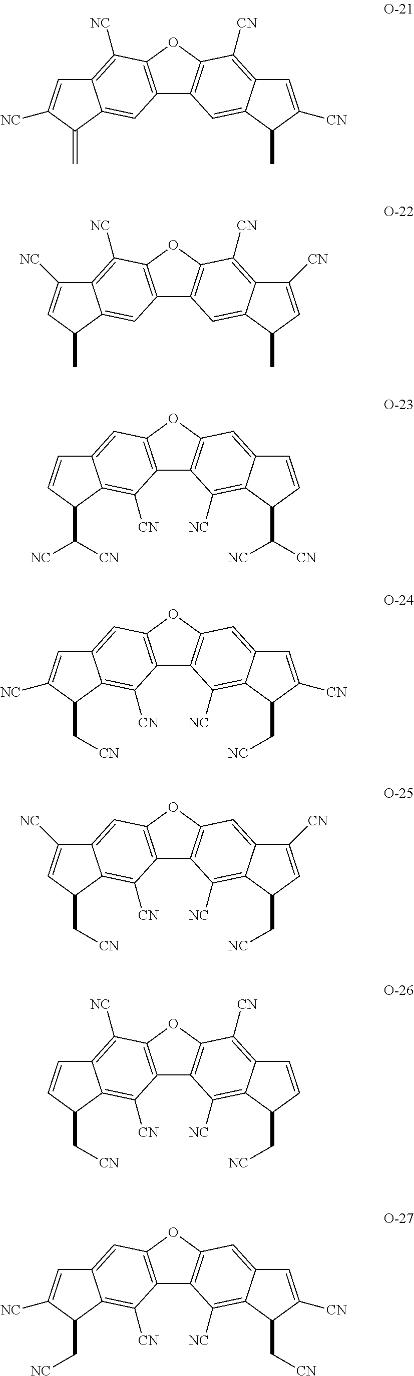 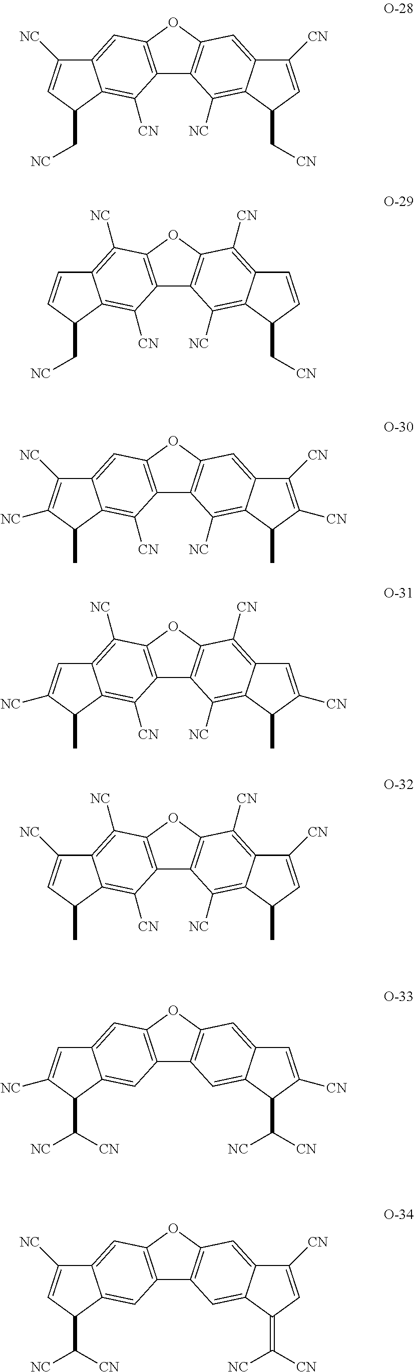 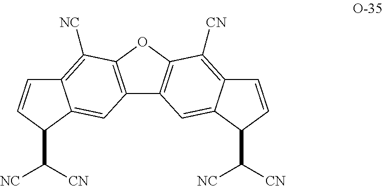 [SMILES: N#Cc1c2c(cc3c1oc1c(C#N)c4c(cc13)[C@@H](C(C#N)C#N)C=C4)[C@H](C(C#N)C#N)C=C2] 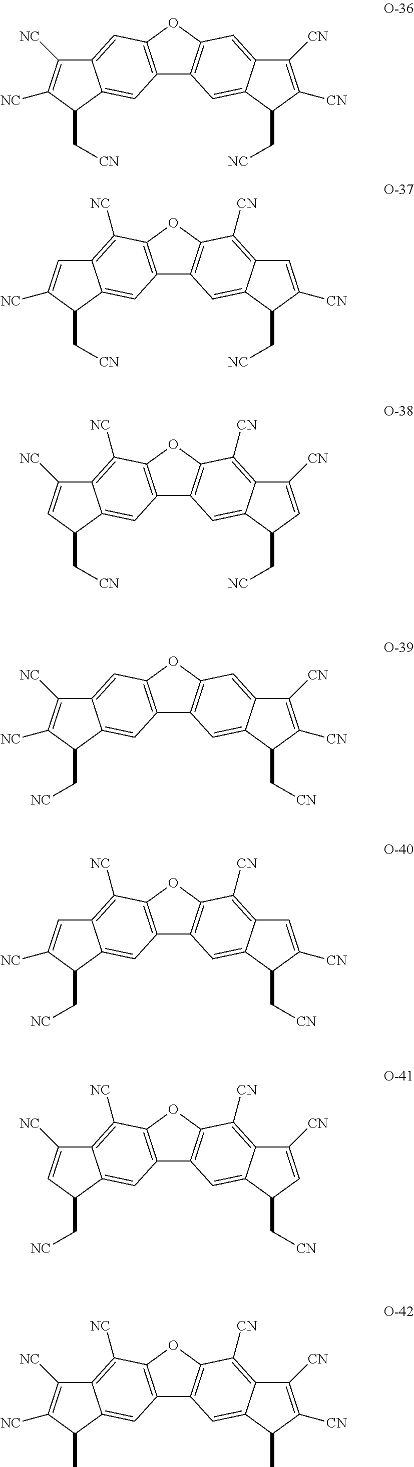 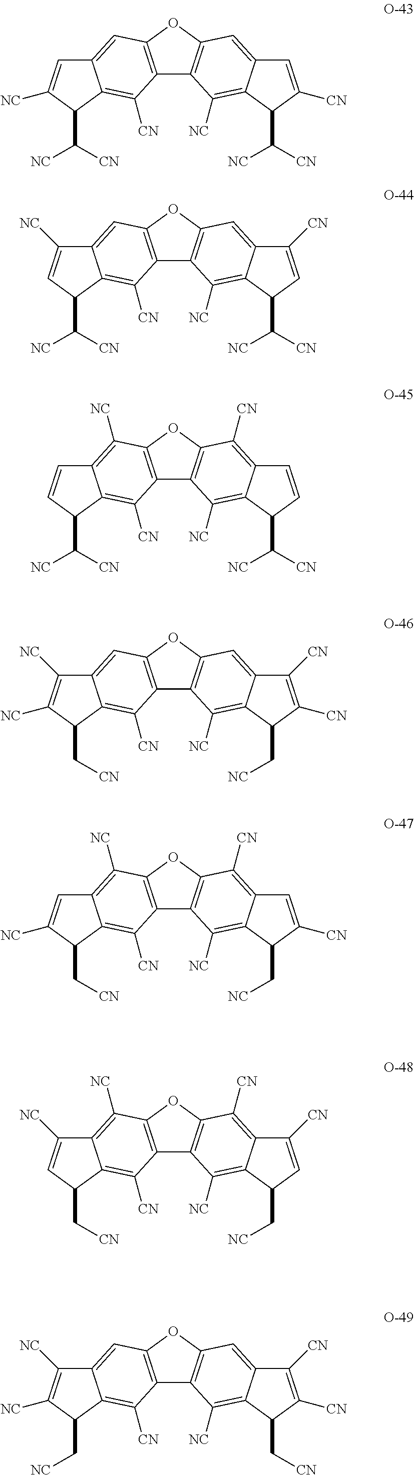 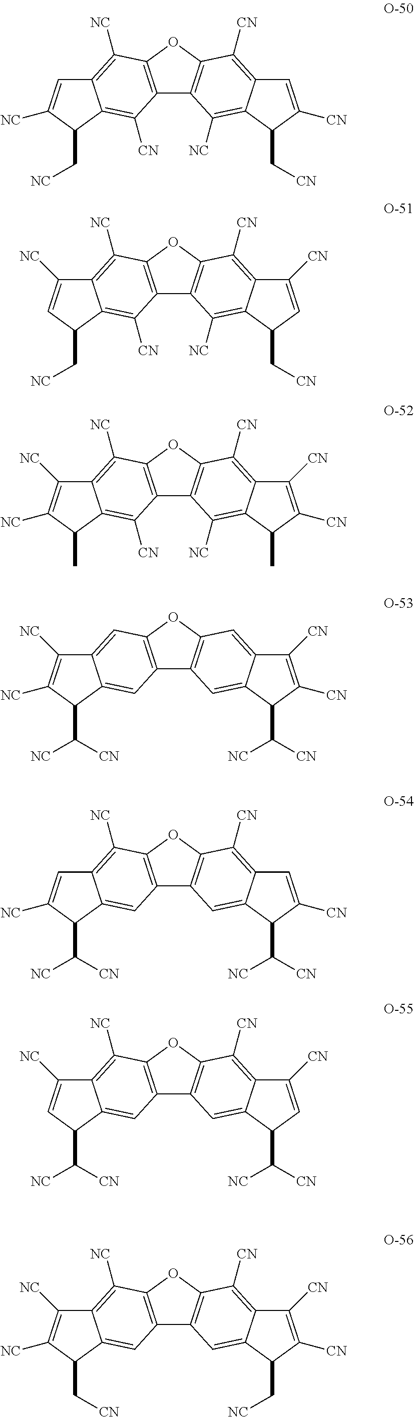 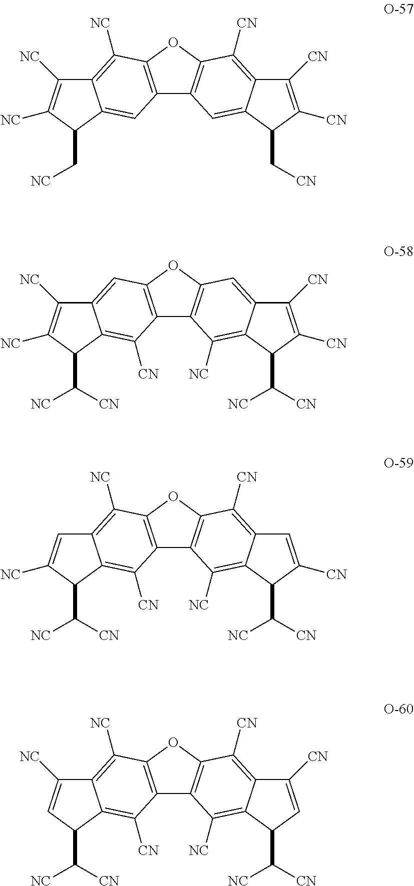 [SMILES: N#CC[C@@H]1C(C#N)=C(C#N)c2c1cc1c(oc3c(C#N)c4c(cc31)[C@@H](CC#N)C(C#N)=C4C#N)c2C#N ; N#CC1=C(C#N)[C@@H](C(C#N)C#N)c2c1cc1oc3cc4c(c(C#N)c3c1c2C#N)[C@@H](C(C#N)C#N)C(C#N)=C4C#N ; N#CC1=Cc2c(c(C#N)c3c(oc4c(C#N)c5c(c(C#N)c43)[C@@H](C(C#N)C#N)C(C#N)=C5)c2C#N)[C@@H]1C(C#N)C#N ; N#CC1=C[C@@H](C(C#N)C#N)c2c1c(C#N)c1oc3c(C#N)c4c(c(C#N)c3c1c2C#N)[C@@H](C(C#N)C#N)C=C4C#N] 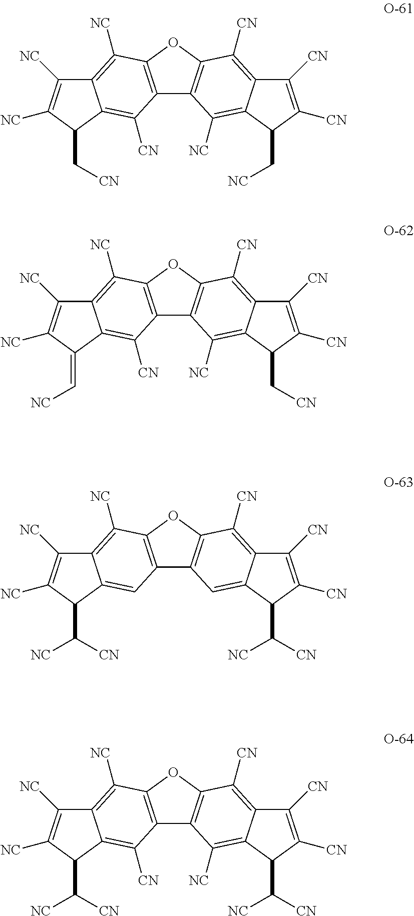 [SMILES: N#CC[C@@H]1C(C#N)=C(C#N)c2c1c(C#N)c1c(oc3c(C#N)c4c(c(C#N)c31)[C@@H](CC#N)C(C#N)=C4C#N)c2C#N ; N#C/C=C1\C(C#N)=C(C#N)c2c1c(C#N)c1c(oc3c(C#N)c4c(c(C#N)c31)[C@H](CC#N)C(C#N)=C4C#N)c2C#N ; N#CC1=C(C#N)[C@@H](C(C#N)C#N)c2cc3c(oc4c(C#N)c5c(cc43)[C@@H](C(C#N)C#N)C(C#N)=C5C#N)c(C#N)c21 ; N#CC1=C(C#N)[C@@H](C(C#N)C#N)c2c1c(C#N)c1oc3c(C#N)c4c(c(C#N)c3c1c2C#N)[C@@H](C(C#N)C#N)C(C#N)=C4C#N] 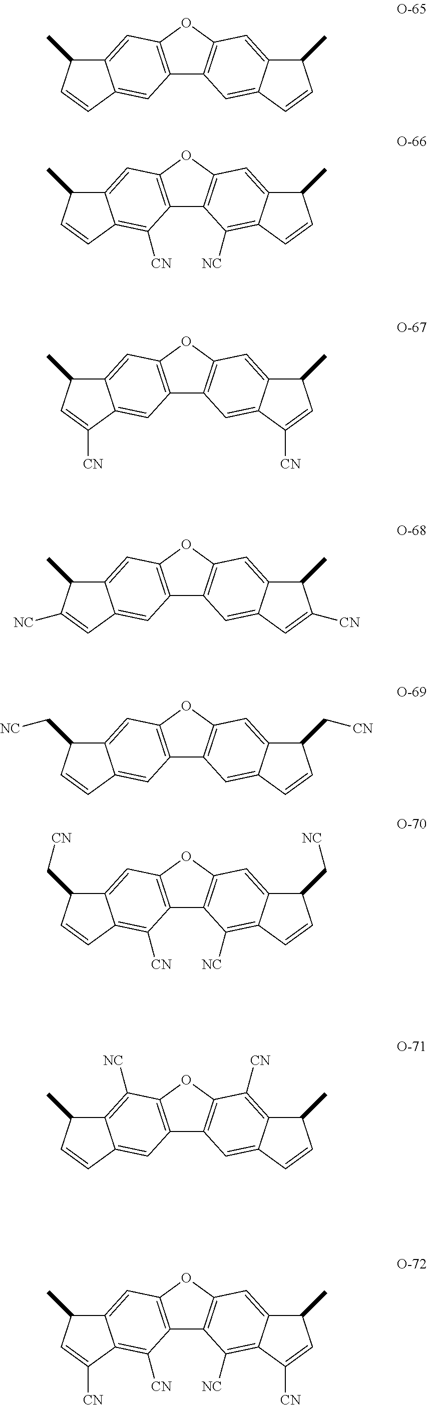 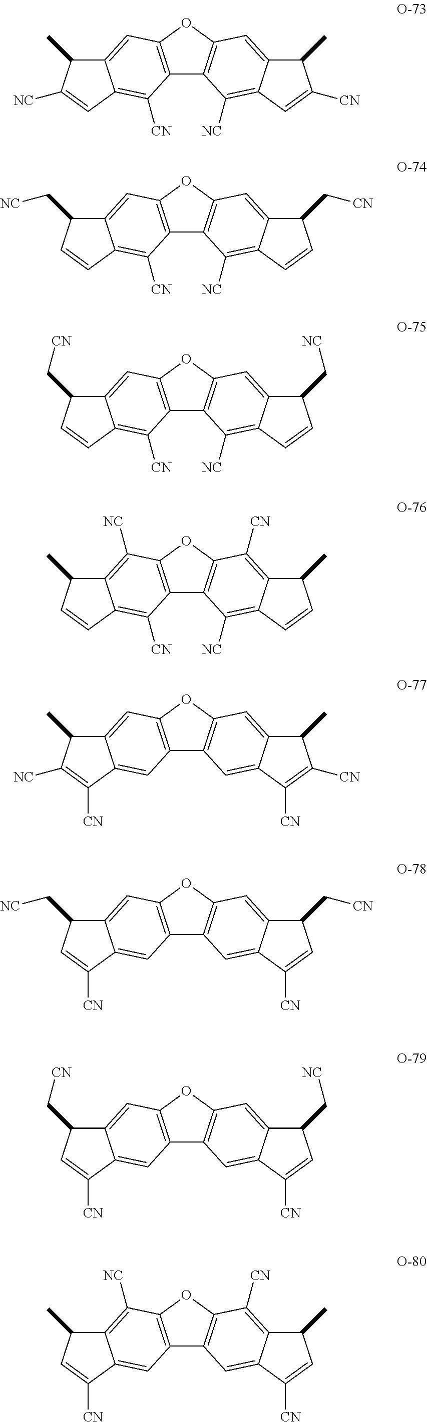 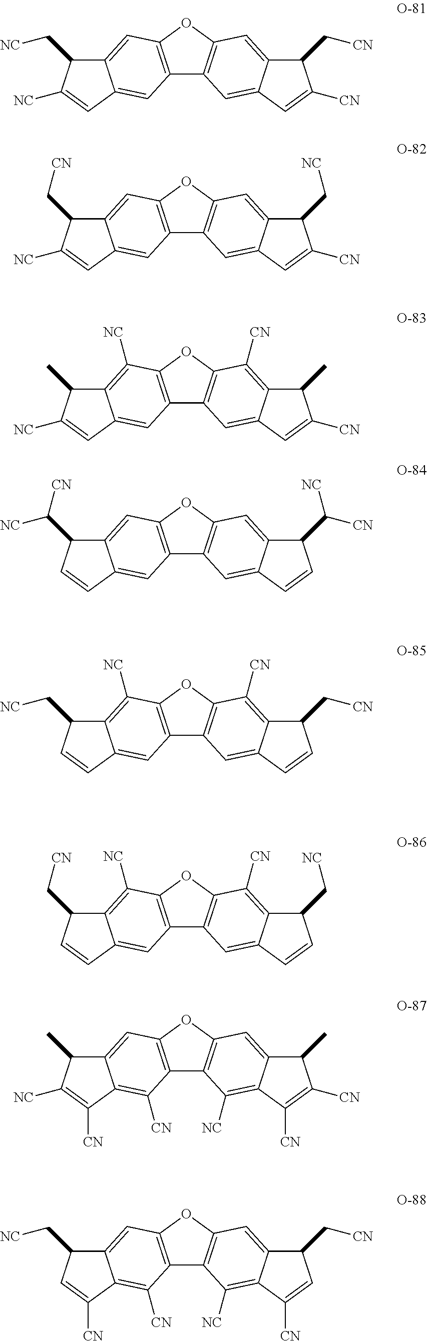 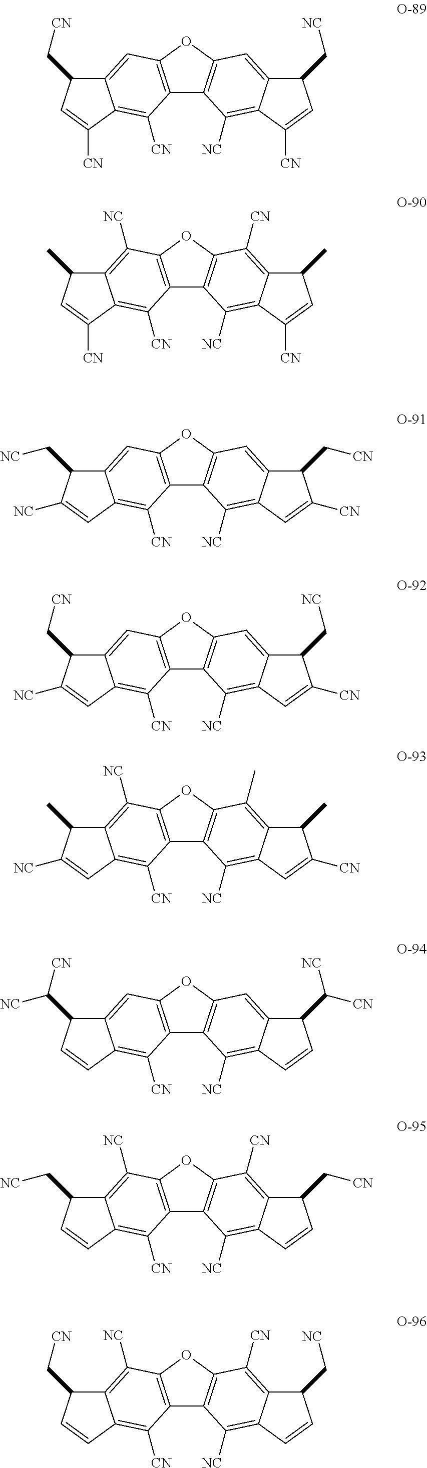 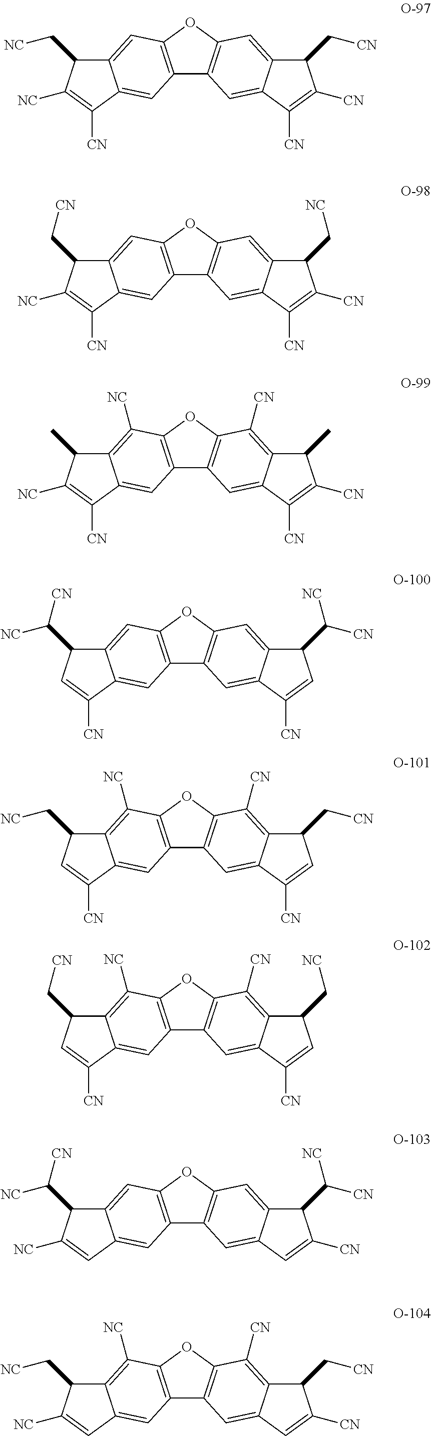 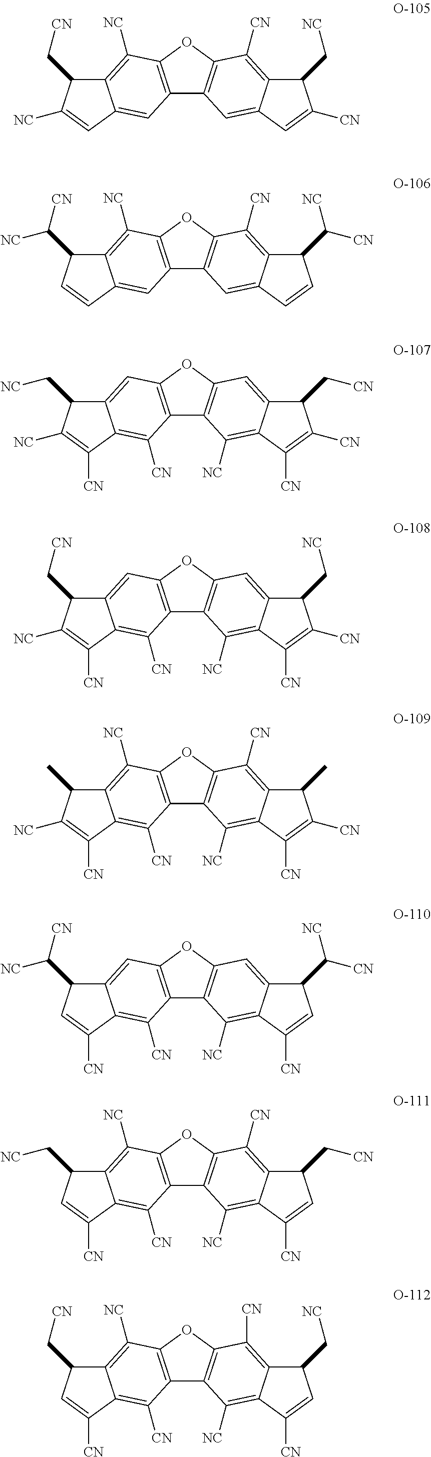 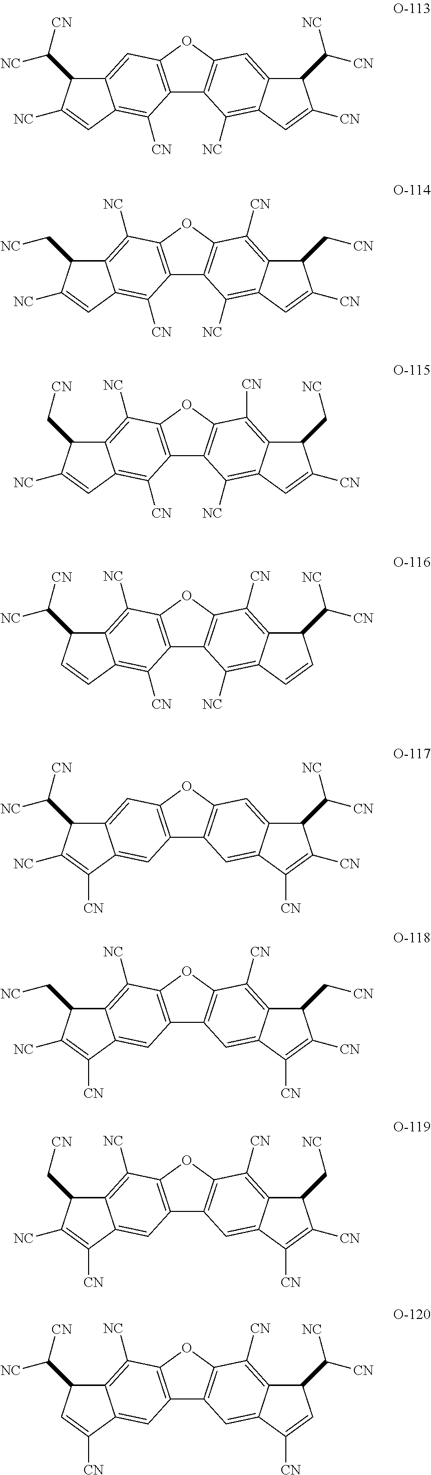 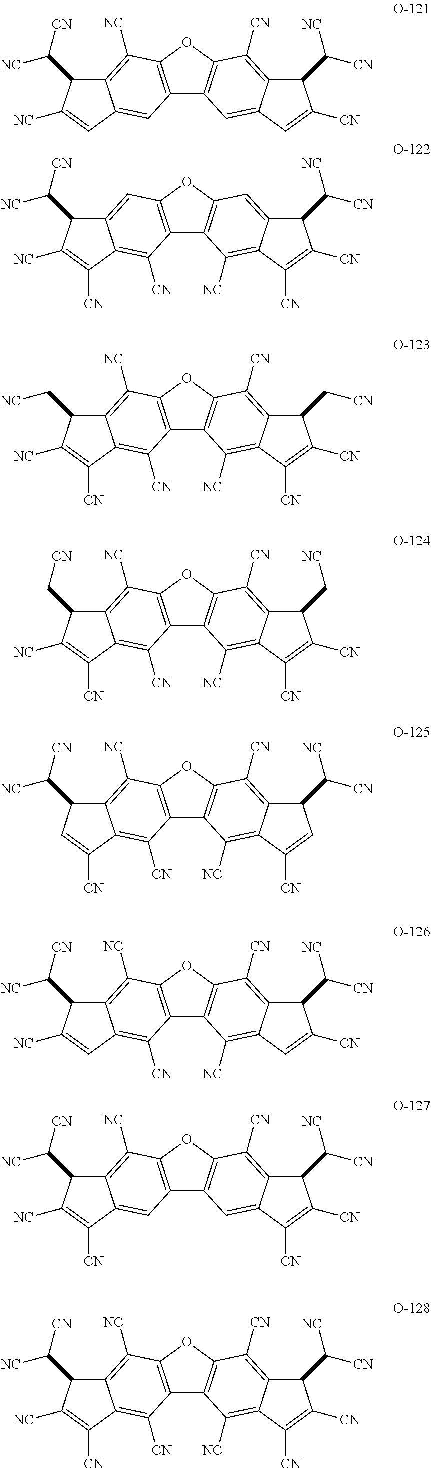 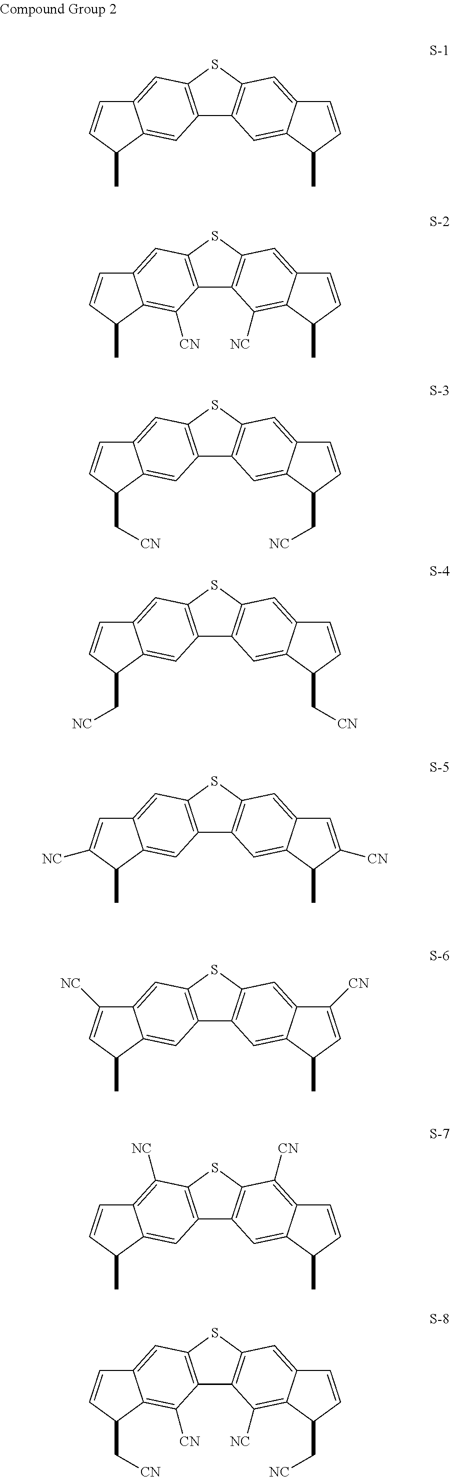 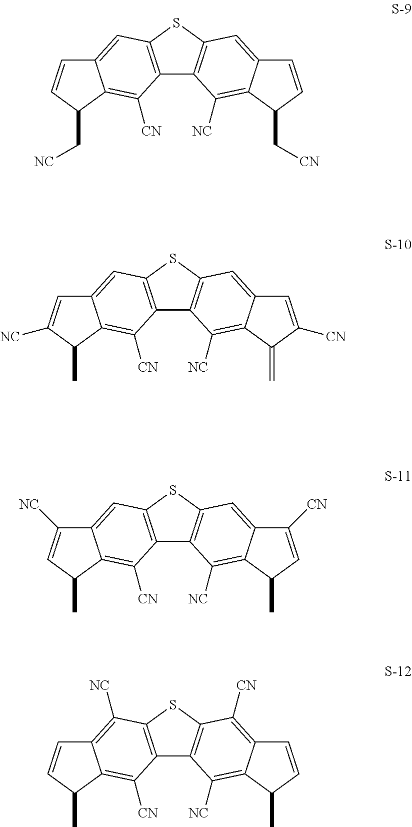 [SMILES: N#CC[C@H]1C=Cc2cc3sc4cc5c(c(C#N)c4c3c(C#N)c21)[C@H](CC#N)C=C5 ; C=C1C(C#N)=Cc2cc3sc4cc5c(c(C#N)c4c3c(C#N)c21)[C@@H](C)C(C#N)=C5 ; C[C@@H]1C=C(C#N)c2cc3sc4cc5c(c(C#N)c4c3c(C#N)c21)[C@@H](C)C=C5C#N ; C[C@@H]1C=Cc2c1c(C#N)c1c(sc3c(C#N)c4c(c(C#N)c31)[C@@H](C)C=C4)c2C#N] 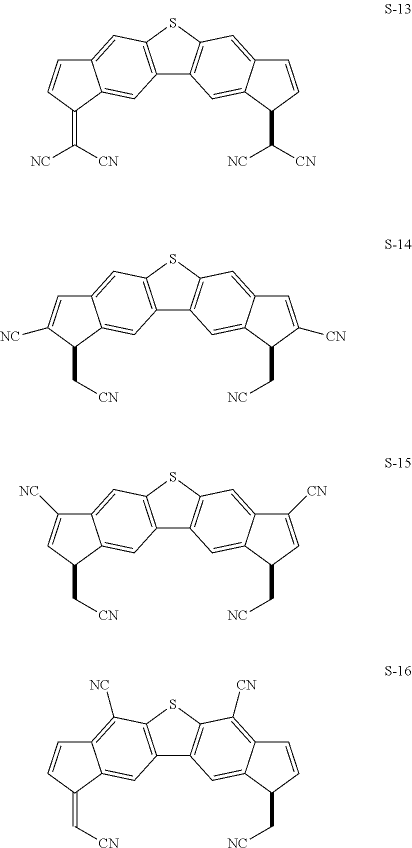 [SMILES: N#CC(C#N)=C1C=Cc2cc3sc4cc5c(cc4c3cc21)[C@H](C(C#N)C#N)C=C5 ; N#CC[C@@H]1C(C#N)=Cc2cc3sc4cc5c(cc4c3cc21)[C@@H](CC#N)C(C#N)=C5 ; N#CC[C@H]1C=C(C#N)c2cc3sc4cc5c(cc4c3cc21)[C@H](CC#N)C=C5C#N ; N#C/C=C1/C=Cc2c1cc1c(sc3c(C#N)c4c(cc31)[C@H](CC#N)C=C4)c2C#N] 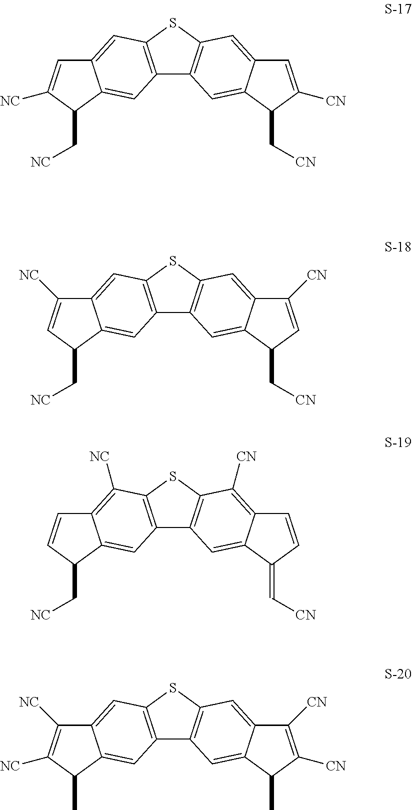 [SMILES: N#CC[C@@H]1C(C#N)=Cc2cc3sc4cc5c(cc4c3cc21)[C@@H](CC#N)C(C#N)=C5 ; N#CC[C@H]1C=C(C#N)c2cc3sc4cc5c(cc4c3cc21)[C@H](CC#N)C=C5C#N ; N#C/C=C1\C=Cc2c1cc1c(sc3c(C#N)c4c(cc31)[C@@H](CC#N)C=C4)c2C#N ; C[C@@H]1C(C#N)=C(C#N)c2cc3sc4cc5c(cc4c3cc21)[C@@H](C)C(C#N)=C5C#N] 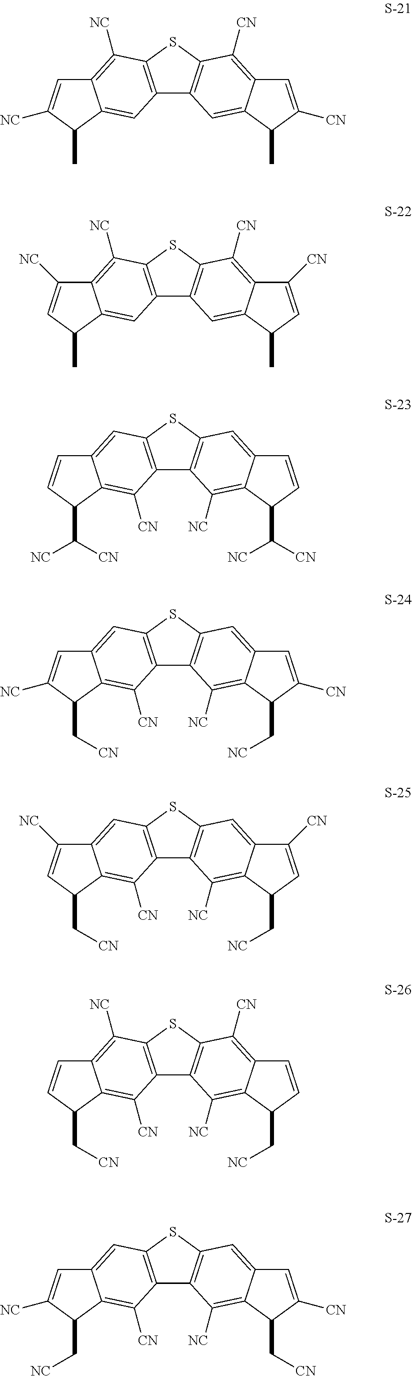 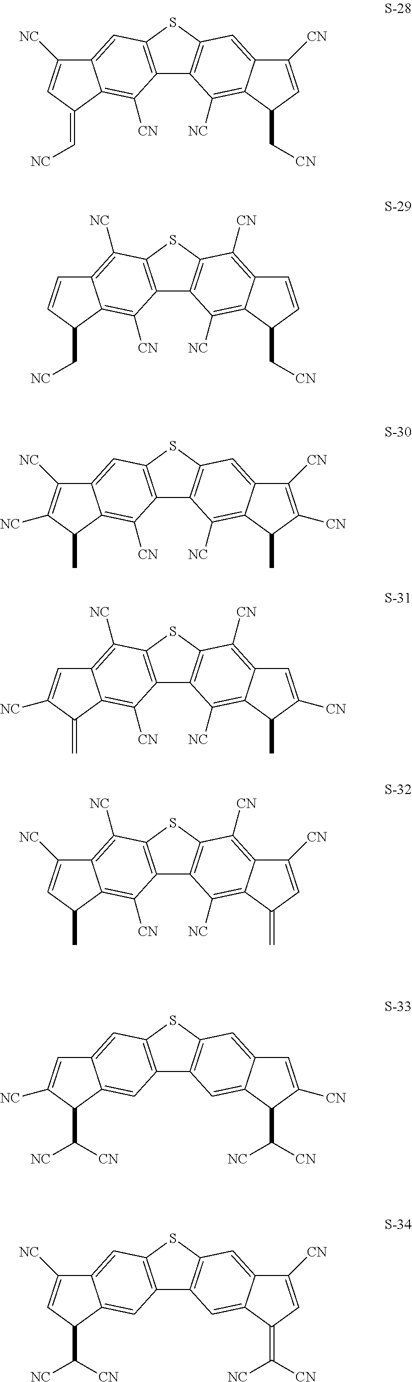 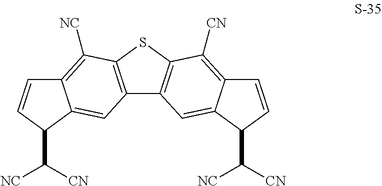 [SMILES: N#Cc1c2c(cc3c1sc1c(C#N)c4c(cc13)[C@@H](C(C#N)C#N)C=C4)[C@H](C(C#N)C#N)C=C2] 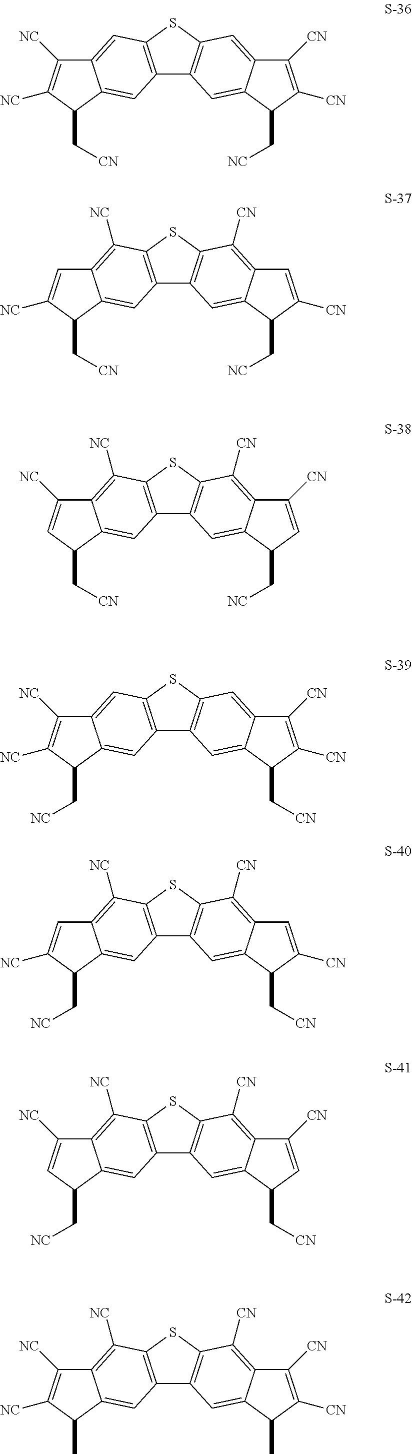 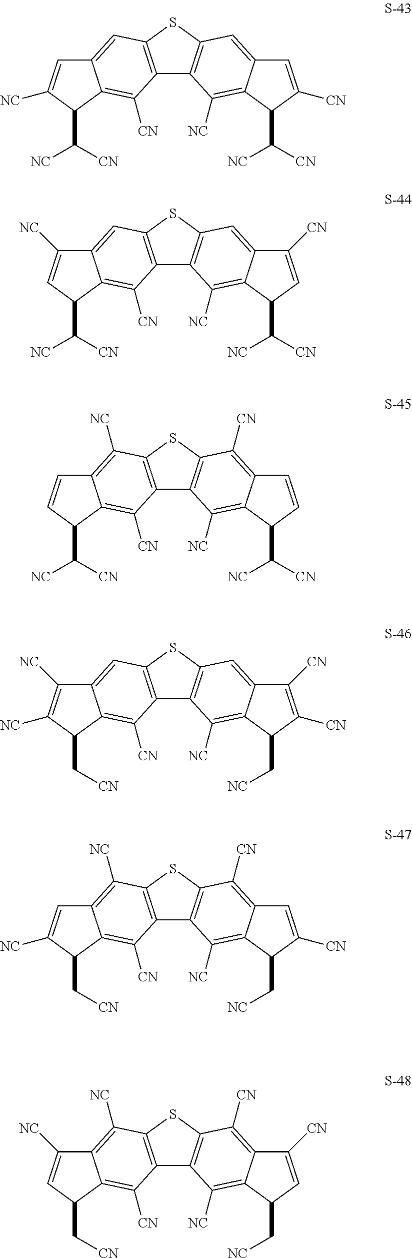 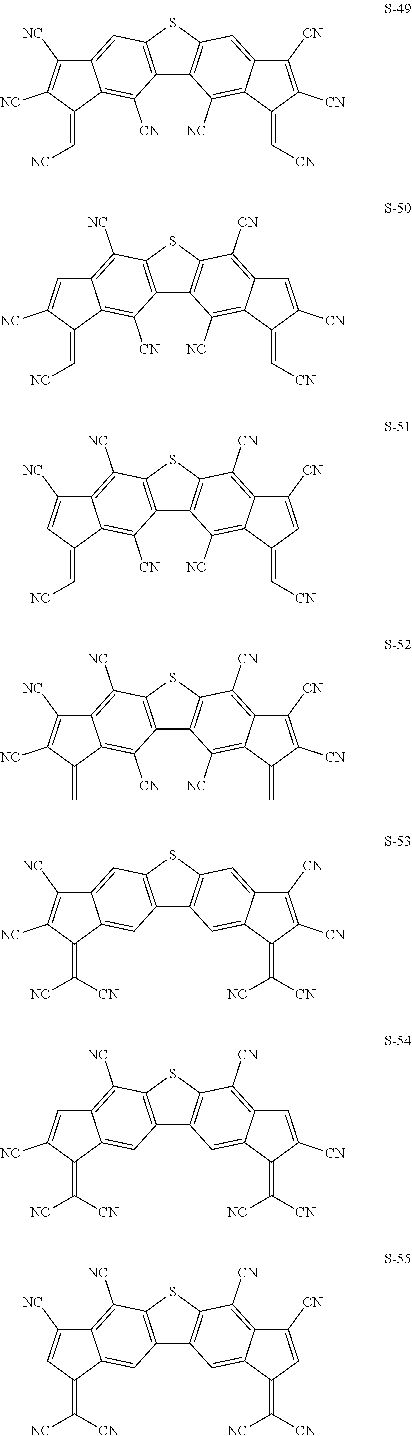 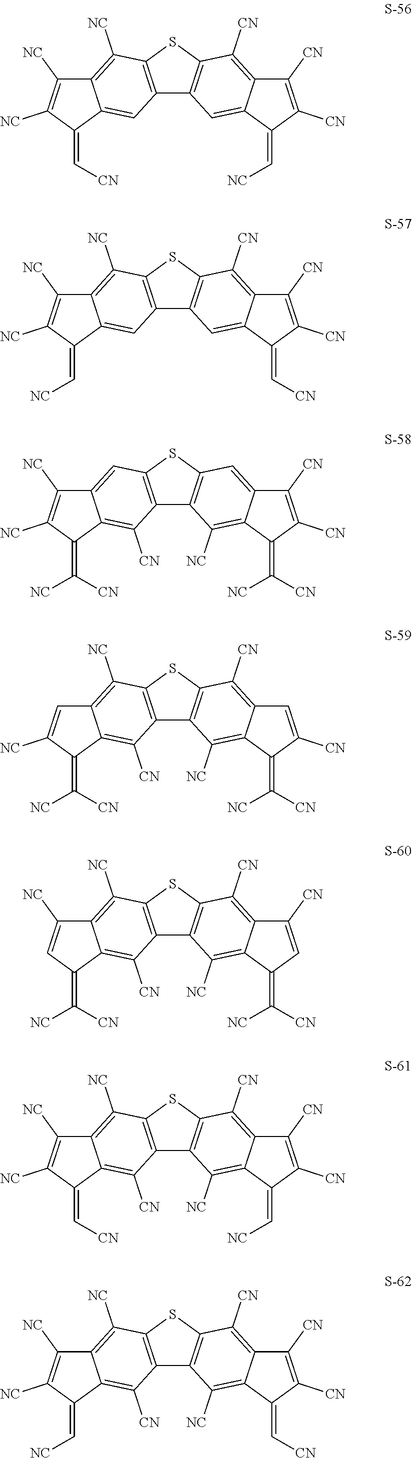 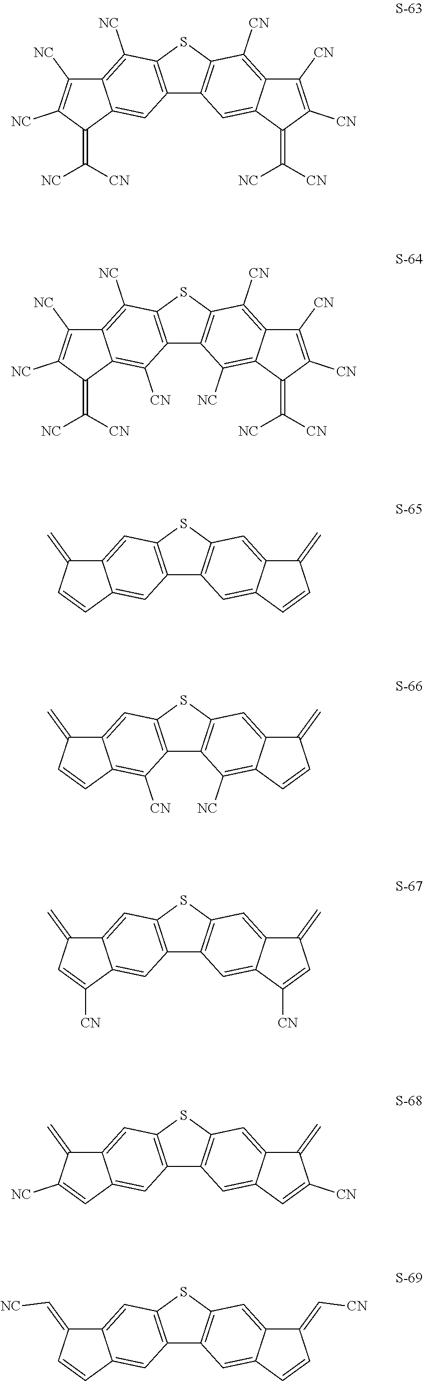 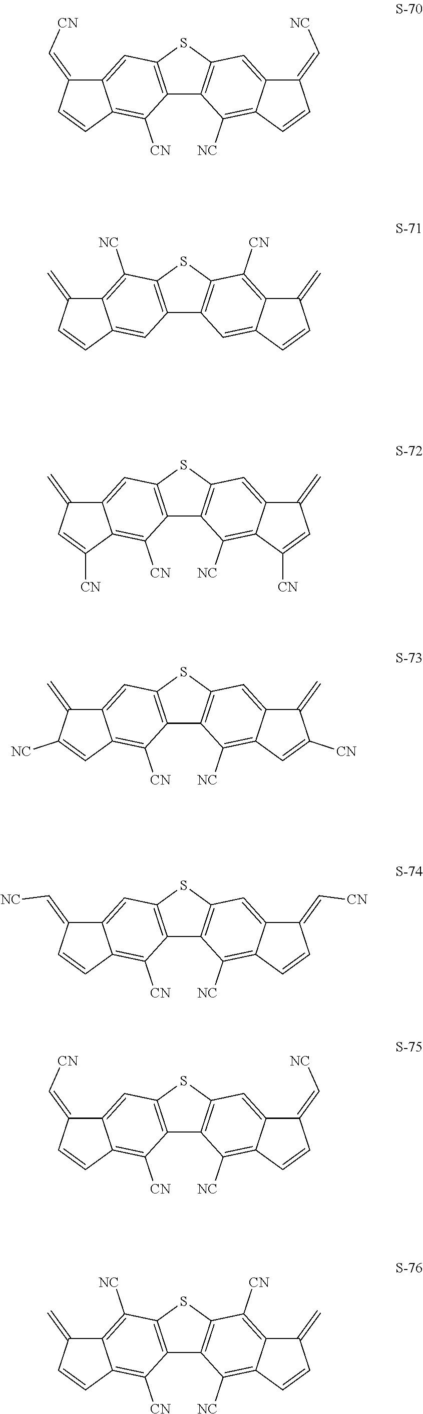 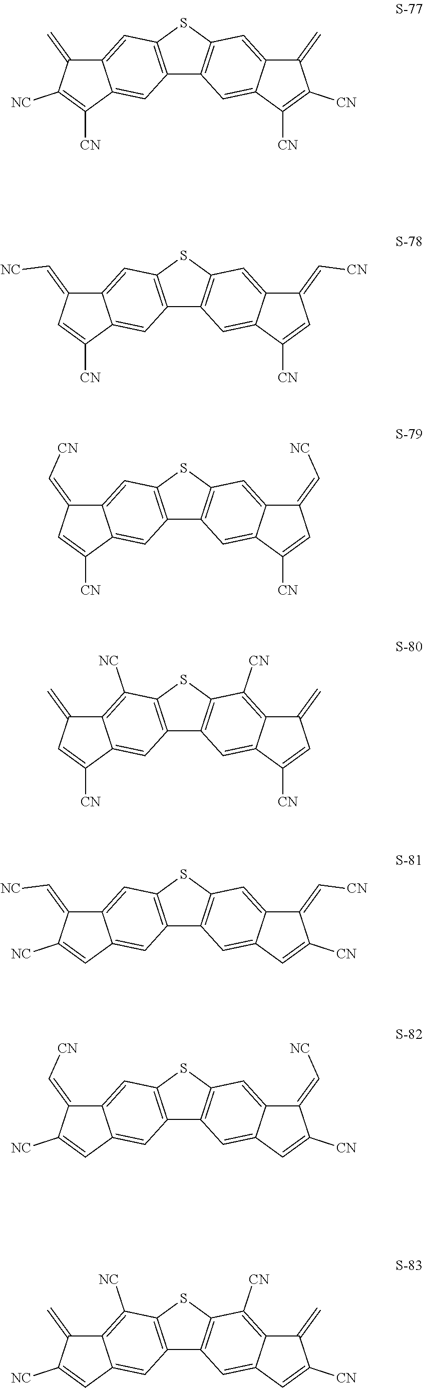 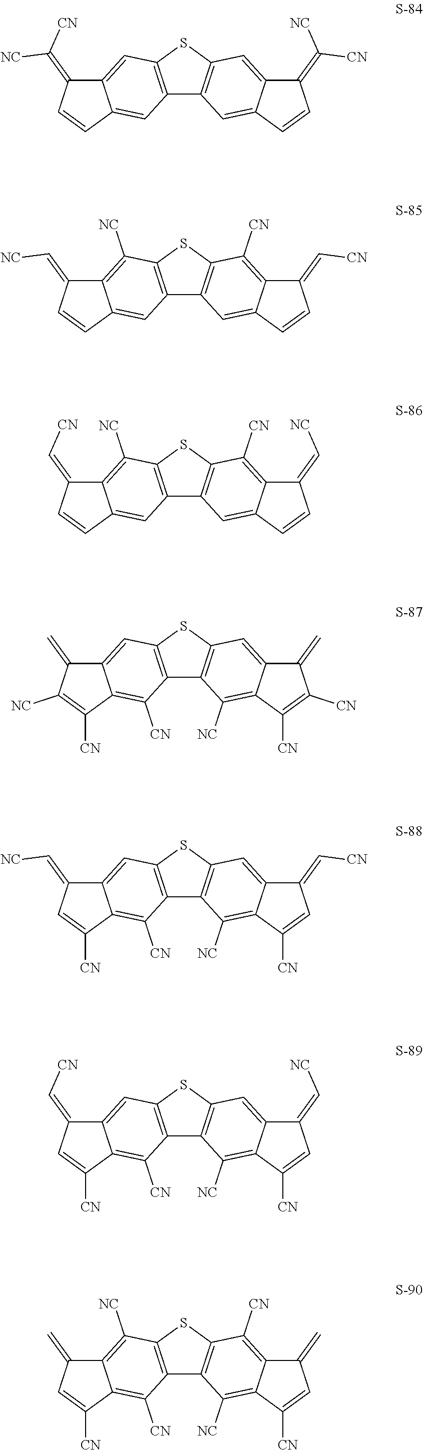 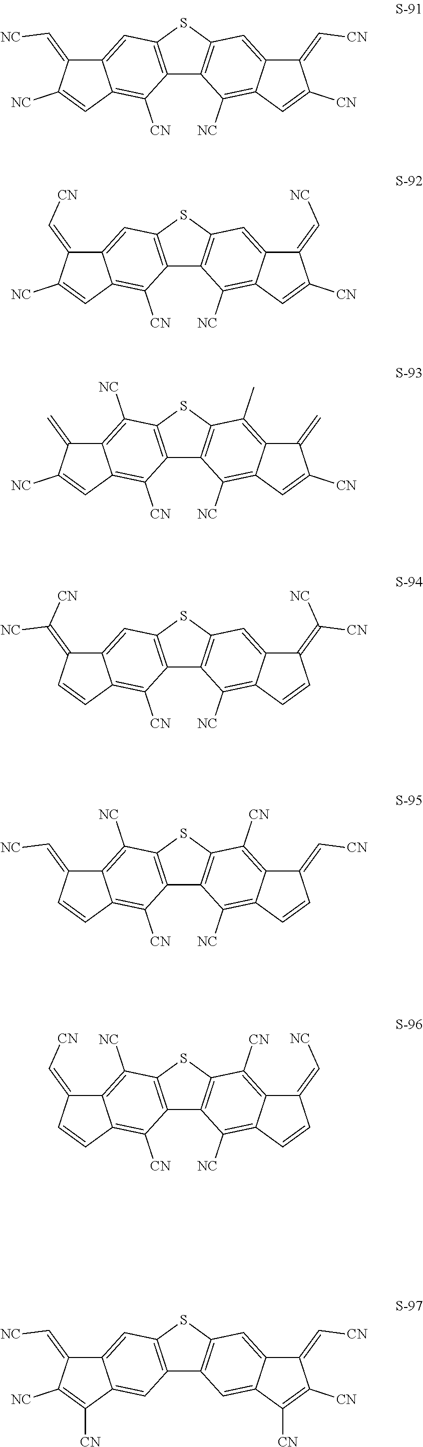 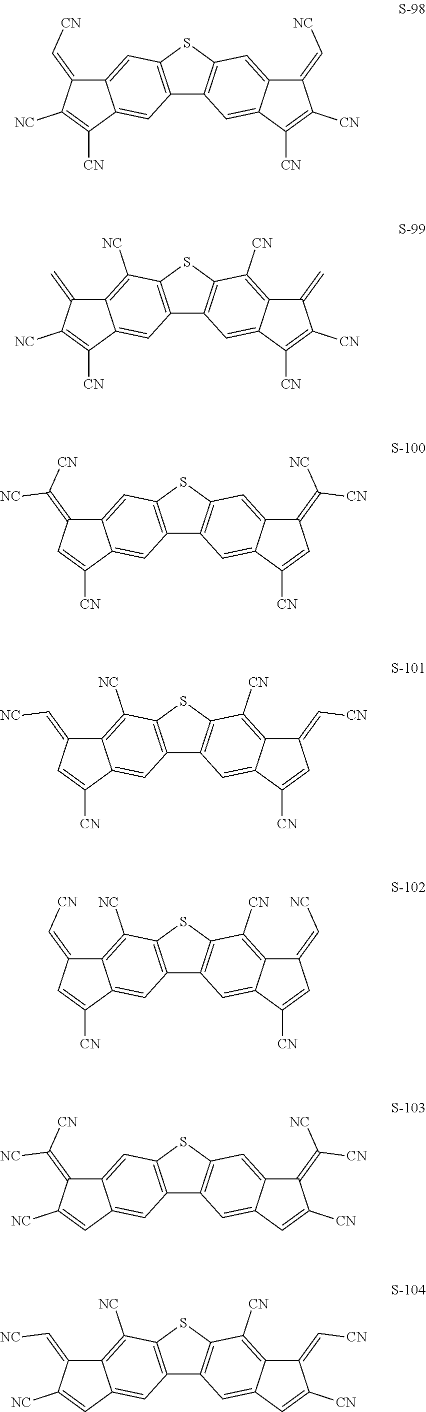 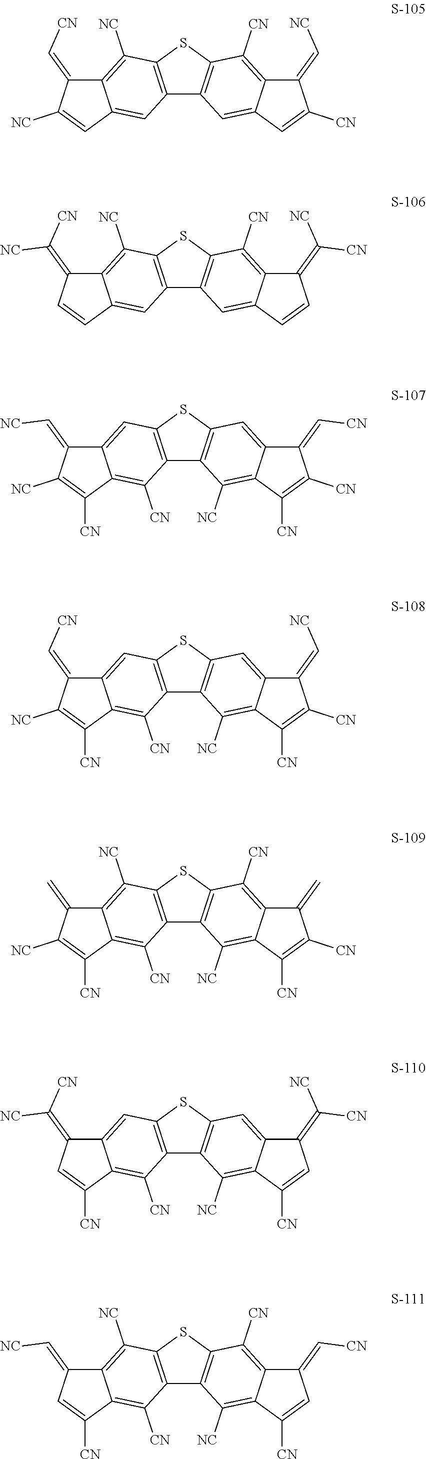 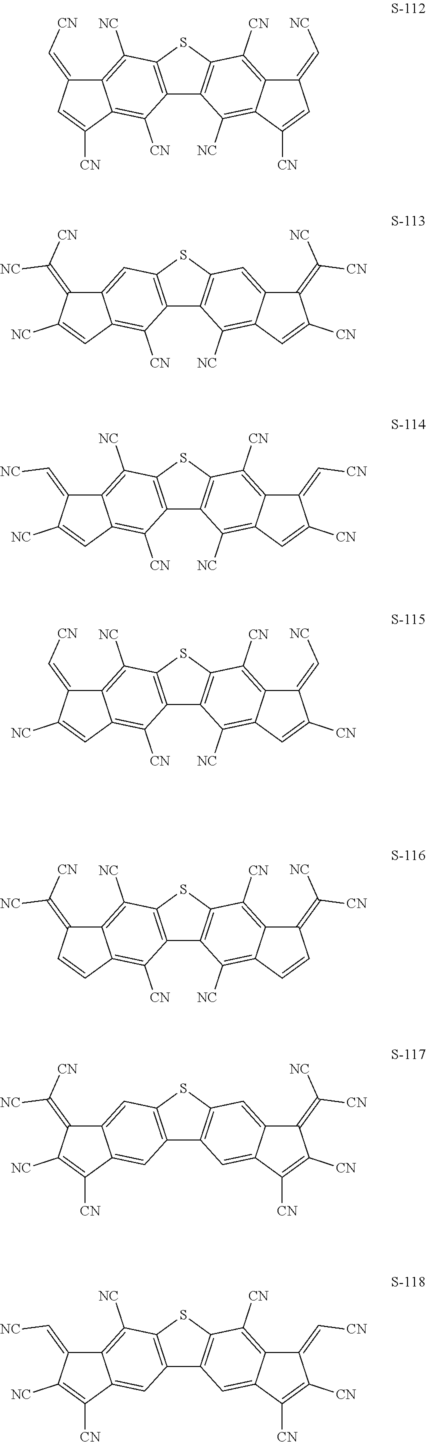 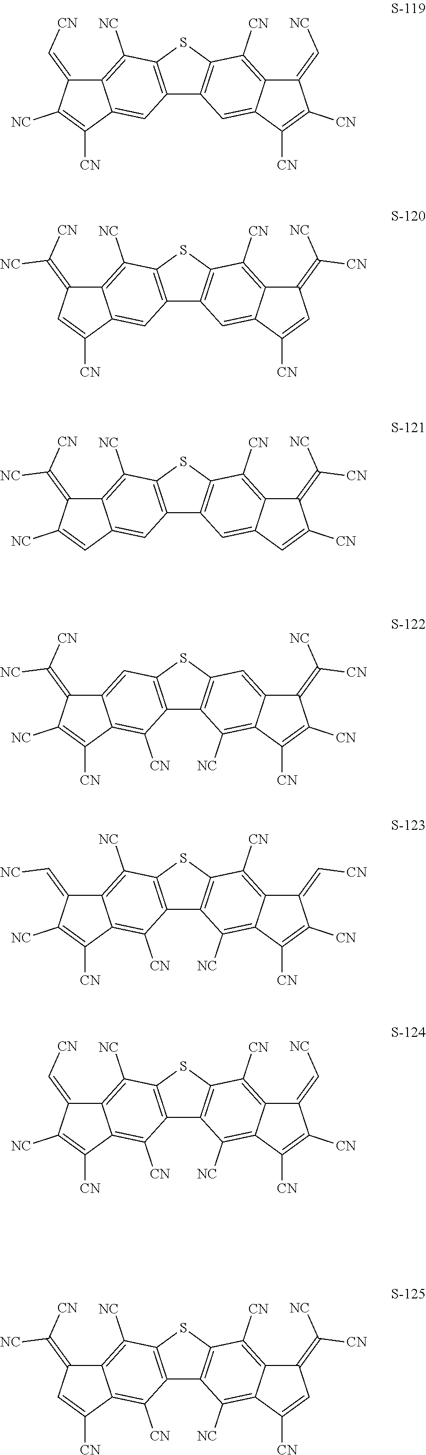 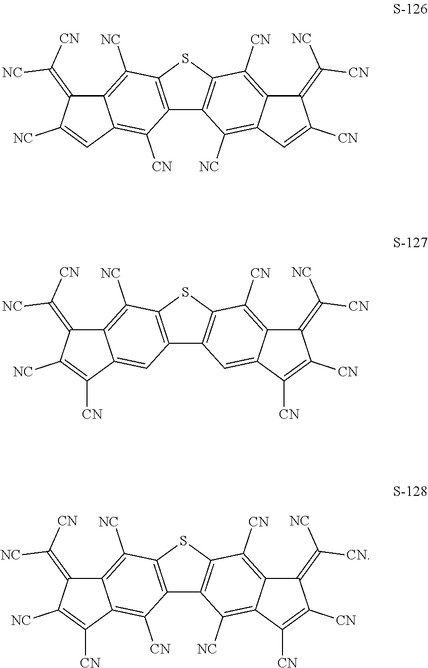 [SMILES: N#CC1=Cc2c(c(C#N)c3sc4c(C#N)c5c(c(C#N)c4c3c2C#N)C=C(C#N)C5=C(C#N)C#N)C1=C(C#N)C#N ; N#CC(C#N)=C1C(C#N)=C(C#N)c2cc3c(sc4c(C#N)c5c(cc43)C(C#N)=C(C#N)C5=C(C#N)C#N)c(C#N)c21 ; N#CC(C#N)=C1C(C#N)=C(C#N)c2c1c(C#N)c1sc3c(C#N)c4c(c(C#N)c3c1c2C#N)C(C#N)=C(C#N)C4=C(C#N)C#N]
